(19) United States
(12) Patent Application Publication
(10) Pub. No.: US 2026/0190600 A1
(43) Pub. Date: Jul. 2, 2026

(54) Light-Emitting Element, Nitrogen-Containing Compound For The Same, And Electronic Apparatus Including The Same

(71) Applicant: Samsung Display Co., Ltd., Yongin-si (KR)

(72) Inventors: Hyoyoung Lee, Yongin-si (KR); Youngjin Park, Yongin-si (KR); Heechoon Ahn, Yongin-si (KR); Hyunah Um, Yongin-si (KR); Juhui Yun, Yongin-si (KR)

(73) Assignee: Samsung Display Co., Ltd., Yongin-si (KR)

(21) Appl. No.: 19/394,144

(22) Filed: Nov. 19, 2025

(30) Foreign Application Priority Data
Dec. 27, 2024 (KR) 10-2024-0198986

(51) Int. Cl. H10K 50/11; H10K 50/15; H10K 85/30; H10K 85/40; H10K 85/60; H10K 101/00

(52) U.S. Cl. CPC H10K 50/11; H10K 50/156; H10K 85/342; H10K 85/346; H10K 85/40; H10K 85/622; H10K 85/623; H10K 85/626; H10K 85/633; H10K 85/636; H10K 85/654; H10K 85/6572; H10K 85/6574; H10K 85/6576; H10K 85/658; H10K 2101/90

(57) ABSTRACT

A light-emitting element may include a first electrode, a second electrode facing the first electrode, and a functional layer disposed between the first electrode and the second electrode. The functional layer may include a nitrogen-containing compound represented by Formula 1-1 below. All the variables in Formula 1-1 are described in detail herein. The light-emitting element may be capable of exhibiting excellent color reproducibility and may have long lifespan characteristics.

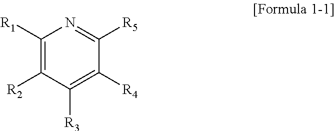

### CROSS-REFERENCE TO RELATED APPLICATIONS

This U.S. non-provisional patent application claims priority under 35 U.S.C. § 119 to Korean Patent Application No. 10-2024-0198986, filed on Dec. 27, 2024, the entire contents of which are hereby incorporated by reference.

### TECHNICAL FIELD

The present disclosure relates to a light-emitting element, a nitrogen-containing compound used for the same, and an electronic apparatus including the light-emitting element.

### BACKGROUND

Recently, organic electroluminescence display devices as image display devices have been actively developed. The organic electroluminescence display devices and the like are display devices including so-called self-luminous type light-emitting element, which recombine, in an emission layer, holes and electrons injected respectively from a first electrode and a second electrode, thereby emitting light using an emission material in the emission layer to implement displaying.

In applying a light-emitting element to display devices, improvements in luminous efficiency, lifespan, and the like are required, and the development of materials for a light-emitting element capable of stably achieving these improvements is continuously required.

### SUMMARY

The present disclosure provides a light-emitting element having improved luminous efficiency and lifespan.

The present disclosure also provides a nitrogen-containing compound having an improved material lifespan.

The present disclosure also provides an electronic apparatus including the light-emitting element having improved luminous efficiency and lifespan to thereby have excellent display quality.

An aspect of the present disclosure provides a light-emitting element that includes a first electrode, a second electrode on the first electrode, and at least one functional layer disposed between the first electrode and the second electrode and including a nitrogen-containing compound represented by any one among Formula 1-1 to Formula 1-4 below.

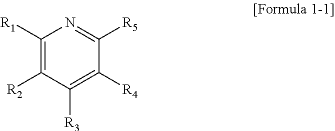

In Formula 1-1 above, R₁ to R₅ are each independently a hydrogen atom, a deuterium atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, at least any one among R₁ to R₅ is a substituent represented by Formula 2 below, and at least another one among R₁ to R₅ is a substituent represented by Formula 3 below.

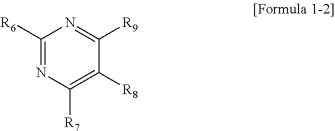

In Formula 1-2 above, R₆ to R₉ are each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, at least any one among R₆ to R₉ is a substituent represented by Formula 2 below, and at least another one among R₆ to R₉ is a substituent represented by Formula 3 below.

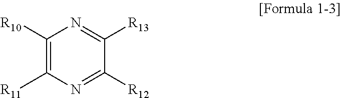

In Formula 1-3 above, R₁₀ to R₁₃ are each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, a substituted or unsubstituted heteroaryl group having 2 to 30 ring-forming carbons, a substituent represented by Formula 2 below, or a substituent represented by Formula 3 below, at least any one among R₁₀ to R₁₃ is a substituent represented by Formula 2 below, and at least another one among R₁₀ to R₁₃ is a substituent represented by Formula 3 below.

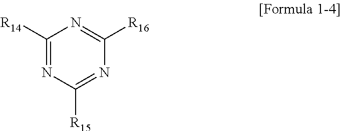

In Formula 1-4 above, R₁₄ to R₁₆ are each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, a substituted or unsubstituted heteroaryl group having 2 to 30 ring-forming carbons, at least any one among R₁₄ to R₁₆ is a substituent represented by Formula 2 below, and at least another one among R₁₄ to R₁₆ is a substituent represented by Formula 3 below.

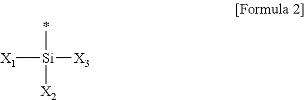

In formula 2 above, X₁ to X₃ are each independently a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and *— is a portion to which at least any one among Formula 1-1 to Formula 1-4 above is connected.

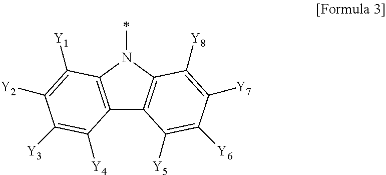

In Formula 3 above, any one among Y₁ to Y₈ is a substituent represented by Formula 4 below, and the others of Y₁ to Y₈ are each independently a hydrogen atom, a deuterium atom, a halogen atom, a cyano group, a substituted or unsubstituted alkyl group having 1 to 20 carbons, or a substituted or unsubstituted aryl group having 6 to 30 ring-forming carbons, and *— is a portion to which at least any one among Formula 1-1 to Formula 1-4 above is connected:

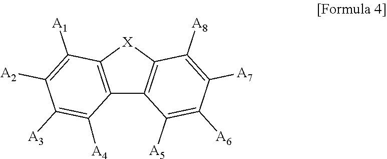

In Formula 4 above, X is O, S, or NA₉, any one among A₁ to A₉ is a portion to which Formula 3 above is connected, and the others of A₁ to A₉ are each independently a hydrogen atom, a deuterium atom, a halogen atom, a cyano group, a substituted or unsubstituted alkyl group having 1 to 20 carbons, or a substituted or unsubstituted aryl group having 6 to 30 ring-forming carbons.

In an aspect, the at least one functional group may include a hole transport region disposed on the first electrode, an emission layer disposed on the hole transport region, and an electron transport region disposed on the emission layer, and the hole transport region or the emission layer may include a first compound represented by any one among Formula 1-1 or Formula 1-4 above.

In an aspect, the hole transport region may include a hole injection layer disposed on the first electrode, and a hole transport layer disposed on the hole injection layer, and the hole transport layer may include the first compound represented by any one among Formula 1-1 to Formula 1-4 above.

In an aspect, the hole transport layer may include a first hole transport layer disposed on the hole injection layer and a second hole transport layer disposed on the first hole transport layer, and the second hole transport layer comprises the first compound represented by any one among Formula 1-1 to Formula 1-4 above.

In an aspect, the first hole transport layer may include a compound represented by Formula H-1 below.

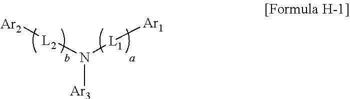

In Formula H-1 above, L₁ and L₂ may be each independently a direct linkage, a substituted or unsubstituted arylene group having 6 to 30 ring-forming carbons, or a substituted or unsubstituted heteroarylene group having 2 to 30 ring-forming carbons, Ar₁ and Ar₂ may be each independently a substituted or unsubstituted aryl group having 6 to 30 ring-forming carbons, or a substituted or unsubstituted heteroaryl group having 2 to 30 ring-forming carbons, Ar₃ may be a substituted or unsubstituted aryl group having 6 to 30 ring-forming carbons, and a and b may be each independently an integer of 0 to 10.

In an aspect, the emission layer may include a host, and a dopant doped into the host, and the host may include the first compound represented by any one among Formula 1-1 to Formula 1-4 above.

In an aspect the host further may include a second compound different from the first compound, and the second compound is represented by Formula ET-1 below.

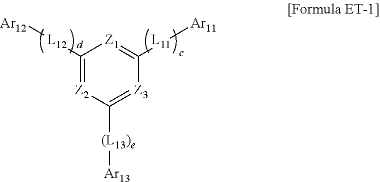

In Formula ET-1 above, Z₁ to Z₃ may be all N, L₁₁ to L₁₃ may be each independently a direct linkage, a substituted or unsubstituted arylene group having 6 to 30 ring-forming carbons, or a substituted or unsubstituted heteroarylene group having 2 to 30 ring-forming carbons, Ar₁₁ to Ar₁₃ may be each independently a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and c to e may be each independently an integer of 0 to 10.

In an aspect, the substituent represented by Formula 3 above is represented by Formula 3-1 or Formula 3-2 below.

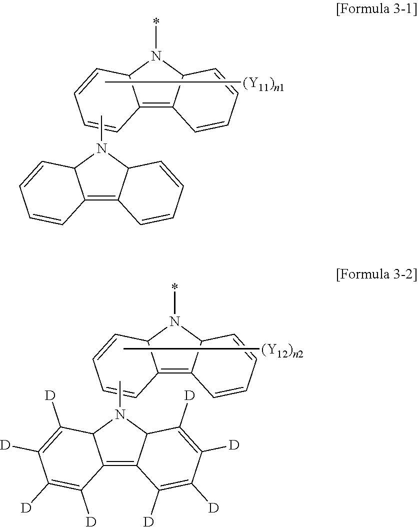

In Formula 3-1 and Formula 3-2 above, Y₁₁ and Y₁₂ may be each independently a hydrogen atom, a deuterium atom, or a substituted or unsubstituted alkyl group having 1 to 10 carbons, n1 and n2 may be each independently an integer of 0 to 7, and “D” may be a deuterium atom.

In an aspect, the substituent represented by Formula 2 above may be represented by any one among Formula 2-1 to Formula 2-6 below.

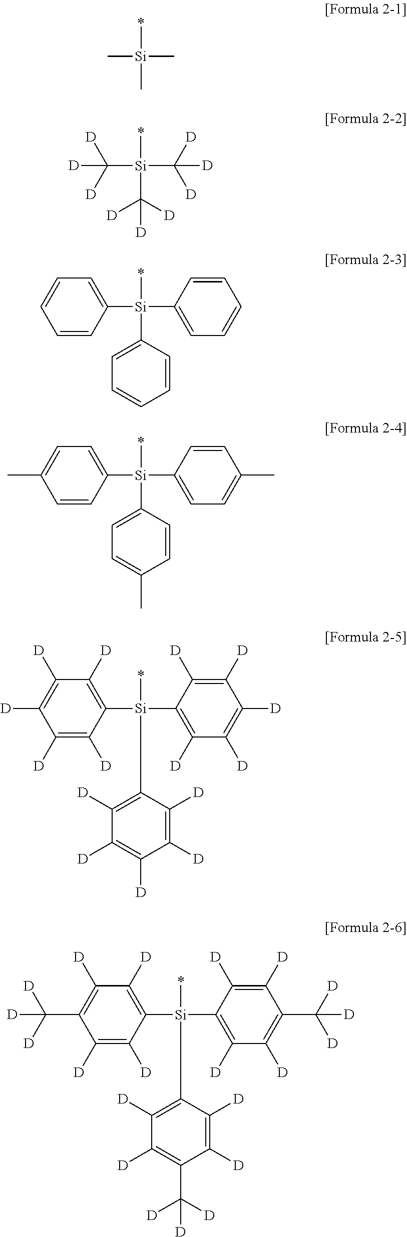

In Formula 2-1 to Formula 2-6 above, “D” may be a deuterium atom.

In an aspect, the first compound represented by Formula 1-1 above may be represented by any one among Formula 1-1-1 to Formula 1-1-6 below.

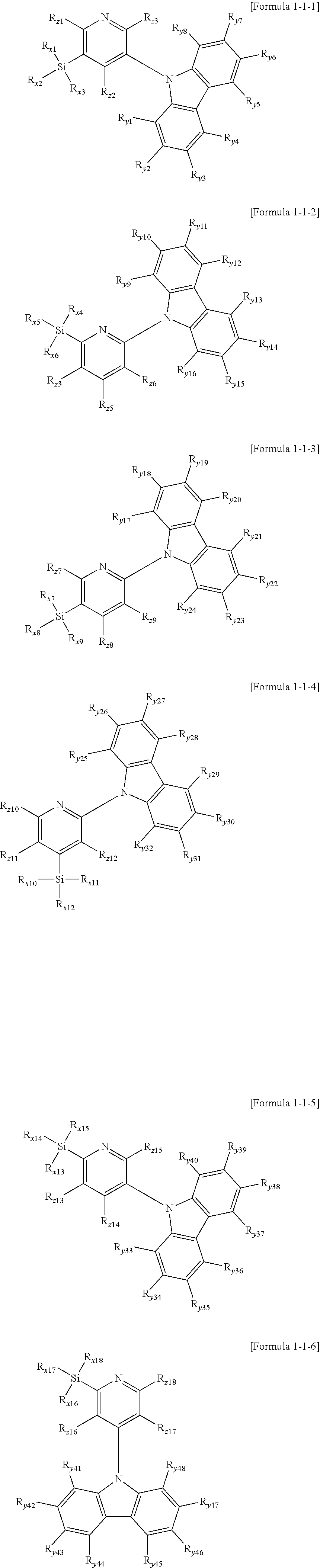

In Formula 1-1-1 to Formula 1-1-6 above, Rₓ₁ to Rₓ₁₈ may be each independently, a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, R_{z1} to R_{z18} may be each independently, a hydrogen atom, a deuterium atom, a halogen atom, a cyano group, or a substituted or unsubstituted alkyl group having 1 to 20 carbons, in Formula 1-1-1 above, any one among R_{y1} to R_{y8} may be a substituent represented by Formula 4 above, and the others of R_{y1} to R_{y8} may be each independently a hydrogen atom, or a deuterium atom, in Formula 1-1-2 above, any one among R_{y9} to R_{y16} is a substituent represented by Formula 4 above, and the others of R_{y9} to R_{y16} may be each independently a hydrogen atom, or a deuterium atom, in Formula 1-1-3 above, any one among R_{y17} to R_{y24} may be a substituent represented by Formula 4 above, and the others of R_{y17} to R_{y24} may be each independently a hydrogen atom, or a deuterium atom, in Formula 1-1-4 above, any one among R_{y25} to R_{y32} may be a substituent represented by Formula 4 above, and the others of R_{y25} to R_{y32} may be each independently a hydrogen atom, or a deuterium atom, in Formula 1-1-5 above, any one among R_{y33} to R_{y40} may be a substituent represented by Formula 4 above, and the others of R_{y33} to R_{y40} may be each independently a hydrogen atom, or a deuterium atom, and in Formula 1-1-6 above, any one among R_{y41} to R_{y48} may be a substituent represented by Formula 4 above, and the others of R_{y41} to R_{y48} may be each independently a hydrogen atom, or a deuterium atom.

In an aspect, the first compound represented by Formula 1-2 above is represented by any one among Formula 1-2-1 to Formula 1-2-4 below.

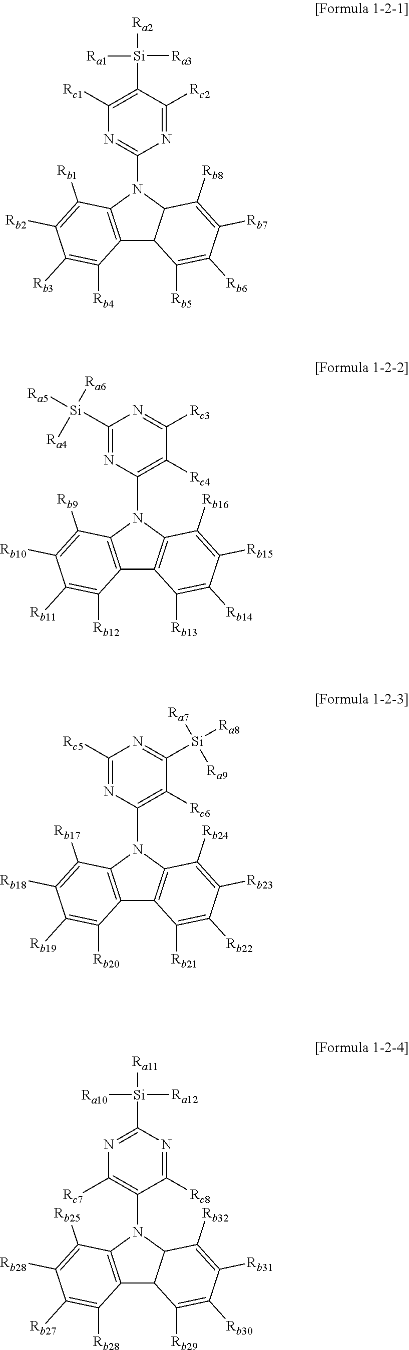

In Formula 1-2-1 to Formula 1-2-4 above, Rₐ₁ to Rₐ₁₂ may be each independently, a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, R_{c1} to R_{c8} may be each independently, a hydrogen atom, a deuterium atom, a halogen atom, a cyano group, or a substituted or unsubstituted alkyl group having 1 to 20 carbons, in Formula 1-2-1 above, any one among R_{b1} to R_{b8} may be a substituent represented by Formula 4 above, and the others of R_{b1} to R_{b8} may be each independently a hydrogen atom, or a deuterium atom, in Formula 1-2-2 above, any one among R_{b9} to R_{b16} may be a substituent represented by Formula 4 above, and the others of R_{b9} to R_{b16} may be each independently a hydrogen atom, or a deuterium atom, in Formula 1-2-3 above, any one among R_{b17} to R_{b24} may be a substituent represented by Formula 4 above, and the others of R_{b17} to R_{b24} may be each independently a hydrogen atom, or a deuterium atom, and in Formula 1-2-4 above, any one among R_{b25} to R_{b32} may be a substituent represented by Formula 4 above, and the others of R_{b25} to R_{b32} may be each independently a hydrogen atom, or a deuterium atom.

In an aspect, the first compound represented by Formula 1-3 above may be represented by Formula 1-3-1 below.

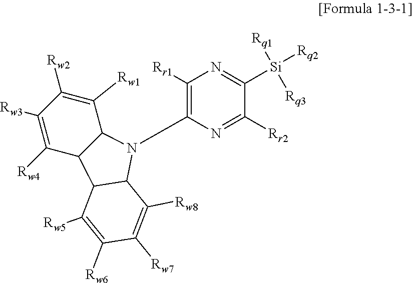

In Formula 1-3-1 above, Rᵣ₁ and Rᵣ₂ may be each independently, a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, R_{q1} to R_{q3} may be each independently, a hydrogen atom, a deuterium atom, a halogen atom, a cyano group, or a substituted or unsubstituted alkyl group having 1 to 20 carbons, and any one among Rᵥ₁ to Rᵥ₈ may be a substituent represented by Formula 4 above, and the others of Rᵥ₁ to Rᵥ₈ may be each independently a hydrogen atom, or a deuterium atom.

In an aspect, the first compound is represented by any one among compounds in Compound Group 1.

In an aspect of the present disclosure, a nitrogen-containing compound is represented by any one among Formula 1-1 to Formula 1-4.

In an aspect of the present disclosure, an electronic apparatus displaying an image includes a display device, and a control part configured to control the display device, the display device includes a base layer, a circuit layer disposed on the base layer, and a display element layer disposed on the circuit layer and including a light-emitting element, and the light-emitting element includes a first electrode, and a second electrode disposed on the first electrode, and at least one functional layer disposed between the first electrode and the second electrode and including a first compound represented by any one among Formula 1-1 to Formula 1-4 above.

### BRIEF DESCRIPTION OF THE DRAWINGS

The accompanying drawings are included to provide a further understanding of aspects of the present disclosure, and are incorporated in and constitute a part of this specification. The drawings illustrate aspects of the present disclosure and, together with the description, serve to explain principles of the present disclosure. In the drawings:

FIG. 1 is a plan view illustrating a display device according to an aspect;

FIG. 2 is a cross-sectional view illustrating a portion taken along line I-I′ in FIG. 1;

FIG. 3 is a cross-sectional view schematically illustrating a light-emitting element according to an aspect;

FIG. 4A is a cross-sectional view schematically illustrating a light-emitting element according to an aspect;

FIG. 4B is a cross-sectional view schematically illustrating a light-emitting element according to an aspect;

FIG. 5 is a cross-sectional view schematically illustrating a light-emitting element according to an aspect;

FIG. 6 is a cross-sectional view schematically illustrating a light-emitting element according to an aspect;

FIG. 7 is a cross-sectional view illustrating a display device according to an aspect;

FIG. 8 is a cross-sectional view illustrating a display device according to an aspect;

FIG. 9 is a cross-sectional view illustrating a display device according to an aspect;

FIG. 10 is a cross-sectional view illustrating a display device according to an aspect;

FIG. 11 shows schematic views of electronic apparatuses according to various embodiments; and

FIG. 12 is a view illustrating an inside of a vehicle in which a display device according to an aspect is disposed.

### DETAILED DESCRIPTION

It should be understood that aspects of the present disclosure may be modified in various manners and have many forms, and thus specific aspects will be exemplified in the drawings and described in detail in the detailed description. However, this is not intended to limit the present disclosure to the particular forms disclosed, but rather, is intended to cover all modifications, equivalents, and alternatives falling within the spirit and scope of the present disclosure.

When explaining each of drawings, like reference numbers are used for referring to like elements. In the accompanying drawings, the dimensions of each structure are exaggeratingly illustrated for clarity of the present disclosure. It will be understood that, although the terms “first,” “second,” etc., may be used herein to describe various components, these components should not be limited by these terms. These terms are only used to distinguish one component from another. For example, a first component could be termed a second component, and, similarly, a second component could be termed a first component, without departing from the scope of aspects of the present disclosure. As used herein, the singular forms, “a,” “an,” and “the” are intended to include the plural forms as well, unless the context clearly indicates otherwise.

In the present disclosure, it will be understood that the terms “include,” “have” or the like specify the presence of features, numbers, steps, operations, component, parts, or combinations thereof disclosed in the specification, but do not exclude the possibility of presence or addition of one or more other features, numbers, steps, operations, component, parts, or combinations thereof.

In the present disclosure, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “below”, “in a lower portion of” another layer, film, region, or plate, it can be not only directly under the layer, film, region, or plate, but intervening layers, films, regions, or plates may also be present. In addition, it will be understood that when a part is referred to as being “on” another part, it can be disposed above the other part, or disposed under the other part as well.

In the specification, the term “substituted or unsubstituted” may mean substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the specification, the phrase “bonded to an adjacent group to form a ring” may mean that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by being bonded to each other may be connected to another ring to form a spiro structure.

In the specification, the term “adjacent group” may mean a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but aspects of the present disclosure are not limited thereto.

In the specification, a cycloalkyl group may mean a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but aspects of the present disclosure are not limited thereto.

In the specification, an alkenyl group means a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, etc., but aspects of the present disclosure are not limited thereto.

In the specification, an alkynyl group means a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, etc., but are not limited thereto.

In the specification, the hydrocarbon ring group means any functional group or substituent derived from an aliphatic hydrocarbon ring. The hydrocarbon ring group may be a saturated hydrocarbon ring group having 5 to 20 ring-forming carbon atoms.

In the specification, an aryl group means any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but aspects of the present disclosure are not limited thereto.

In the specification, the fluorenyl group may be substituted, and two substituents may be bonded to each other to form a spiro structure. Examples of the substituted fluorenyl group are as follows. However, aspects of the present disclosure are not limited thereto.

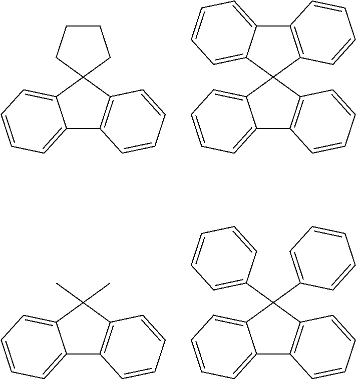

The heterocyclic group herein means any functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. If the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, S or Se as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but aspects of the present disclosure are not limited thereto.

In the specification, the heteroaryl group may contain at least one of B, O, N, P, Si, S or Se as a heteroatom. If the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but aspects of the present disclosure are not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the silyl group includes an alkylsilyl group or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but aspects of the present disclosure are not limited thereto.

In the specification, the number of ring-forming carbon atoms in the carbonyl group is not specifically limited, but may be 1 to 40, 1 to 30, or 1 to 20. For example, the carbonyl group may have the following structures, but aspects of the present disclosure are not limited thereto.

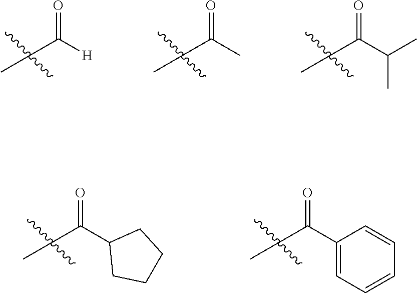

In the specification, the number of carbon atoms in the sulfinyl group and the sulfonyl group is not particularly limited, but may be 1 to 30. The sulfinyl group may include an alkyl sulfinyl group or an aryl sulfinyl group. The sulfonyl group may include an alkyl sulfonyl group or an aryl sulfonyl group.

In the specification, the thio group may include an alkylthio group or an arylthio group. The thio group may mean that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, or a naphthylthio group, but aspects of the present disclosure are not limited thereto.

In the specification, an oxy group may mean that an oxygen atom is bonded to the alkyl group or the aryl group as defined above. The oxy group may include an alkoxy group or an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but aspects of the present disclosure are not limited thereto.

The boron group herein may mean that a boron atom is bonded to the alkyl group or the aryl group as defined above. The boron group includes an alkyl boron group or an aryl boron group. Examples of the boron group may include a dimethylboron group, a trimethylboron group, a t-butyldimethylboron group, a diphenylboron group, a phenylboron group, etc., but aspects of the present disclosure are not limited thereto.

In the specification, the alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, etc., but aspects of the present disclosure are not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but aspects of the present disclosure are not limited thereto.

In the specification, examples of the alkyl group of an alkylthio group, an alkylsulfoxy group, an alkylaryl group, an alkylamino group, an alkyl boron group, an alkyl silyl group, or an alkyl amine group are the same as the examples of the alkyl group described above.

In the specification, examples of the aryl group of an aryloxy group, an arylthio group, an arylsulfoxy group, an arylamino group, an arylboron group, an arylsilyl group, or an arylamine group are the same as the examples of the aryl group described above.

In the specification, a direct linkage may mean a single bond.

Meanwhile, in the specification,

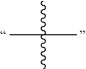

and “—*” mean a position to be connected.

Hereinafter, aspects of the present disclosure will be described with reference to the accompanying drawings.

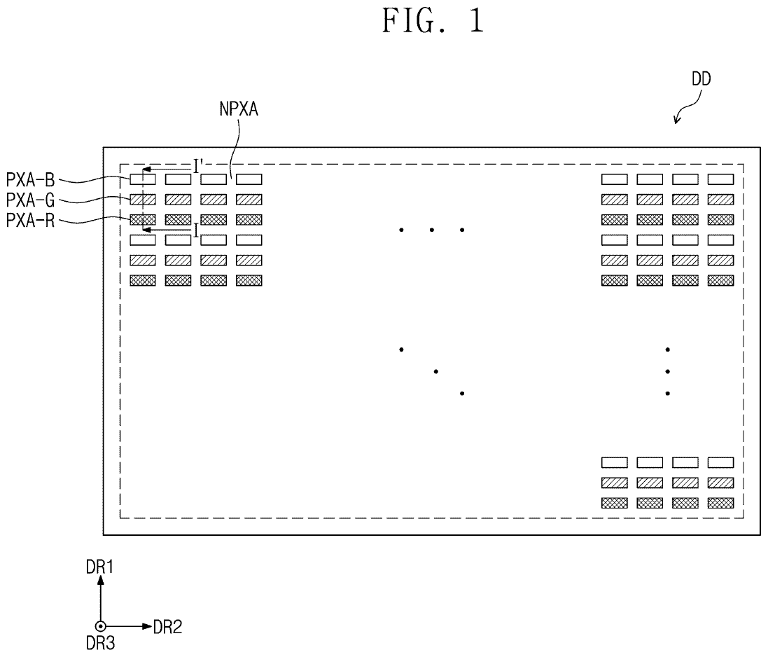

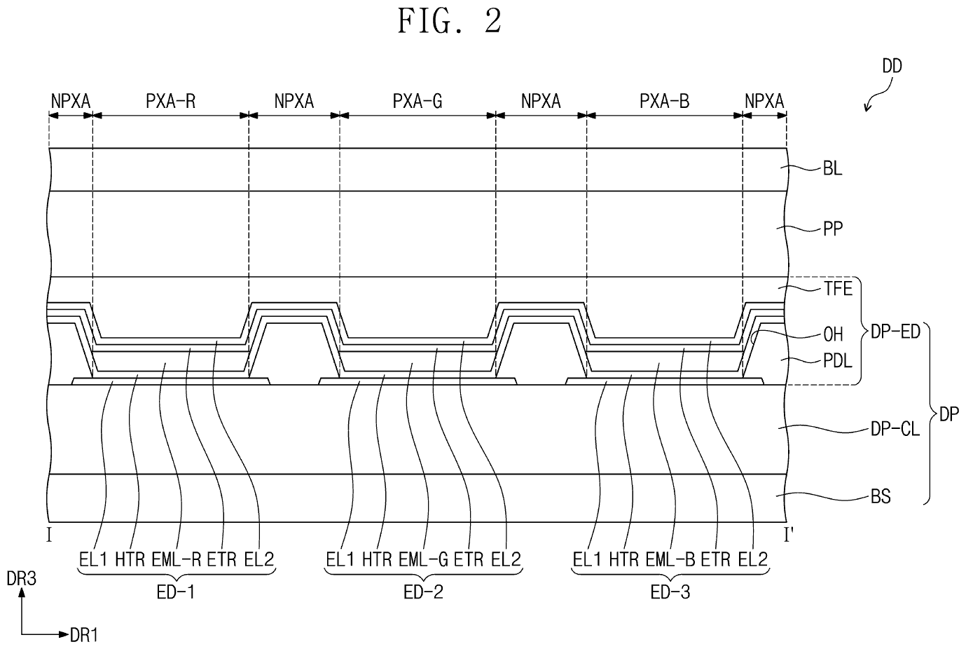

FIG. 1 is a plan view illustrating an aspect of a display apparatus DD. FIG. 2 is a cross-sectional view of the display apparatus DD taken along line I-I′ of FIG. 1.

The display apparatus DD may include a display panel DP and an optical layer PP disposed on the display panel DP. The display panel DP includes light emitting devices ED-1, ED-2, and ED-3. The display apparatus DD may include a plurality of light emitting devices ED-1, ED-2, and ED-3. The optical layer PP may be disposed on the display panel DP to control reflected light in the display panel DP due to external light. The optical layer PP may include, for example, a polarization layer or a color filter layer. Meanwhile, unlike the configuration illustrated in the drawing, the optical layer PP may be omitted from the display apparatus DD of an aspect.

A base substrate BL may be disposed on the optical layer PP. The base substrate BL may be a member which provides a base surface on which the optical layer PP disposed. The base substrate BL may be a glass substrate, a metal substrate, a plastic substrate, etc. However, aspects of the present disclosure are not limited thereto, and the base substrate BL may be an inorganic layer, an organic layer, or a composite material layer. In addition, unlike the configuration illustrated, in an aspect, the base substrate BL may be omitted.

The display apparatus DD according to an aspect may further include a filling layer (not shown). The filling layer may be disposed between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting devices ED-1, ED-2, and ED-3 disposed between portions of the pixel defining film PDL, and an encapsulation layer TFE disposed on the light emitting devices ED-1, ED-2, and ED-3.

The base layer BS may be a member which provides a base surface on which the display device layer DP-ED is disposed. The base layer BS may be a glass substrate, a metal substrate, a plastic substrate, etc. However, the aspects of the present disclosure are not limited thereto, and the base layer BS may be an inorganic layer, an organic layer, or a composite material layer.

In an aspect, the circuit layer DP-CL is disposed on the base layer BS, and the circuit layer DP-CL may include a plurality of transistors (not shown). Each of the transistors may include a control electrode, an input electrode, and an output electrode. For example, the circuit layer DP-CL may include a switching transistor and a driving transistor for driving the light emitting devices ED-1, ED-2, and ED-3 of the display device layer DP-ED.

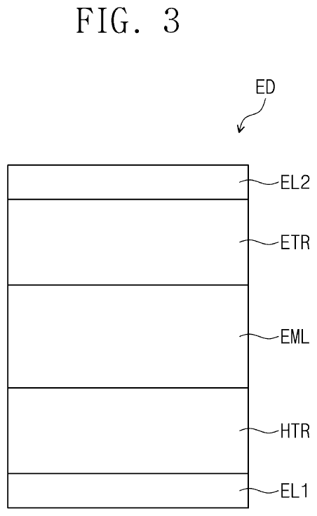

Each of the light emitting devices ED-1, ED-2, and ED-3 may have a structure of each light emitting device ED of aspects according to FIGS. 3 to 6, which will be described later. Each of the light emitting devices ED-1, ED-2, and ED-3 may include a first electrode EL1, a hole transport region HTR, emission layers EML-R, EML-G, and EML-B, an electron transport region ETR, and a second electrode EL2.

FIG. 2 illustrates an aspect in which the emission layers EML-R, EML-G, and EML-B of the light emitting devices ED-1, ED-2, and ED-3 are disposed in openings OH defined in the pixel defining film PDL, and the hole transport region HTR, the electron transport region ETR, and the second electrode EL2 are provided as a common layer in the entire light emitting devices ED-1, ED-2, and ED-3. However, aspects of the present disclosure are not limited thereto, and unlike the configuration illustrated in FIG. 2, the hole transport region HTR and the electron transport region ETR in an aspect may be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 in an aspect may be provided by being patterned in an inkjet printing method.

The encapsulation layer TFE may cover the light emitting devices ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to an aspect may include at least one inorganic film (hereinafter, an encapsulation-inorganic film). The encapsulation layer TFE according to an aspect may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but aspects of the present disclosure are not particularly limited thereto. The encapsulation-organic film may include an acrylic-based compound, an epoxy-based compound, or the like. The encapsulation-organic film may include a photopolymerizable organic material, but aspects of the present disclosure are not particularly limited thereto.

The encapsulation layer TFE may be disposed on the second electrode EL2 and may be disposed filling the opening OH.

Referring to FIGS. 1 and 2, the display apparatus DD may include a non-light emitting region NPXA and light emitting regions PXA-R, PXA-G, and PXA-B. The light emitting regions PXA-R, PXA-G, and PXA-B may be regions in which light generated by the respective light emitting devices ED-1, ED-2, and ED-3 is emitted. The light emitting regions PXA-R, PXA-G, and PXA-B may be spaced apart from each other on a plane.

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. Meanwhile, in the specification, the light emitting regions PXA-R, PXA-G, and PXA-B may respectively correspond to pixels. The pixel defining film PDL may divide the light emitting devices ED-1, ED-2, and ED-3. The emission layers EML-R, EML-G, and EML-B of the light emitting devices ED-1, ED-2, and ED-3 may be disposed in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display apparatus DD of an aspect illustrated in FIGS. 1 and 2, three light emitting regions PXA-R, PXA-G, and PXA-B, which emit red light, green light, and blue light, respectively, are exemplarily illustrated. For example, the display device DD of an aspect may include the red light emitting region PXA-R, the green light emitting region PXA-G, and the blue light emitting region PXA-B that are separated from each other.

In the display apparatus DD according to an aspect, the plurality of light emitting devices ED-1, ED-2 and ED-3 may emit light beams having wavelengths different from each other. For example, in an aspect, the display apparatus DD may include a first light emitting device ED-1 that emits red light, a second light emitting device ED-2 that emits green light, and a third light emitting device ED-3 that emits blue light. That is, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, aspects of the present disclosure are not limited thereto, and the first to third light emitting devices ED-1, ED-2, and ED-3 may emit light beams in the same wavelength range or at least one light emitting device may emit a light beam in a wavelength range different from the others. For example, the first to third light emitting devices ED-1, ED-2, and ED-3 may all emit blue light.

The light emitting regions PXA-R, PXA-G, and PXA-B in the display apparatus DD according to an aspect may be arranged in a stripe form. Referring to FIG. 1, the plurality of red light emitting regions PXA-R, the plurality of green light emitting regions PXA-G, and the plurality of blue light emitting regions PXA-B each may be arranged along a second directional axis DR2. In addition, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have similar area, but aspects of the present disclosure are not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may mean areas when viewed on a plane defined by the first directional axis DR1 and the second directional axis DR2.

Meanwhile, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the characteristics of display quality required in the display apparatus DD. For example, the arrangement form of the light emitting regions PXA-R, PXA-G, and PXA-B may be a pentile (PENTILE™) arrangement form or a diamond (Diamond Pixel™) arrangement form.

In addition, the areas of the light emitting regions PXA-R, PXA-G, and PXA-B may be different from each other. For example, in an aspect, the area of the green light emitting region PXA-G may be smaller than that of the blue light emitting region PXA-B, but t aspects of the present disclosure are not limited thereto.

Hereinafter, FIG. 3 to FIG. 6 are cross-sectional views schematically showing light emitting devices according to aspects. The light emitting device ED of an aspect may include a first electrode EL1, a hole transport region HTR, an emission layer EML, an electron transport region ETR, and a second electrode EL2 stacked in order.

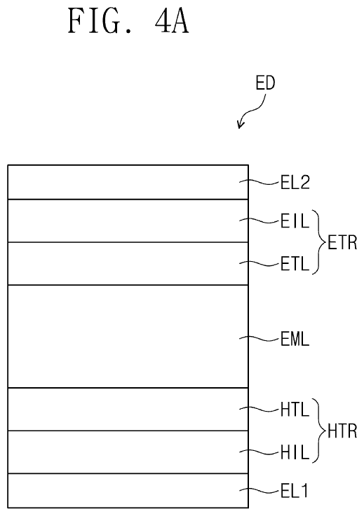

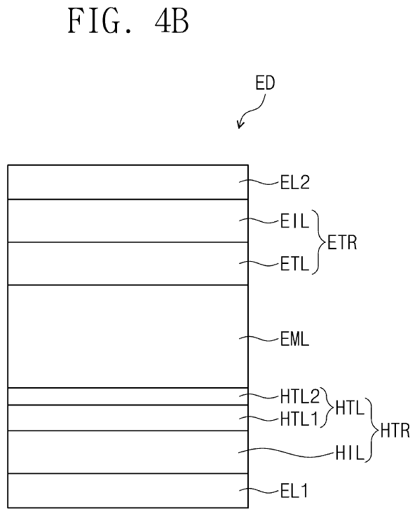

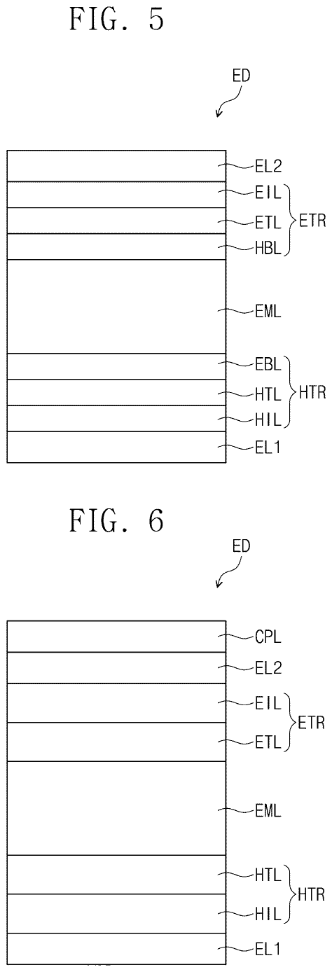

Compared to FIG. 3, FIG. 4A illustrates a cross-sectional view of a light-emitting element ED according to an aspect, in which a hole transport region HTR includes a hole injection layer HIL and a hole transport layer HTL, and an electron transport region ETR includes an electron injection layer EIL, and an electron transport layer ETL. Compared to FIG. 4A, FIG. 4B illustrates a cross-sectional view of a light-emitting element ED according to an aspect, in which a hole transport layer HTL includes a first hole transport layer HTL1 and a second hole transport layer HTL2. In addition, compared to FIG. 3, FIG. 5 illustrates a cross-sectional view of a light-emitting element ED according to an aspect, in which a hole transport region HTR includes a hole injection layer HIL, a hole transport layer HTL, and an electron blocking layer EBL and an electron transport region ETR includes an electron injection layer EIL, an electron transport layer ETL and a hole blocking layer HBL. Compared to FIG. 4A, FIG. 6 illustrates a cross-sectional view of a light-emitting element ED according to an aspect, which includes a capping layer CPL disposed on the second electrode EL2.

Meanwhile, in FIG. 4A to FIG. 6, etc., the hole injection layer HIL, the hole transport layer HTL, the electron blocking layer EBL, the emission layer EML, the hole blocking layer HBL, the electron transport layer EBL, the electron injection layer EIL, or the like, which are functional layers, are each illustrated as a single layer, but aspects of the present disclosure are not limited thereto, and each functional layer may include a stacked structure of multiple layers. For example, each functional layer may include multiple layers having different material compositions. As illustrated in FIG. 4B, the hole transport layer HTL may include a stacked structure of a first hole transport layer HTL1 and a second hole transport layer HTL2.

The first electrode EL1 has conductivity. The first electrode EL1 may be formed of a metal material, a metal alloy, or a conductive compound. The first electrode EL1 may be an anode or a cathode. However, t aspects of the present disclosure are not limited thereto. In addition, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, or Zn, a compound of two or more selected from among these, a mixture of two or more selected from among these, or an oxide thereof.

If the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (e.g., a mixture of Ag and Mg). Alternatively, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but aspects of the present disclosure are not limited thereto. In addition, the first electrode EL1 may include the above-described metal materials, combinations of at least two metal materials of the above-described metal materials, oxides of the above-described metal materials, or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may have a single layer formed of a single material, a single layer formed of a plurality of different materials, or a multilayer structure including a plurality of layers formed of a plurality of different materials.

The hole transport region HTR may include at least one among a hole injection layer HIL, a hole transport layer HTL, and an electron blocking layer EBL. In addition, unlike what described previously, the hole transport region HTR may have a single layered structure of a hole injection layer HIL or a hole transport layer HTL, or may have a single layered structure formed using a hole injection material and a hole transport material. In an aspect, the hole transport region HTR may have a single-layered structure formed using a plurality of different materials, or may also have a structure of hole injection layer HIL/hole transport layer HTL sequentially stacked from the first electrode EL1, a hole injection layer HIL/first hole transport layer HTL1/second hole transport layer HTL2, hole injection layer HIL/first hole transport layer HTL1/second hole transport layer HTL2/buffer layer (not illustrated), hole injection layer HIL/buffer layer (not illustrated), or hole transport layer HTL/buffer layer (not illustrated), but aspects of the present disclosure are not limited thereto.

The hole transport region HTR may be formed using various methods such as a vacuum deposition method, a spin coating method, a cast method, a Langmuir-Blodgett method, an inkjet printing method, a laser printing method, or a laser induced thermal imaging (LITI) method.

The light-emitting element ED according to an aspect may include a nitrogen-containing compound represented by any one among Formula 1-1 to Formula 1-4 below in at least one functional layer disposed between a first electrode EL1 and a second electrode EL2. In the light-emitting element ED according to an aspect, the nitrogen-containing compound according to an aspect may be included in at least one among the hole transport region HTR and the emission layer EML. The hole transport region HTR may include the nitrogen-containing-compound according to an aspect. The nitrogen-containing compound according to an aspect may be included in an adjacent layer to the emission layer EML among layers included in the hole transport region HTR. In the light-emitting element ED according to an aspect, the hole transport region HTR may include a hole injection layer HIL, and a hole transport layer HTL, the hole transport layer HTL may include a first hole transport layer HTL1 and a second hole transport layer HTL2, and the second hole transport layer HTL2 may include the nitrogen-containing compound according to an aspect. Meanwhile, in the present specification, the nitrogen-containing compound according to an aspect to be described later may be referred to as a first compound.

The nitrogen-containing compound according to an aspect includes a heterocyclic core in which one or more carbon atoms of a benzene ring are substituted with N, and the heterocyclic core includes a structure where a first substituent and a second substituent are connected to the heterocyclic core. The heterocyclic core may include any one among Formulae FG1 to FG4 below.

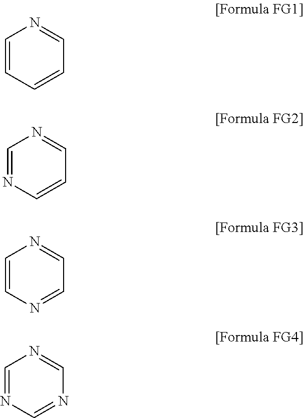

The nitrogen-containing compound according to an aspect includes a first substituent connected to a carbon atom of the heterocyclic core. The first substituent may include a first heterocycle, and may include a second heterocycle connected to the first heterocycle. The first heterocycle may include a carbazole moiety. The first heterocycle may include a first benzene moiety and a second benzene moiety which are linked to each other via a first hetero atom. The first hetero atom may be a nitrogen atom. The first hetero atom of the first heterocycle may be connected to a carbon atom of the heterocyclic core. The second heterocycle may include any one among a dibenzofuran moiety, a dibenzothiophene moiety, or a carbazole moiety. The second heterocycle may include a third benzene moiety, and a fourth benzene moiety linked to each other via a second hetero atom. The second hetero atom may be any one among O, S, or N. The second hetero atom of the second heterocycle may be linked to the first heterocycle. The second hetero atom of the second heterocycle may be linked to an arbitrary carbon atom constituting the first benzene moiety, or the second benzene moiety of the first heterocycle. Alternatively, an arbitrary carbon atom constituting the third benzene moiety or the fourth benzene moiety of the second heterocycle may be linked to the first heterocycle. An arbitrary carbon atom constituting the third benzene moiety or the fourth benzene moiety of the second heterocycle may be linked to an arbitrary carbon atom constituting the first benzene moiety or the second benzene moiety of the first heterocycle

The nitrogen-containing compound according to an aspect includes the second substituent connected to a carbon atom of the heterocyclic core. The second substituent contains a silicon atom, and the silicon atom of the second substituent may be directly linked to a carbon atom of the heterocyclic core. The second substituent may be a substituted or unsubstituted silyl group.

The nitrogen-containing compound according to an aspect is represented by any one among Formula 1-1 to Formula 1-4 below.

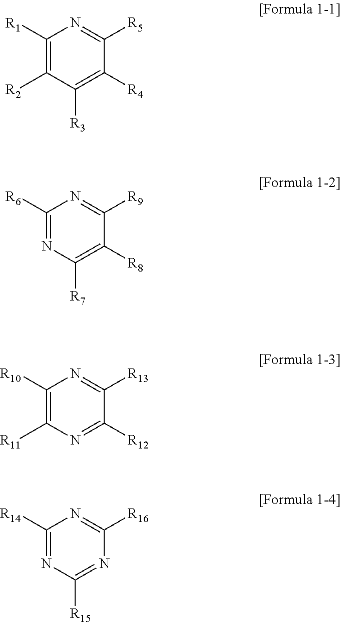

In Formula 1-1 to Formula 1-4, R₁ to R₁₆ are each independently, a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons. For example, R₁ to R₁₆ may be each independently a hydrogen atom, or a deuterium atom.

When the nitrogen-containing compound according to an aspect is represented by Formula 1-1, any one among R₁ to R₅ in Formula 1-1 is a substituent represented by Formula 2 below, and at least another one among R₁ to R₅ is a substituent represented by Formula 3 below.

When the nitrogen-containing compound according to an aspect is represented by Formula 1-2, any one among R₆ to R₉ in Formula 1-2 is a substituent represented by Formula 2 below, and at least another one among R₆ to R₉ is a substituent represented by Formula 3 below.

When the nitrogen-containing compound according to an aspect is represented by Formula 1-3, any one among R₁₀ to R₁₃ in Formula 1-3 is a substituent represented by Formula 2 below, and at least another one among R₁₀ to R₁₃ is a substituent represented by Formula 3 below.

When the nitrogen-containing compound according to an aspect is represented by Formula 1-4, any one among R₁₄ to R₁₆ in Formula 1-4 is a substituent represented by Formula 2 below, and at least another one among R₁₄ to R₁₆ is a substituent represented by Formula 3 below.

Meanwhile, in the present specification, any one among a pyridine ring substituted with a substituent represented by R₁ to R₅ in Formula 1-1, pyrimidine ring substituted with a substituent represented by R₆ to R₉ in Formula 1-2, pyrimidine ring substituted with a substituent represented by R₁₀ to R₁₃ in Formula 1-3, and a triazine ring substituted with a substituent represented by R₁₄ to R₁₆ in Formula 1-4 may correspond to the above-described heterocyclic core.

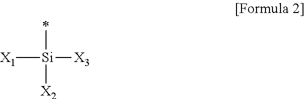

In Formula 2, X₁ to X₃ are each independently a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons. For example, X₁ to X₃ may be each independently a hydrogen atom, a deuterium atom, a substituted or unsubstituted alkyl group having 1 to 10 carbons, or a substituted or unsubstituted phenyl group.

In Formula 2, *— is a portion to which any one among Formula 1-1 to Formula 1-4 is connected.

Meanwhile, in the present specification, Formula 2 may correspond to the above-described second substituent. A Si atom in Formula 2 may correspond to the above-described silicon atom.

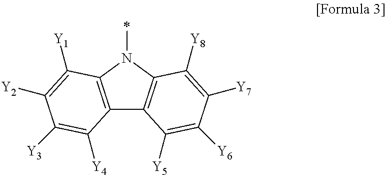

In Formula 3, any one among Y₁ to Y₈ is a substituent represented by Formula 4 below, and the others of Y₁ to Y₈ are each independently, a hydrogen atom, a deuterium atom, a halogen atom, a cyano group, a substituted or unsubstituted alkyl group having 1 to 20 carbons, or a substituted or unsubstituted aryl group having 6 to 30 ring-forming carbons. For example, Y₆ is a substituent represented by Formula 4 below, and Y₁ to Y₅, Y₇ and Y₈ may be each independently a hydrogen atom, or a deuterium atom.

In Formula 3, *— is a portion to which any one among Formula 1-1 to Formula 1-4 is connected.

Meanwhile, in the present specification, Formula 3 may correspond to the first heterocycle of the first substituent, described previously. N in Formula 3 may correspond to the above-described first hetero atom.

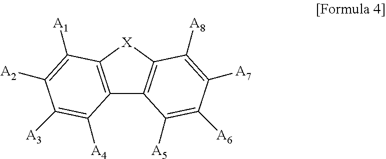

In Formula 4, X is O, S, or NA₉.

In Formula 4, any one among A₁ to A₉ is a portion to which Formula 3 above is connected, and the others among A₁ to A₉ are each independently a hydrogen atom, a deuterium atom, a halogen atom, a cyano group, a substituted or unsubstituted alkyl group having 1 to 20 carbons, or a substituted or unsubstituted aryl group having 6 to 30 ring-forming carbons. For example, X may be NA₉, A₉ is a portion to which Formula 3 above is connected, and A₁ to A₈ are each independently a hydrogen atom, or a deuterium atom.

Meanwhile, in the present specification, Formula 4 may correspond to the second heterocycle of the first substituent, described previously. X in Formula 4 may correspond to the above-described second hetero atom.

In an aspect, the nitrogen-containing compound represented by Formula 1-1 may be represented by any one among Formula 1-1-1 to Formula 1-1-6.

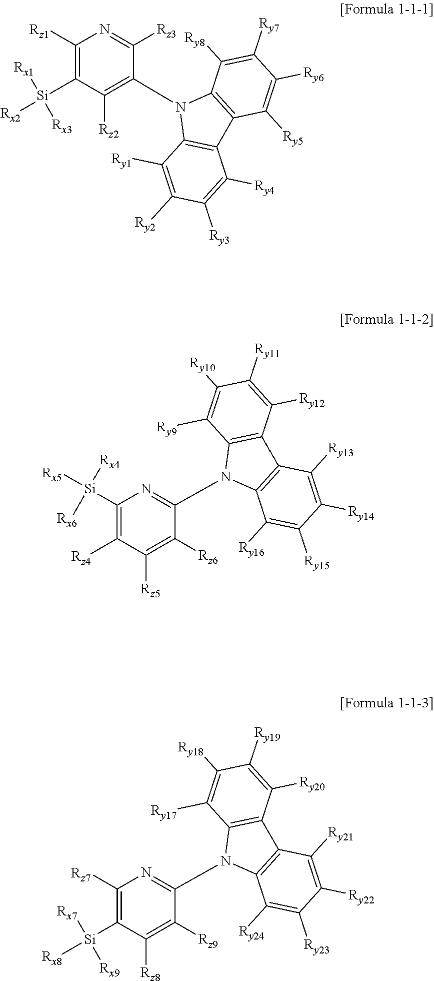

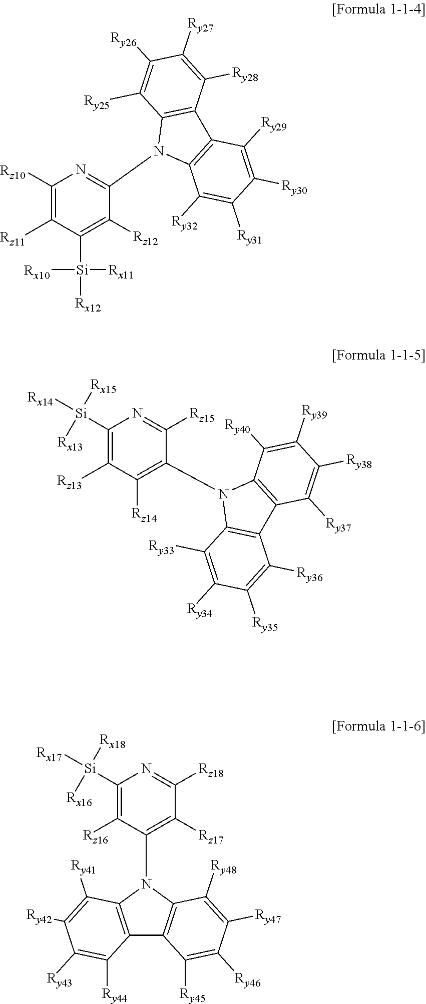

Formula 1-1-1 to Formula 1-1-6 represent cases where substituents represented by R₁ to R₅ in Formula 1-1 are specified. Formula 1-1-1 represents a case where R₂ is a substituent represented by Formula 2, and R₄ is a substituent represented by Formula 3 in Formula 1-1, Formula 1-1-2 represents a case where R₁ is a substituent represented by Formula 2, and R₅ is a substituent represented by Formula 3 in Formula 1-1, Formula 1-1-3 represents a case where R₂ is a substituent represented by Formula 2, and R₅ is a substituent represented by Formula 3 in Formula 1-1, Formula 1-1-4 represents a case where R₃ is a substituent represented by Formula 2, and R₅ is a substituent represented by Formula 3 in Formula 1-1, Formula 1-1-5 represents a case where R₁ is a substituent represented by Formula 2, and R₄ is a substituent represented by Formula 3 in Formula 1-1, and Formula 1-1-6 represents a case where R₁ is a substituent represented by Formula 2, and R₃ is a substituent represented by Formula 3 in Formula 1-1.

In Formula 1-1-1 to Formula 1-1-6, Rₓ₁ to Rₓ₁₈ may be each independently a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons. For example, Rₓ₁ to Rₓ₁₈ may be each independently a hydrogen atom, a deuterium atom, a substituted or unsubstituted alkyl group having 1 to 20 carbons, or a substituted or unsubstituted phenyl group.

In Formula 1-1-1 to Formula 1-1-6, R_{z1} to R_{z18} may be each independently a hydrogen atom, a deuterium atom, a halogen atom, a cyano group, or a substituted or unsubstituted alkyl group having 1 to 20 carbons. For example, R_{z1} to R_{z18} may be each independently a hydrogen atom, or a deuterium atom.

If the nitrogen-containing compound according to an aspect is represented by Formula 1-1-1, any one among R_{y1} to R_{y8} in Formula 1-1-1 may be a substituent represented by Formula 4, and the others of R_{y1} to R_{y8} may be each independently a hydrogen atom, or a deuterium atom. For example, R_{y6} may be a substituent represented by Formula 4 above, and R_{y1} to R_{y5}, R_{y7} and R_{y8} may be each independently a hydrogen atom, or a deuterium atom.

If the nitrogen-containing compound according to an aspect is represented by Formula 1-1-2, any one among R_{y9} to R_{y16} in Formula 1-1-2 may be a substituent represented by Formula 4 above, and the others of R_{y9} to R_{y16} may be each independently a hydrogen atom, or a deuterium atom. For example, R_{y14} may be a substituent represented by Formula 4 above, and R_{y9} to R_{y3}, R_{y15} and R_{y16} may be each independently a hydrogen atom, or a deuterium atom.

If the nitrogen-containing compound according to an aspect is represented by Formula 1-1-3, any one among R_{y17} to R_{y24} in Formula 1-1-3 may be a substituent represented by Formula 4 above, and the others of R_{y7} to R_{y24} may be each independently a hydrogen atom, or a deuterium atom. For example, R_{y22} may be a substituent represented by Formula 4 above, and R_{y17} to R_{y21}, R_{y23} and R_{y24} may be each independently a hydrogen atom, or a deuterium atom.

If the nitrogen-containing compound according to an aspect is represented by Formula 1-1-4, any one among R_{y25} to R_{y32} in Formula 1-1-4 may be a substituent represented by Formula 4 above, and the others of R_{y25} to R_{y32} may be each independently a hydrogen atom, or a deuterium atom. For example, R_{y30} may be a substituent represented by Formula 4 above, and R_{y25} to R_{y29}, R_{y31} and R_{y32} may be each independently a hydrogen atom, or a deuterium atom.

If the nitrogen-containing compound according to an aspect is represented by Formula 1-1-5, any one among R_{y33} to R_{y40} in Formula 1-1-5 may be a substituent represented by Formula 4 above, and the others of R_{y33} to R_{y40} may be each independently a hydrogen atom, or a deuterium atom. For example, R_{y38} may be a substituent represented by Formula 4 above, and R_{y33} to R_{y37}, R_{y39} and R_{y40} may be each independently a hydrogen atom, or a deuterium atom.

If the nitrogen-containing compound according to an aspect is represented by Formula 1-1-6, any one among R_{y41} to R_{y48} in Formula 1-1-6 may be a substituent represented by Formula 4 above, and the others of R_{y41} to R_{y48} may be each independently a hydrogen atom, or a deuterium atom. For example, R_{y46} may be a substituent represented by Formula 4 above, and R_{y41} to R_{y45}, R_{y47} and R_{y48} may be each independently a hydrogen atom, or a deuterium atom.

In an aspect, the nitrogen-containing compound represented by Formula 1-2 may be represented by any one among Formula 1-2-1 to Formula 1-2-4 below.

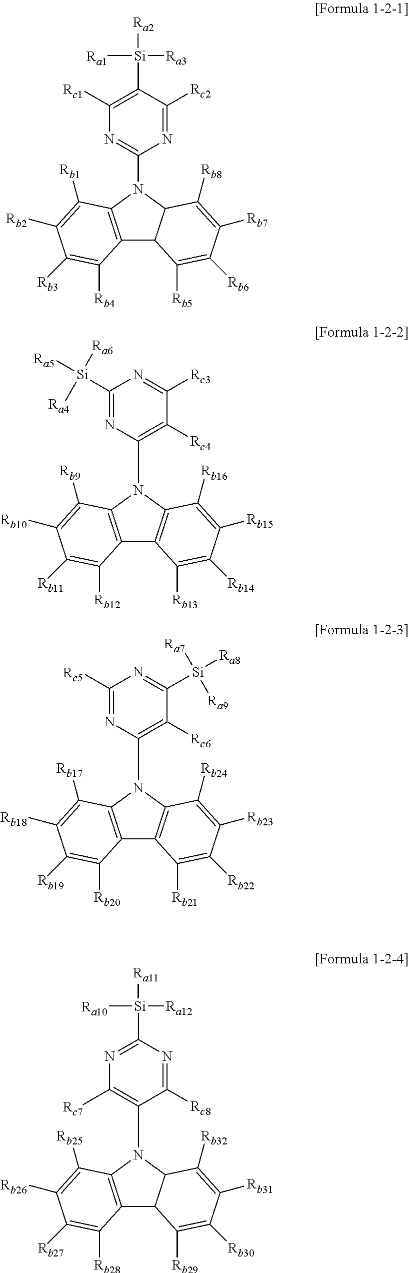

Formula 1-2-1 to Formula 1-2-4 represent cases where substituents represented by R₆ to R₉ in Formula 1-2 are specified. Formula 1-2-1 represents a case where R₅ is a substituent represented by Formula 2 and R₆ is a substituent represented by Formula 3 in Formula 1-2, Formula 1-2-2 represents a case where R₆ is a substituent represented by Formula 2 and R₇ is a substituent represented by Formula 3 in Formula 1-2, Formula 1-2-3 represents a case where R₇ is a substituent represented by Formula 2 and R₉ is a substituent represented by Formula 3 in Formula 1-2, and Formula 1-2-4 represents a case where R₆ is a substituent represented by Formula 2 and R₅ is a substituent represented by Formula 3 in Formula 1-2.

In Formula 1-2-1 to Formula 1-2-4, Rₐ₁ to Rₐ₁₂ may be each independently a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons. For example, Rₐ₁ to Rₐ₁₂ may be each independently a hydrogen atom, a deuterium atom, a substituted or unsubstituted alkyl group having 1 to 20 carbons, or a substituted or unsubstituted phenyl group.

In Formula 1-2-1 to Formula 1-2-4, Rₑ₁ to R_{c}s may be each independently a hydrogen atom, a deuterium atom, a halogen atom, a cyano group, or a substituted or unsubstituted alkyl group having 1 to 20 carbons. For example, Rₑ₁ to R_{c8} may be each independently a hydrogen atom, or a deuterium atom.

If the nitrogen-containing compound according to an aspect is represented by Formula 1-2-1, any one among R_{b1} to R_{b}s may be a substituent represented by Formula 4 above, and the others of R_{b1} to R_{b8} may be each independently a hydrogen atom, or a deuterium atom in Formula 1-2-1. For example, R_{b6} may be a substituent represented by Formula 4 above, and R_{b1} to R_{b8}, R_{b7} and R_{b8} may be each independently a hydrogen atom, or a deuterium atom.

If the nitrogen-containing compound according to an aspect is represented by Formula 1-2-2, any one among R_{b9} to R_{b16} may be a substituent represented by Formula 4 above, and the others of R_{b9} to R_{b16} may be each independently a hydrogen atom, or a deuterium atom in Formula 1-2-2. For example, R_{b14} may be a substituent represented by Formula 4 above, and R_{b9} to R_{b13}, R_{b15} and R_{b16} may be each independently a hydrogen atom, or a deuterium atom.

If the nitrogen-containing compound according to an aspect is represented by Formula 1-2-3, any one among R_{b17} to R_{b24} may be a substituent represented by Formula 4 above, and the others of R_{b17} to R_{b24} may be each independently a hydrogen atom, or a deuterium atom in Formula 1-2-3. For example, R_{b22} may be a substituent represented by Formula 4 above, and R_{b17} to R_{b21}, R_{b23} and R_{b24} may be each independently a hydrogen atom, or a deuterium atom.

If the nitrogen-containing compound according to an aspect is represented by Formula 1-2-4, any one among R_{b25} to R_{b32} may be a substituent represented by Formula 4 above, and the others of R_{b25} to R_{b32} may be each independently a hydrogen atom, or a deuterium atom in Formula 1-2-4. For example, R_{b30} may be a substituent represented by Formula 4 above, and R_{b25} to R_{b29}, R_{b31} and R_{b32} may be each independently a hydrogen atom, or a deuterium atom.

In an aspect, the nitrogen-containing compound represented by Formula 1-3 may be represented by Formula 1-3-1 below.

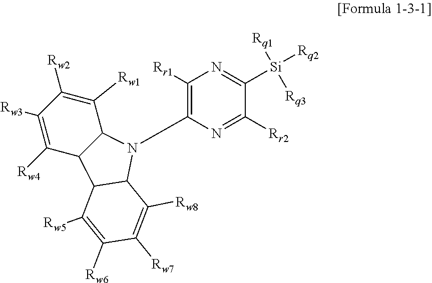

Formula 1-3-1 represents a case where substituents represented by R₁₀ to R₁₃ in Formula 1-3 are specified. Formula 1-3-1 represents a case where R₁₁ is a substituent represented by Formula 2, and R₁₃ is a substituent represented by Formula 3 in Formula 1-3.

In Formula 1-3-1, Rᵣ₁ and Rᵣ₂ may be each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons. For example, Rᵣ₁ and Rᵣ₂ may be each independently a hydrogen atom, a deuterium atom, a substituted or unsubstituted alkyl group having 1 to 10 carbons, or a substituted or unsubstituted phenyl group.

In Formula 1-3-1, R_{q1} to R_{q3} may be each independently a hydrogen atom, a deuterium atom, a halogen atom, a cyano group, or a substituted or unsubstituted alkyl group having 1 to 20 carbons. For example, R_{q1} to R_{q3} may be each independently a hydrogen atom, or a deuterium atom.

In Formula 1-3-1, any one among R_{w1} to R_{w8} may be a substituent represented by Formula 4 above, and the others of R_{w1} to R_{w8} may be each independently a hydrogen atom, or deuterium atom. For example, R_{w6} may be a substituent represented by Formula 4 above, and R_{w1} to R_{w8}, R_{w7} and R_{w8} may be each independently a hydrogen atom, or a deuterium atom.

The substituent represented by Formula 2 may be represented by any one among Formula 2-1 to Formula 2-6 below.

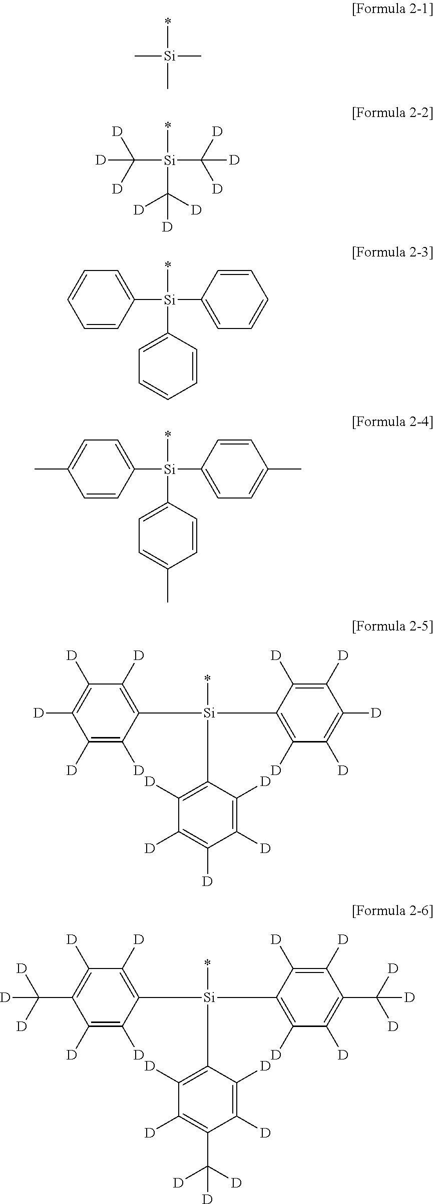

Formula 2-1 to Formula 2-6 represent cases where types of substituents represented by X₁ to X₃ in Formula 2 are specified.

In Formula 2-1 to Formula 2-6, “D” may be a deuterium atom.

In Formula 2-1 to Formula 2-6, *— is a portion to which any one among Formula 1-1 to Formula 1-4 is connected.

The substituent represented by Formula 3 may be represented by Formula 3-1 or Formula 3-2 below.

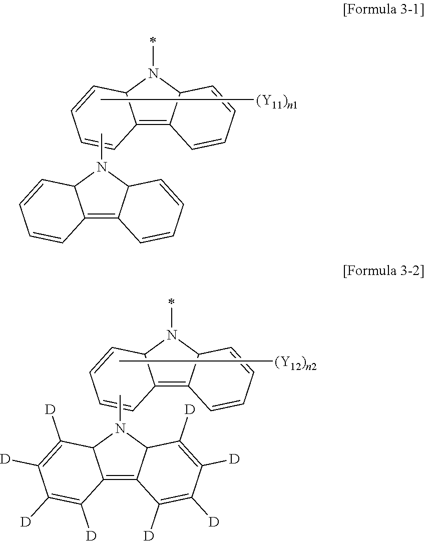

Formula 3-1 and Formula 3-2 represent cases where types of substituents represented by Y₁ to Y₈ in Formula 3 are specified.

In Formula 3-1 and Formula 3-2, Y₁₁ and Y₁₂ may be each independently a hydrogen atom, a deuterium atom, or a substituted or unsubstituted alkyl group having 1 to 10 carbons. For example, Y₁₁ and Y₁₂ may be each independently a hydrogen atom, or a deuterium atom.

In Formula 3-1 and Formula 3-2, n1 and n2 may be each independently an integer of 0 to 7. If n1 is 0, the nitrogen-containing compound according to an aspect may mean being unsubstituted with Y₁₁, and if n2 is 0, the nitrogen-containing compound according to an aspect may mean being unsubstituted with each of Y₁₂. A case where n1 is 7 and all Y₁₁ are hydrogen atoms may be the same as the case where n1 is 0, and a case where n2 is 7 and all Y₁₂ are hydrogen atoms may be the same as the case where n2 is 0. If n1 is an integer of 2 or greater, Y₁₁ provided in plurality may be all the same, or at least one among the plurality of Y₁ may be different, and if n2 is an integer of 2 or greater, Y₁₂ provided in plurality may be all the same, or at least one among the plurality of Y₁₂ may be different.

In Formula 3-1 and Formula 3-2, “D” is a deuterium atom.

The nitrogen-containing compound according to an aspect may be any one among compounds present in Compound Group 1 below. The light-emitting element ED according to an aspect may include, in the hole transport region HTR, at least one nitrogen-containing compound among the compounds present in Compound Group 1.

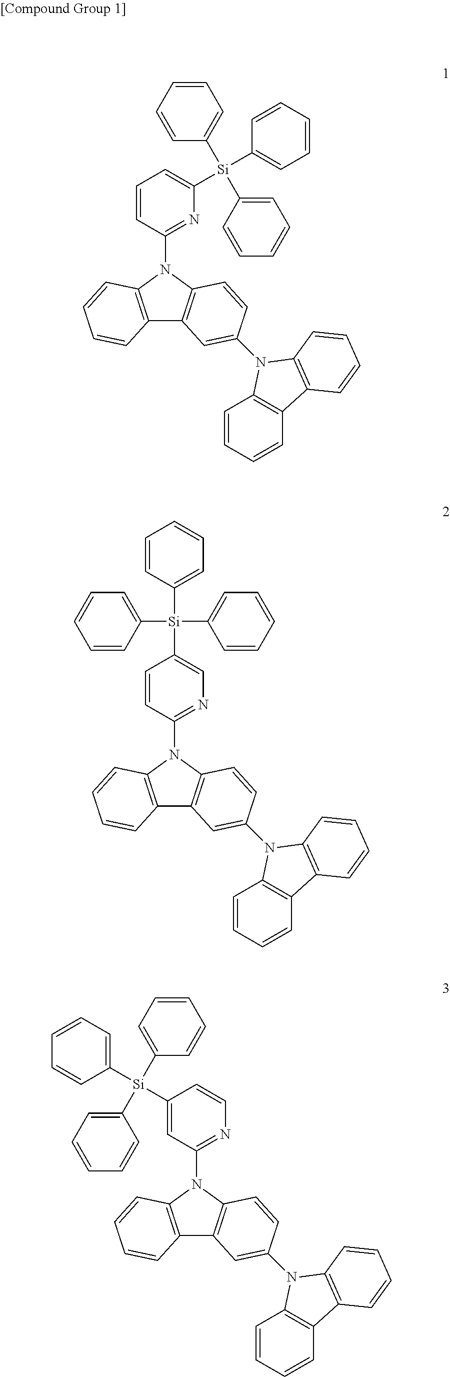 [SMILES: c1ccc([Si](c2ccccc2)(c2ccccc2)c2cccc(-n3c4ccccc4c4cc(-n5c6ccccc6c6ccccc65)ccc43)n2)cc1 ; c1ccc([Si](c2ccccc2)(c2ccccc2)c2ccc(-n3c4ccccc4c4cc(-n5c6ccccc6c6ccccc65)ccc43)nc2)cc1 ; c1ccc([Si](c2ccccc2)(c2ccccc2)c2ccnc(-n3c4ccccc4c4cc(-n5c6ccccc6c6ccccc65)ccc43)c2)cc1]

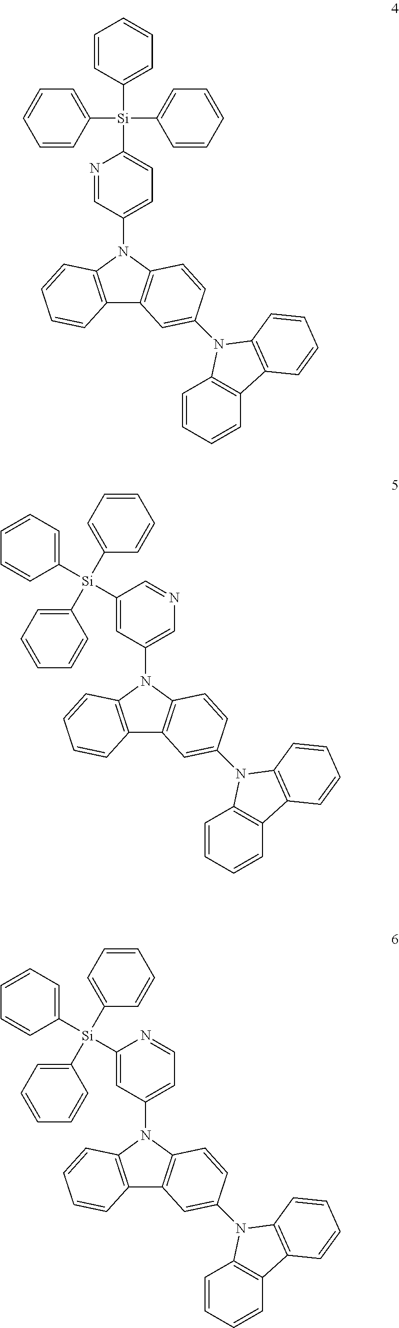 [SMILES: c1ccc([Si](c2ccccc2)(c2ccccc2)c2ccc(-n3c4ccccc4c4cc(-n5c6ccccc6c6ccccc65)ccc43)cn2)cc1 ; c1ccc([Si](c2ccccc2)(c2ccccc2)c2cncc(-n3c4ccccc4c4cc(-n5c6ccccc6c6ccccc65)ccc43)c2)cc1 ; c1ccc([Si](c2ccccc2)(c2ccccc2)c2cc(-n3c4ccccc4c4cc(-n5c6ccccc6c6ccccc65)ccc43)ccn2)cc1]

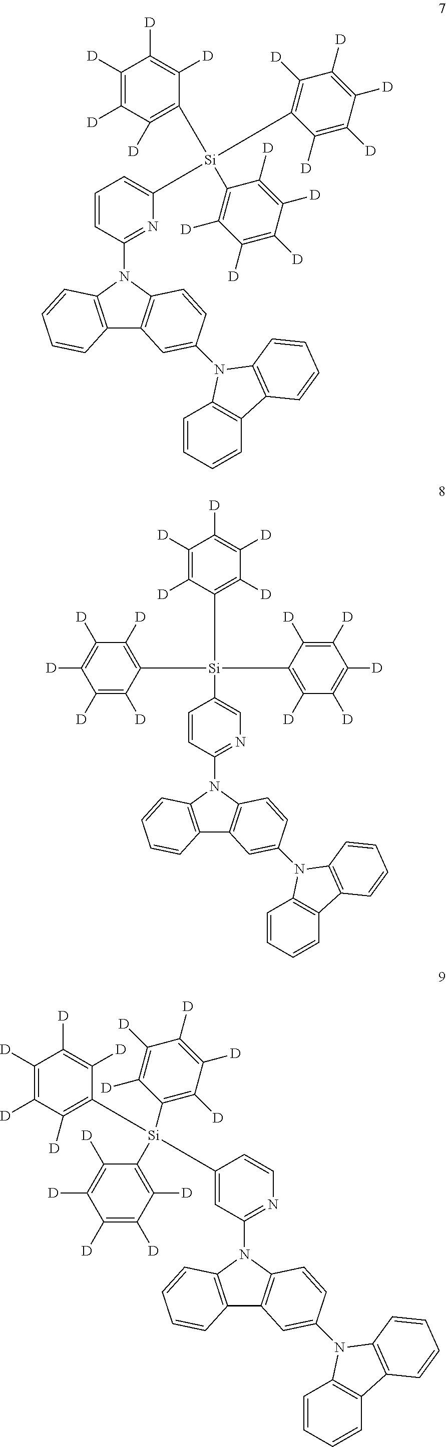

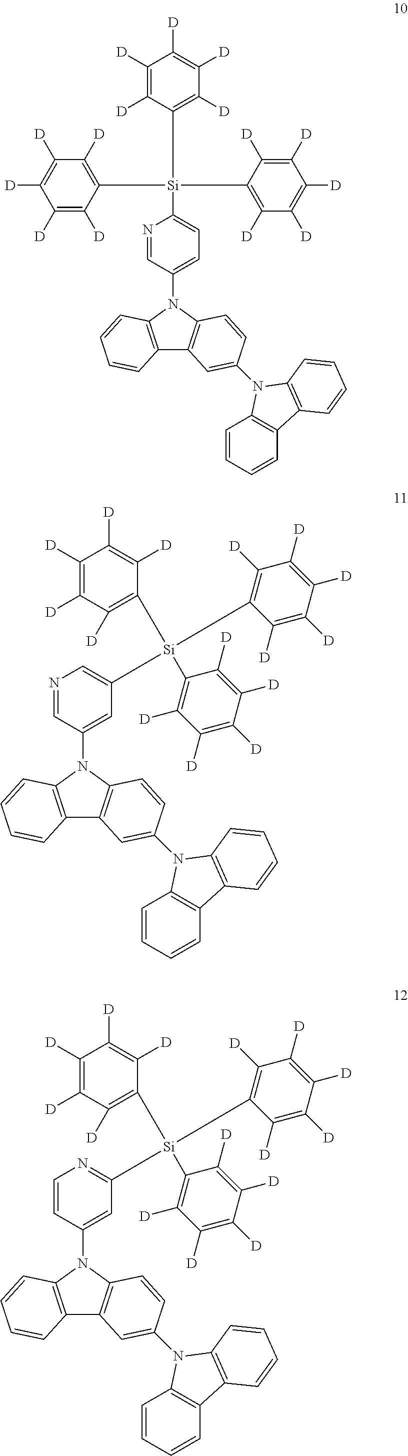

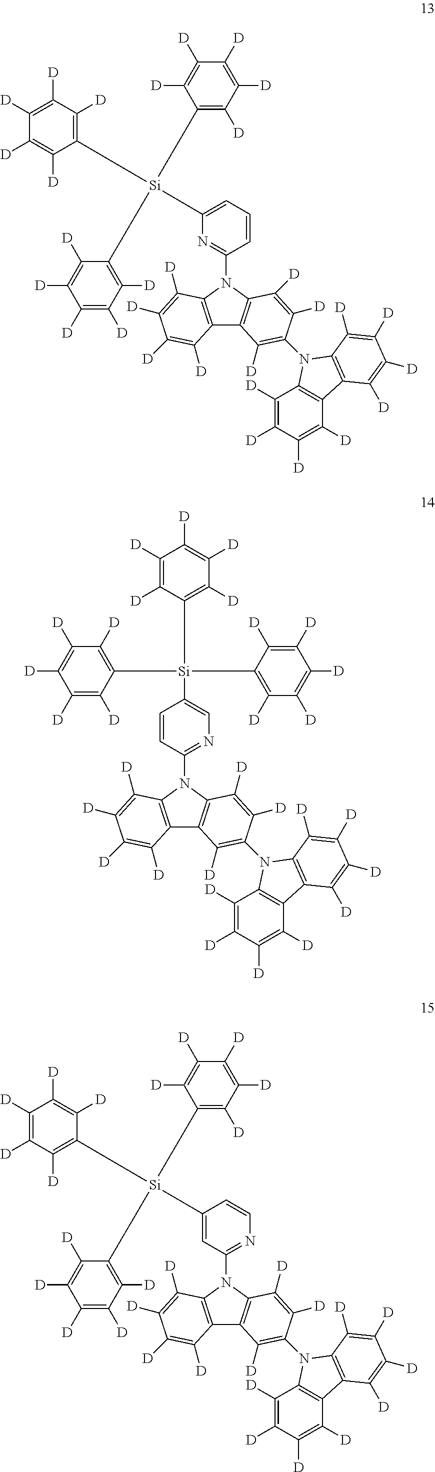

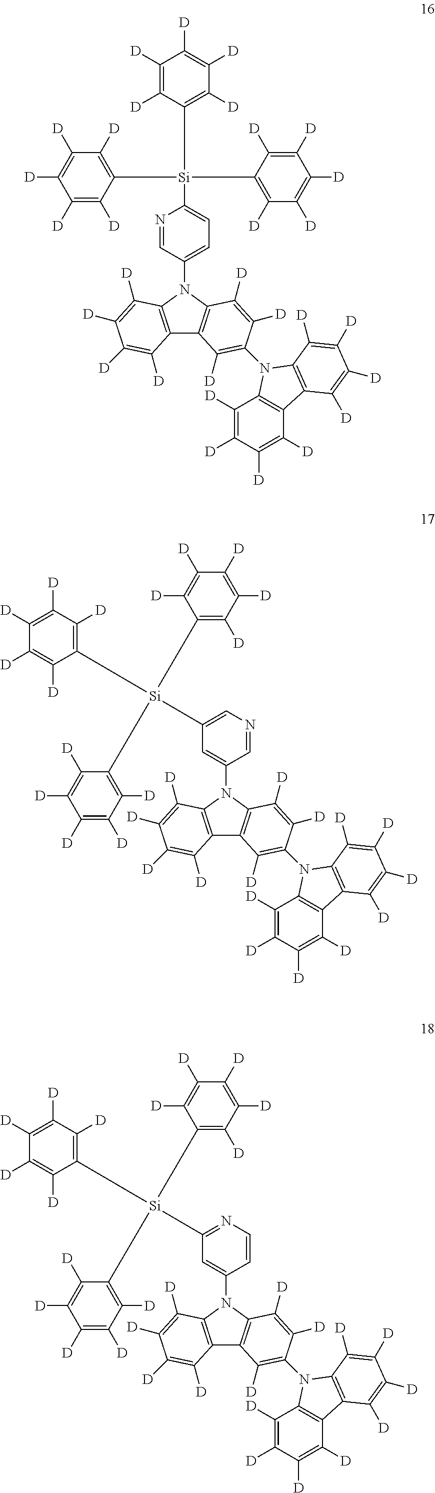

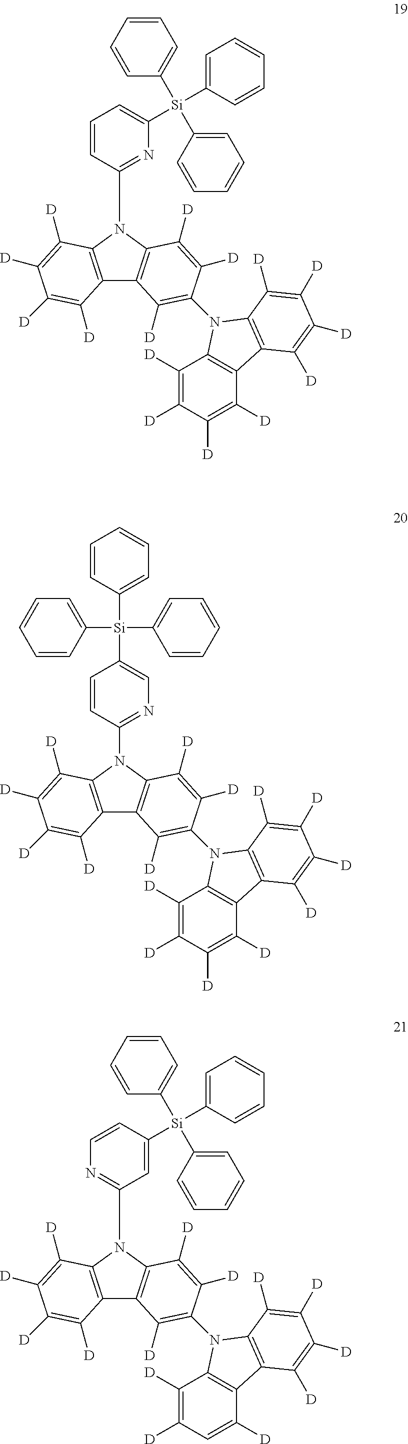

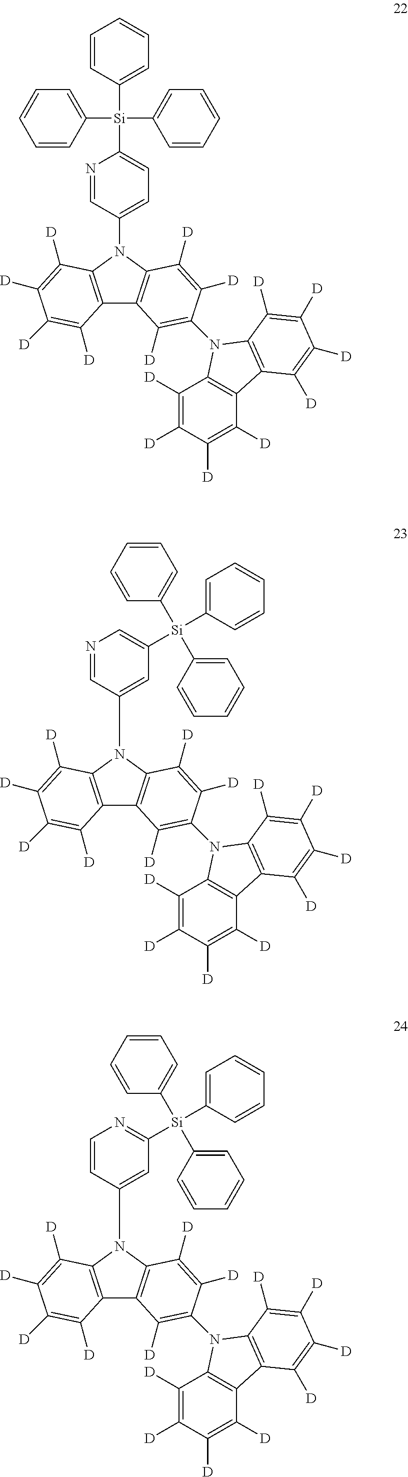

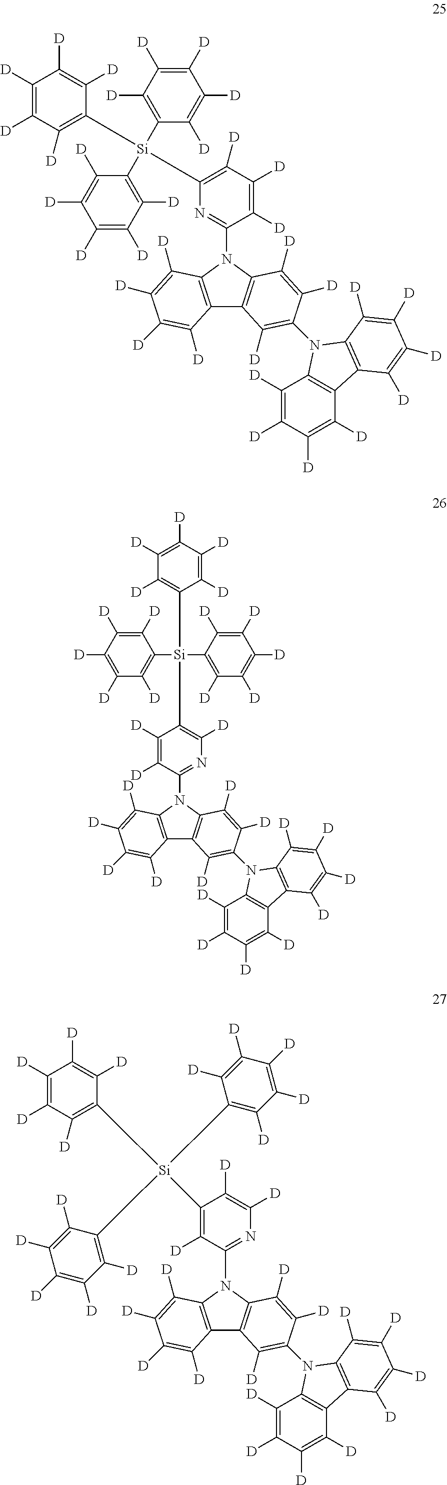

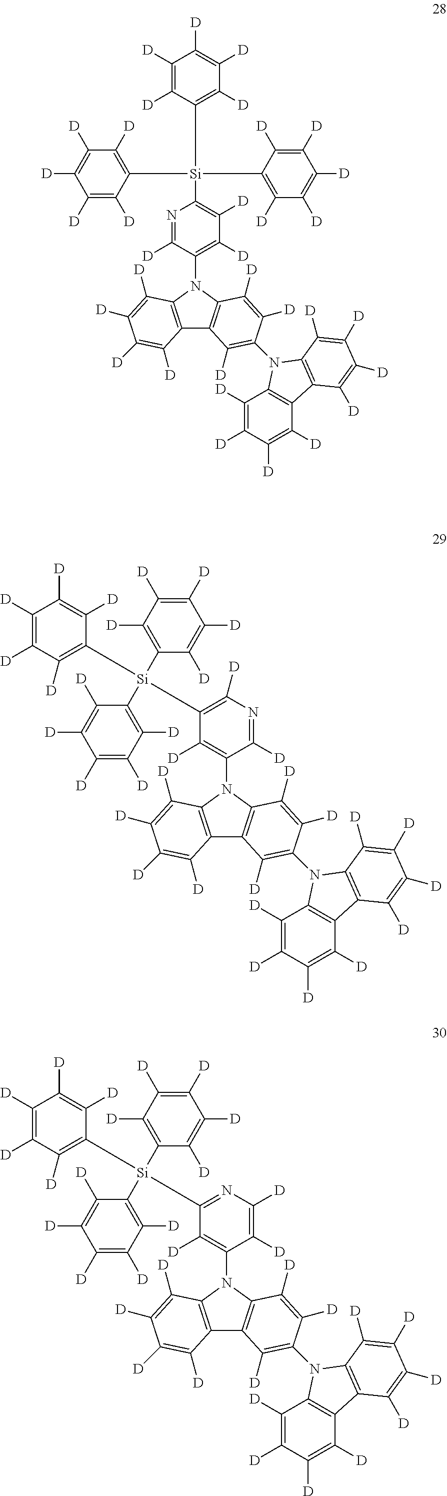

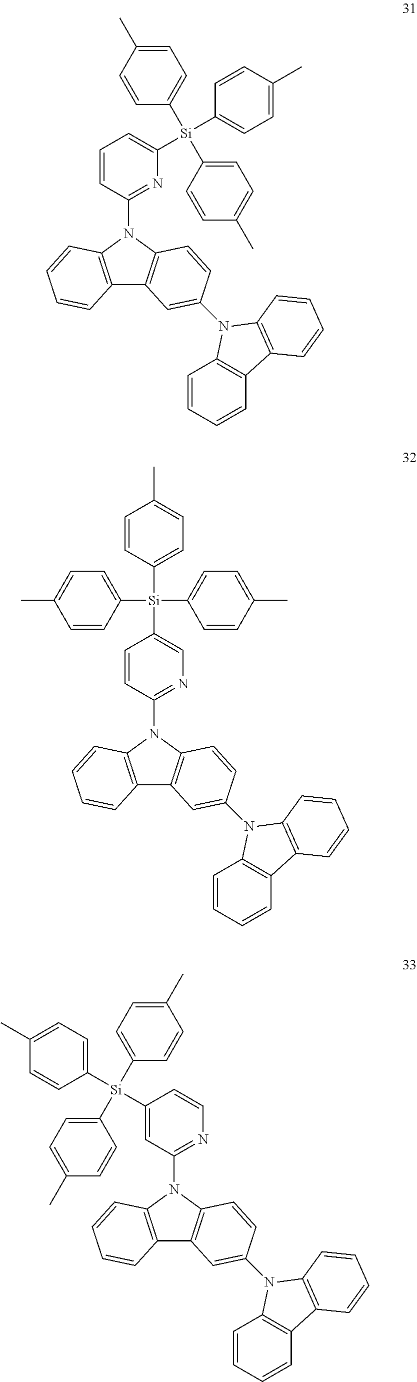 [SMILES: Cc1ccc([Si](c2ccc(C)cc2)(c2ccc(C)cc2)c2cccc(-n3c4ccccc4c4cc(-n5c6ccccc6c6ccccc65)ccc43)n2)cc1 ; Cc1ccc([Si](c2ccc(C)cc2)(c2ccc(C)cc2)c2ccc(-n3c4ccccc4c4cc(-n5c6ccccc6c6ccccc65)ccc43)nc2)cc1 ; Cc1ccc([Si](c2ccc(C)cc2)(c2ccc(C)cc2)c2ccnc(-n3c4ccccc4c4cc(-n5c6ccccc6c6ccccc65)ccc43)c2)cc1]

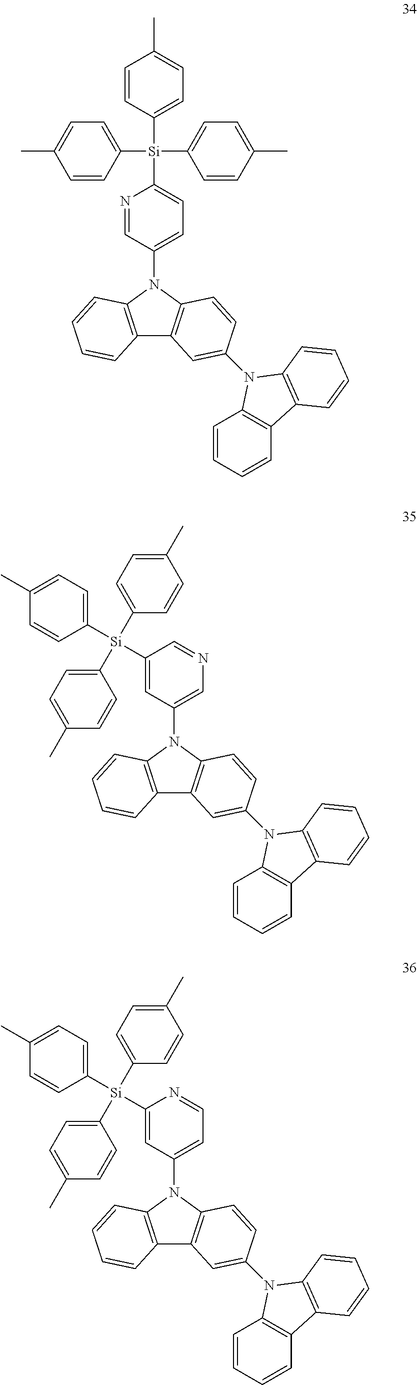 [SMILES: Cc1ccc([Si](c2ccc(C)cc2)(c2ccc(C)cc2)c2ccc(-n3c4ccccc4c4cc(-n5c6ccccc6c6ccccc65)ccc43)cn2)cc1 ; Cc1ccc([Si](c2ccc(C)cc2)(c2ccc(C)cc2)c2cncc(-n3c4ccccc4c4cc(-n5c6ccccc6c6ccccc65)ccc43)c2)cc1 ; Cc1ccc([Si](c2ccc(C)cc2)(c2ccc(C)cc2)c2cc(-n3c4ccccc4c4cc(-n5c6ccccc6c6ccccc65)ccc43)ccn2)cc1]

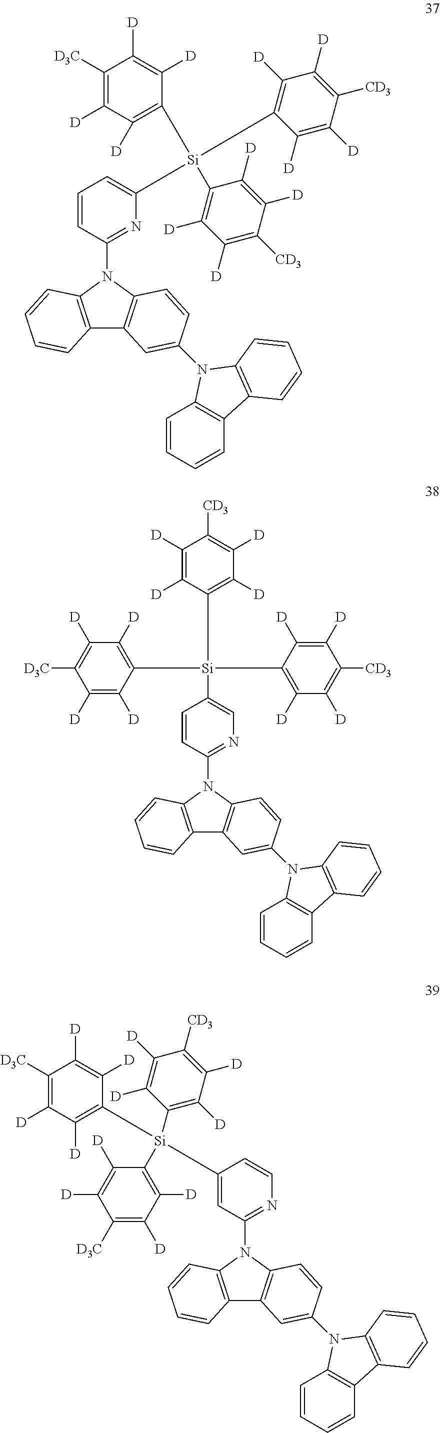

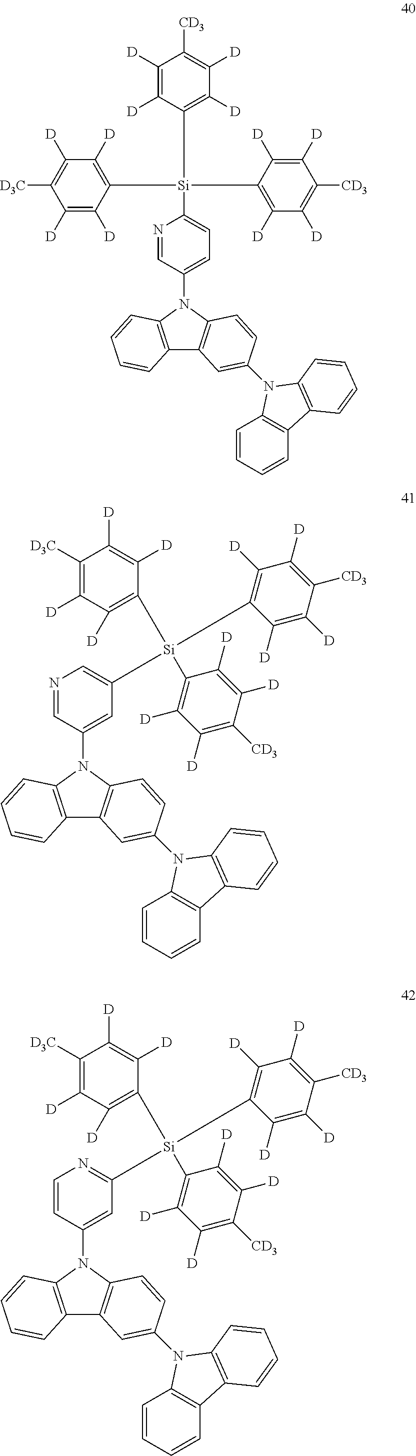

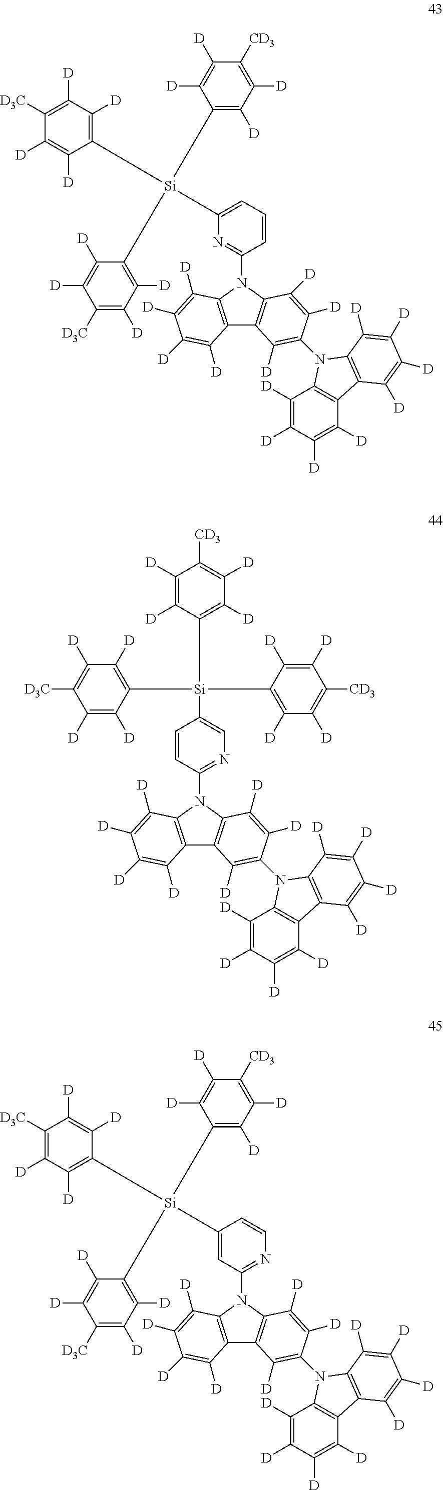

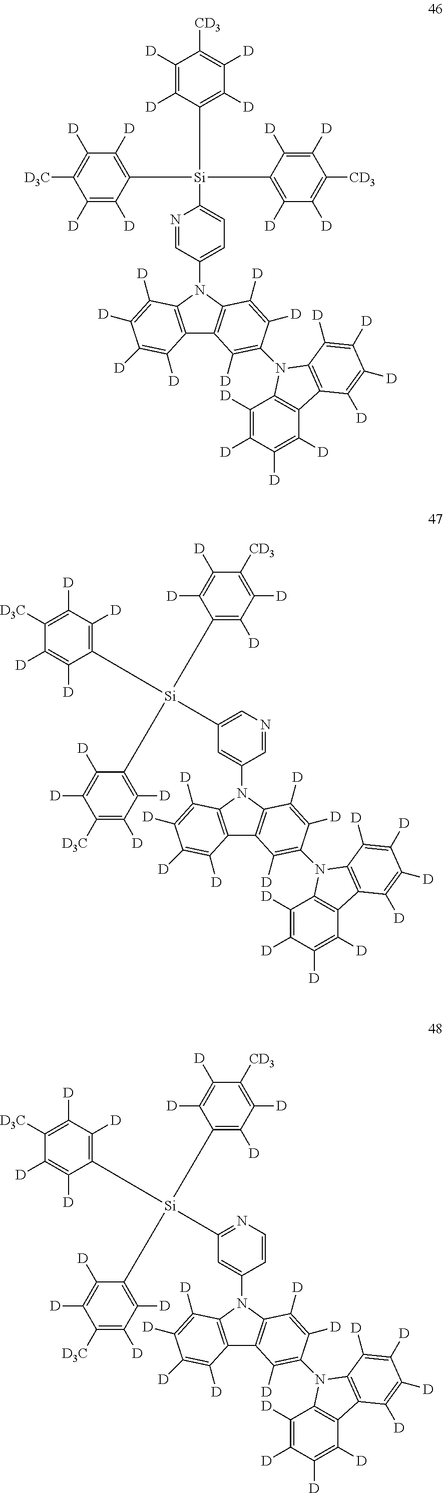

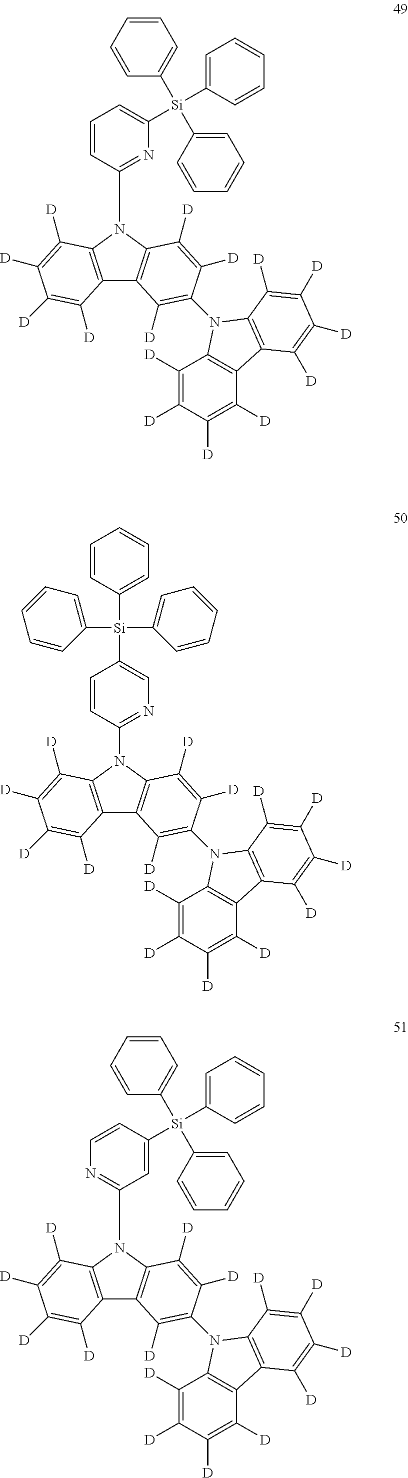

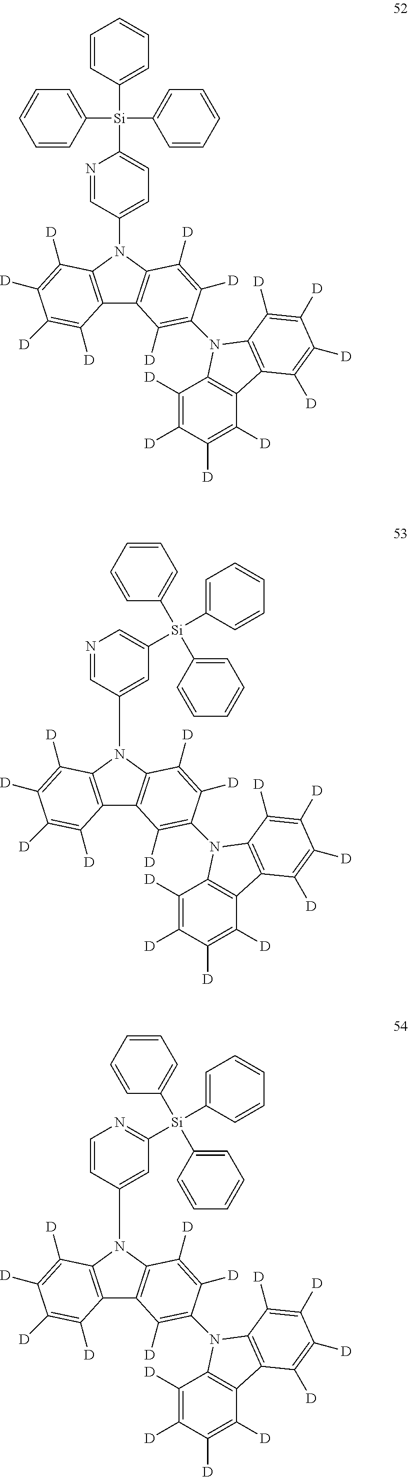

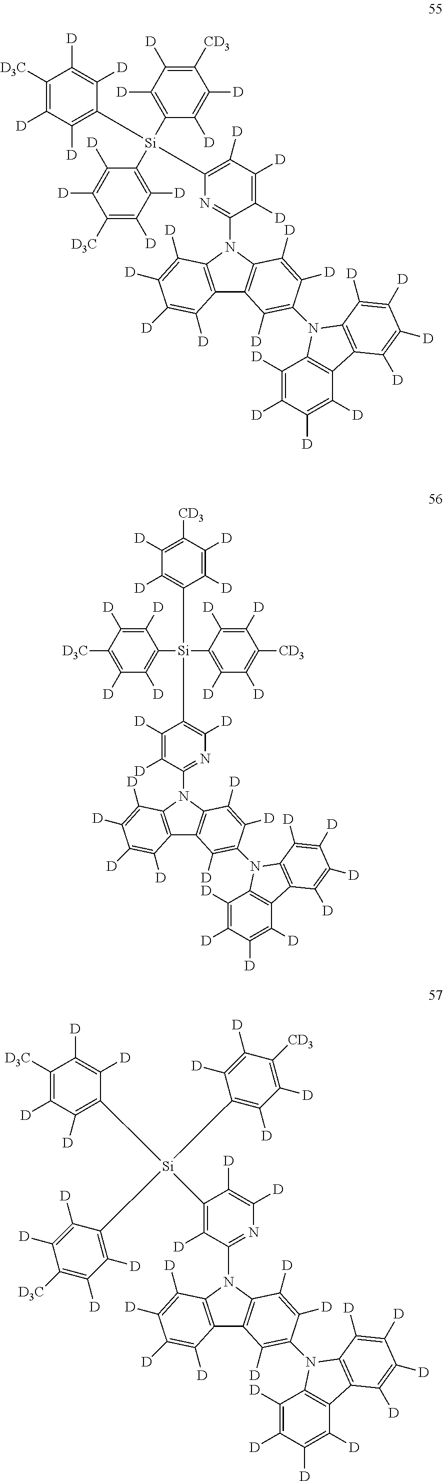

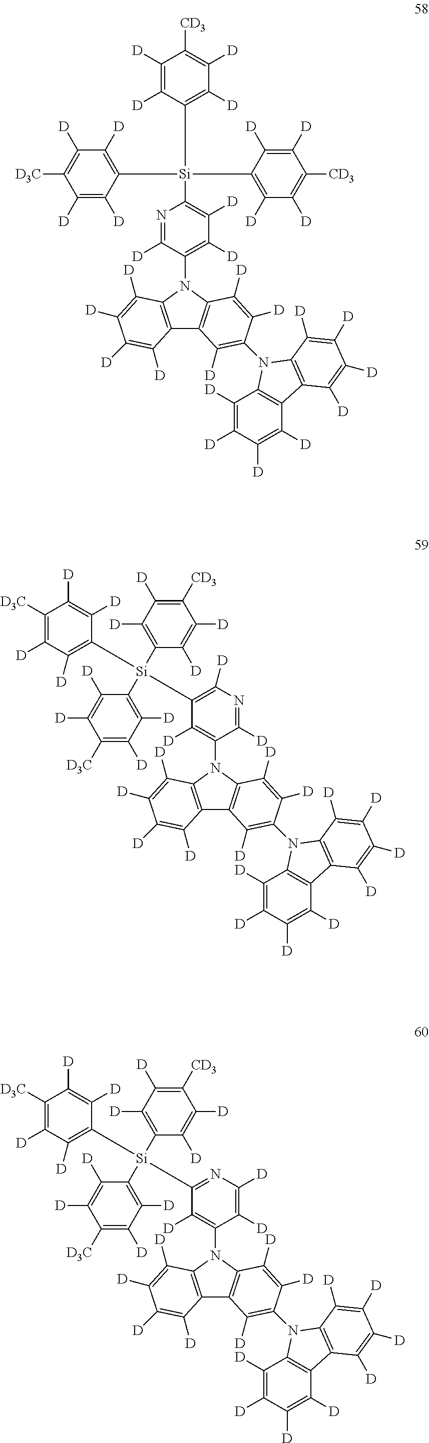

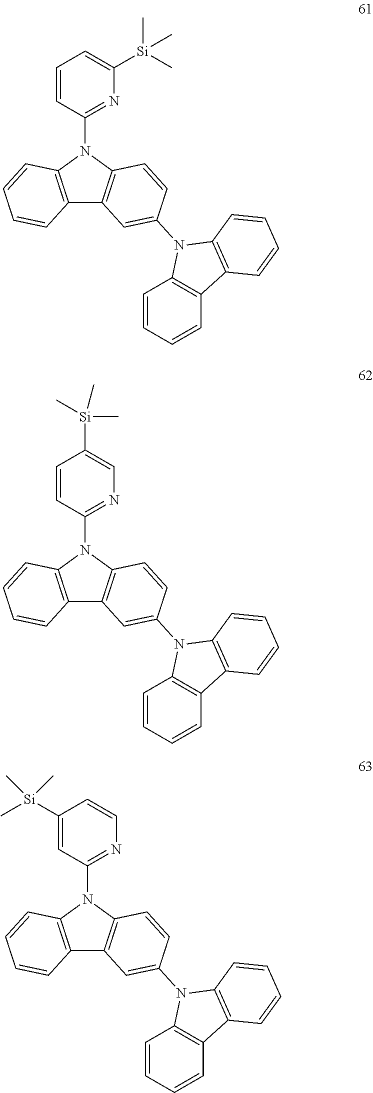 [SMILES: C[Si](C)(C)c1cccc(-n2c3ccccc3c3cc(-n4c5ccccc5c5ccccc54)ccc32)n1 ; C[Si](C)(C)c1ccc(-n2c3ccccc3c3cc(-n4c5ccccc5c5ccccc54)ccc32)nc1 ; C[Si](C)(C)c1ccnc(-n2c3ccccc3c3cc(-n4c5ccccc5c5ccccc54)ccc32)c1]

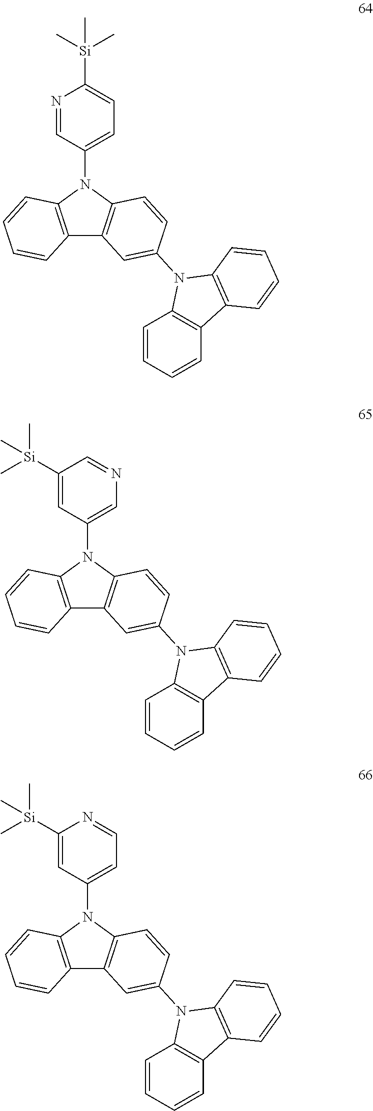 [SMILES: C[Si](C)(C)c1ccc(-n2c3ccccc3c3cc(-n4c5ccccc5c5ccccc54)ccc32)cn1 ; C[Si](C)(C)c1cncc(-n2c3ccccc3c3cc(-n4c5ccccc5c5ccccc54)ccc32)c1 ; C[Si](C)(C)c1cc(-n2c3ccccc3c3cc(-n4c5ccccc5c5ccccc54)ccc32)ccn1]

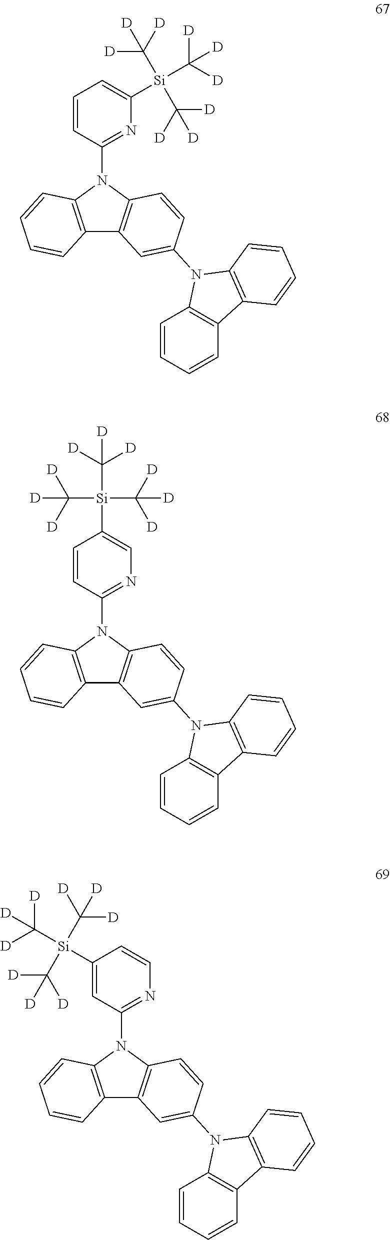 [SMILES: [2H]C([2H])([2H])[Si](c1cccc(-n2c3ccccc3c3cc(-n4c5ccccc5c5ccccc54)ccc32)n1)(C([2H])([2H])[2H])C([2H])([2H])[2H] ; [2H]C([2H])([2H])[Si](c1ccc(-n2c3ccccc3c3cc(-n4c5ccccc5c5ccccc54)ccc32)nc1)(C([2H])([2H])[2H])C([2H])([2H])[2H] ; [2H]C([2H])([2H])[Si](c1ccnc(-n2c3ccccc3c3cc(-n4c5ccccc5c5ccccc54)ccc32)c1)(C([2H])([2H])[2H])C([2H])([2H])[2H]]

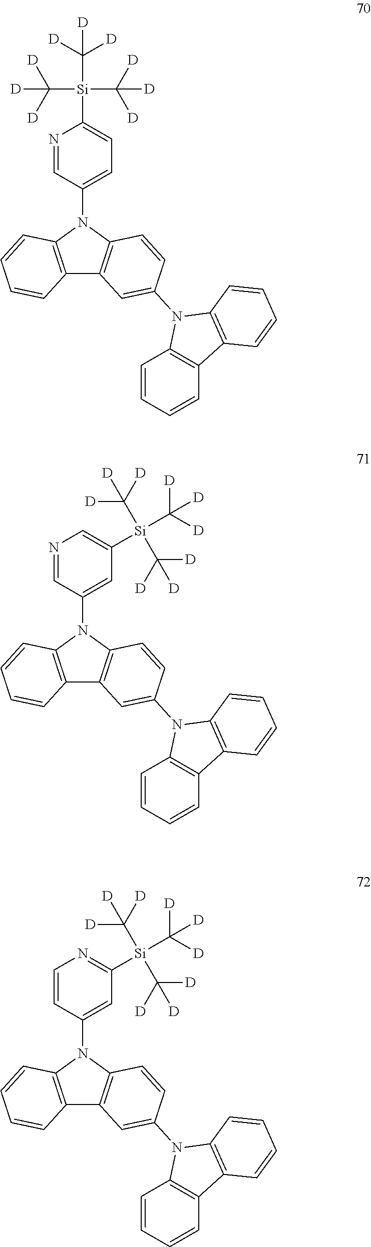 [SMILES: [2H]C([2H])([2H])[Si](c1ccc(-n2c3ccccc3c3cc(-n4c5ccccc5c5ccccc54)ccc32)cn1)(C([2H])([2H])[2H])C([2H])([2H])[2H] ; [2H]C([2H])([2H])[Si](c1cncc(-n2c3ccccc3c3cc(-n4c5ccccc5c5ccccc54)ccc32)c1)(C([2H])([2H])[2H])C([2H])([2H])[2H] ; [2H]C([2H])([2H])[Si](c1cc(-n2c3ccccc3c3cc(-n4c5ccccc5c5ccccc54)ccc32)ccn1)(C([2H])([2H])[2H])C([2H])([2H])[2H]]

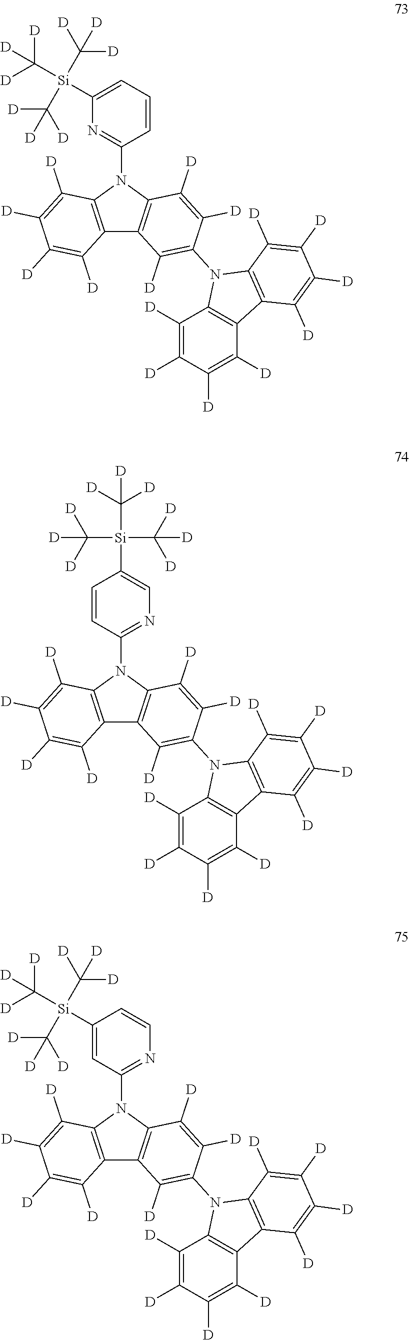

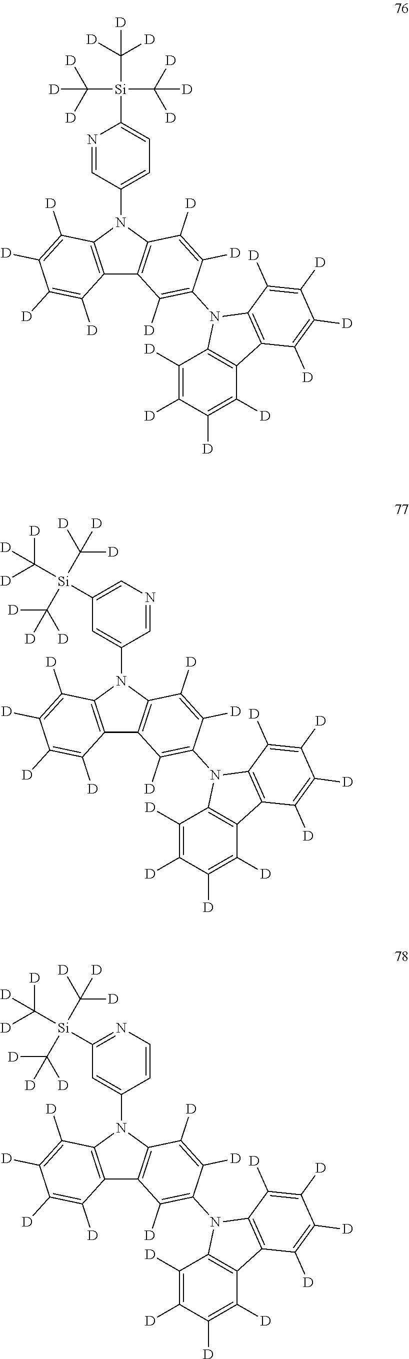

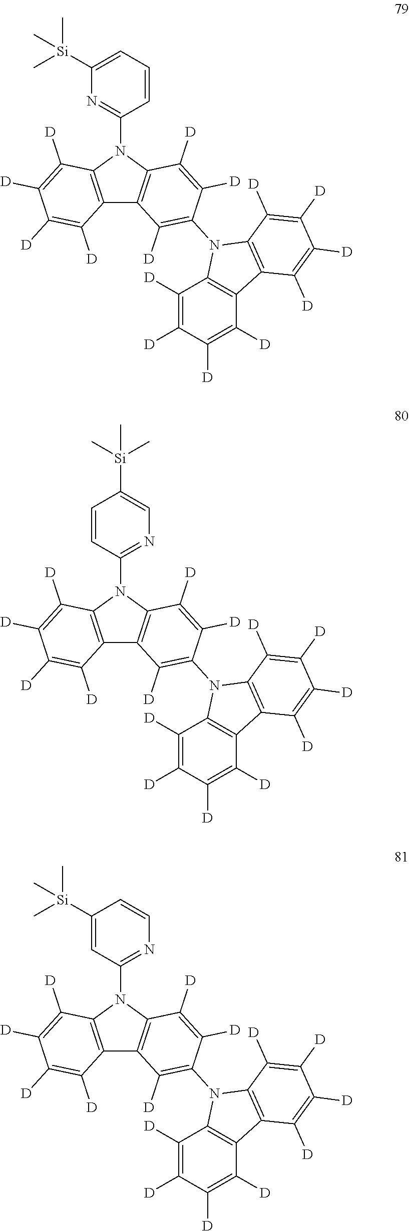 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cccc([Si](C)(C)C)n1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccc([Si](C)(C)C)cn1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cc([Si](C)(C)C)ccn1]

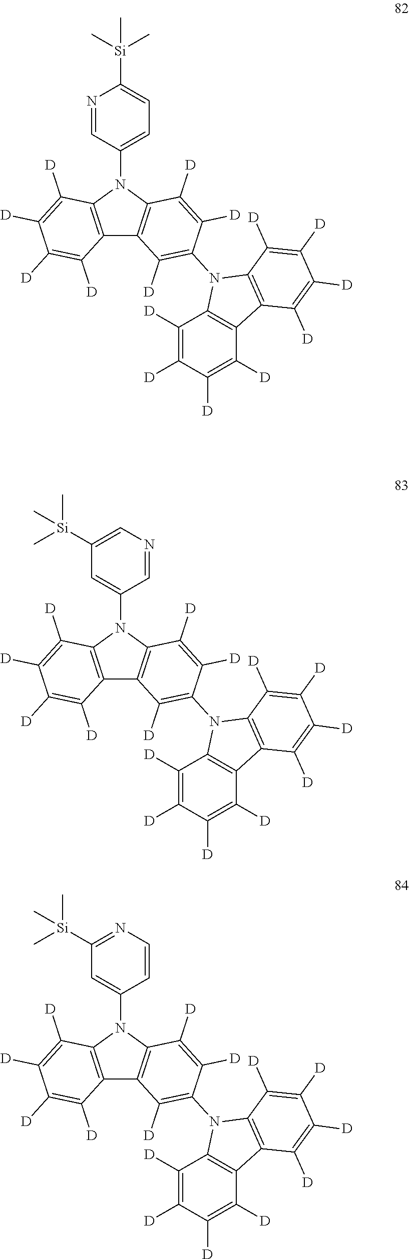 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccc([Si](C)(C)C)nc1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cncc([Si](C)(C)C)c1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccnc([Si](C)(C)C)c1]

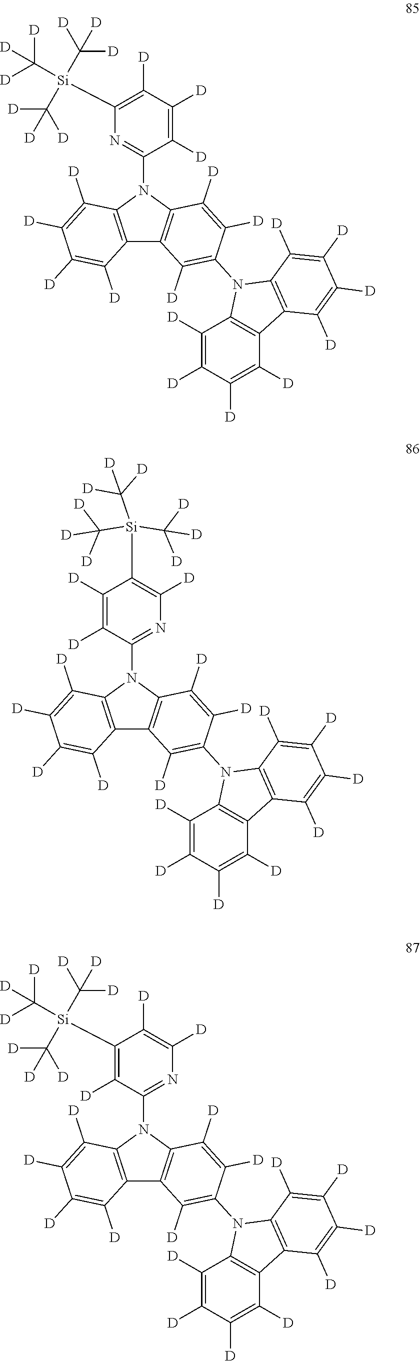

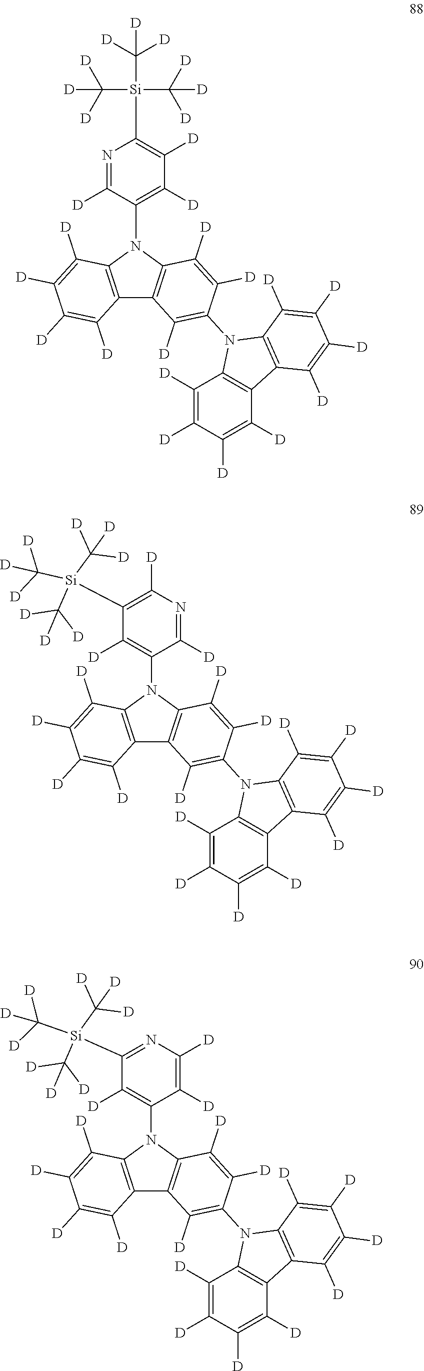

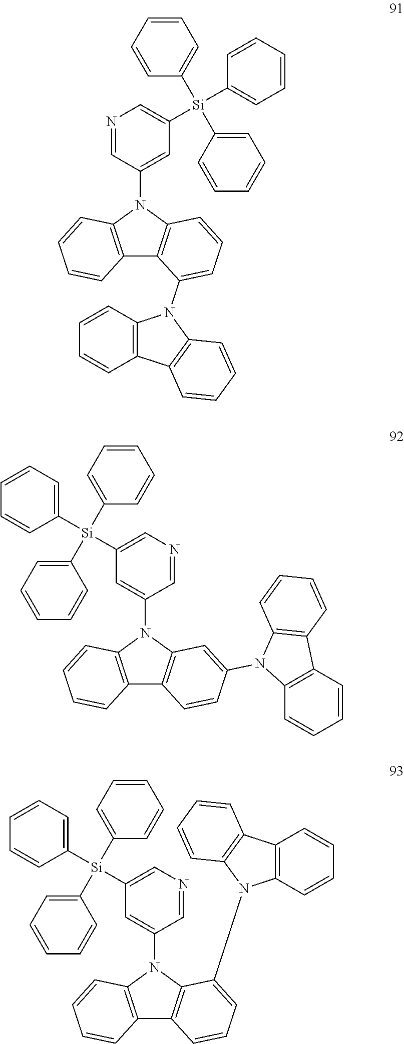 [SMILES: c1ccc([Si](c2ccccc2)(c2ccccc2)c2cncc(-n3c4ccccc4c4c(-n5c6ccccc6c6ccccc65)cccc43)c2)cc1 ; c1ccc([Si](c2ccccc2)(c2ccccc2)c2cncc(-n3c4ccccc4c4ccc(-n5c6ccccc6c6ccccc65)cc43)c2)cc1 ; c1ccc([Si](c2ccccc2)(c2ccccc2)c2cncc(-n3c4ccccc4c4cccc(-n5c6ccccc6c6ccccc65)c43)c2)cc1]

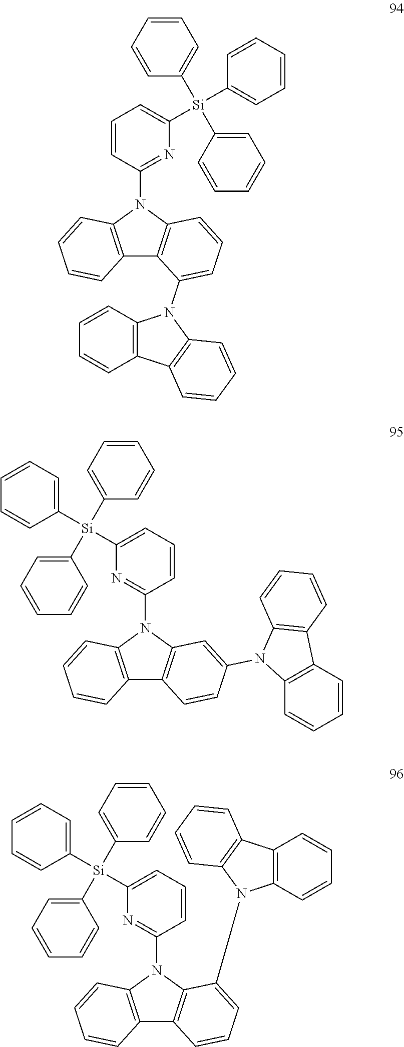 [SMILES: c1ccc([Si](c2ccccc2)(c2ccccc2)c2cccc(-n3c4ccccc4c4c(-n5c6ccccc6c6ccccc65)cccc43)n2)cc1 ; c1ccc([Si](c2ccccc2)(c2ccccc2)c2cccc(-n3c4ccccc4c4ccc(-n5c6ccccc6c6ccccc65)cc43)n2)cc1 ; c1ccc([Si](c2ccccc2)(c2ccccc2)c2cccc(-n3c4ccccc4c4cccc(-n5c6ccccc6c6ccccc65)c43)n2)cc1]

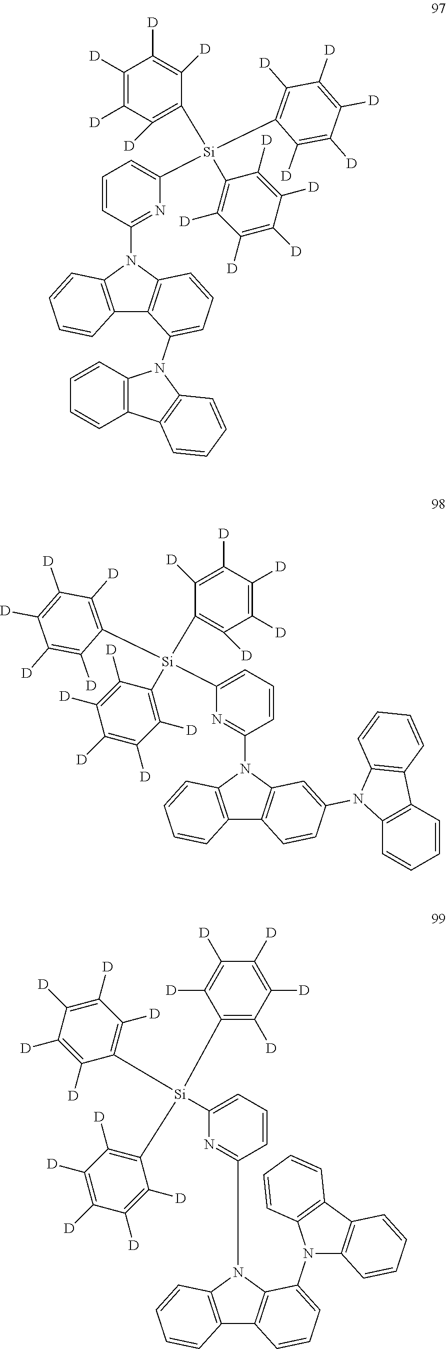

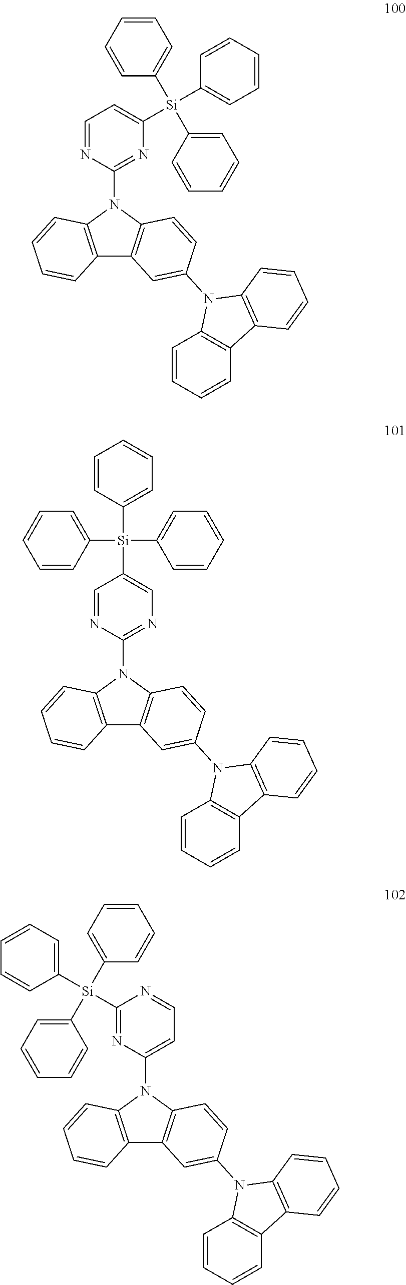 [SMILES: c1ccc([Si](c2ccccc2)(c2ccccc2)c2ccnc(-n3c4ccccc4c4cc(-n5c6ccccc6c6ccccc65)ccc43)n2)cc1 ; c1ccc([Si](c2ccccc2)(c2ccccc2)c2cnc(-n3c4ccccc4c4cc(-n5c6ccccc6c6ccccc65)ccc43)nc2)cc1 ; c1ccc([Si](c2ccccc2)(c2ccccc2)c2nccc(-n3c4ccccc4c4cc(-n5c6ccccc6c6ccccc65)ccc43)n2)cc1]

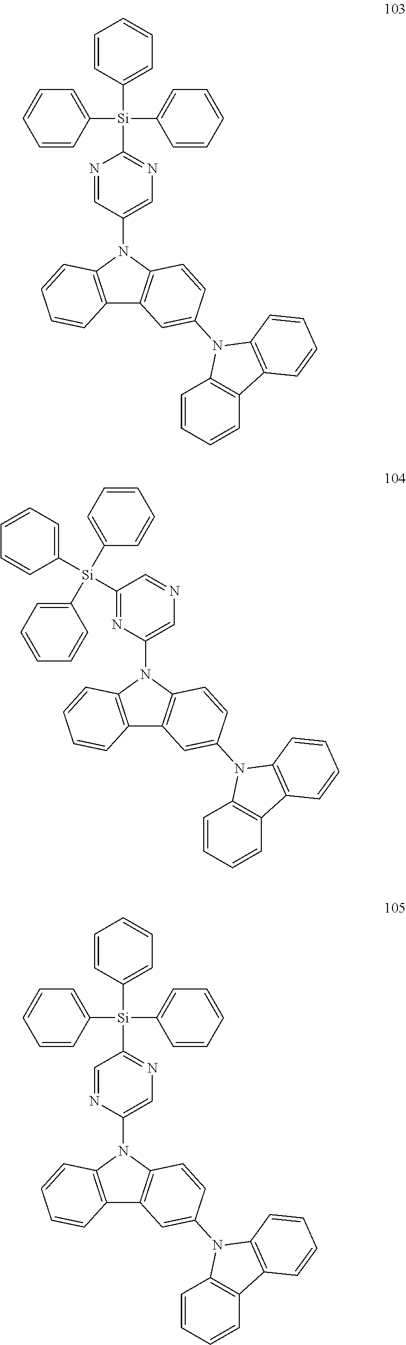 [SMILES: c1ccc([Si](c2ccccc2)(c2ccccc2)c2ncc(-n3c4ccccc4c4cc(-n5c6ccccc6c6ccccc65)ccc43)cn2)cc1 ; c1ccc([Si](c2ccccc2)(c2ccccc2)c2cncc(-n3c4ccccc4c4cc(-n5c6ccccc6c6ccccc65)ccc43)n2)cc1 ; c1ccc([Si](c2ccccc2)(c2ccccc2)c2cnc(-n3c4ccccc4c4cc(-n5c6ccccc6c6ccccc65)ccc43)cn2)cc1]

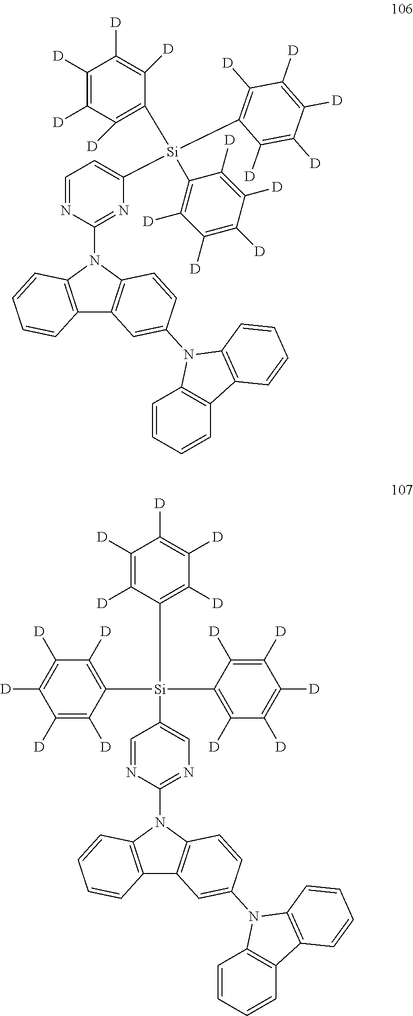 [SMILES: [2H]c1c([2H])c([2H])c([Si](c2ccnc(-n3c4ccccc4c4cc(-n5c6ccccc6c6ccccc65)ccc43)n2)(c2c([2H])c([2H])c([2H])c([2H])c2[2H])c2c([2H])c([2H])c([2H])c([2H])c2[2H])c([2H])c1[2H] ; [2H]c1c([2H])c([2H])c([Si](c2cnc(-n3c4ccccc4c4cc(-n5c6ccccc6c6ccccc65)ccc43)nc2)(c2c([2H])c([2H])c([2H])c([2H])c2[2H])c2c([2H])c([2H])c([2H])c([2H])c2[2H])c([2H])c1[2H]]

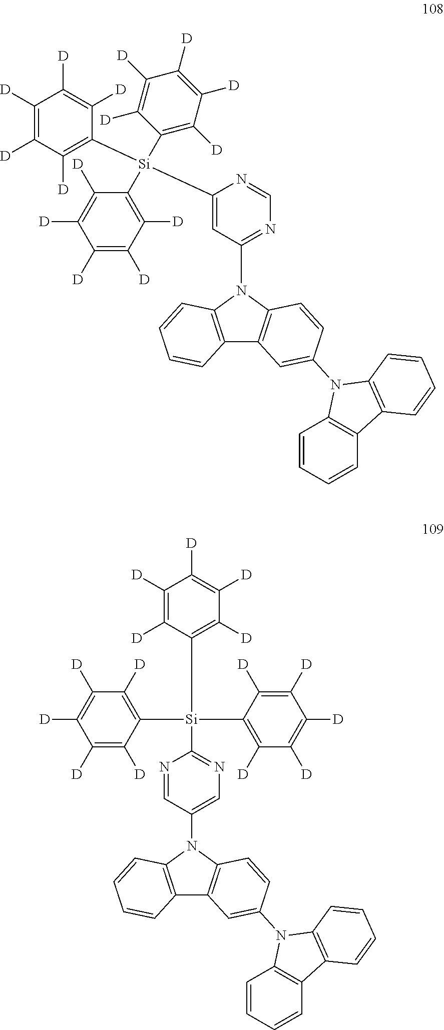 [SMILES: [2H]c1c([2H])c([2H])c([Si](c2cc(-n3c4ccccc4c4cc(-n5c6ccccc6c6ccccc65)ccc43)ncn2)(c2c([2H])c([2H])c([2H])c([2H])c2[2H])c2c([2H])c([2H])c([2H])c([2H])c2[2H])c([2H])c1[2H] ; [2H]c1c([2H])c([2H])c([Si](c2ncc(-n3c4ccccc4c4cc(-n5c6ccccc6c6ccccc65)ccc43)cn2)(c2c([2H])c([2H])c([2H])c([2H])c2[2H])c2c([2H])c([2H])c([2H])c([2H])c2[2H])c([2H])c1[2H]]

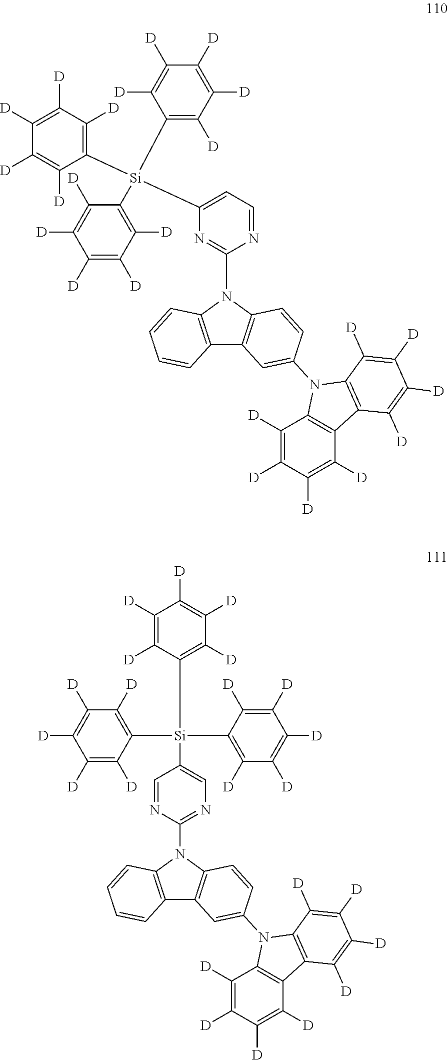 [SMILES: [2H]c1c([2H])c([2H])c([Si](c2ccnc(-n3c4ccccc4c4cc(-n5c6c([2H])c([2H])c([2H])c([2H])c6c6c([2H])c([2H])c([2H])c([2H])c65)ccc43)n2)(c2c([2H])c([2H])c([2H])c([2H])c2[2H])c2c([2H])c([2H])c([2H])c([2H])c2[2H])c([2H])c1[2H] ; [2H]c1c([2H])c([2H])c([Si](c2cnc(-n3c4ccccc4c4cc(-n5c6c([2H])c([2H])c([2H])c([2H])c6c6c([2H])c([2H])c([2H])c([2H])c65)ccc43)nc2)(c2c([2H])c([2H])c([2H])c([2H])c2[2H])c2c([2H])c([2H])c([2H])c([2H])c2[2H])c([2H])c1[2H]]

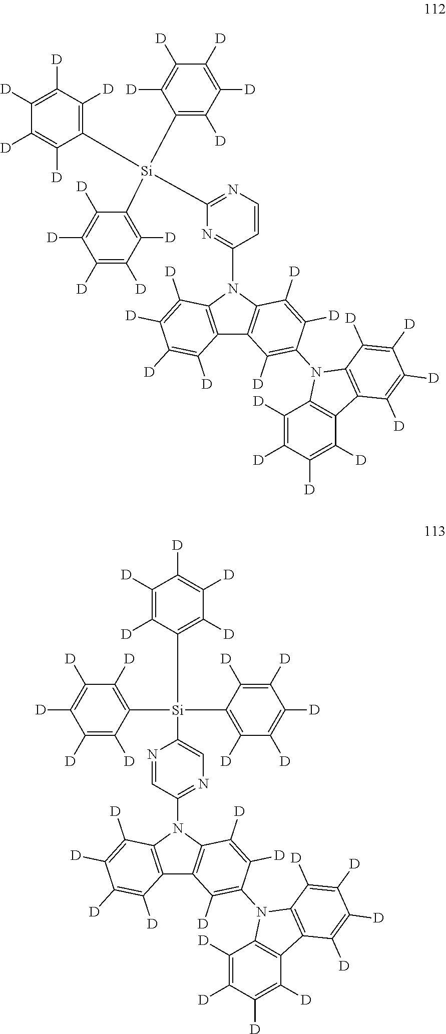

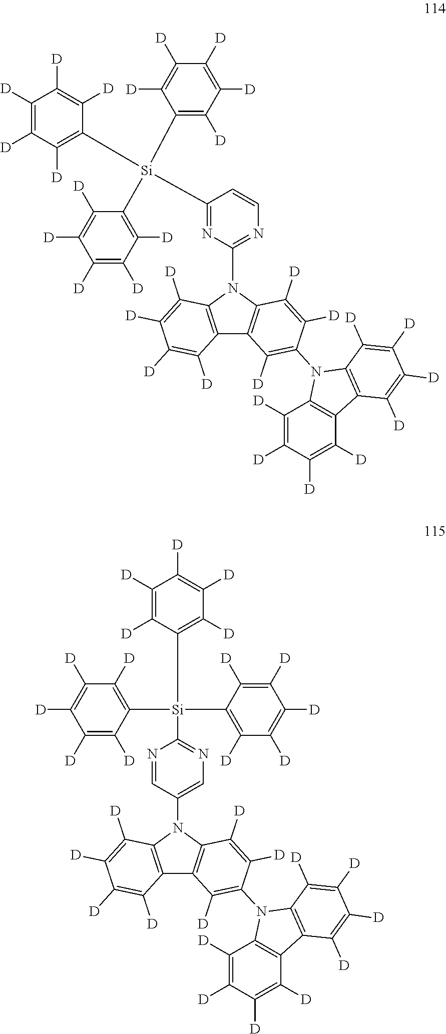

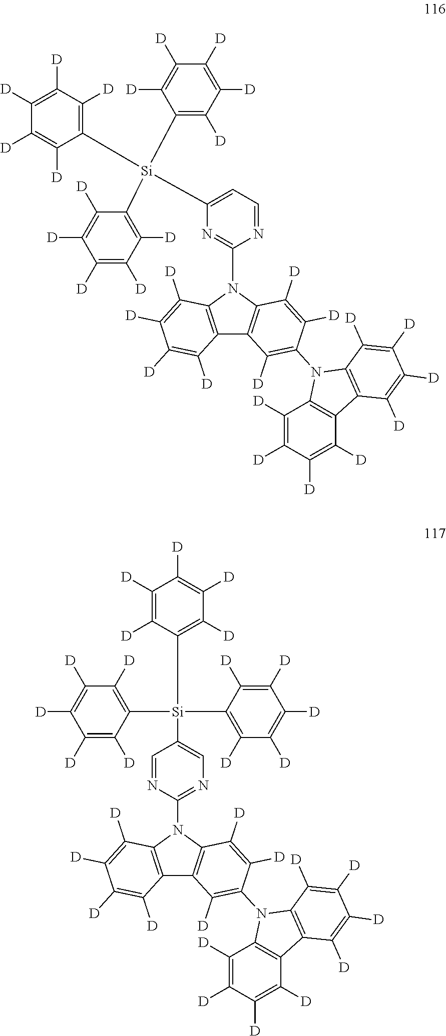

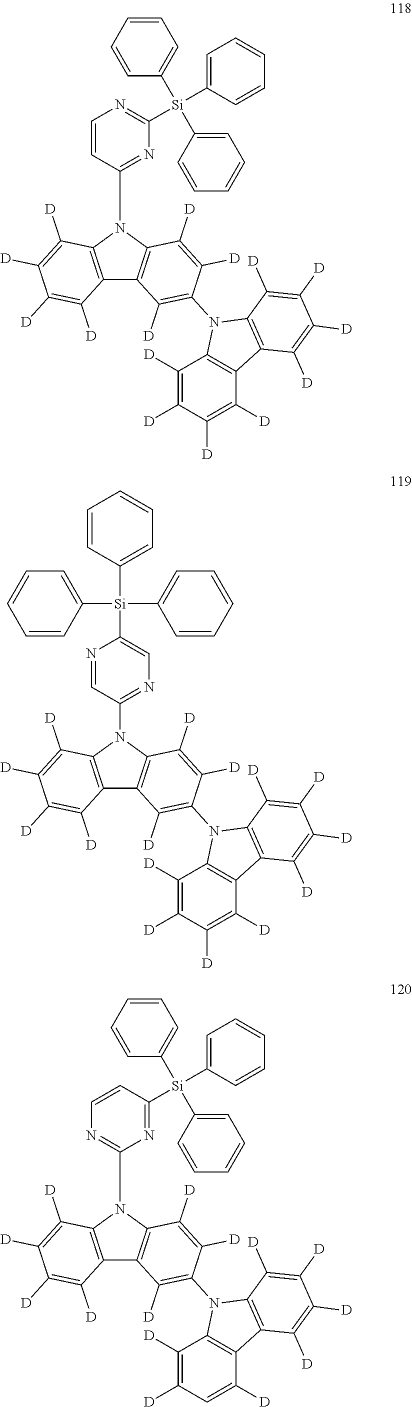

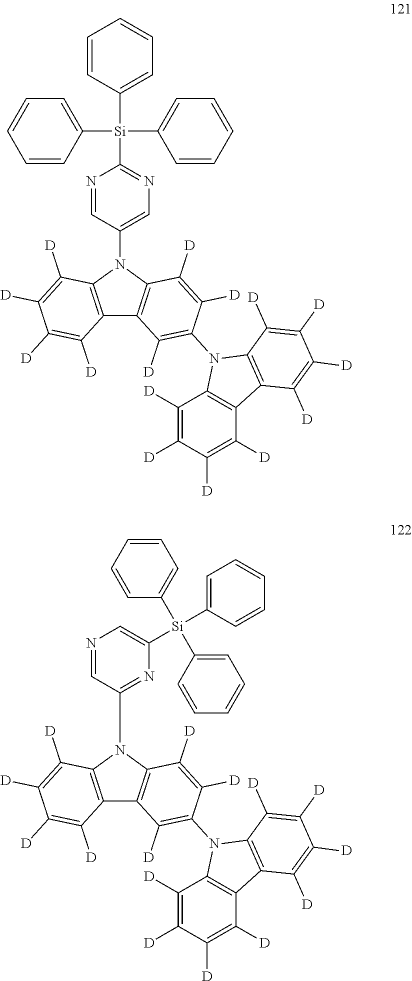 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cnc([Si](c2ccccc2)(c2ccccc2)c2ccccc2)nc1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cncc([Si](c2ccccc2)(c2ccccc2)c2ccccc2)n1]

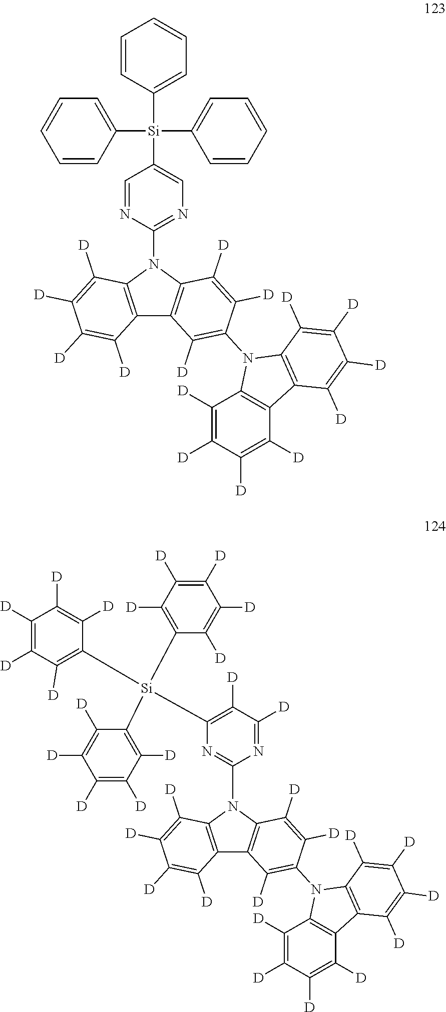 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ncc([Si](c2ccccc2)(c2ccccc2)c2ccccc2)cn1 ; [2H]c1nc(-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)nc([Si](c2c([2H])c([2H])c([2H])c([2H])c2[2H])(c2c([2H])c([2H])c([2H])c([2H])c2[2H])c2c([2H])c([2H])c([2H])c([2H])c2[2H])c1[2H]]

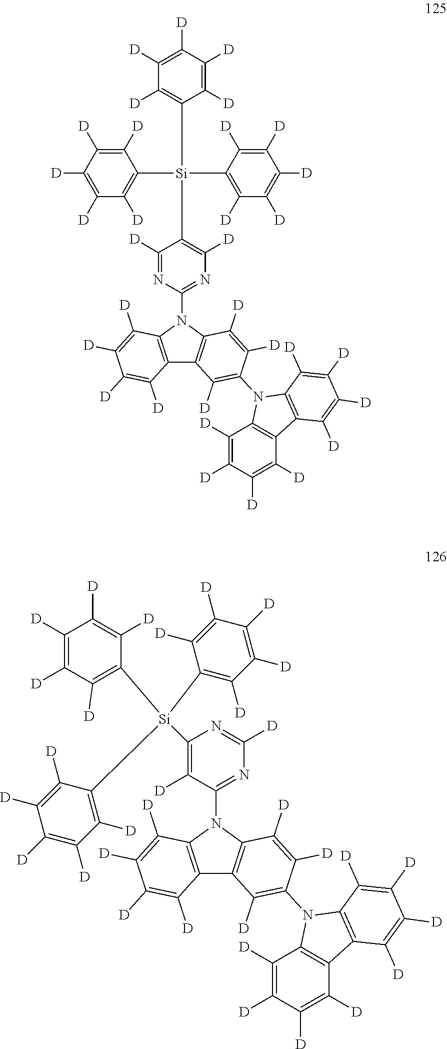

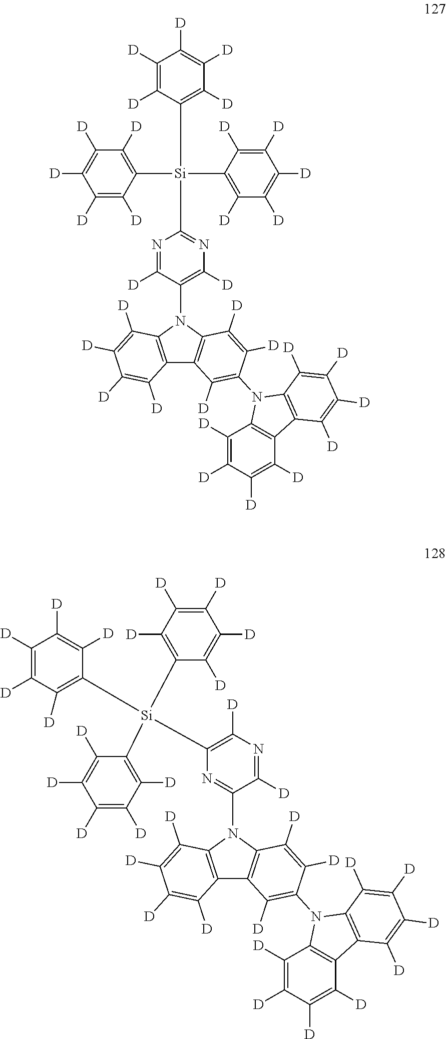

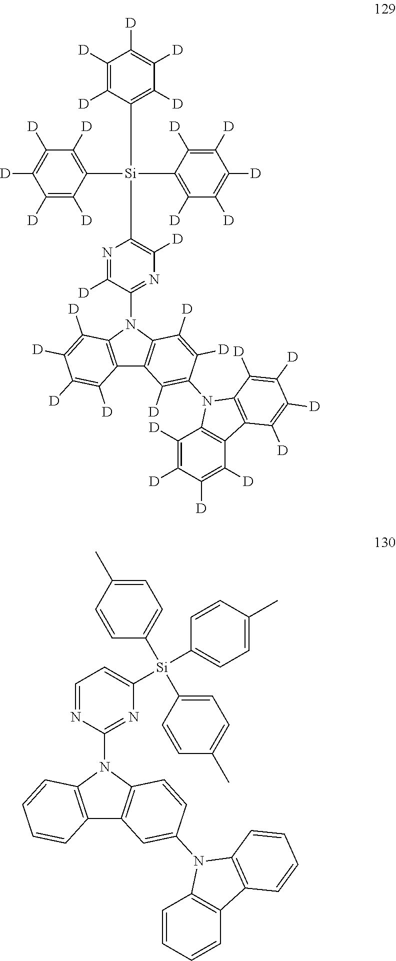 [SMILES: [2H]c1nc([Si](c2c([2H])c([2H])c([2H])c([2H])c2[2H])(c2c([2H])c([2H])c([2H])c([2H])c2[2H])c2c([2H])c([2H])c([2H])c([2H])c2[2H])c([2H])nc1-n1c2c([2H])c([2H])c([2H])c([2H])c2c2c([2H])c(-n3c4c([2H])c([2H])c([2H])c([2H])c4c4c([2H])c([2H])c([2H])c([2H])c43)c([2H])c([2H])c21 ; Cc1ccc([Si](c2ccc(C)cc2)(c2ccc(C)cc2)c2ccnc(-n3c4ccccc4c4cc(-n5c6ccccc6c6ccccc65)ccc43)n2)cc1]

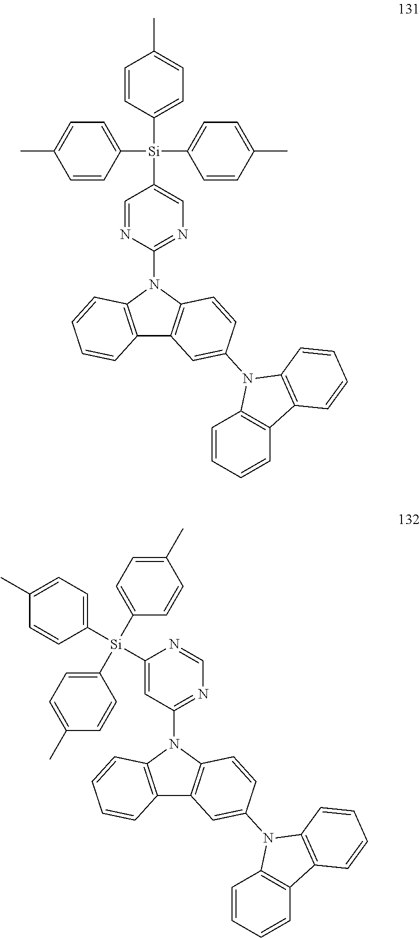 [SMILES: Cc1ccc([Si](c2ccc(C)cc2)(c2ccc(C)cc2)c2cnc(-n3c4ccccc4c4cc(-n5c6ccccc6c6ccccc65)ccc43)nc2)cc1 ; Cc1ccc([Si](c2ccc(C)cc2)(c2ccc(C)cc2)c2cc(-n3c4ccccc4c4cc(-n5c6ccccc6c6ccccc65)ccc43)ncn2)cc1]

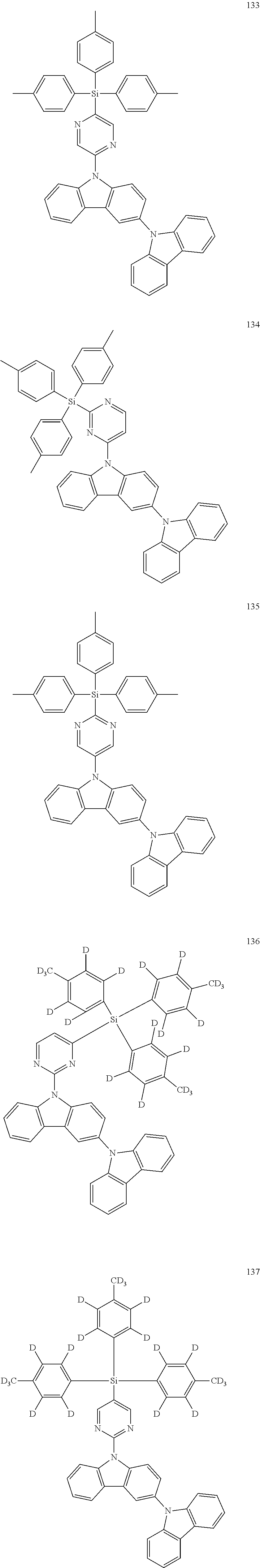

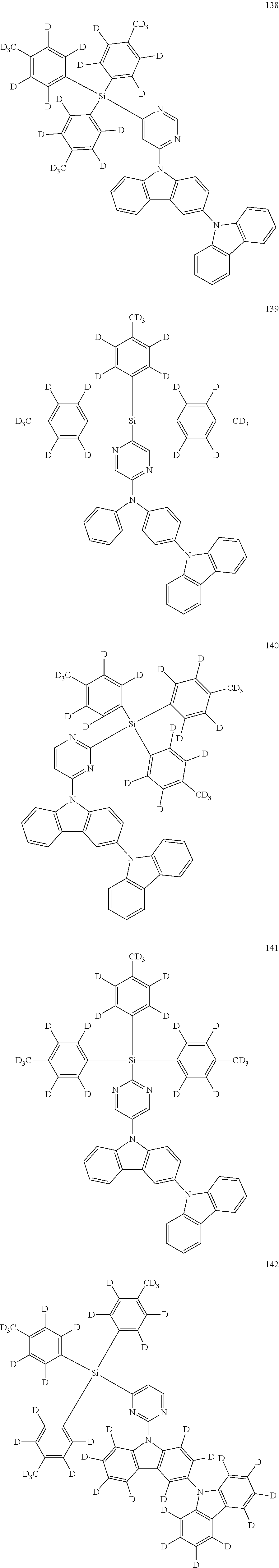

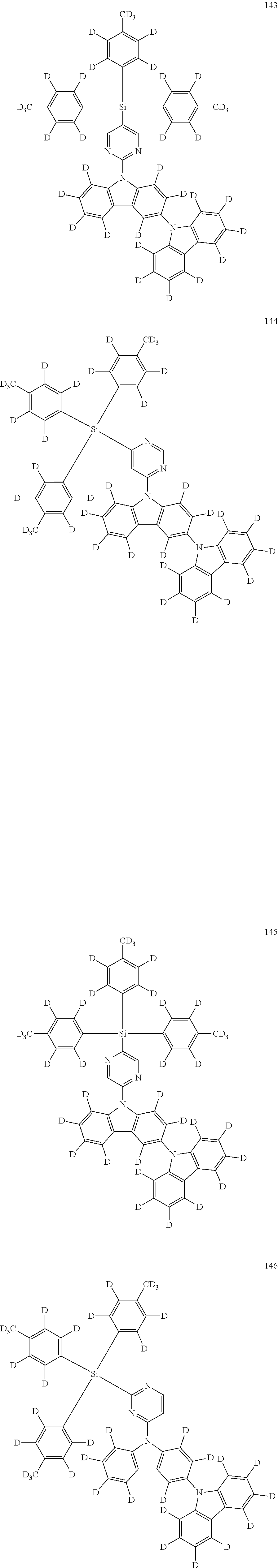

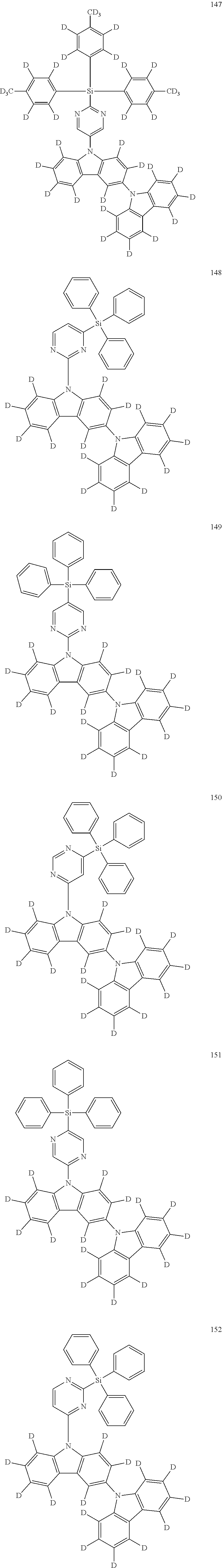

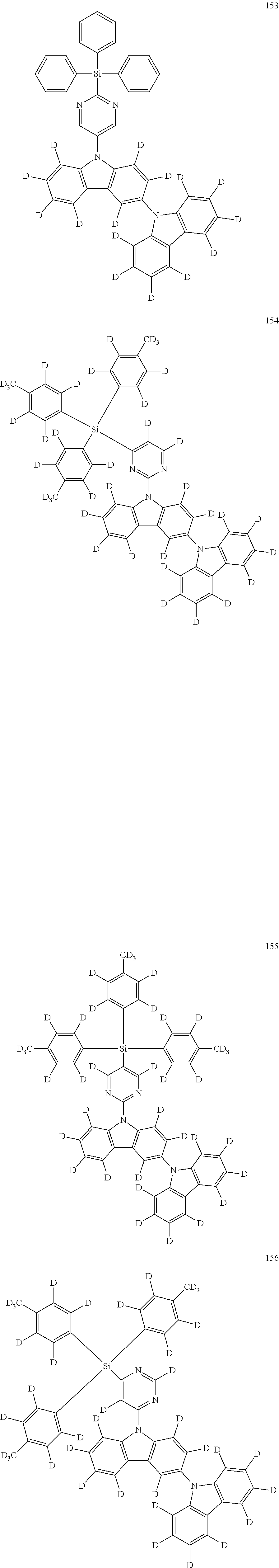

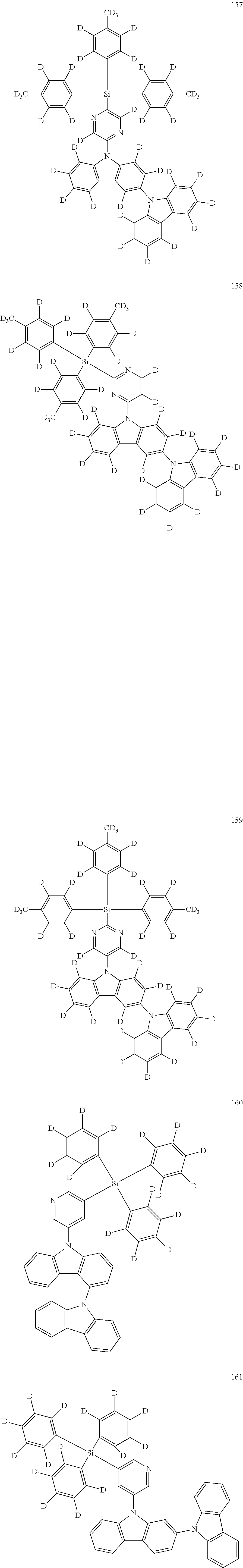

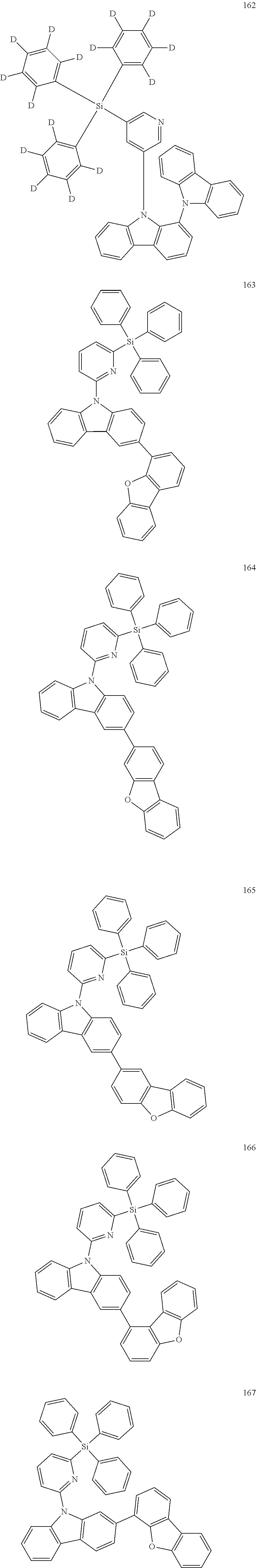

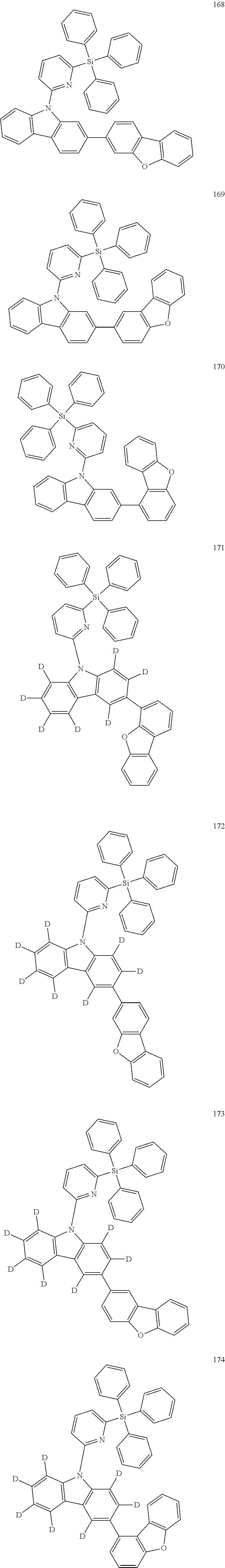

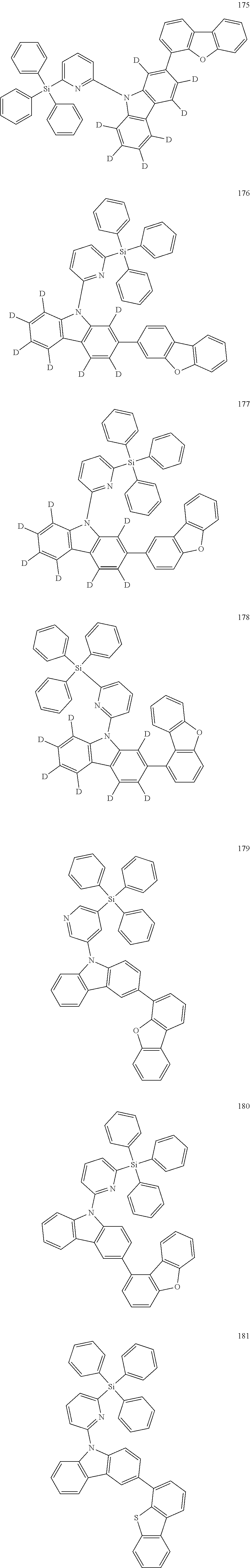

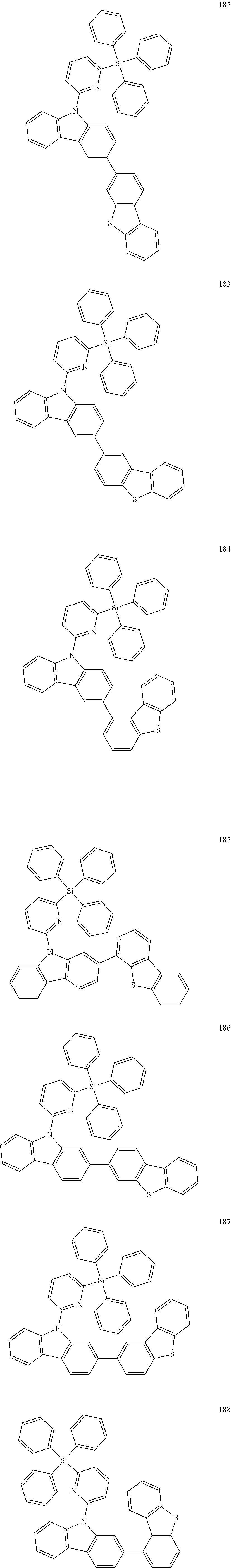

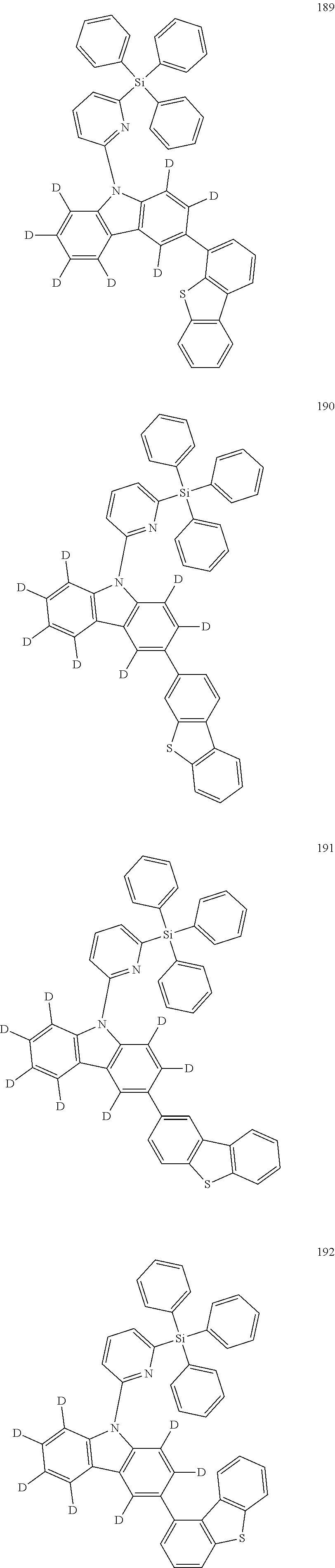

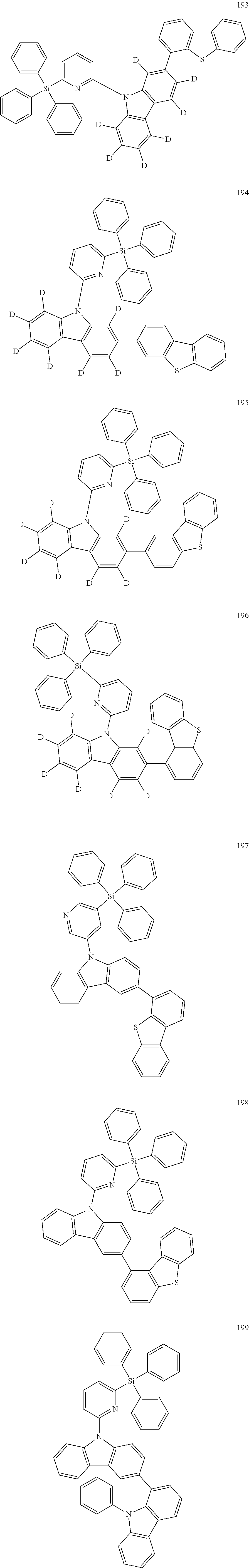

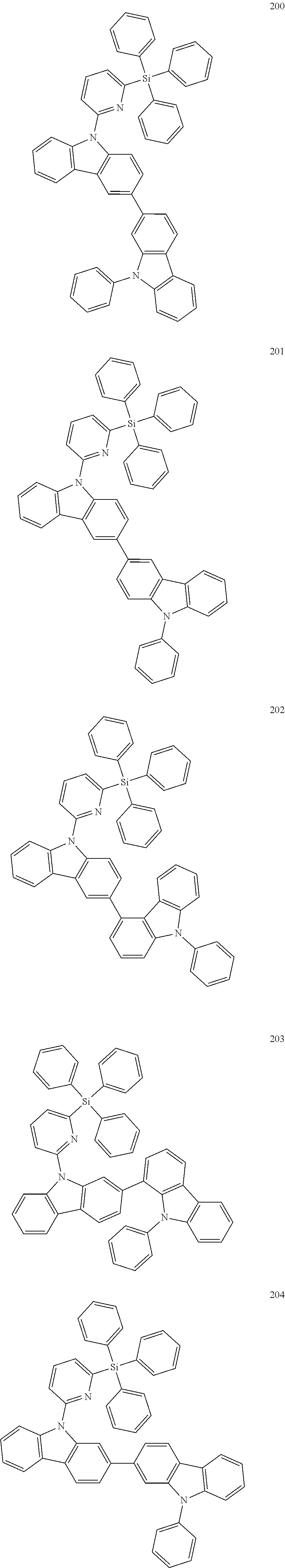 [SMILES: c1ccc(-n2c3ccccc3c3ccc(-c4ccc5c(c4)c4ccccc4n5-c4cccc([Si](c5ccccc5)(c5ccccc5)c5ccccc5)n4)cc32)cc1 ; c1ccc(-n2c3ccccc3c3cc(-c4ccc5c(c4)c4ccccc4n5-c4cccc([Si](c5ccccc5)(c5ccccc5)c5ccccc5)n4)ccc32)cc1 ; c1ccc(-n2c3ccccc3c3c(-c4ccc5c(c4)c4ccccc4n5-c4cccc([Si](c5ccccc5)(c5ccccc5)c5ccccc5)n4)cccc32)cc1 ; c1ccc(-n2c3ccccc3c3cccc(-c4ccc5c6ccccc6n(-c6cccc([Si](c7ccccc7)(c7ccccc7)c7ccccc7)n6)c5c4)c32)cc1 ; c1ccc(-n2c3ccccc3c3ccc(-c4ccc5c6ccccc6n(-c6cccc([Si](c7ccccc7)(c7ccccc7)c7ccccc7)n6)c5c4)cc32)cc1]

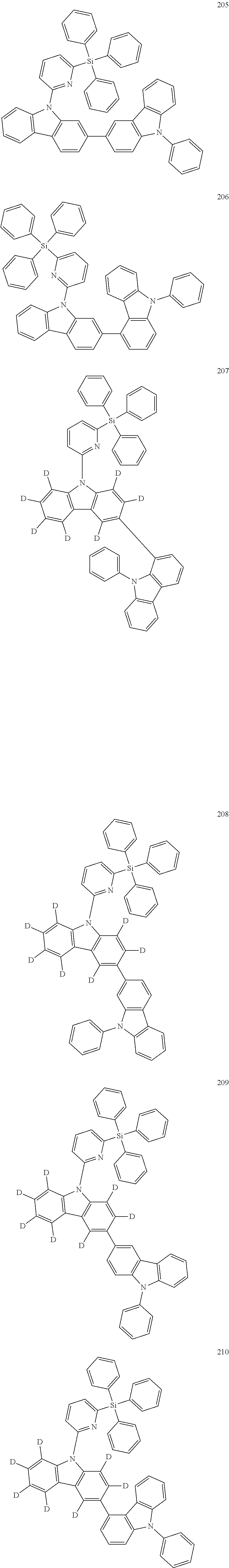

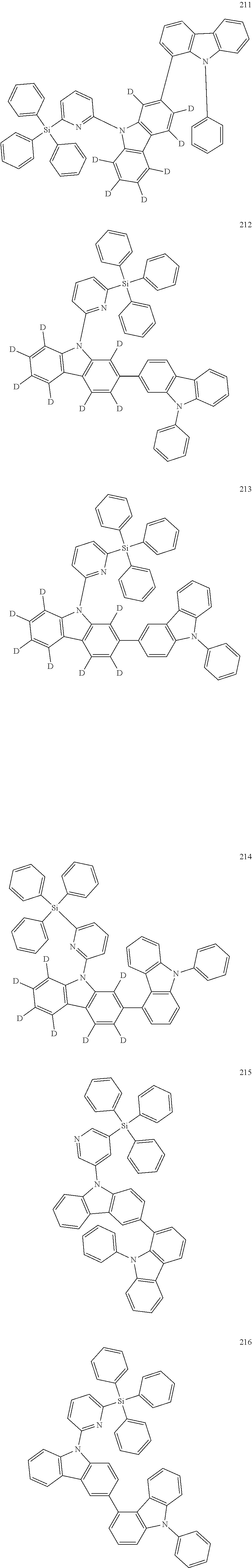

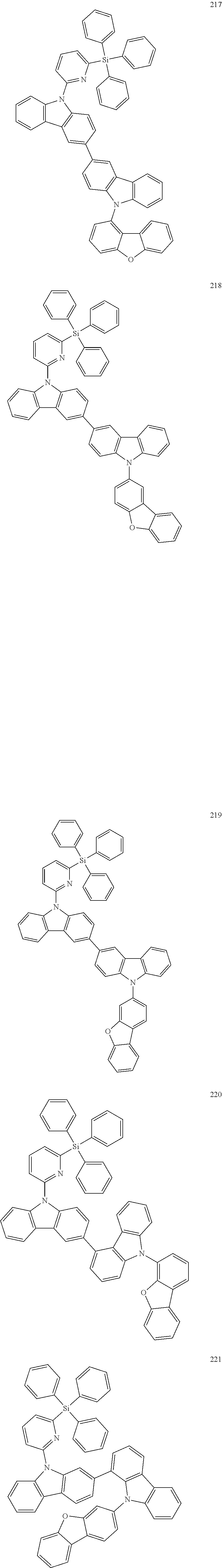

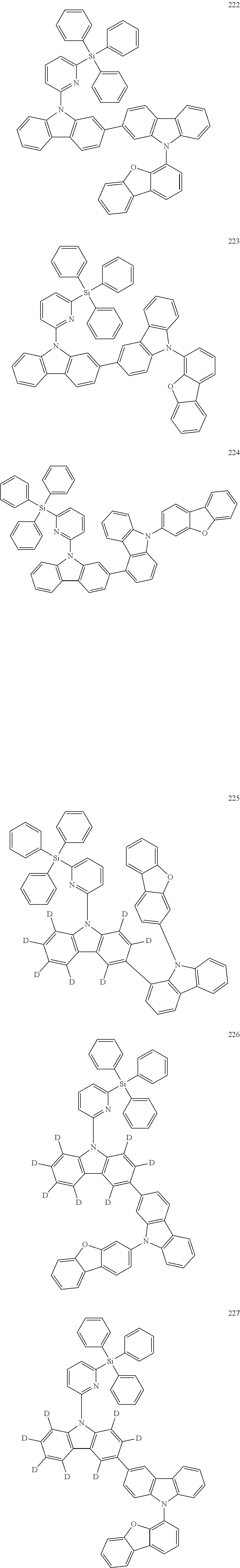

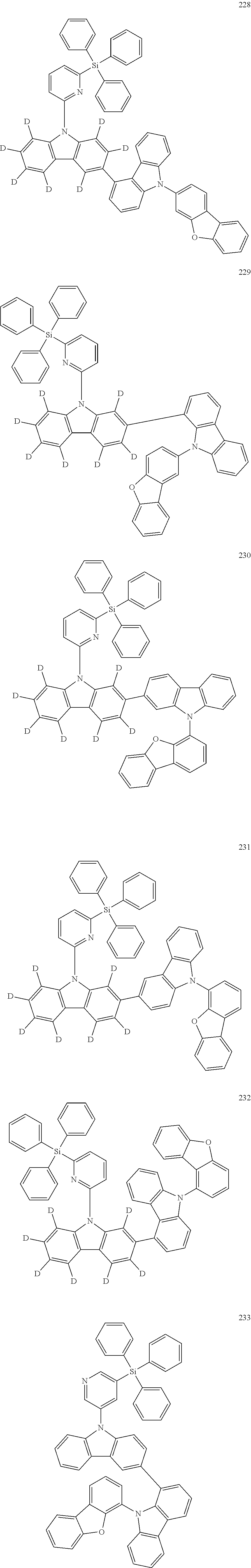

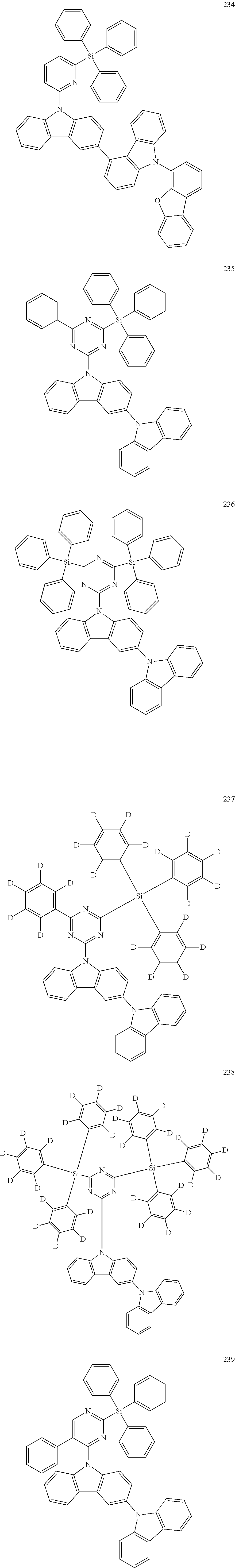

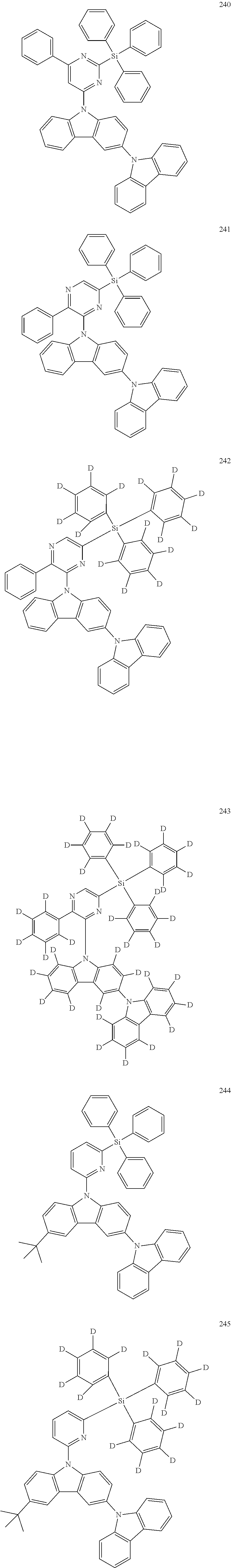

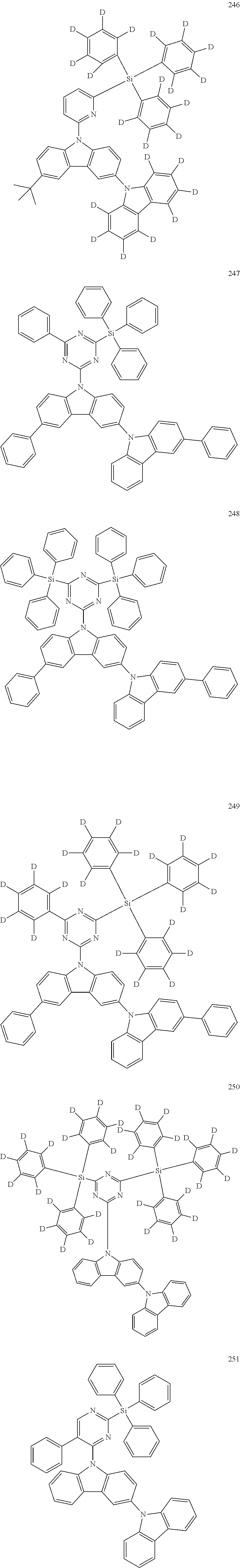

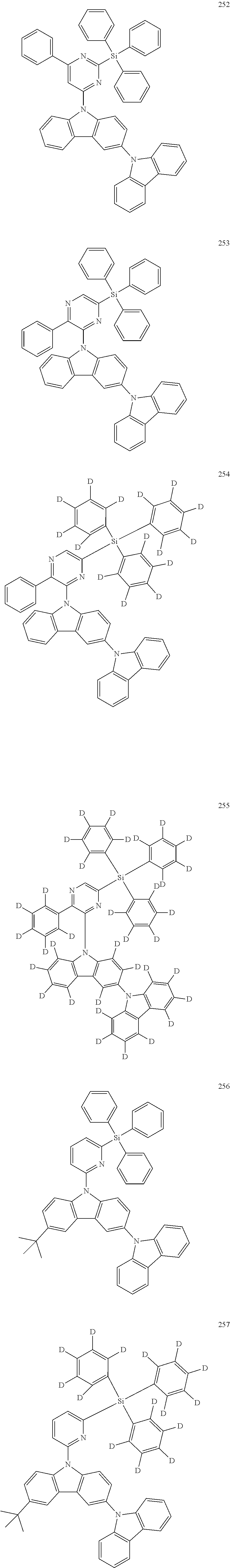

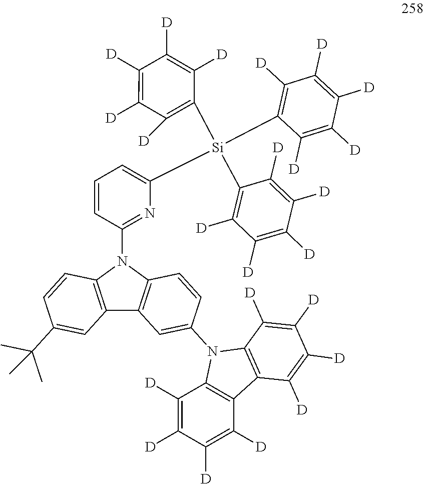 [SMILES: [2H]c1c([2H])c([2H])c([Si](c2cccc(-n3c4ccc(-n5c6c([2H])c([2H])c([2H])c([2H])c6c6c([2H])c([2H])c([2H])c([2H])c65)cc4c4cc(C(C)(C)C)ccc43)n2)(c2c([2H])c([2H])c([2H])c([2H])c2[2H])c2c([2H])c([2H])c([2H])c([2H])c2[2H])c([2H])c1[2H]]

The nitrogen-containing compound represented by any one among Formula 1-1 to Formula 1-4, according to an aspect, may have a structure in which the first substituent and the second substituent are introduced to the heterocyclic core, and thus improvements in luminous characteristics and long lifespan may be achieved.

The nitrogen-containing compound according to an aspect includes a heterocyclic core in which one or more among carbon atoms of a benzene ring is substituted with N, and the first substituent and the second substituent are connected to an arbitrary carbon atom in the heterocyclic core. The first substituent has a structure the first heterocycle of a moiety such carbazole and the second heterocycle are connected, and the second substituent includes a silyl group. Due to inclusion of the heterocyclic core, the first substituent, and the second substituent, the nitrogen-containing compound according to an aspect has high triplet (T1) energy level characteristics and bipolar characteristics, and thus may achieve high charge transport capability when introduced to the hole transport region HTR of the light-emitting element ED. When the nitrogen-containing compound according to an aspect is applied to the hole transport region HTR, the light-emitting element having improvements in high efficiency and long lifespan may be implemented.

In the light-emitting element ED according to an aspect, the hole transport region HTR may further include a compound represented by Formula H-1 below. In the light-emitting element ED according to an aspect, the hole transport region HTR may include a hole injection layer HIL, and a hole transport layer HTL, and the hole transport layer HTL may include a first hole transport layer HTL1 and a second hole transport layer HTL2, and the first hole transport layer HTL1 may include a compound represented by Formula H-1 below.

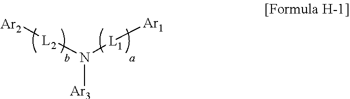

In Formula H-1 above, L₁ and L₂ may be each independently a direct linkage, a substituted or unsubstituted arylene group having 6 to 30 ring-forming carbons, or a substituted or unsubstituted heteroarylene group having 2 to 30 ring-forming carbons. a and b may be an integer of 0 to 10. Meanwhile, if a or b is an integer of 2 or greater, L₁ and L₂ that are plural may be each independently a substituted or unsubstituted arylene group having 6 to 30 ring-forming carbons, or a substituted or unsubstituted heteroarylene group having 2 to 30 ring-forming carbons.

In Formula H-1, Ar₁ and Ar₂ may be each independently a substituted or unsubstituted aryl group having 6 to 30 ring-forming carbons, or a substituted or unsubstituted heteroaryl group having 2 to 30 ring-forming carbons. In addition, in Formula H-1, Ar₃ may be a substituted or unsubstituted aryl group having 6 to 30 ring-forming carbons.

The compound represented by Formula H-1 above may be a monoamine compound. Alternatively, the compound represented by Formula H-1 above, may be a diamine compound in which at least one among Ar₁ to Ar₃ includes an amine group as a substituent. In addition, the compound represented by Formula H-1 above may be a carbazole-based compound including a substituted or unsubstituted carbazole group in at least one among Ar₁ and Ar₂, or a fluorene-based compound including a substituted or unsubstituted fluorene group in at least one among Ar₁ and Ar₂.

The compound represented by Formula H-1 may be represented by any one among compounds in Compound Group H below. However, the compounds present in Compound Group H below are suggested as examples, but the compound represented by Formula H-1 is not limited to the compounds present in Compound Group H below.

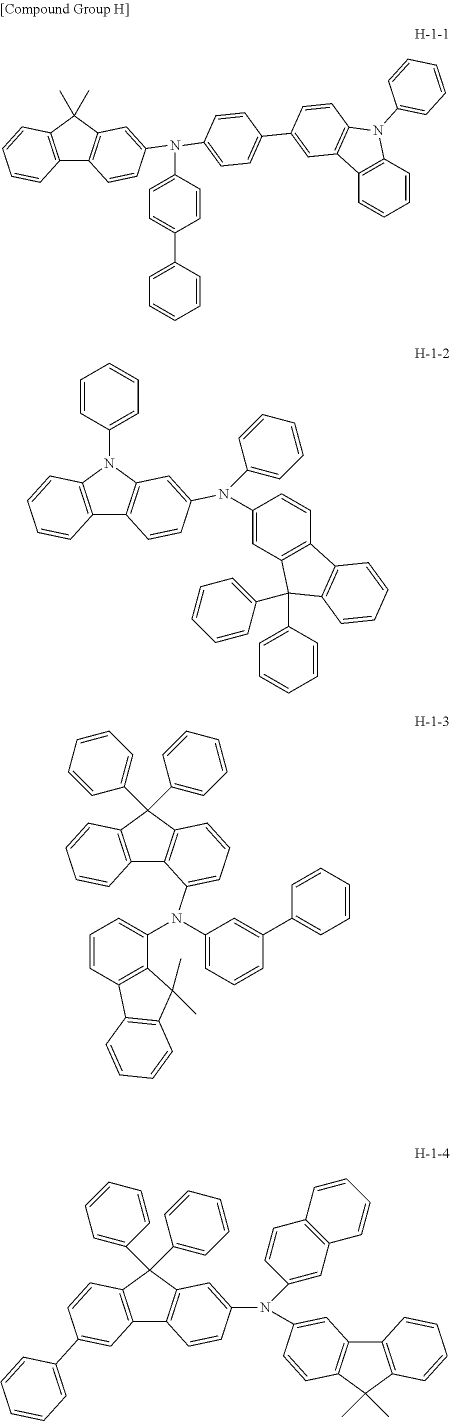 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

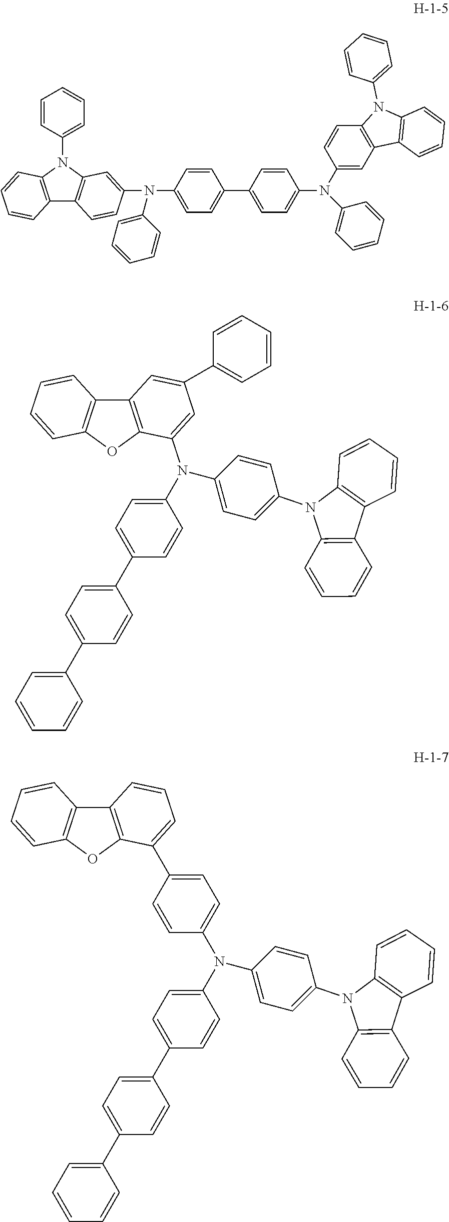 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

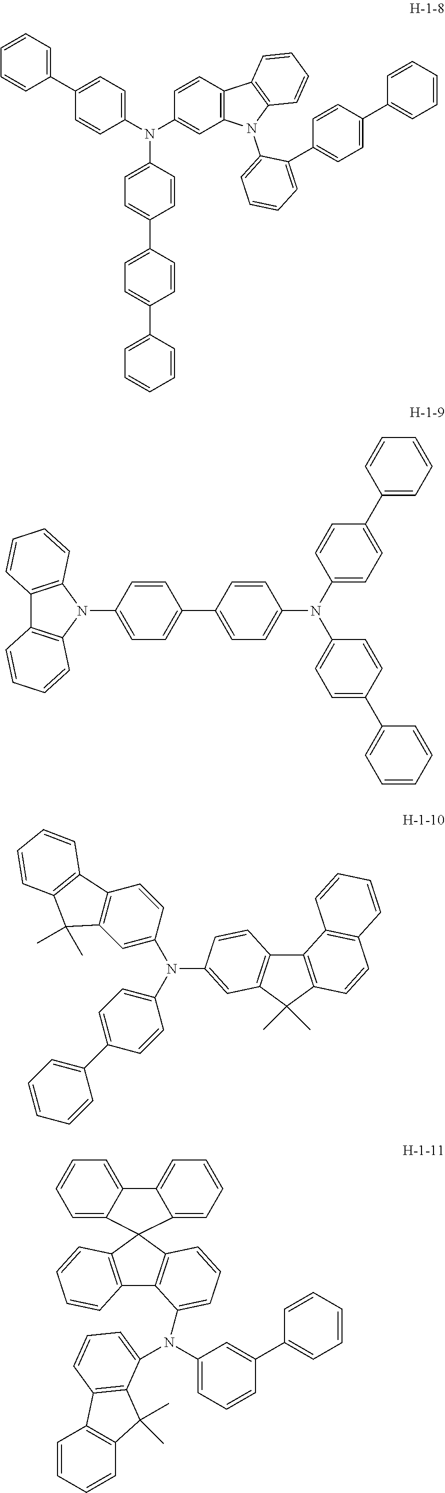

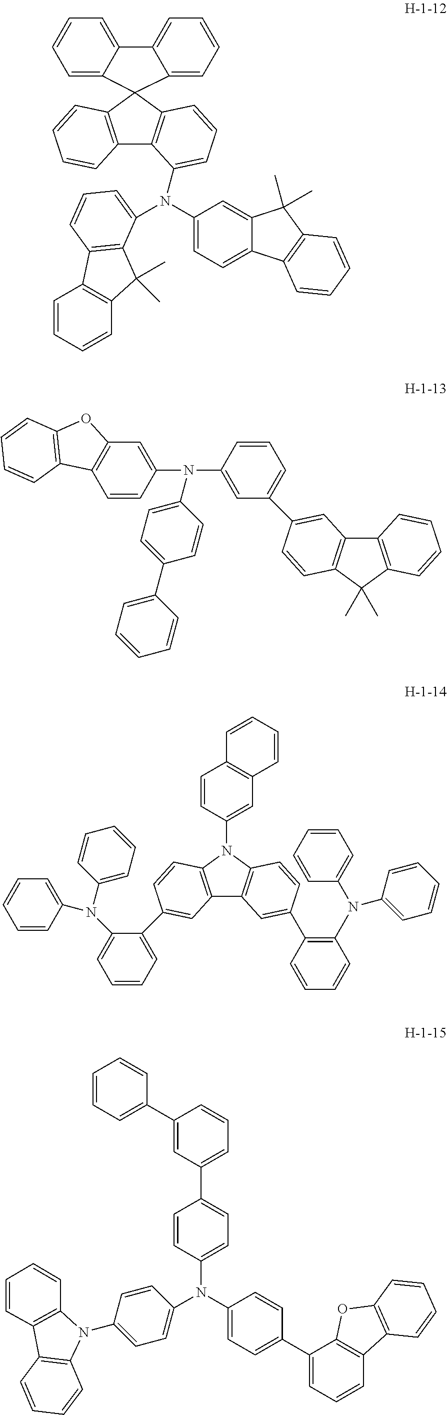 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

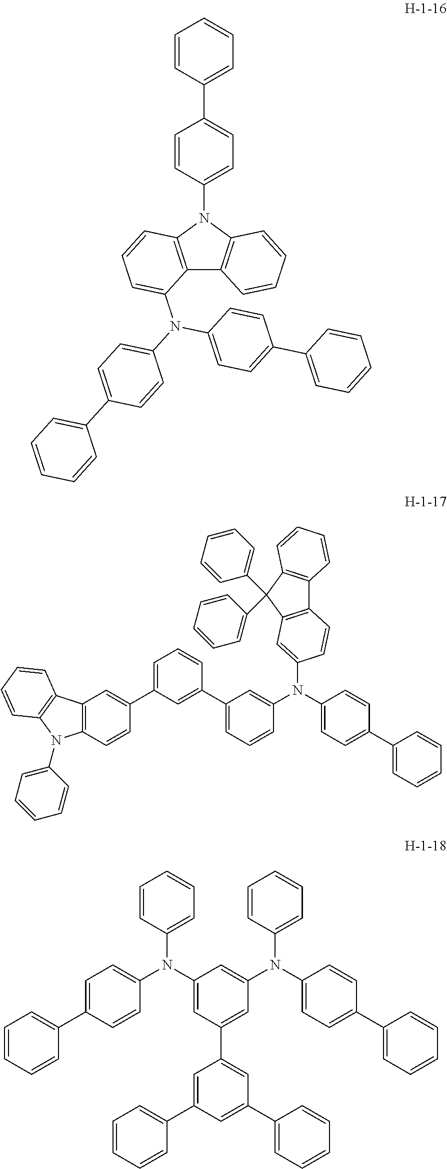 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

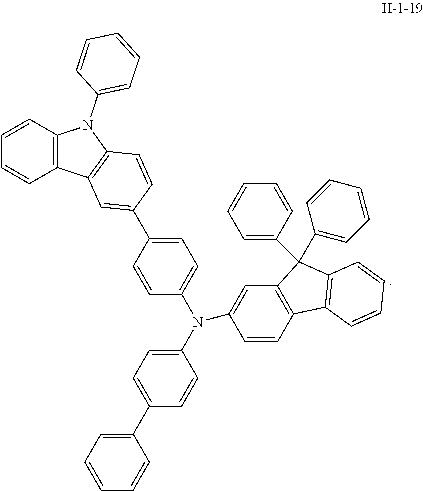 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

Besides, the hole transport region HTR may further include known hole transport materials. For example, the hole transport region HTR may include a phthalocyanine compound such as copper phthalocyanine, N1,N1′-([1,1′-biphenyl]-4,4′-diyl)bis(N1-phenyl-N4,N4-di-m-tolylbenzene-1,4-diamine) (DNTPD), 4,4′,4″-[tris(3-methylphenyl)phenyl amino]triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrene sulfonate) (PANI/PSS), N,N′-di(naphthalene-1-yl)-N,N′-diphenyl-benzidine (NPB), polyetherketone containing triphenylamine (TPAPEK), 4-isopropyl-4′-methyldiphenyliodonium [Tetrakis(pentafluorophenyl)borate], dipyrazino[2,3-f: 2′,3′-h]quinoxaline-2,3,6,7,10,11-hexacarbonitrile (HATCN), etc.

The hole transport region HTR may also include carbazole-based derivatives such as N-phenylcarbazole, and polyvinyl carbazol e, fluorene-based derivatives, triphenylamine-based derivatives such as N,N′-bis(3-methylphenyl)-N,N′-diphenyl-[1,1′-biphenyl]-4,4′-diamine (TPD), or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), etc.

In addition, the hole transport region HTR may include 9-(4-tert-butylphenyl)-3,6-bis(triphenylsilyl)-9H-carbazole (CzSi), 9-phenyl-9H-3,9′-bicarbazole (CCP), or 1,3-bis(1,8-dimethyl-9H-carbazol-9-yl)benzene (mDCP), etc.

The hole transport region HTR may include the above-described compounds for the hole transport region in at least one among the hole injection HIL, the hole transport layer HTL, and the electron blocking layer EBL.

A thickness of the hole transport region HTR may be about 100 Å to about 10000 Å, for example, about 100 Å to about 5000 Å. When the hole transport region HTR includes the hole injection layer HIL, a thickness of the hole injection layer HIL may be, for example, about 30 Å to about 1000 Å. When the hole transport region includes the hole transport layer HTL, a thickness of the hole transport layer HTL may be about 30 Å to about 1000 Å. For example, when the hole transport region HTR includes the electron blocking layer EBL, a thickness of the electron blocking layer EBL may be about 10 Å to about 1000 Å. When thicknesses of the hole transport region HTR, the hole injection layer HIL, the hole transport layer HTL, and the electron blocking layer EBL fall within the above-described ranges, hole transporting characteristics in a satisfactory degree may be obtained without increasing in substantial driving voltage.

The hole transport region HTR may further include a charge generating material for improving conductivity in addition to the materials described previously. The charge generating material may be uniformly or non-uniformly distributed in the hole transport region HTR. The charge generating material may be, for example, a p-dopant. The p-dopant may include at least one among a halogenated metal compound, a quinone derivative, a metal oxide, and a cyano-containing compound, but is not limited thereto. For example, the p-dopant may be: the halogenated metal compound such as CuI and RbI; the quinone derivative such as tetracyanoquinodimethane (TCNQ) or 2,3,5,6-tetrafluoro-7,7′8,8-tetracyanoquinodimethane (F4-TCNQ); the metal oxide such as tungsten oxide or molybdenum oxide; and the cyano-containing compound such as dipyrazino[2,3-f: 2′,3′-h]quinoxaline-2,3,6,7,10,11-hexacarbonitrile (HATCN), or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), but aspects of the present disclosure are not limited thereto.

As described above, the hole transport region HTR may further include, in addition to the hole injection layer HIL, and the hole transport layer HTL, at least one among a buffer layer (not illustrated) and an electron blocking layer EBL. The buffer layer (not illustrated) may compensate for a resonance distance according to a wavelength of light emitted in the emission layer EML to thereby increase luminous efficiency. As materials included in the buffer layer (not illustrated), any material that may be included in the hole transport region HTR may be used. The electron blocking layer EBL is a layer to serve to prevent electrons from being injected from the electron transport region ETR to the hole transport region HTR.

The emission layer EML is provided on the hole transport region HTR. The emission layer EML may have a thickness, for example, of about 100 Å to about 1000 Å, or about 100 Å to about 300 Å. The emission layer EML may have a single layer formed using a single material, a single layer formed using multiple different materials, or a multilayered structure including multiple layers formed using multiple different materials.

The emission layer EML may be formed using various methods such as a vacuum deposition method, a spin coating method, a cast method, a Langmuir-Blodgett (LB) method, an inkjet printing method, a laser printing method, or a laser induced thermal imaging (LITI) method.

In the light-emitting element ED according to an aspect, the emission layer EML may include a nitrogen-containing compound, which is the above-described first compound. The emission layer EML may include a nitrogen-containing compound represented by any one among Formula 1-1 to Formula 1-4 above. The nitrogen-containing compound according to an aspect may be any one among the compounds present in Compound Group 1 above. The light-emitting element ED according to an aspect may include, in the emission layer EML, at least one nitrogen-containing compound among the compounds present in Compound Group 1 above. The nitrogen-containing compound according to an aspect may be included as a host in the emission layer EML.

The nitrogen-containing compound according to an aspect may have bipolar characteristics by including a heterocyclic core, a first substituent such as bi-carbazole, and a second substituent such as a silyl group, connected to the heterocyclic core. Therefore, when the nitrogen-containing compound according to an aspect is included in the emission layer EML to be used as a host material, excellent material stability may be exhibited. Due to the excellent material stability of the nitrogen-containing compound according to an aspect, the light-emitting element ED according to the aspect may show an effect of improved element lifespan.

The nitrogen-containing compound according to an aspect may be used as a host material by having a high triplet (T1) energy level. The nitrogen-containing compound according to an aspect may be included in the emission layer EML with a phosphorescent dopant or a fluorescent dopant and the nitrogen-containing compound according to an aspect may be used as a host material. For example, the nitrogen-containing compound according to an aspect may be used as a phosphorescent host.

The emission layer EML of the light-emitting element ED including the nitrogen-containing compound according to an aspect may emit blue light. For example, the emission layer EML including the nitrogen-containing compound according to an aspect may emit deep blue light.

Meanwhile, in the nitrogen-containing compound according to an aspect, at least one hydrogen atom may be substituted with a deuterium atom, and the nitrogen compound substituted with a deuterium atom may exhibit a high T1 energy level of about 2.8 eV or higher.

In the light-emitting element ED according to an aspect, the emission layer EML may be a phosphorescent emission layer including a host and a dopant. However, aspects of the present disclosure are not limited thereto, and the emission layer EML may further include a delayed fluorescent dopant, and the light-emitting element ED may emit delayed fluorescence.

In an aspect, the emission layer EML may include the nitrogen-containing compound according to an aspect and may further include at least one among second to fourth compounds to be described later. In an aspect, the first compound included in the emission layer EML may be used as a hole transporting host material.

The light-emitting element ED according to an aspect may further include, in addition to the first compound, a second compound as a host material. The emission layer EML may further include the second compound different from the first compound. The emission layer EML may further include the second compound represented by Formula ET-1 below. For example, the second compound may be included as an electron transporting host material in the emission layer EML.

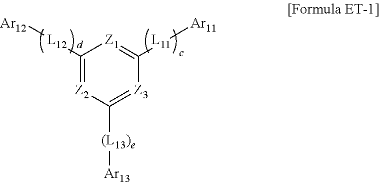

In Formula ET-1, at least one among Z₁ to Z₃ may be N, and the others may be CR56. Alternatively, in Formula ET-1, all Z₁ to Z₃ may be N. In this case, the second compound represented by Formula ET-1 may include a triazine moiety.

In Formula ET-1, R56 may be a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons.

In Formula ET-1, c to e may be each independently an integer of 0 to 10.

In Formula ET-1, Ar₁₁ to Ar₁₃ may be each independently a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. For example, Ar₁₁ to Ar₁₃ may be a substituted or unsubstituted phenyl group, or a substituted or unsubstituted carbazole group.

In Formula ET-1, L₁₁ to L₁₃ may be each independently a direct linkage, a substituted or unsubstituted arylene group having 6 to 30 ring-forming carbons, or a substituted or unsubstituted heteroarylene group having 2 to 30 ring-forming carbons. For example, L₁₁ to L₁₃ may be each independently a substituted or unsubstituted arylene group having 6 to 30 ring-forming carbons.

Meanwhile, if c to e are an integer of 2 or greater, L₁₁ to L₁₃ may be each independently a substituted or unsubstituted arylene group having 6 to 30 ring-forming carbons, or a substituted or unsubstituted heteroarylene group having 2 to 30 ring-forming carbons.

In an aspect, the second compound may be represented by any one among compounds in Compound Group 2 below. The light-emitting element ED according to an aspect may further include any one among the compounds in Compound Group 2 in the emission layer EML.

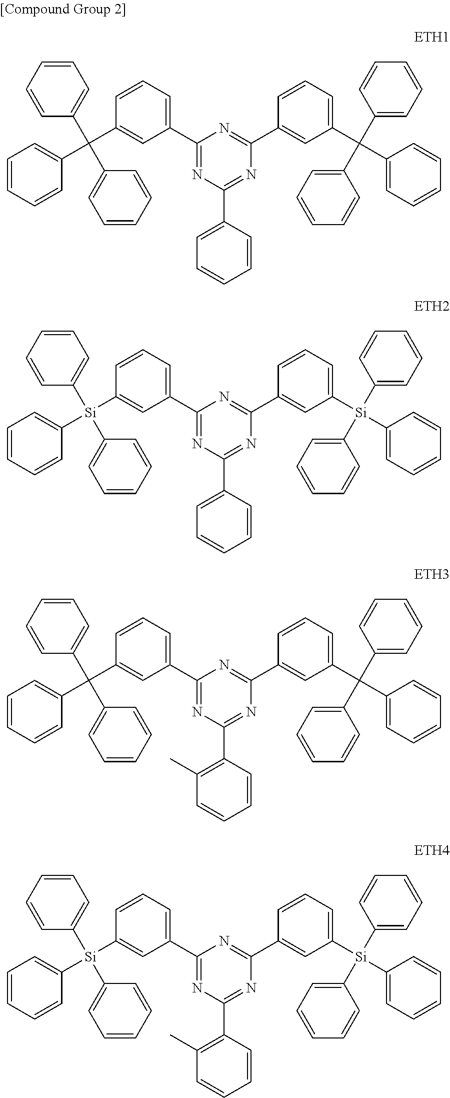 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

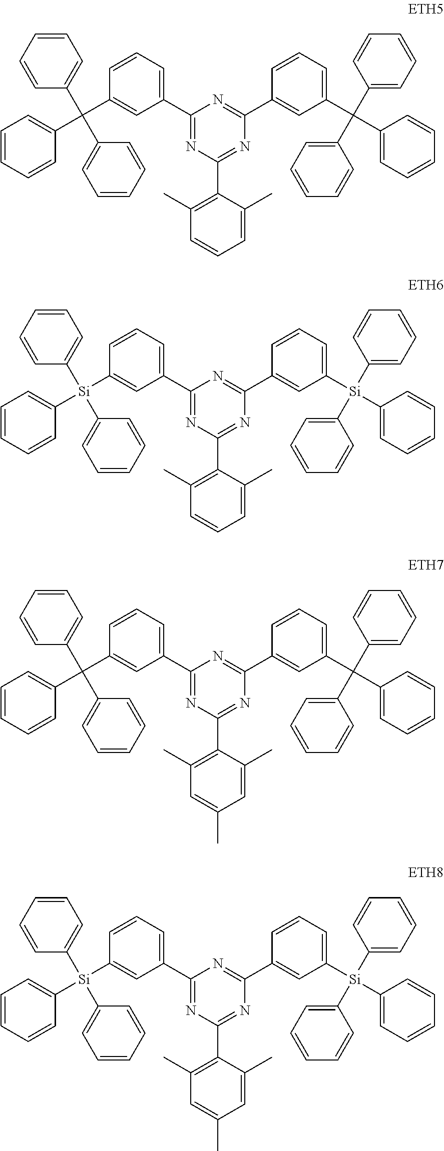 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

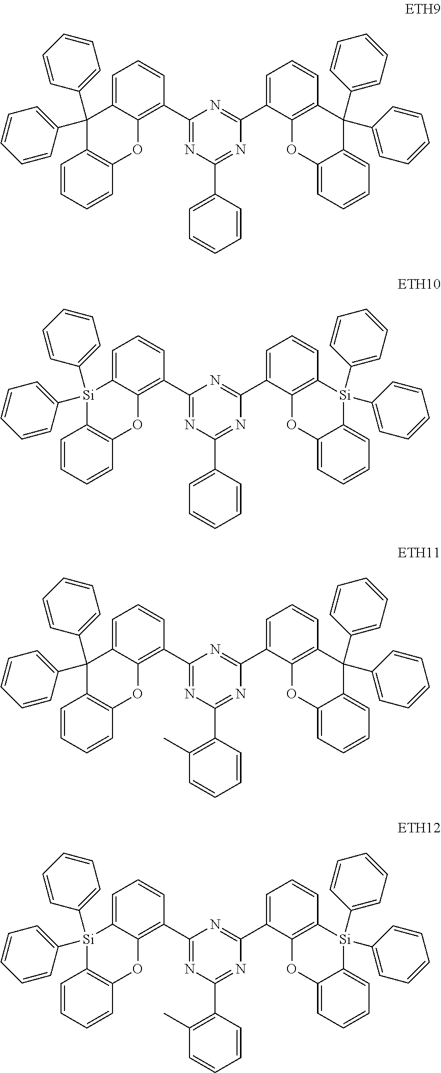 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

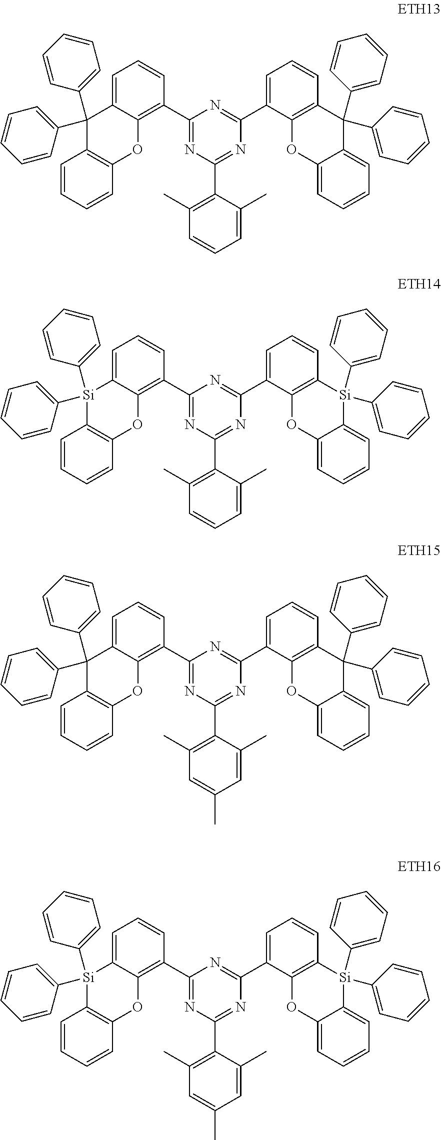 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

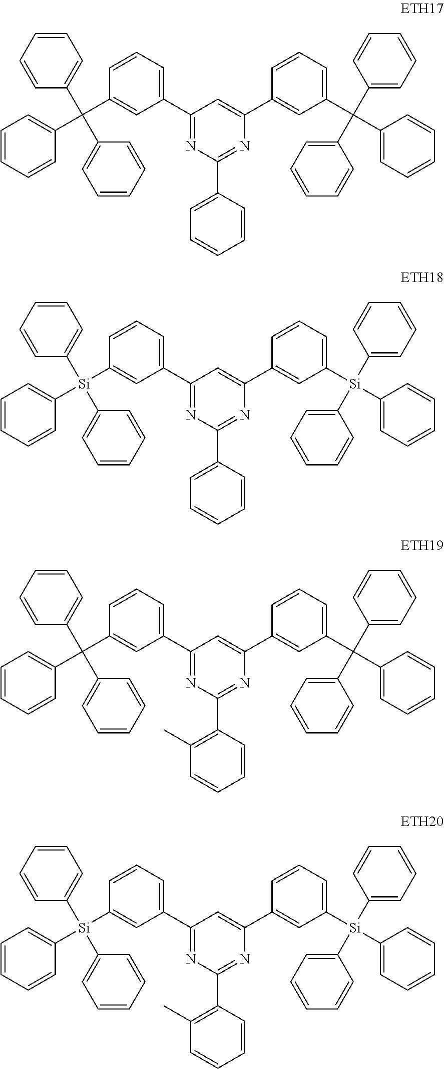 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

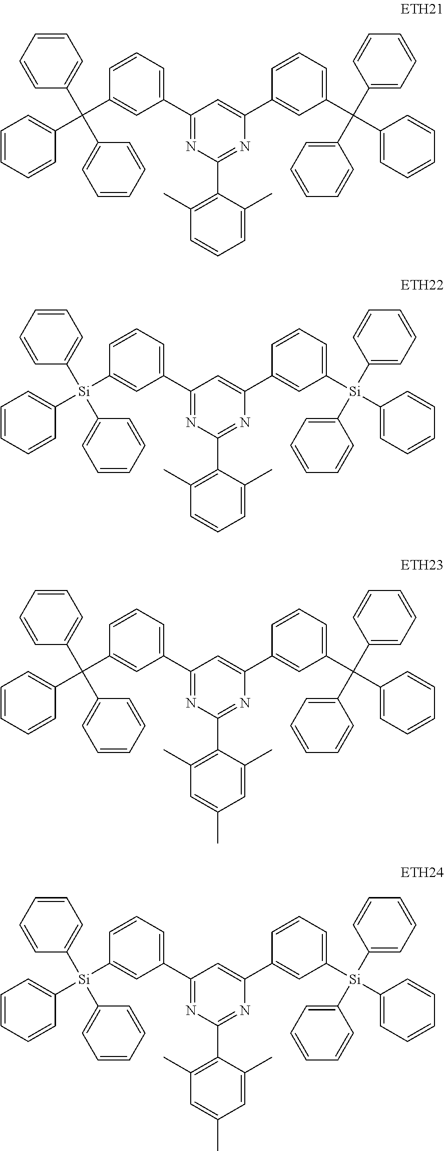 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

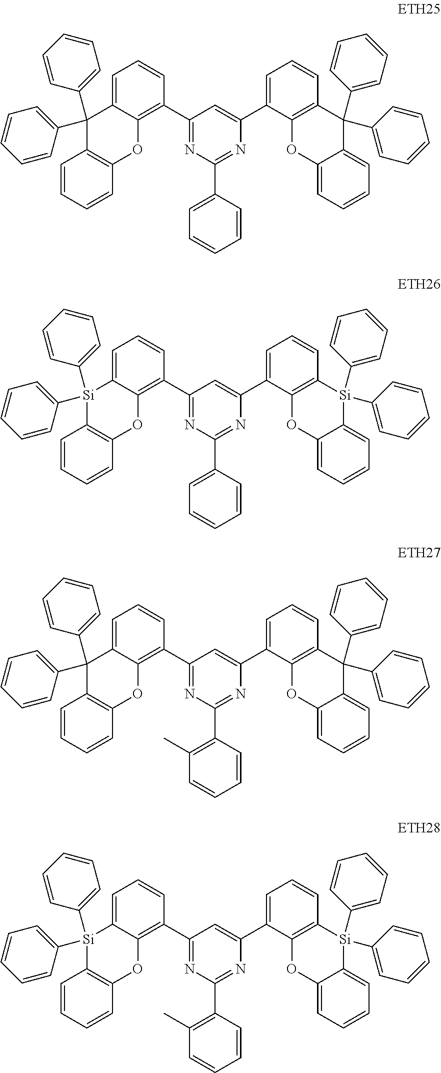 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

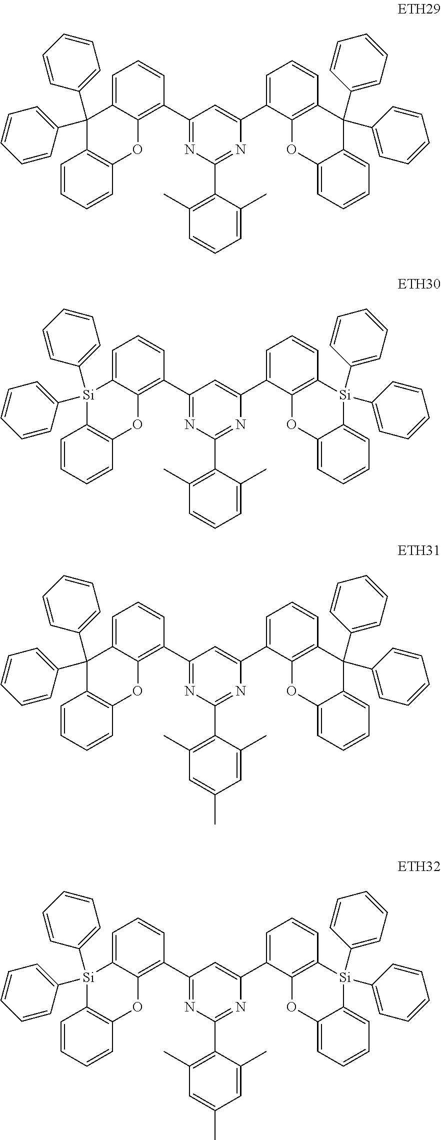 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

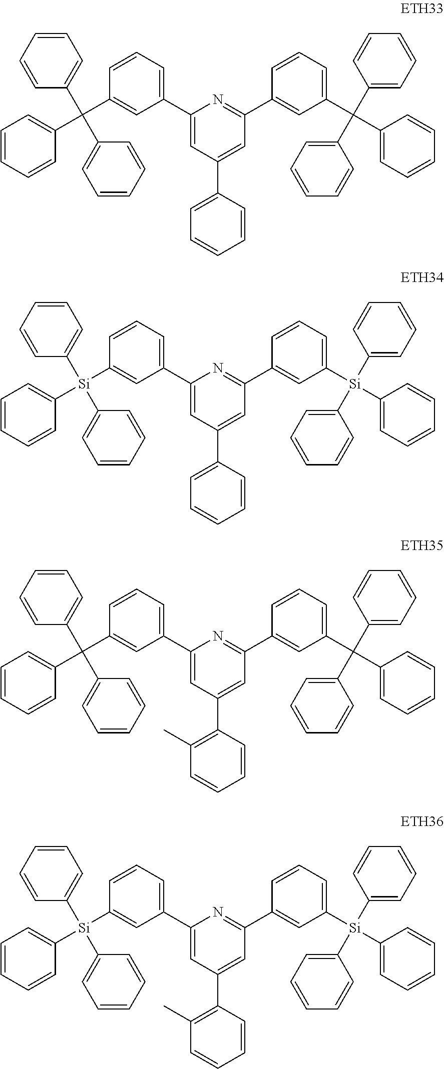 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

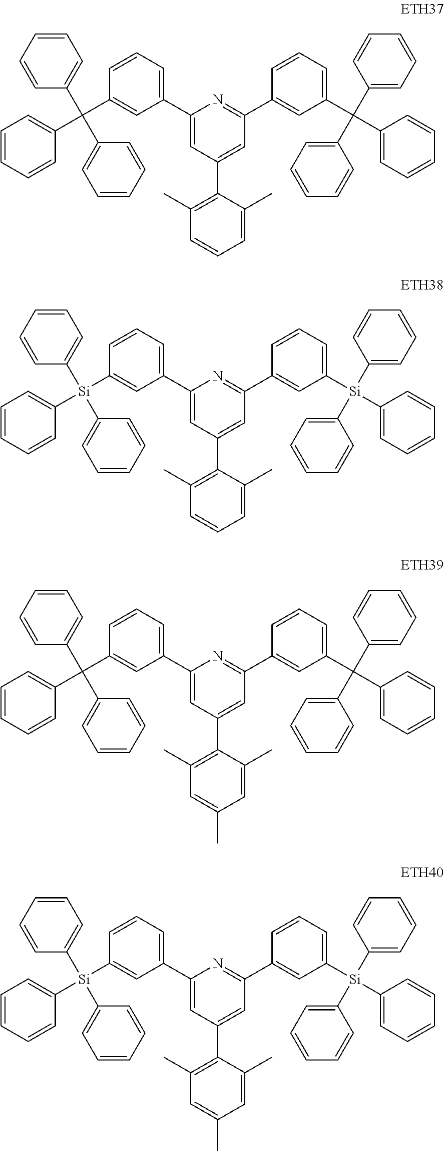 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

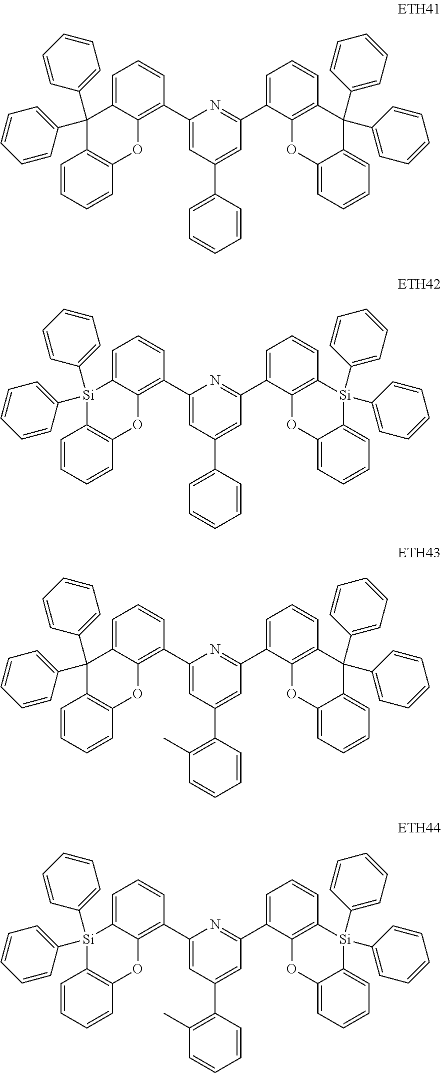 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

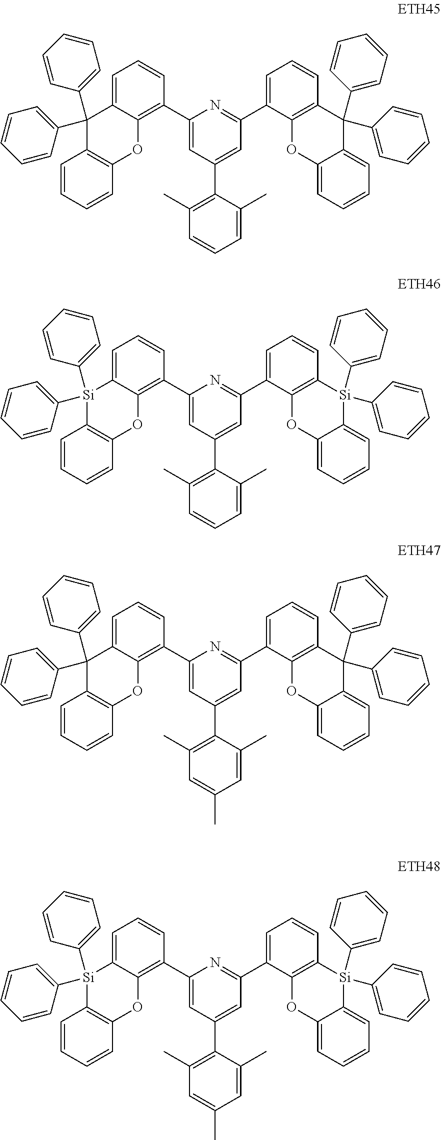 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

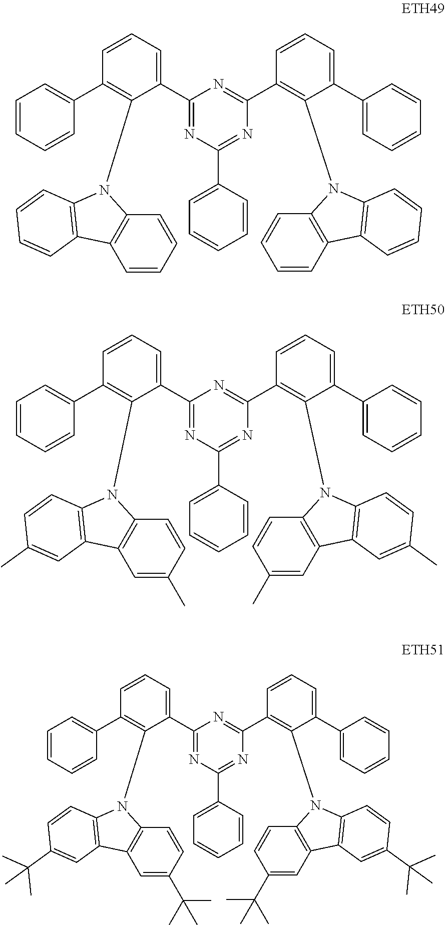

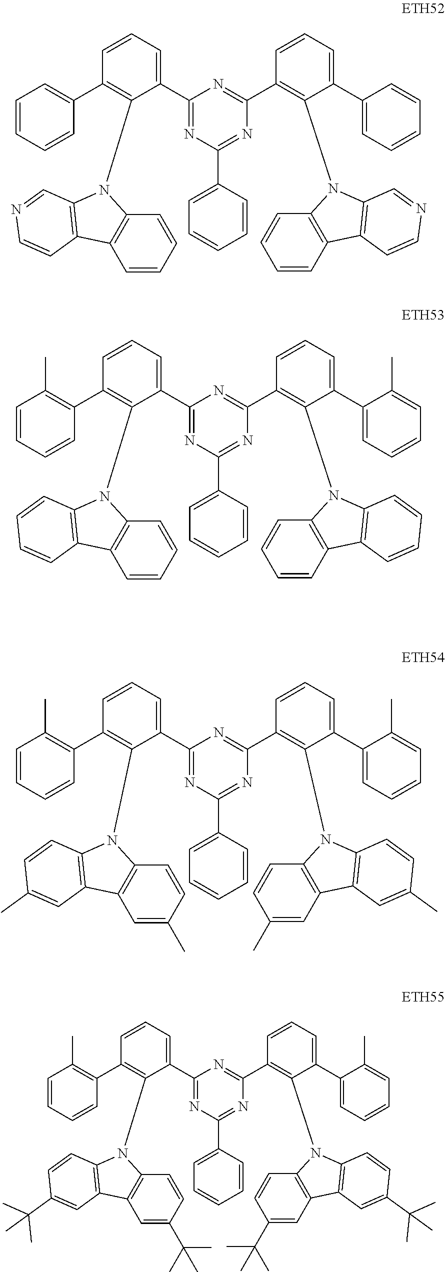

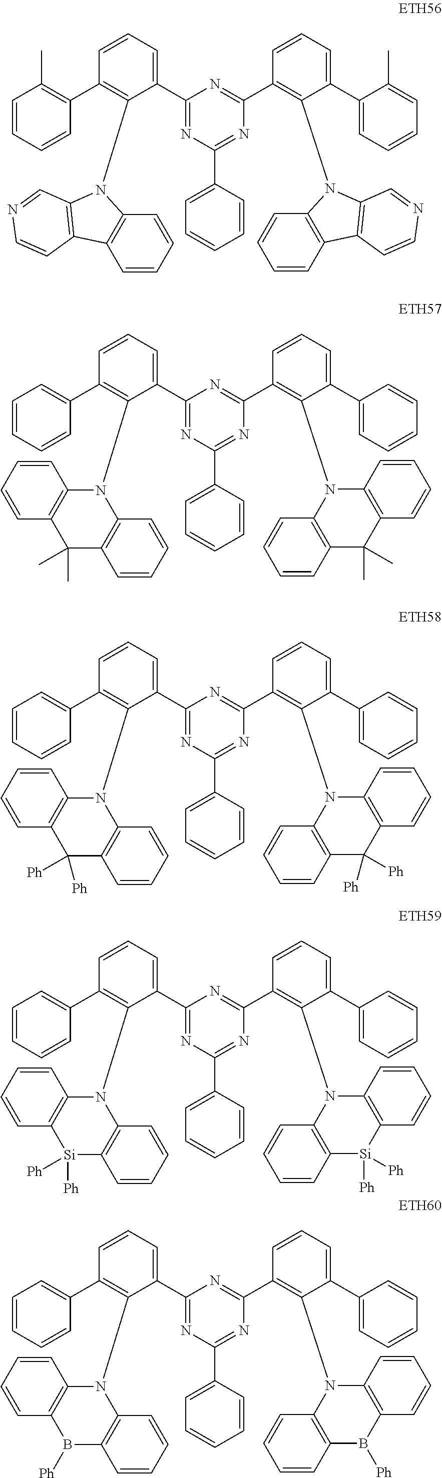

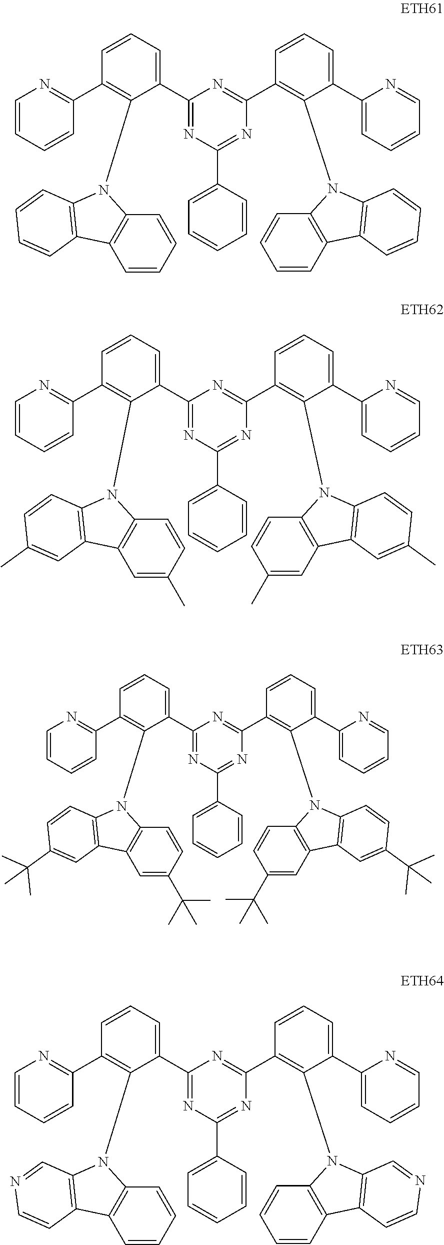

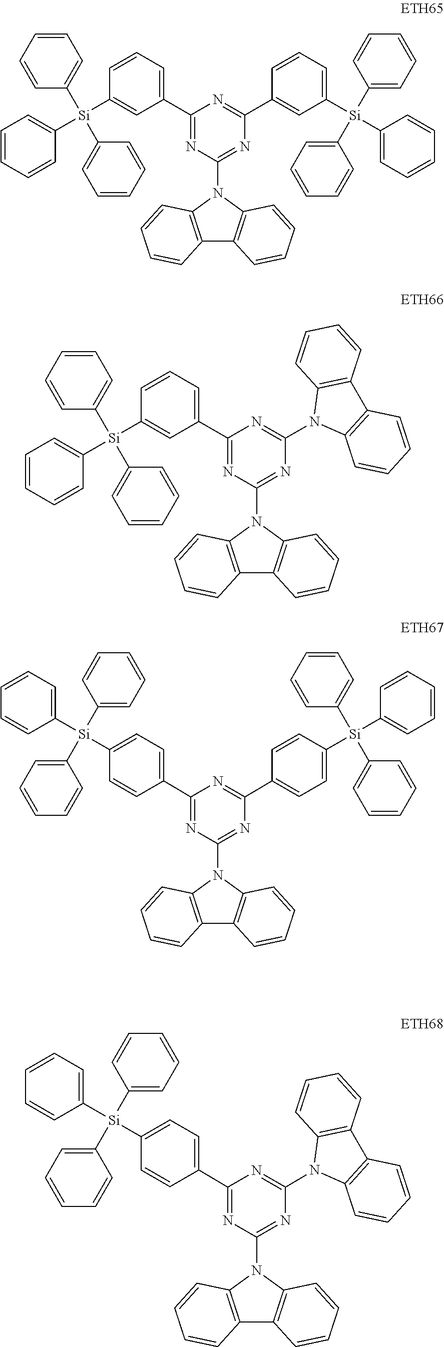 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

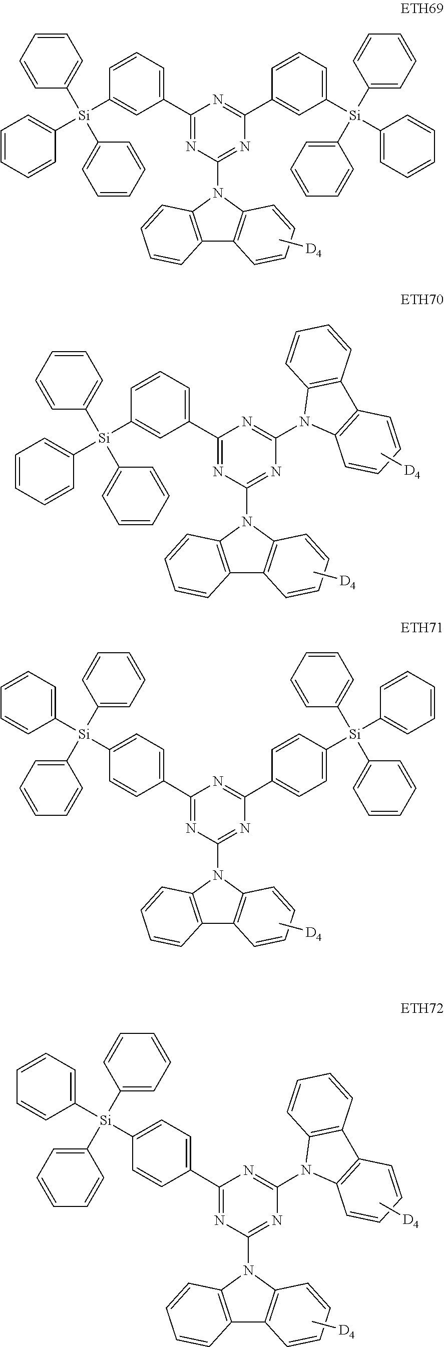

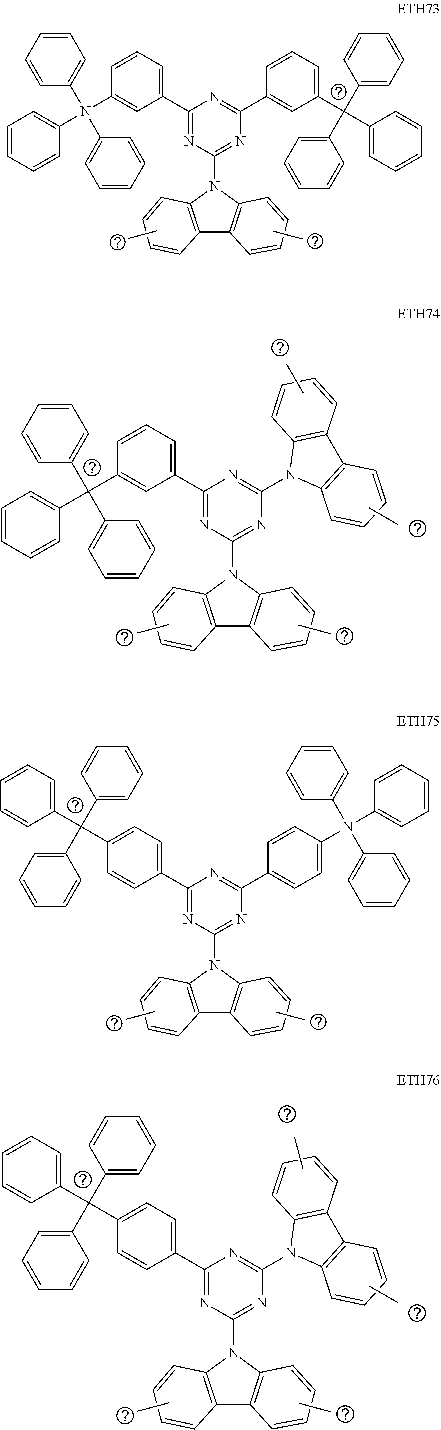

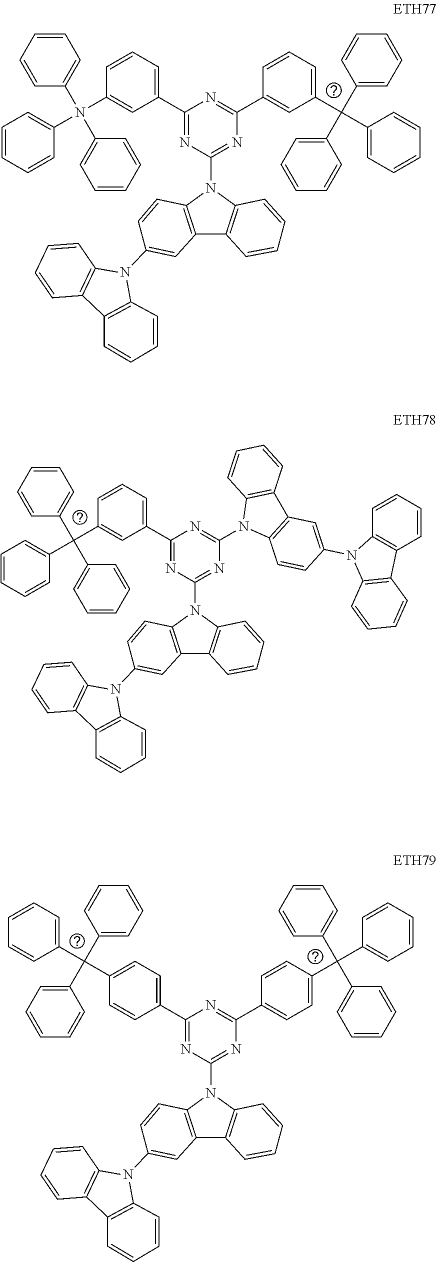

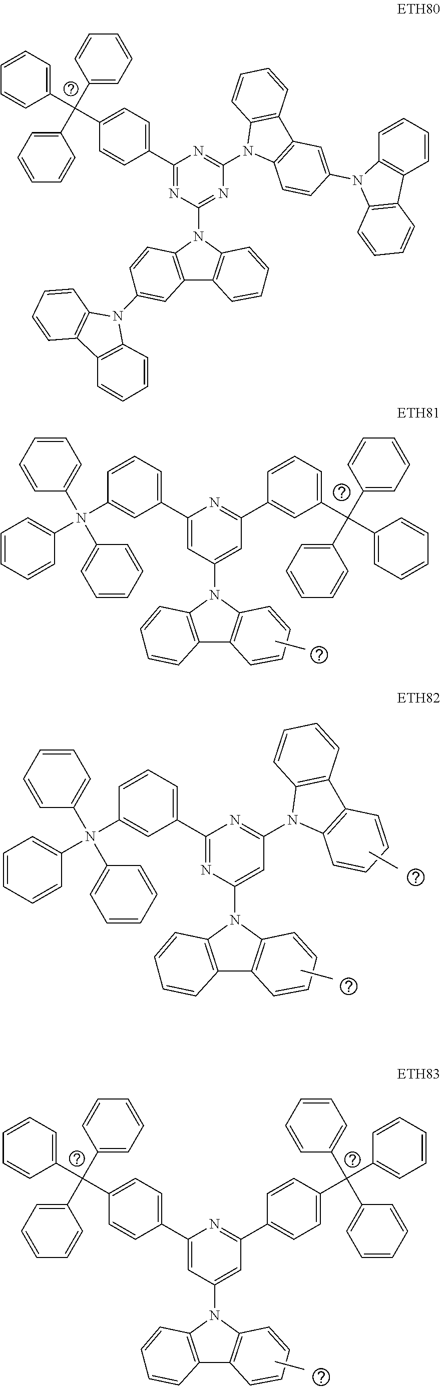

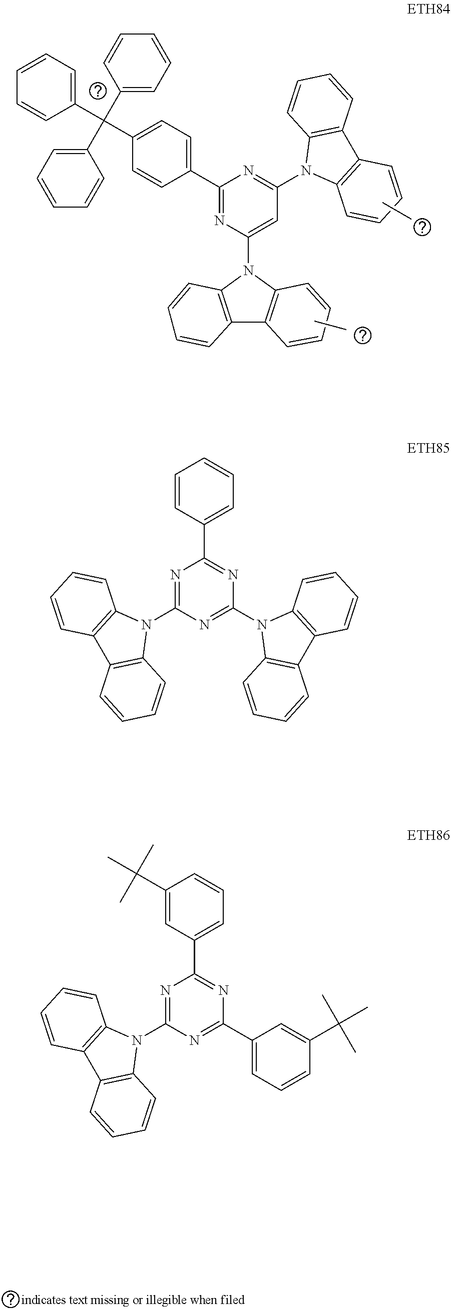

In specific example compounds suggested in Compound Group 2, “D” means a deuterium atom, and “Ph” means a unsubstituted phenyl group.

In an aspect, the emission layer EML may include the first compound which is the nitrogen-containing compound according to an aspect and the third compound which is a phosphorescent dopant. The third compound may be an organometallic complex. For example, the emission layer EML may include platinum (Pt) as a central metal atom, and ligands bonded to the central metal atom as the third compound. In the light-emitting element ED according to an aspect, the emission layer EML may include a compound represented by Formula D-1 below as the second compound.

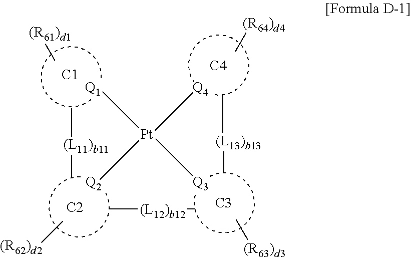

In Formula D-1, Q₁ to Q₄ may be each independently C or N. C1 to C4 may be each independently a substituted or unsubstituted hydrocarbon ring having 5 to 30 ring-forming carbons, or a substituted or unsubstituted heterocycle having 2 to 30 ring-forming carbons.

In Formula D-1, L₁₁ to L₁₃ may be each independently a direct linkage,

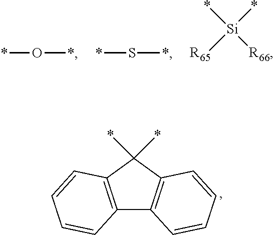

a substituted or unsubstituted divalent alkyl group having 1 to 20 carbons, a substituted or unsubstituted arylene group having 6 to 30 ring-forming carbons, or a substituted or unsubstituted heteroarylene group having 2 to 30 ring-forming carbons. In L₁₁ to L₁₃, “—*” means a portion to which C1 to C4 are connected.

In Formula D-1, b11 to b13 may be each independently 0 or 1. If b11 is 0, C1 and C2 may not be connected to each other. If b12 is 0, C2 and C3 may not be connected to each other. If b13 is 0, C3 and C4 may not be connected to each other.

In Formula D-1, R₆₁ to R₆₆ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons. Alternatively, R₆₁ to R₆₆ may be bonded to an adjacent group to form a ring. R₆₁ to R₆₆ may be each independently a substituted or unsubstituted methyl group, or a substituted or unsubstituted t-butyl group.

In Formula D-1, d1 to d4 may be each independently an integer of 0 to 4. In Formula D-1, when d1 to d4 are each 0, the fourth compound may be respectively unsubstituted with R₆₁ to R₆₄. A case where d1 is 4 and all R₆₁ are hydrogen atoms may be the same as the case where d1 is 0, a case where d2 is 4 and all R₆₂ are hydrogen atoms may be the same as the case where d2 is 0, a case where d3 is 4 and all R₆₃ are hydrogen atoms may be the same as the case where d3 is 0, and a case where d4 is 4 and all R₆₄ are hydrogen atoms may be the same as the case where d4 is 0. When d1 is an integer of 2 or greater, R₆₁ provided in plurality may be all the same, or at least one may be different, when d2 is an integer of 2 or greater, R₆₂ provided in plurality may be all the same, or at least one may be different, when d3 is an integer of 2 or greater, R₆₃ provided in plurality may be all the same, or at least one may be different, and when d1 is an integer of 2 or greater, R₆₁ provided in plurality may be all the same, or at least one may be different.

In Formula D-1, C1 to C4 may be each independently a substituted or unsubstituted hydrocarbon ring represented by any one among C-1 to C-4 below, or a substituted or unsubstituted heterocycle.

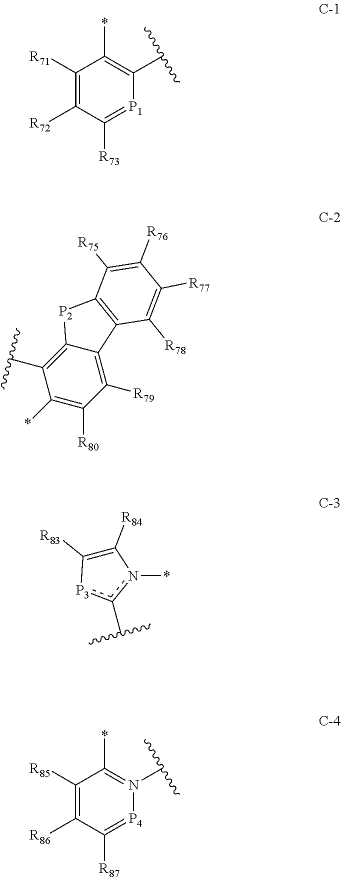

In C-1 to C-4, P₁ may be C—*, or CR₇₄, P₂ may be N—*, or NR₈₁, P₃ may be N—*, or NR₈₂, and P₄ may be C—*, or CR₈₈. R₇₁ to R₈₈ may be each independently a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, or may be bonded to an adjacent group to form a ring.

In addition, in C-1 to C-4,

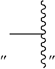

is a portion to which Pt which is a central metal atom is connected, and “—*” corresponds to a portion to which the adjacent cyclic groups (C1 to C4) or linkers (L₁₁ to L₁₃) are connected.

In an aspect, the third compound represented by Formula D-1 may be represented by at least one among compounds present in Compound Group 3 below. The emission layer EML may include, as a phosphorescent dopant, at least one among the compounds present in Compound Group 3 below. However, the phosphorescent dopant is not limited to the compounds present in Compound Group 3 below.

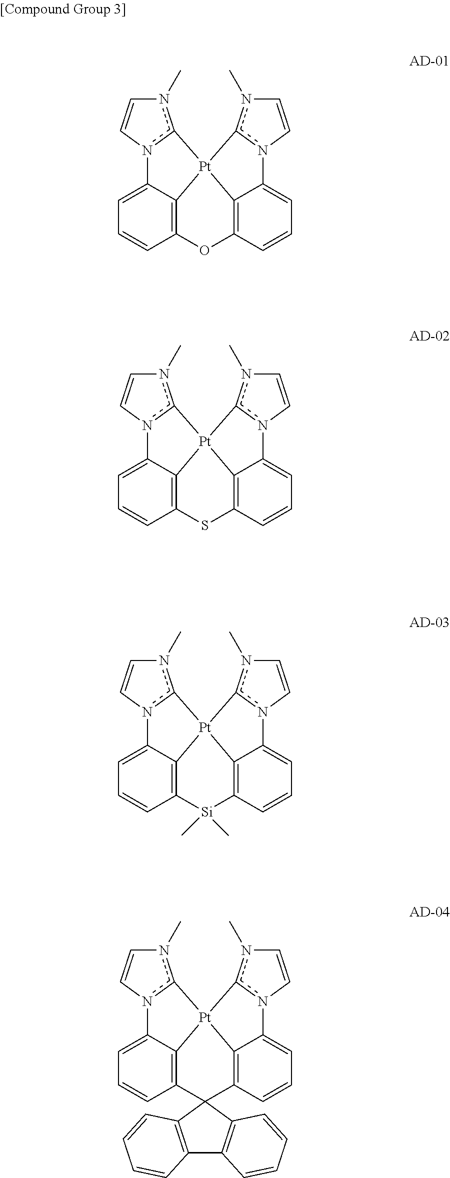

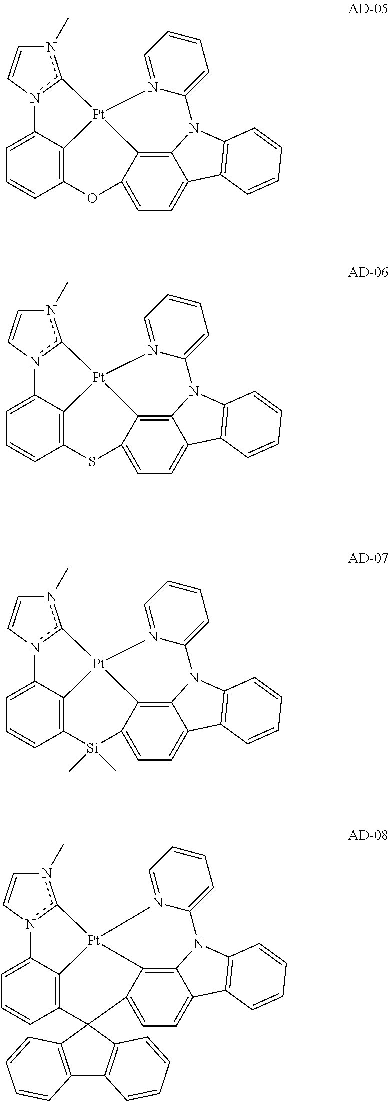

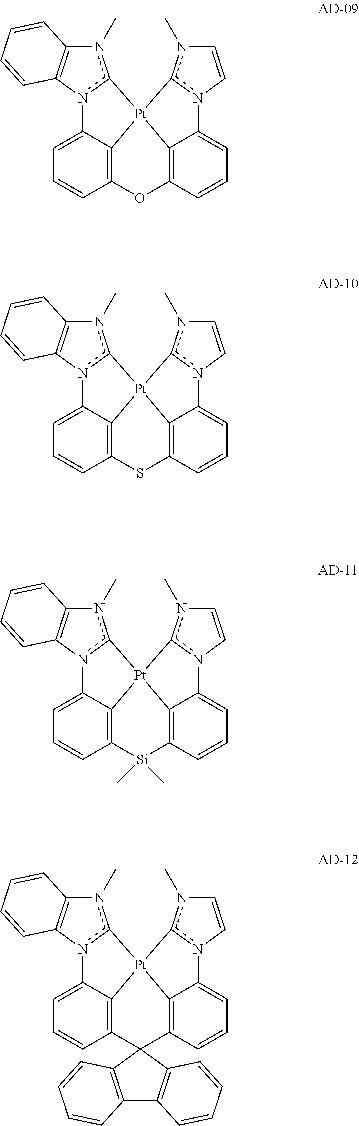

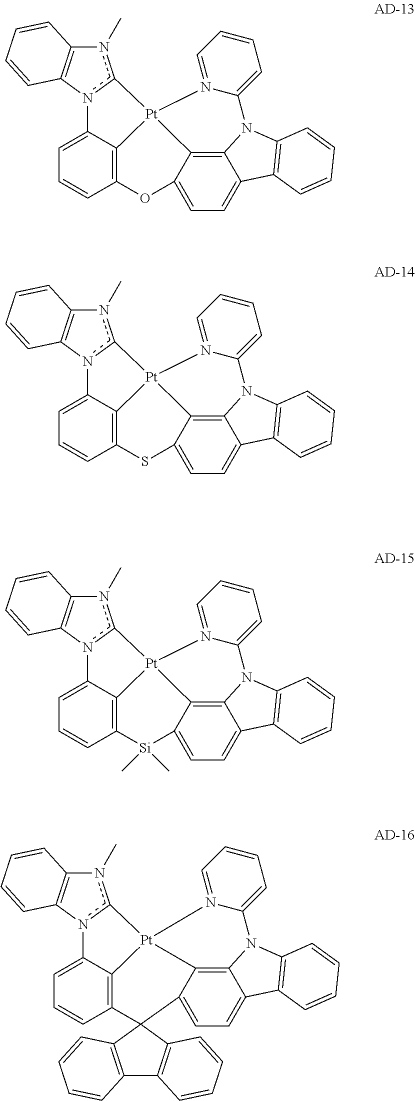

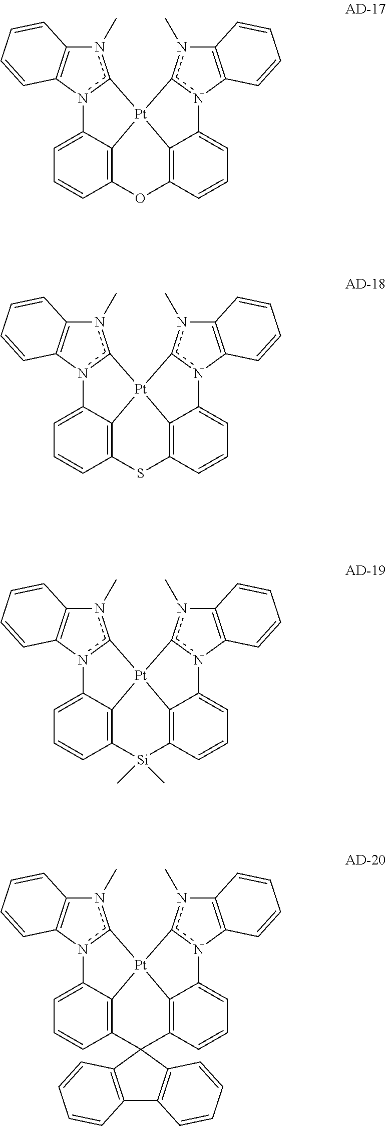

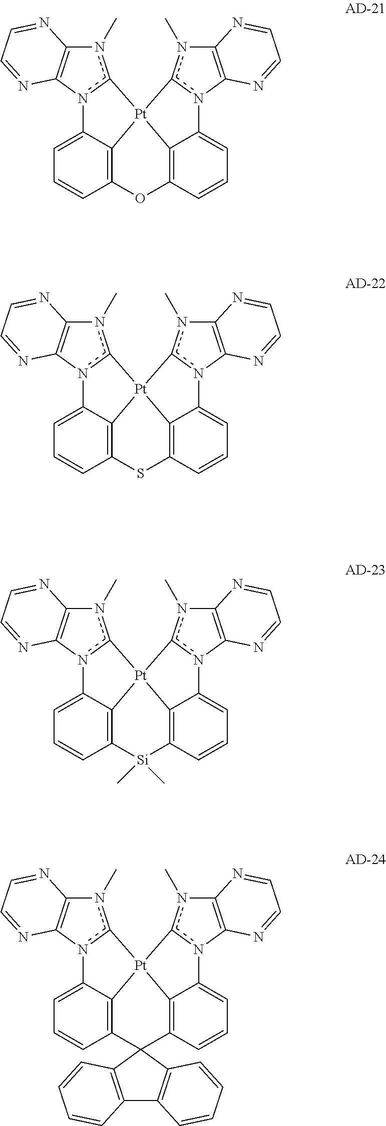

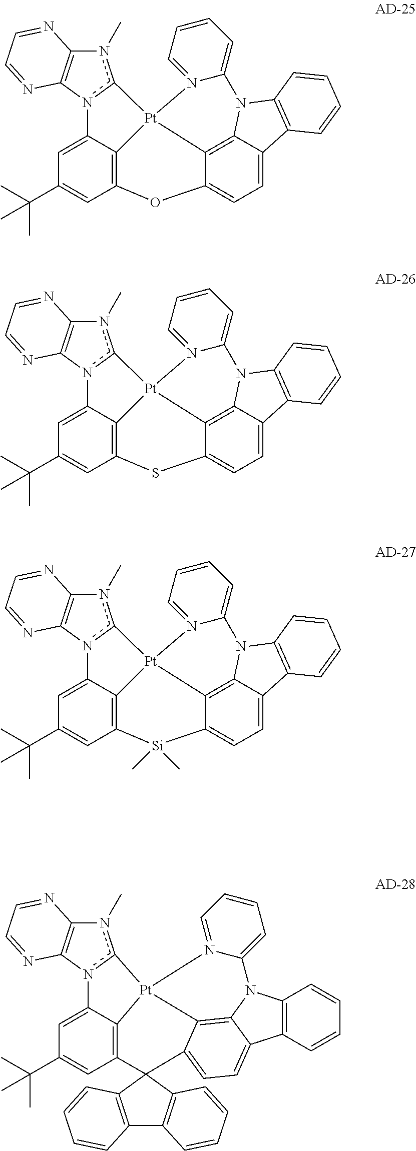

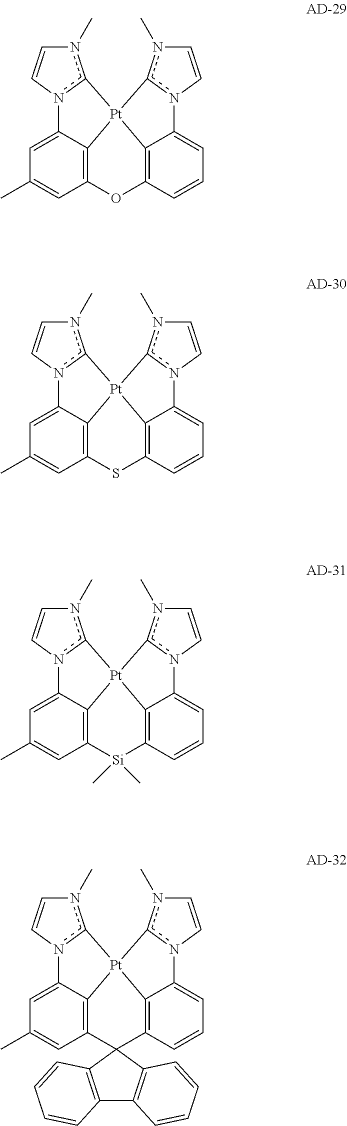

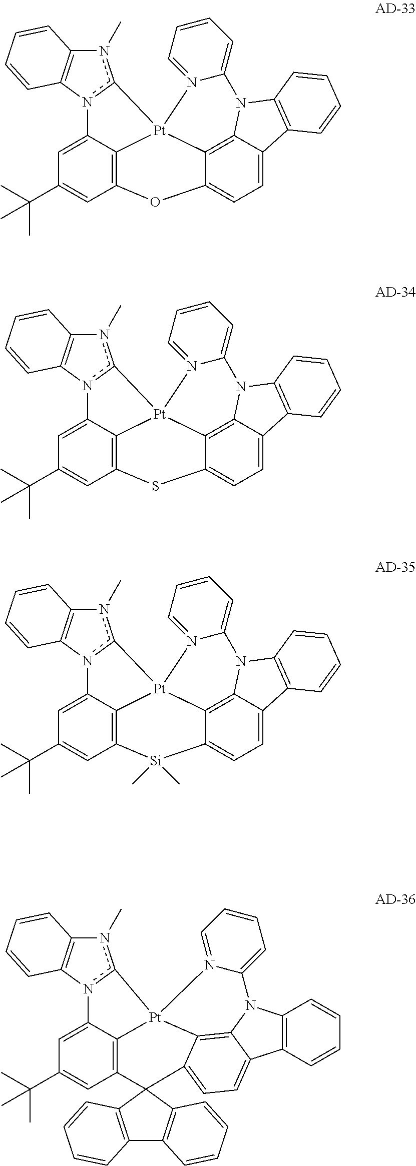

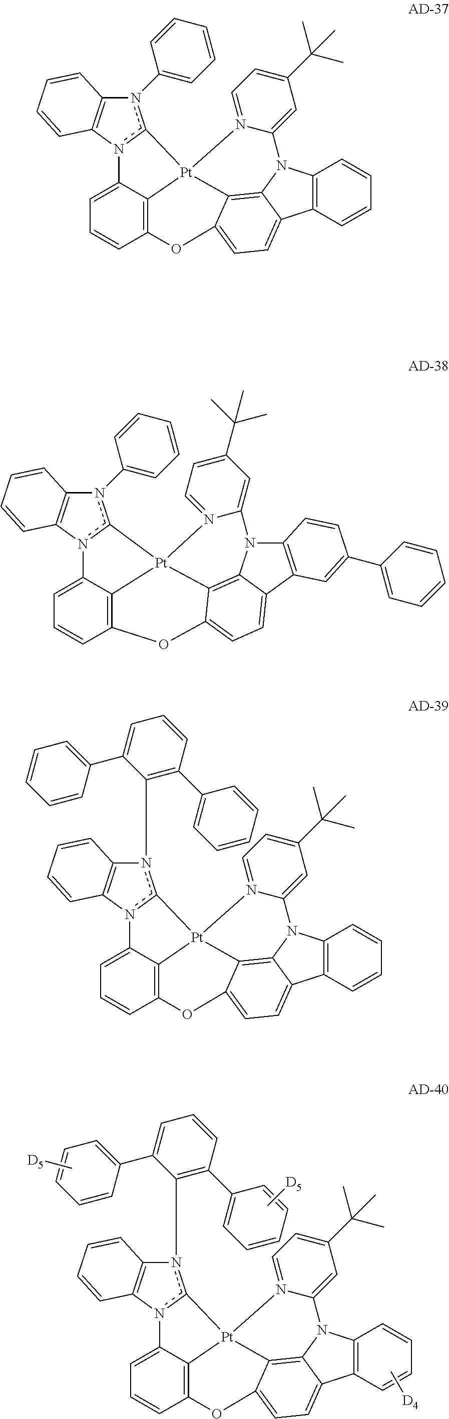

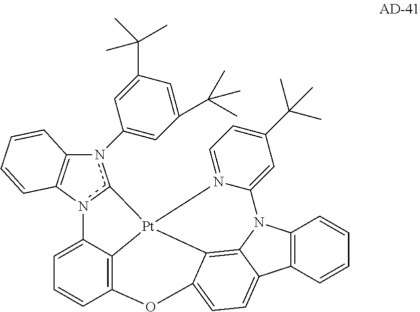

In the specific example compounds suggested in Compound Group 3, “D” means a deuterium atom.

Meanwhile, in an aspect, the third compound included in the emission layer EML may be used as phosphorescent sensitizer. When the emission layer EML includes the first compound which is the nitrogen-containing compound according to an aspect, the second compound which is an electron transporting host, the third compound which is an organometallic complex, and a fourth compound to be described later, the third compound may transfer energy to a fourth compound as a phosphorescent sensitizer. In this case, the fourth compound may emit light as a dopant.

In an aspect, the emission layer EML may further include the fourth compound represented by Formula F-1 below.

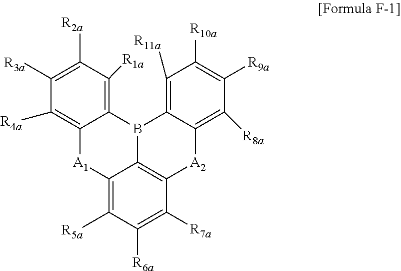

In Formula F-1, A₁ and A₂ may be each independently O, S, Se, or NRₘ, Rₘ may be a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. R₁ₐ to R₁₁ₐ are each independently a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, or is bonded to an adjacent group to form a ring.

In Formula F-1, A₁ and A₂ may be each independently bonded to substituents of an adjacent ring to form a fused ring. For example, when A₁ and A₂ are each independently NRₘ, A₁ may be bonded to R₄ₐ or R₅ₐ to thereby form a ring. In addition, A₁ may be bonded to R₇ₐ or R₈ₐ to thereby form a ring.

For example, the fourth compound represented by Formula F-1 may be included in the emission layer EML as a dopant. In an aspect, the fourth compound represented by Formula F-1 may be a thermally activated delayed fluorescent dopant.

The fourth compound may be represented by any one among compounds in Compound Group 4 below.

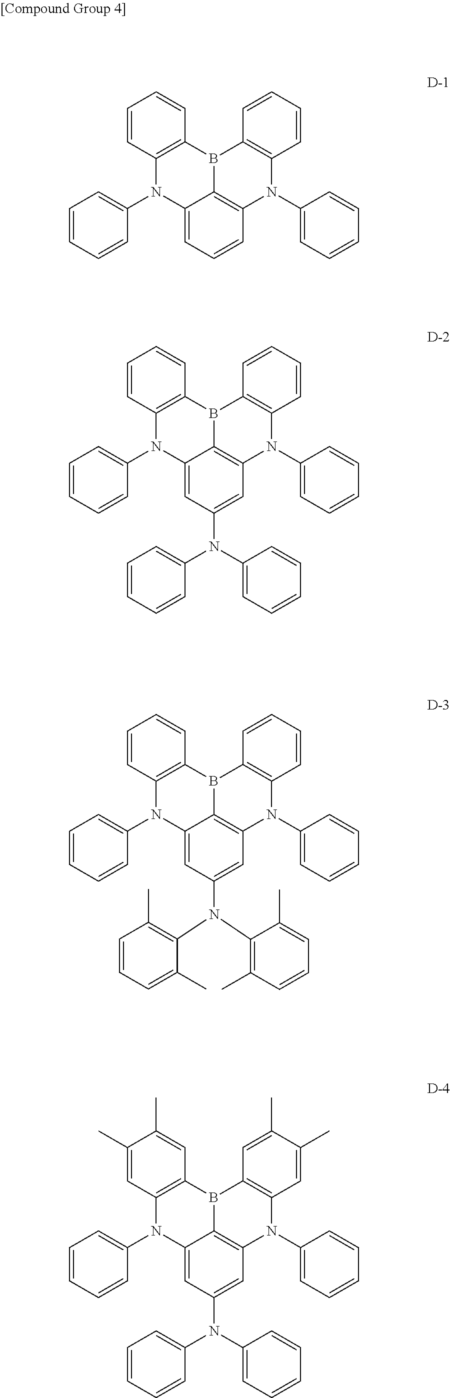 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; Cc1cccc(C)c1N(c1cc2c3c(c1)N(c1ccccc1)c1ccccc1B3c1ccccc1N2c1ccccc1)c1c(C)cccc1C ; Cc1cc2c(cc1C)N(c1ccccc1)c1cc(N(c3ccccc3)c3ccccc3)cc3c1B2c1cc(C)c(C)cc1N3c1ccccc1]

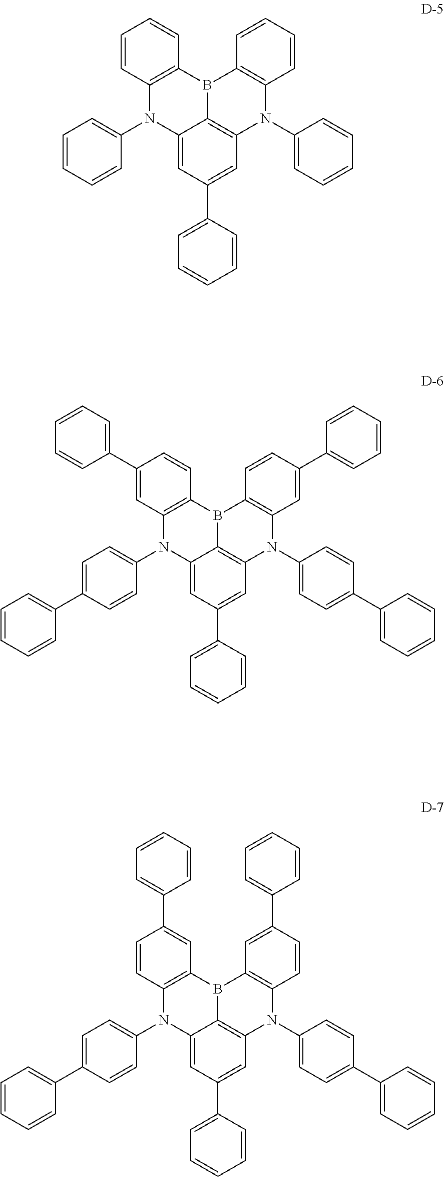 [SMILES: c1ccc(-c2cc3c4c(c2)N(c2ccccc2)c2ccccc2B4c2ccccc2N3c2ccccc2)cc1 ; c1ccc(-c2ccc(N3c4cc(-c5ccccc5)ccc4B4c5ccc(-c6ccccc6)cc5N(c5ccc(-c6ccccc6)cc5)c5cc(-c6ccccc6)cc3c54)cc2)cc1 ; c1ccc(-c2ccc(N3c4ccc(-c5ccccc5)cc4B4c5cc(-c6ccccc6)ccc5N(c5ccc(-c6ccccc6)cc5)c5cc(-c6ccccc6)cc3c54)cc2)cc1]

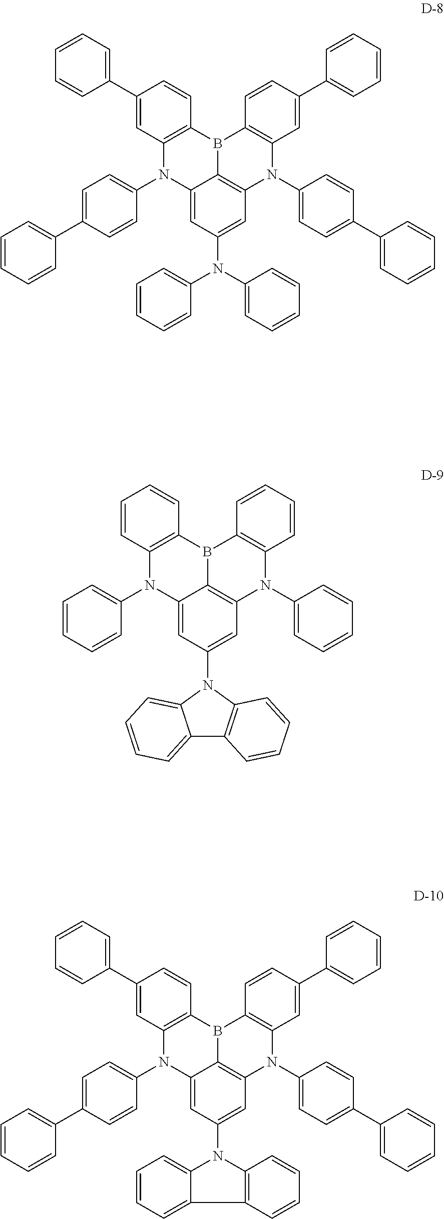 [SMILES: c1ccc(-c2ccc(N3c4cc(-c5ccccc5)ccc4B4c5ccc(-c6ccccc6)cc5N(c5ccc(-c6ccccc6)cc5)c5cc(N(c6ccccc6)c6ccccc6)cc3c54)cc2)cc1 ; c1ccc(N2c3ccccc3B3c4ccccc4N(c4ccccc4)c4cc(-n5c6ccccc6c6ccccc65)cc2c43)cc1 ; c1ccc(-c2ccc(N3c4cc(-c5ccccc5)ccc4B4c5ccc(-c6ccccc6)cc5N(c5ccc(-c6ccccc6)cc5)c5cc(-n6c7ccccc7c7ccccc76)cc3c54)cc2)cc1]

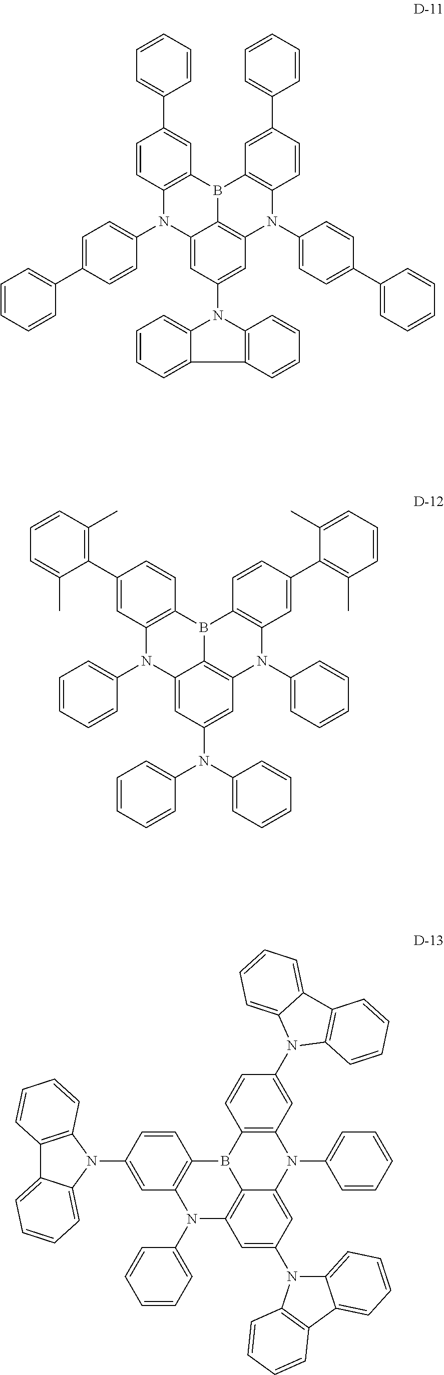 [SMILES: c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1 ; Cc1cccc(C)c1-c1ccc2c(c1)N(c1ccccc1)c1cc(N(c3ccccc3)c3ccccc3)cc3c1B2c1ccc(-c2c(C)cccc2C)cc1N3c1ccccc1 ; c1ccc(N2c3cc(-n4c5ccccc5c5ccccc54)ccc3B3c4ccc(-n5c6ccccc6c6ccccc65)cc4N(c4ccccc4)c4cc(-n5c6ccccc6c6ccccc65)cc2c43)cc1]

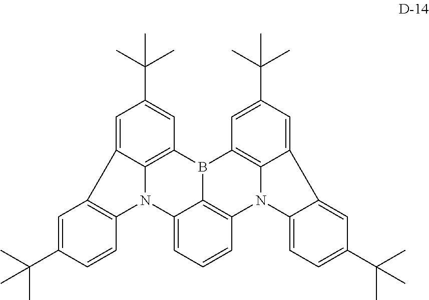 [SMILES: CC(C)(C)c1ccc2c(c1)c1cc(C(C)(C)C)cc3c1n2-c1cccc2c1B3c1cc(C(C)(C)C)cc3c4cc(C(C)(C)C)ccc4n-2c13]

The fourth compound may be a delayed fluorescent dopant. For example, the fourth compound may be a thermally activated delayed fluorescent dopant. Meanwhile, types of the fourth compounds are not limited to the specific example compounds present in Compound Group 4 above, materials for the delayed fluorescent dopant, in an aspect, may be included in the emission layer as a dopant material with the nitrogen-containing compound which is the first compound.

The emission layer EML according to an aspect may include the first compound which is the nitrogen-containing compound, and at least one among the second to fourth compounds. For example, the emission layer EML may include the first compound, the second compound, and the third compound.

In addition, the emission layer EML may include all the first compound, the second compound, the third compound, and the fourth compound. That is, the emission layer EML may include a combination of two host materials and two dopant materials. In the light-emitting element ED according to an aspect, the emission layer EML may simultaneously include the first compound and the second compound, which are different two hosts, the fourth compound emitting delayed fluorescence, and the third compound including an organometallic complex to thereby exhibit characteristics of excellent luminous efficiency.

In the emission layer EML, an exciplex may be formed by the hole transporting host and the electron transporting host. In the emission layer EML, the first compound and the second compound may form an exciplex. In this case, the exciplex formed by the hole transporting host and the electron transporting host may have triplet energy corresponding to a difference between energy levels of a lowest unoccupied molecular orbital (LUMO) of the electron transporting host and a highest occupied molecular orbital (HOMO) of the hole transporting host.

In the emission layer EML, the first compound which is the hole transporting host material and the second compound which is an electron transporting material may form an exciplex, and energy may be transferred from the exciplex to the third compound and the fourth compound, thereby emitting light. In an aspect, the third compound may serve as a sensitizer. In the light-emitting element ED according to an aspect, the third compound included in the emission layer EML may serve as a sensitizer to thereby play a role in transferring energy from the host to the fourth compound which is an emission dopant. That is, the third compound serving as an auxiliary dopant may accelerate energy transfer to the fourth compound which is an emission dopant to thereby increase an emission rate of the fourth compound.

In the light-emitting element ED according to an aspect, when the emission layer EML includes the above described first compound, second compound and third compound, amounts of the first compound and the third compound, which are host materials, may be about 65 wt % to about 95 wt % based on the total weight of the first compound, the second compound, and the third compound.

Meanwhile, in an aspect, the emission layer EML may include a fifth compound represented by Formula HT-1 below. For example, the fifth compound may be further included in the emission layer EML as a hole transporting host material.

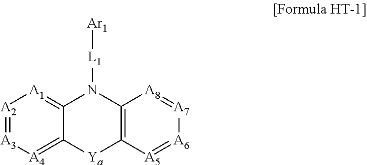

In Formula HT-1, A₁ to A₈ may be each independently N, or CR₅₁. For example, all A₁ to A₈ may be CR₅₁. Alternatively, any one among A₁ to A₈ may be N, and the others may be CR₅₁.

In Formula HT-1, L1 may be a direct linkage, a substituted or unsubstituted arylene group having 6 to 30 ring-forming carbons, or a substituted or unsubstituted heteroarylene group having 2 to 30 ring-forming carbons. For example, L1 may be a direct linkage, a substituted or unsubstituted phenylene group, a substituted or unsubstituted divalent biphenyl group, a substituted or unsubstituted divalent carbazole group, but aspects of the present disclosure are not limited thereto.

In Formula HT-1, Ya may be a direct linkage, CR₅₂R₅₃, or SiR₅₄R₅₅. That is, it means that two benzene rings connected to a nitrogen atom in Formula HT-1 may be connected via a direct linkage,

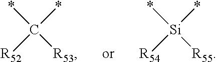

In Formula HT-1, when Ya is a direct linkage, the second compound represented by Formula HT-1 may include a carbazole moiety.

In Formula HT-1, Ar₁ may be a substituted or unsubstituted aryl group having 6 to 30 ring-forming carbons, or a substituted or unsubstituted heteroaryl group having 2 to 30 ring-forming carbons. For example, Ar₁ may be a substituted or unsubstituted carbazole group, a substituted or unsubstituted dibenzofuran group, a substituted or unsubstituted dibenzothiophene group, or a substituted or unsubstituted biphenyl group, etc. However, aspects of the present disclosure are not limited thereto.

In Formula HT-1, Rs₅₁ to R₅₅ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons. Alternatively, each of R₅₁ to R₅₅ may be bonded to an adjacent group to form a ring. For example, R₅₁ to R₅₅ may be each independently a hydrogen atom, or a deuterium atom. Rs₅₁ to R₅₅ may be each independently a substituted or unsubstituted methyl group, or a substituted or unsubstituted phenyl group.

In an aspect, the fifth compound represented by Formula HT-1 may be represented by any one among compounds present in Compound Group 5 below. The emission layer EML may include any one among the compounds present in Compound Group 5 below.

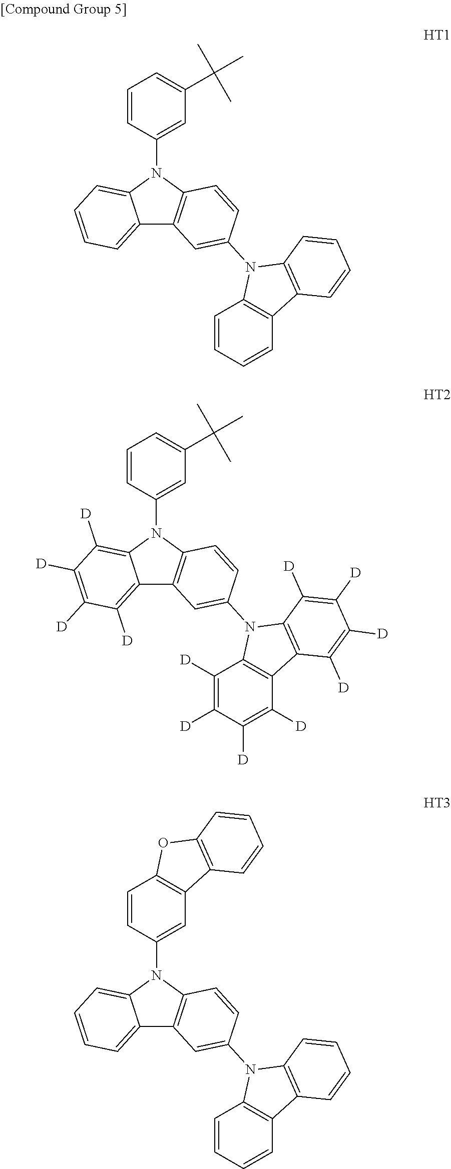 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

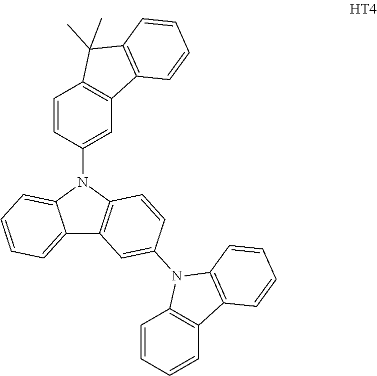 [SMILES: CC1(C)c2ccccc2-c2cc(-n3c4ccccc4c4cc(-n5c6ccccc6c6ccccc65)ccc43)ccc21]

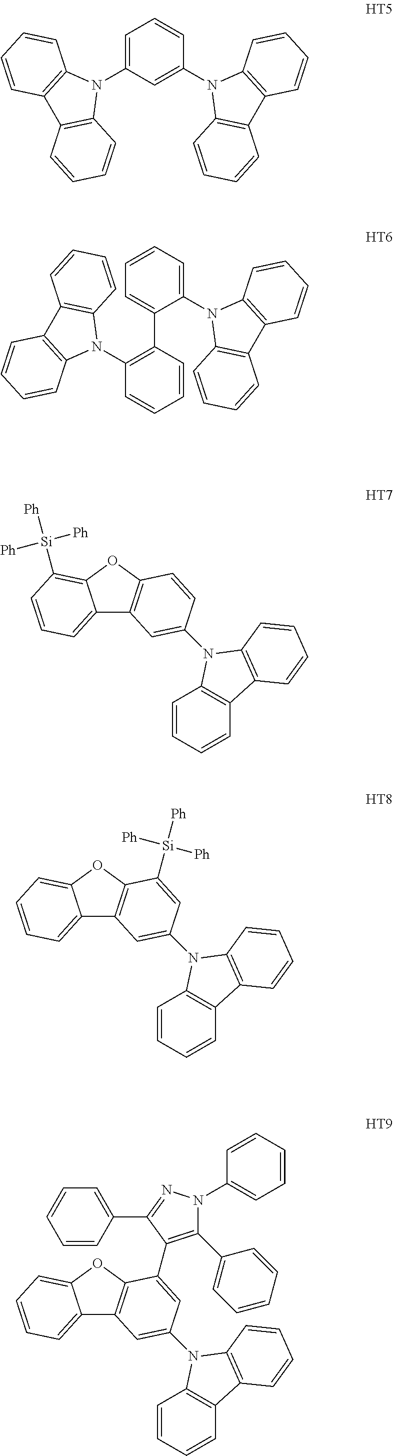 [SMILES: c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1]

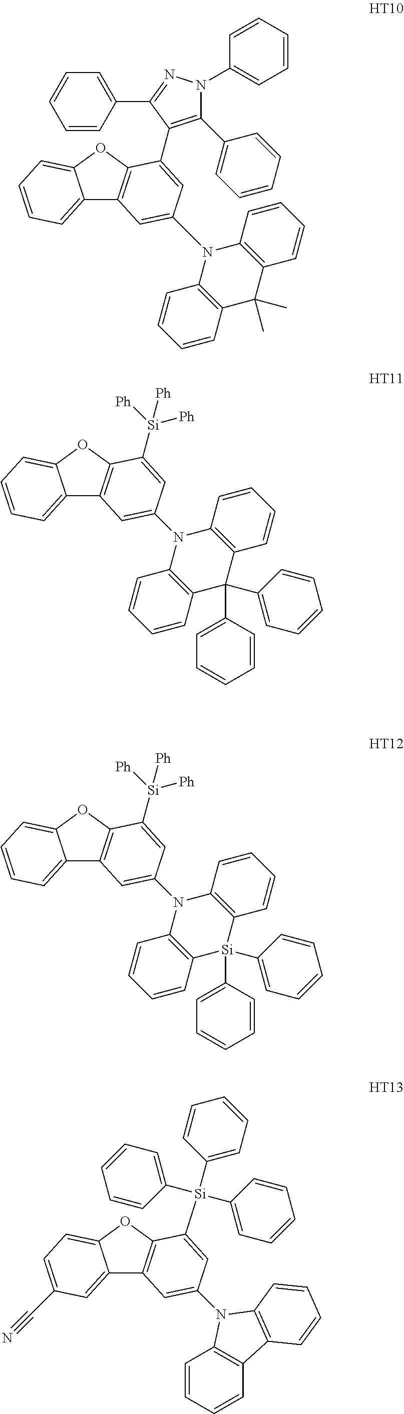 [SMILES: CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1]

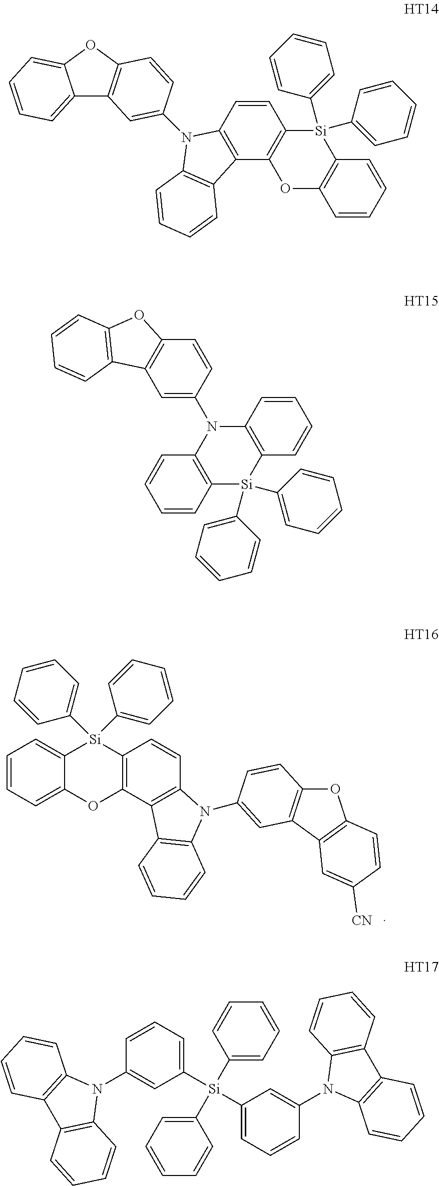 [SMILES: c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

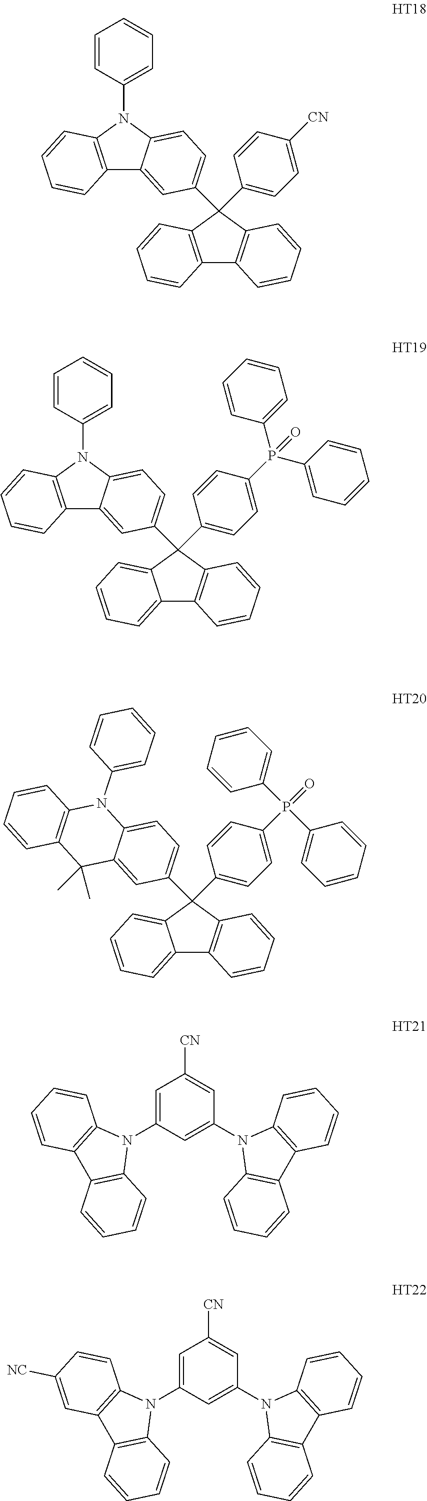 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

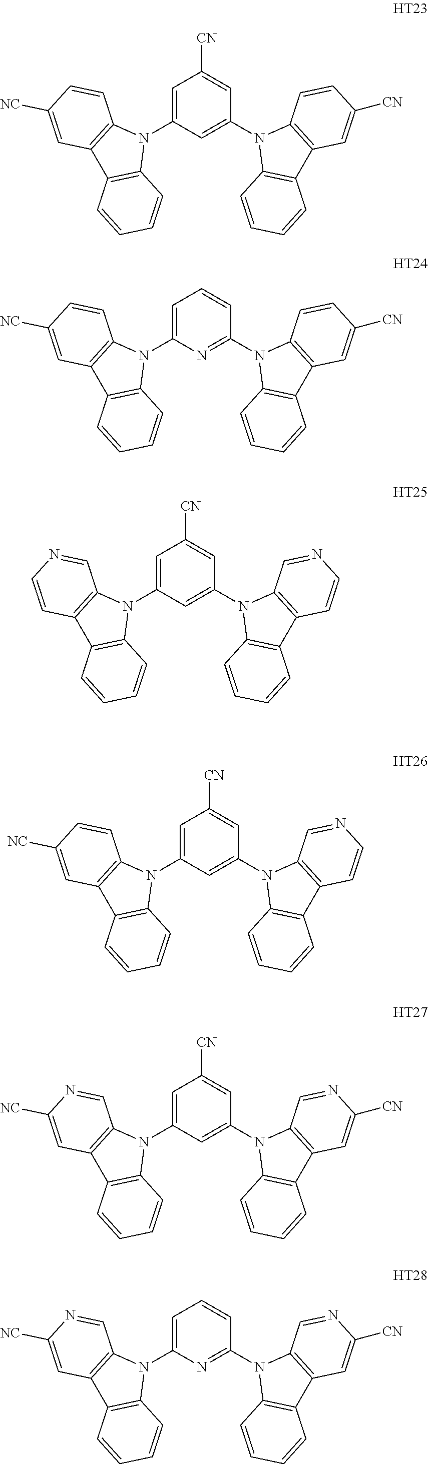 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

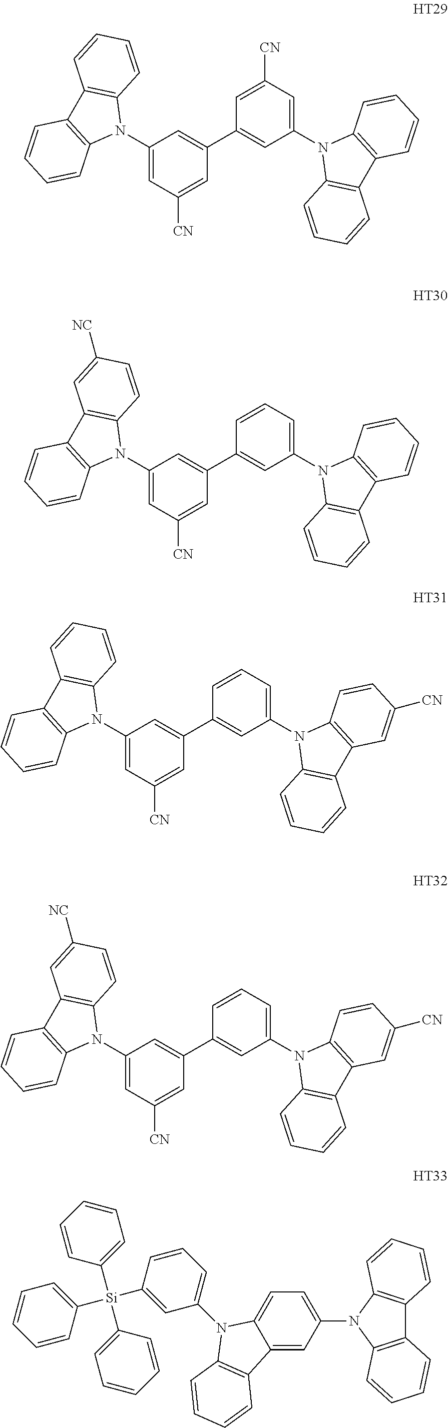 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

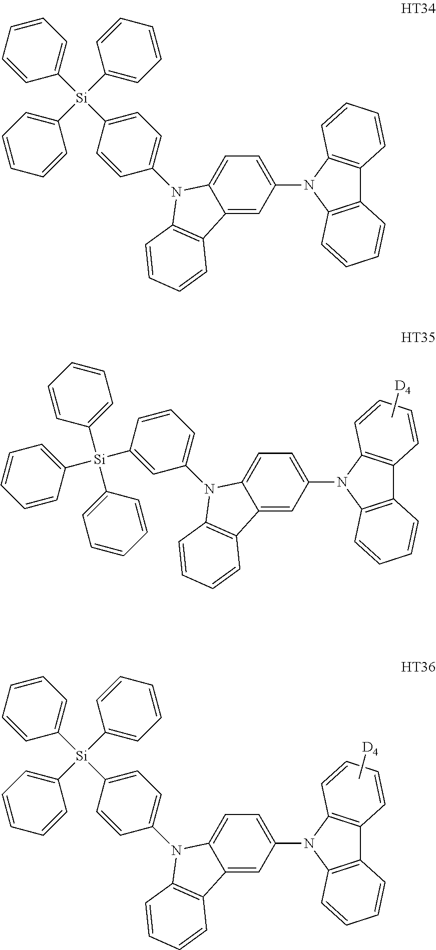

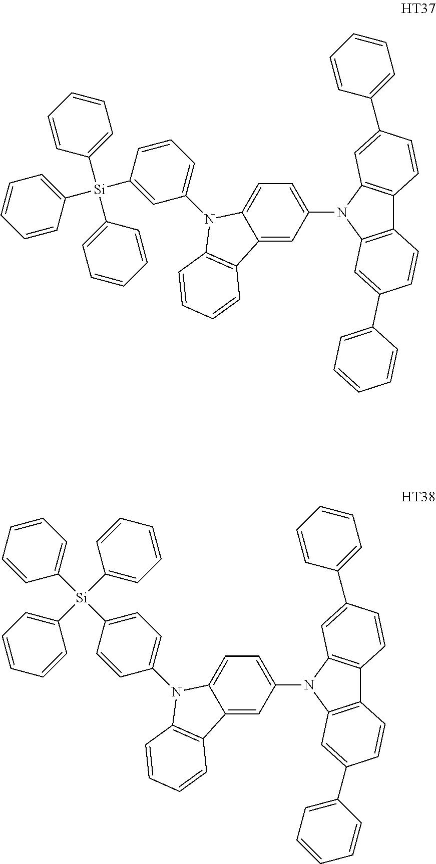 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

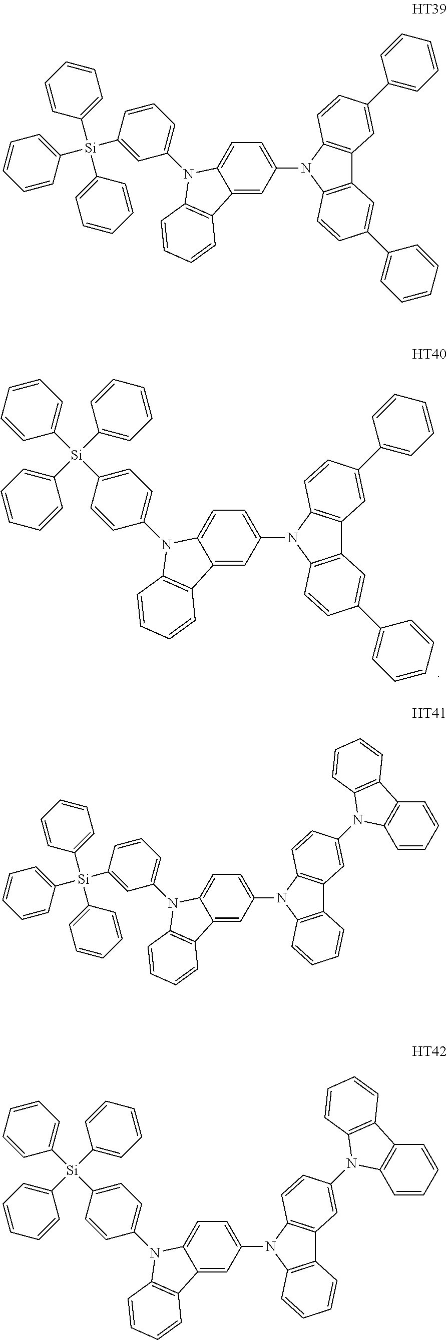 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

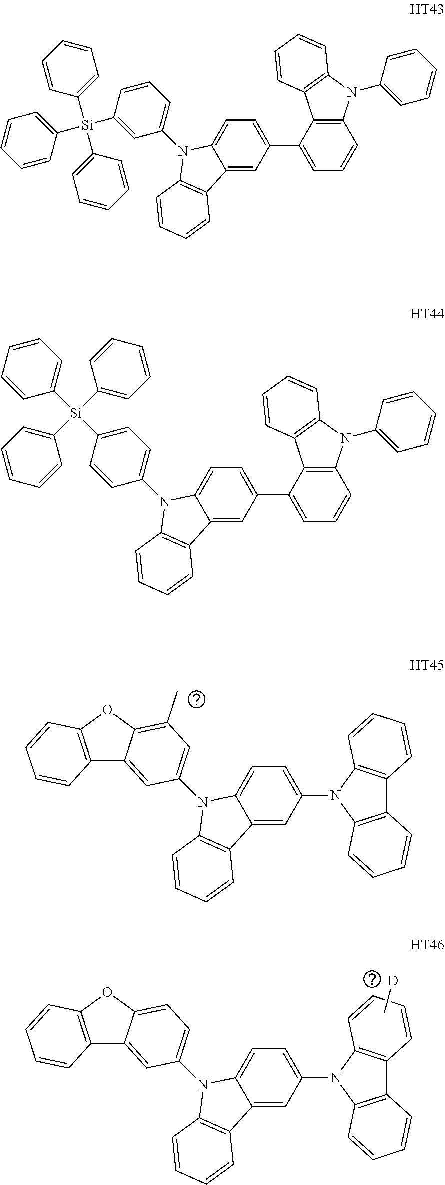

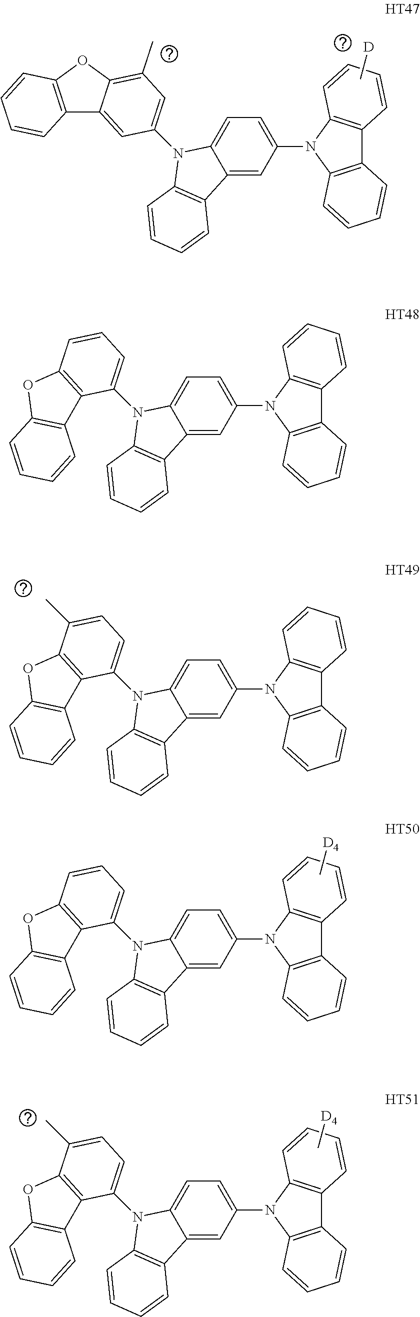

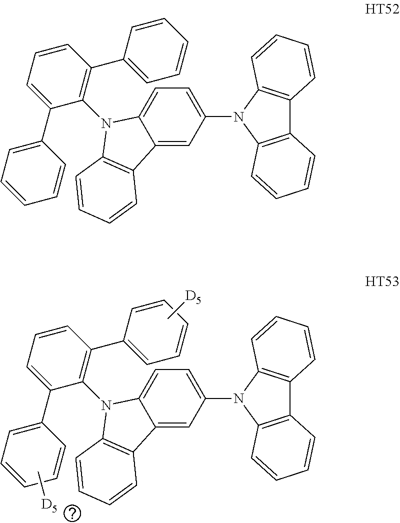

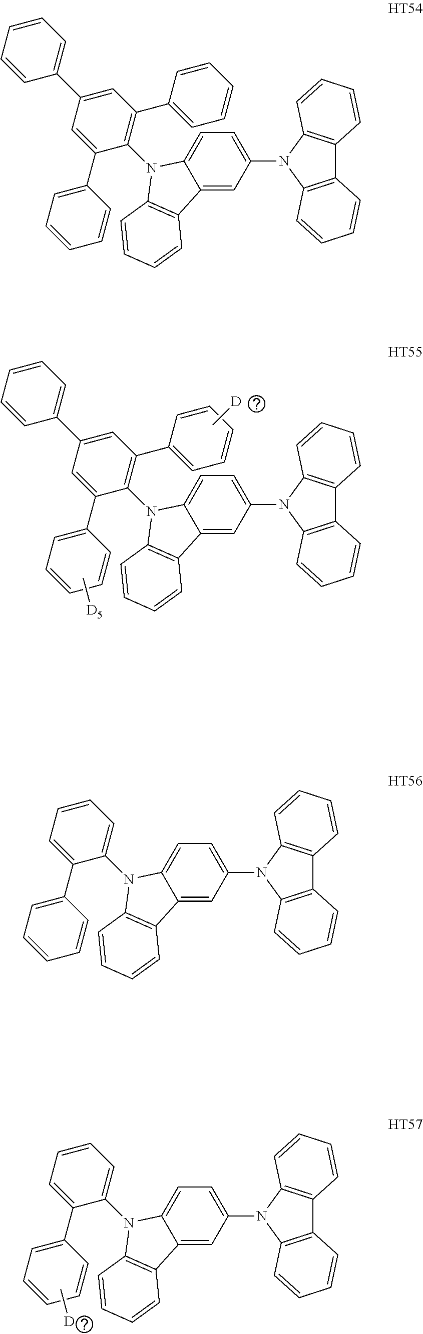

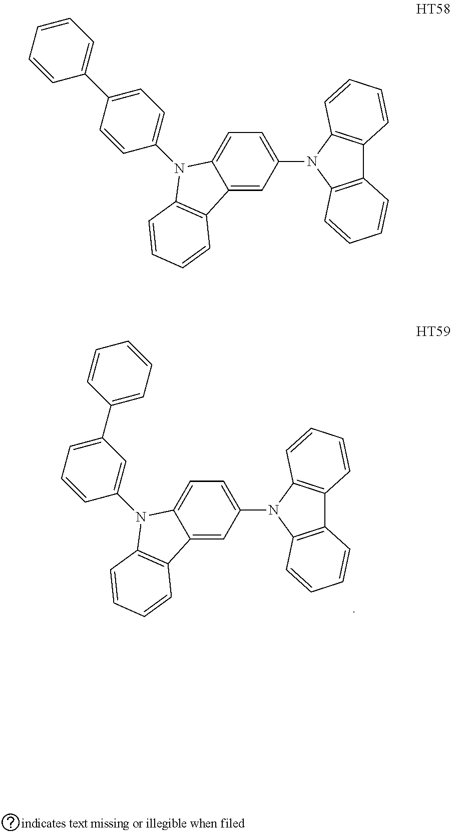 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In the specific example compounds suggested in Compound Group 5, “D” may mean a deuterium atom, and “Ph” may mean a substituted or unsubstituted phenyl group. For example, the specific example compounds suggested in Compound Group 5, “Ph” may be an unsubstituted phenyl group.

Meanwhile, the fifth compound represented by Formula HT-1 may be included as a material for the hole transport region HTR.

In the light-emitting element ED according to an aspect illustrated in FIG. 3 to FIG. 6, the emission layer EML may include the above-described nitrogen-containing compound according to an aspect as a host. In addition, in the light-emitting element ED according to an aspect illustrated in FIG. 3 to FIG. 6, the hole transport region HTR may include the nitrogen-containing compound according to an aspect.

Meanwhile, the light-emitting element ED according to an aspect may further include an anthracene derivative, a pyrene derivative, a fluoranthene derivative, a chrysene derivative, a dihydrobenzanthracene derivative, or a triphenylene derivative. Specifically, the emission layer EML may further include an anthracene derivative, or a pyrene derivative.

In each light emitting device ED of aspects illustrated in FIGS. 3 to 6, the emission layer EML may further include a known host and dopant besides the above-described host and dopant, and for example the emission layer EML may include a compound represented by Formula E-1 below. The compound represented by Formula E-1 below may be used as a fluorescent host material.

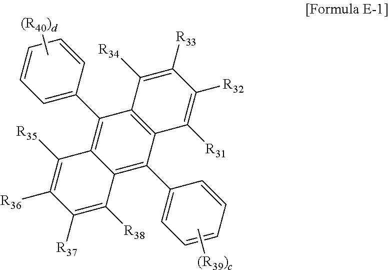

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Meanwhile, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may be each independently an integer of 0 to 5.

Formula E-1 may be represented by any one among Compound E1 to Compound E19 below:

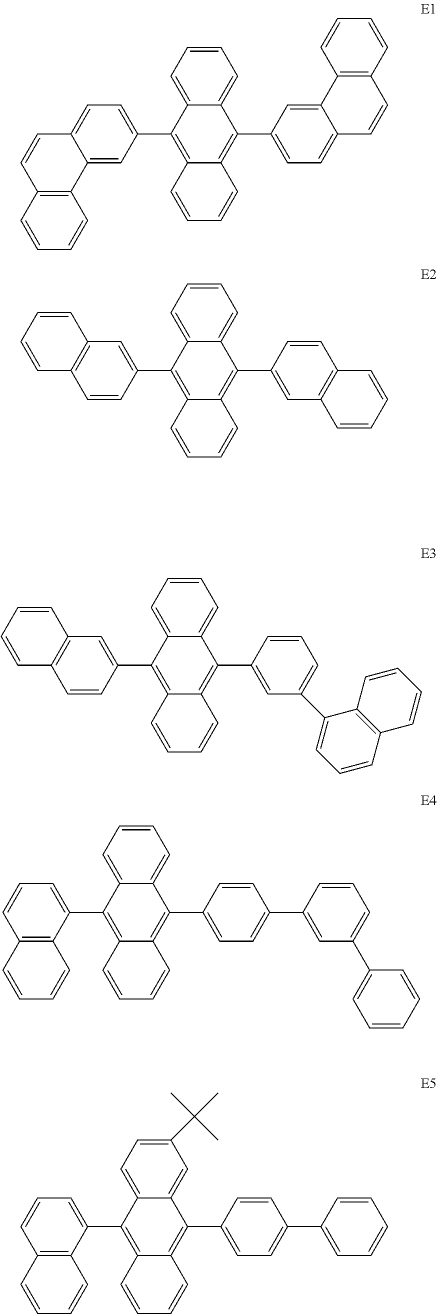

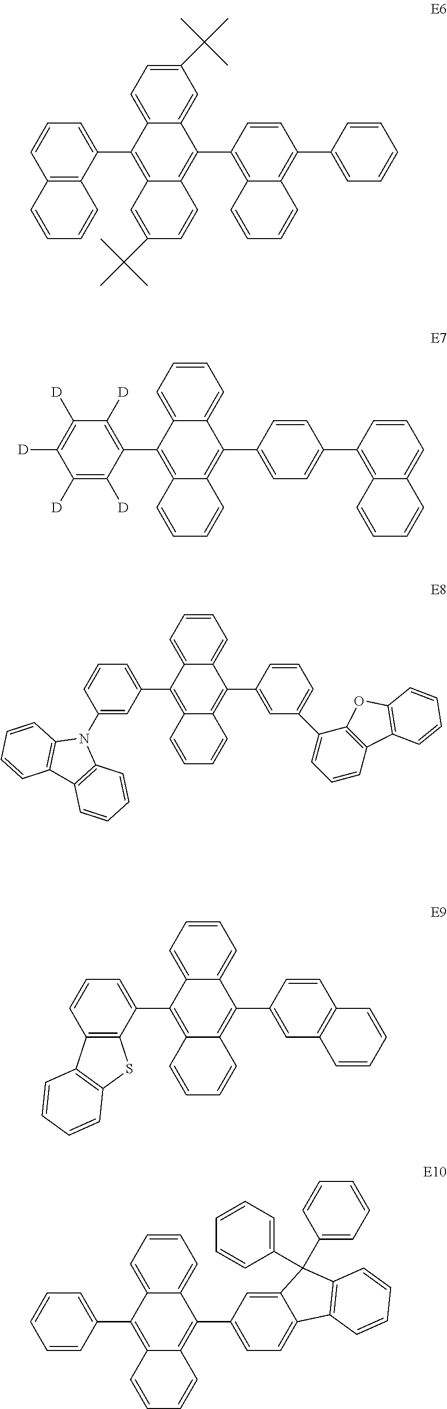

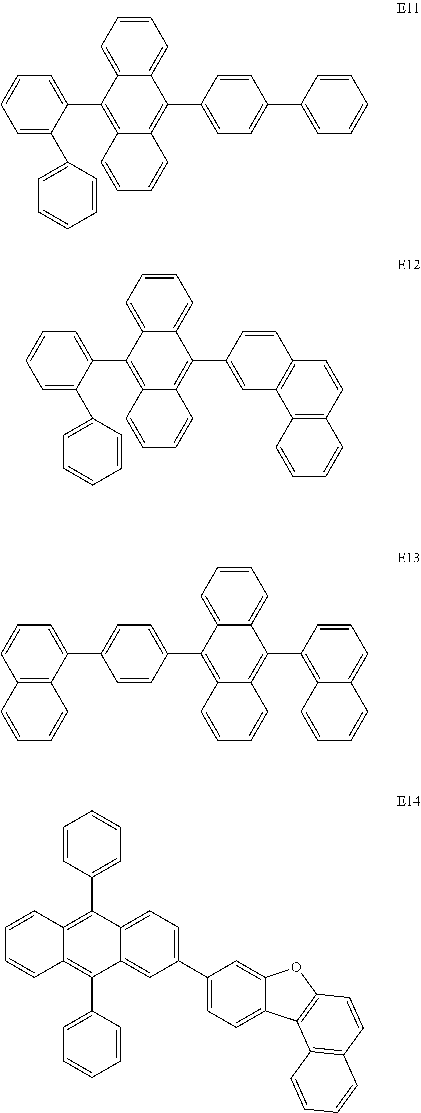

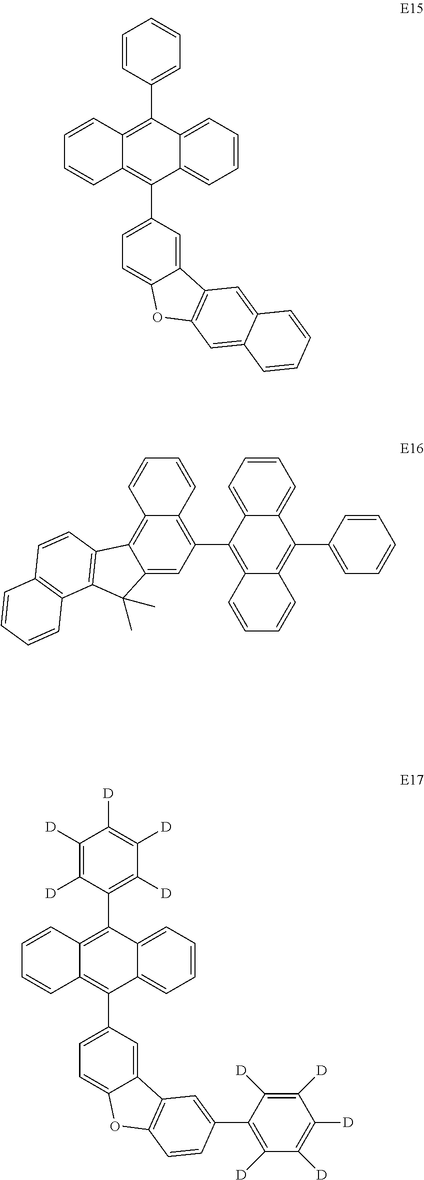

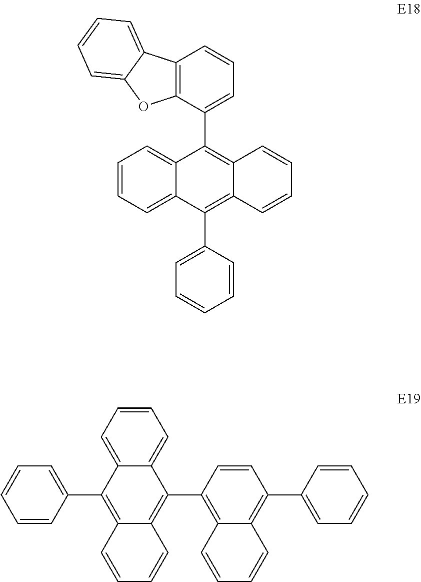

In an aspect, the emission layer EML may include a compound represented by Formula E-2a or Formula E-2b below. The compound represented by Formula E-2a or Formula E-2b below may be used as a phosphorescent host material.

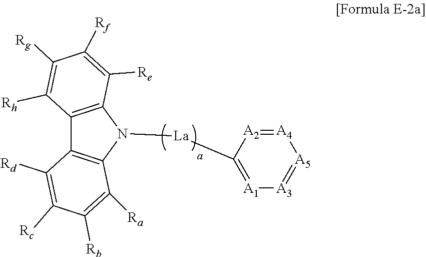

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. Meanwhile, when a is an integer of 2 or greater, a plurality of Lₐ's may be each independently a substituted or unsubstituted arylene group having 6 to 30 ring-forming carbon atoms, or a substituted or unsubstituted heteroarylene group having 2 to 30 ring-forming carbon atoms.

In addition, in Formula E-2a, A₁ to A₅ may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, etc., as a ring-forming atom.

Meanwhile, in Formula E-2a, two or three selected from among A₁ to A₅ may be N, and the rest may be CRᵢ.

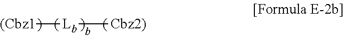

In Formula E-2b, Cbz1 and Cbz2 may be each independently an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. Meanwhile, b is an integer of 0 to 10, and when b is an integer of 2 or more, a plurality of L_{b}'s may be each independently a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one among the compounds of Compound Group E-2 below. However, the compounds listed in Compound Group E-2 below are exemplary, and the compound represented by Formula E-2a or Formula E-2b is not limited to those represented in Compound Group E-2 below.

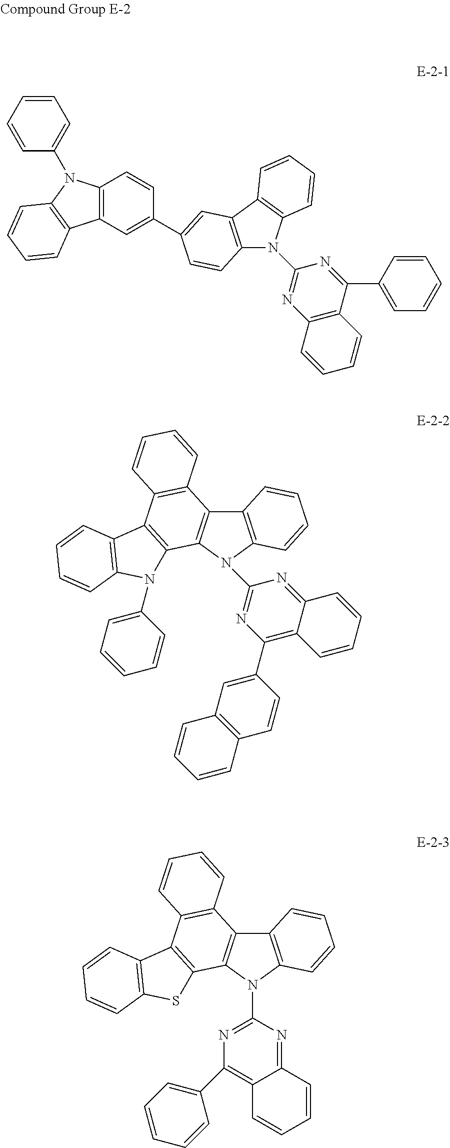 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

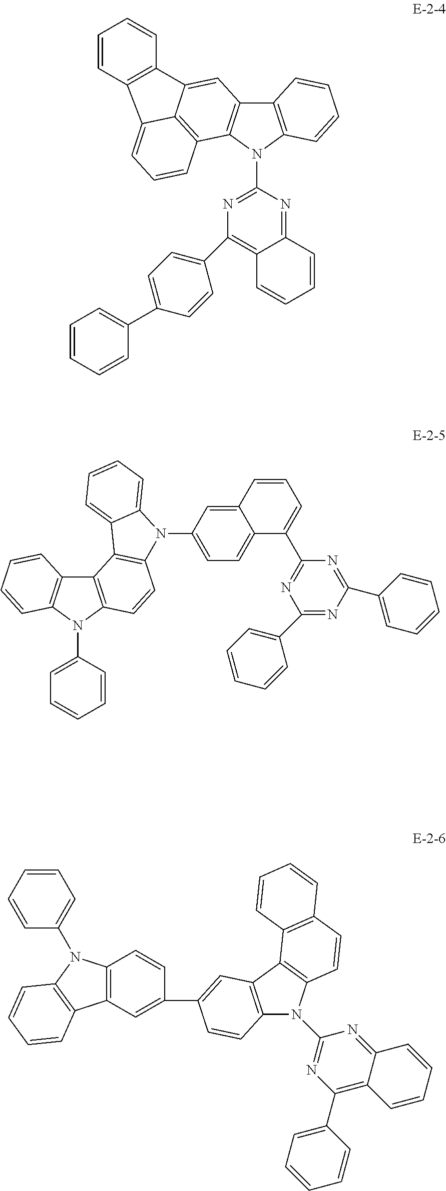 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

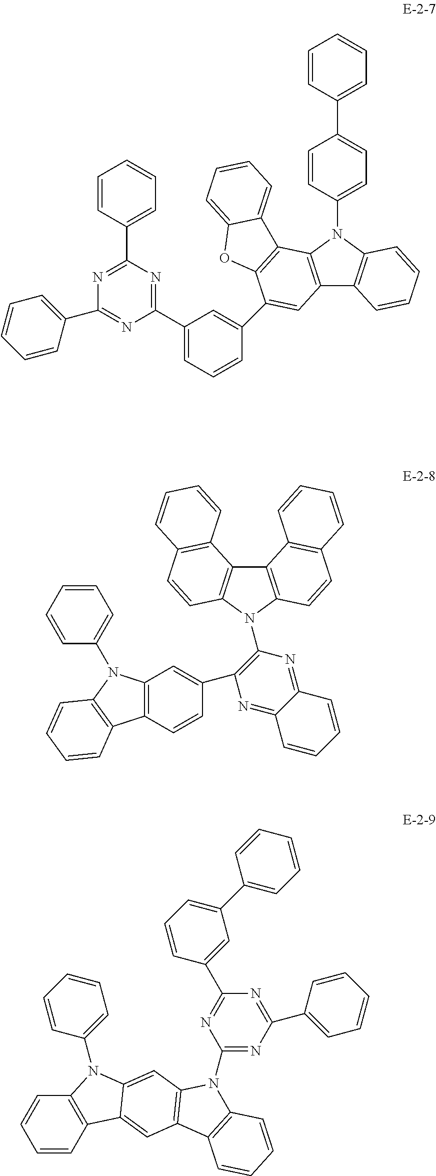 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

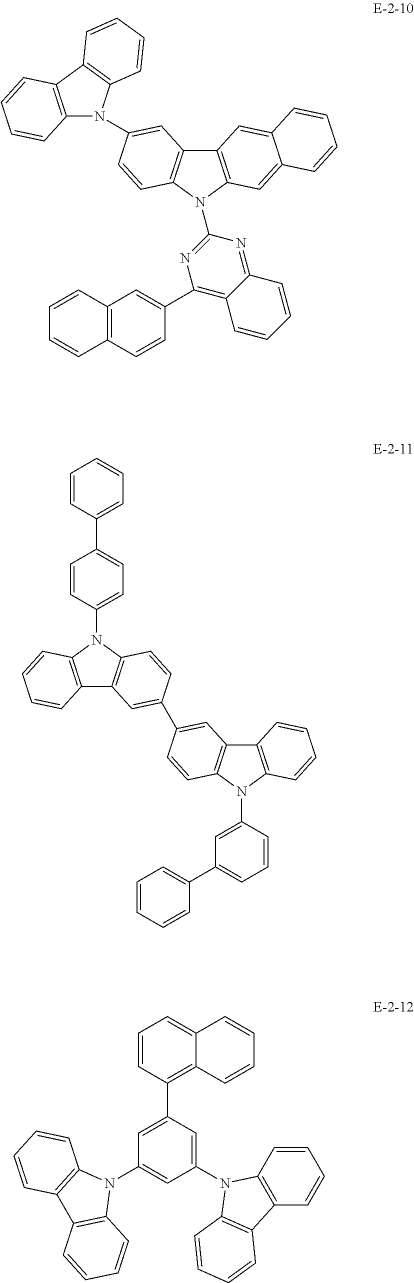 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

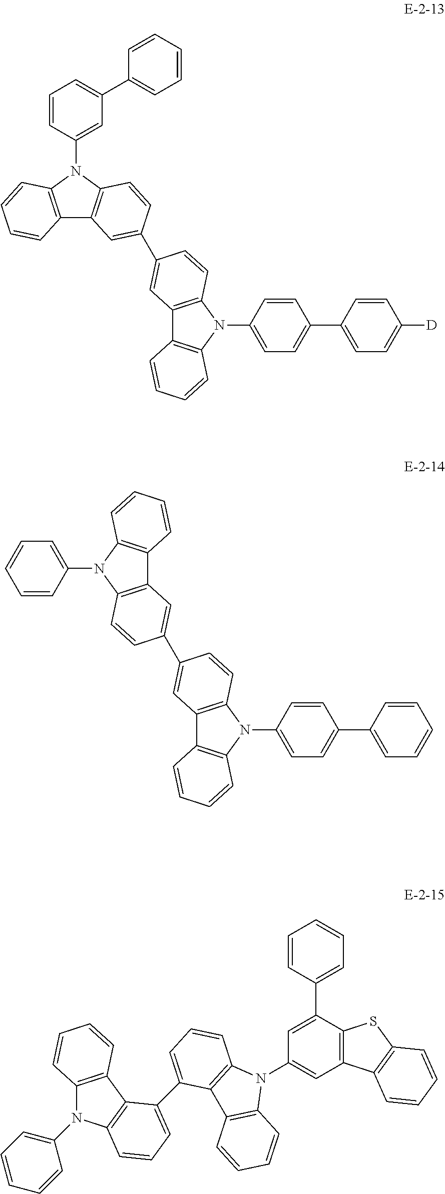 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

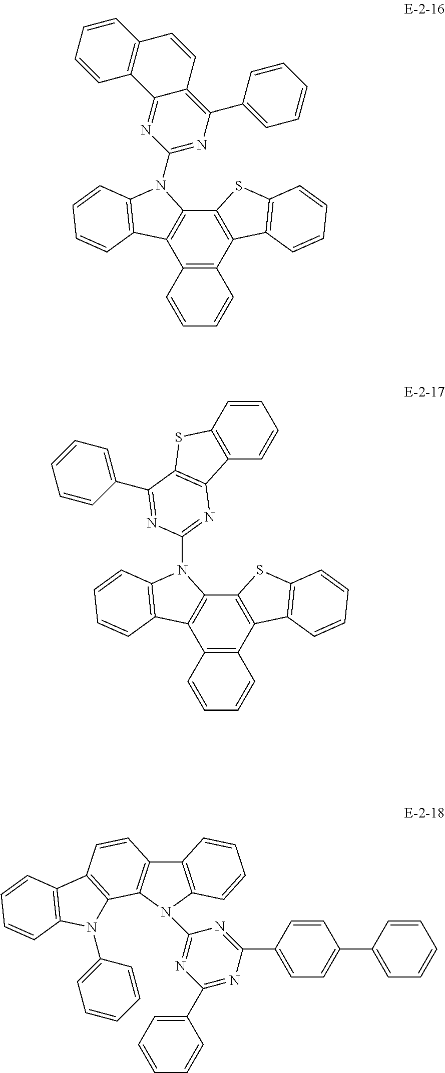 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

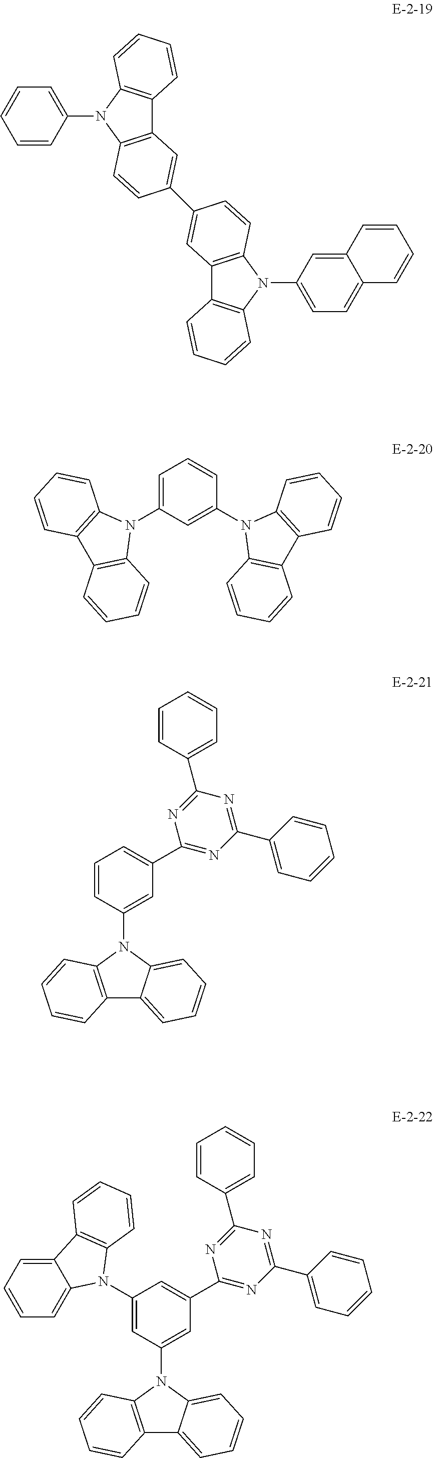 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

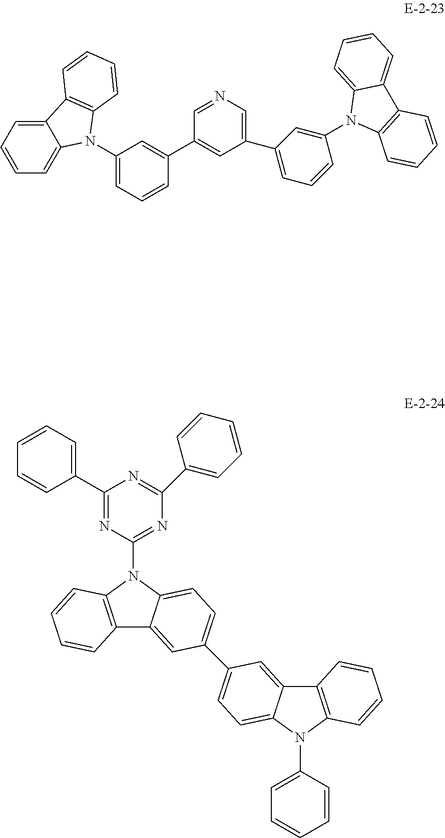 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may include the compound represented by Formula M-a below. The compound represented by Formula M-a below may be used as a phosphorescent dopant material.

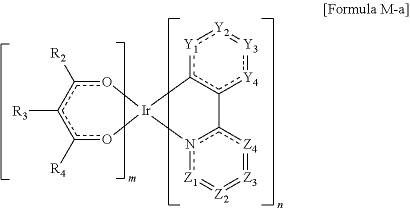

In Formula M-a above, Y₁ to Y₄ and Z₁ to Z₄ may be each independently CR₁ or N, R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be used as a phosphorescent dopant.

The compound represented by Formula M-a may be represented by any one among Compound M-a1 to Compound M-a25 below. However, Compounds M-a1 to M-a25 below are examples, and the compound represented by Formula M-a is not limited to those represented by Compounds M-a1 to M-a25 below.

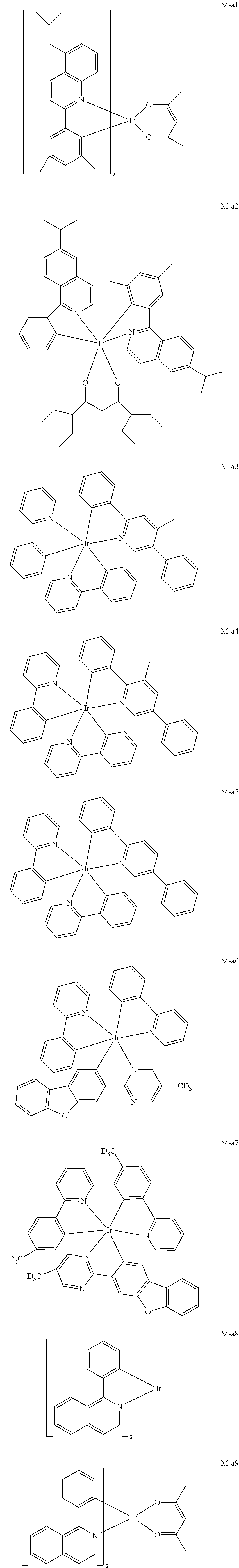

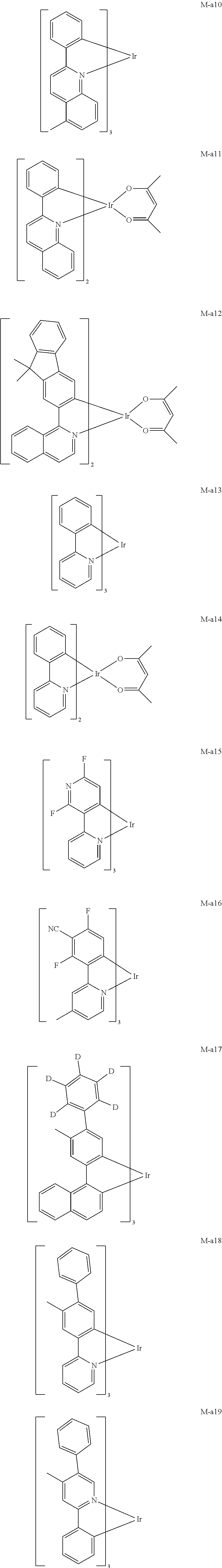

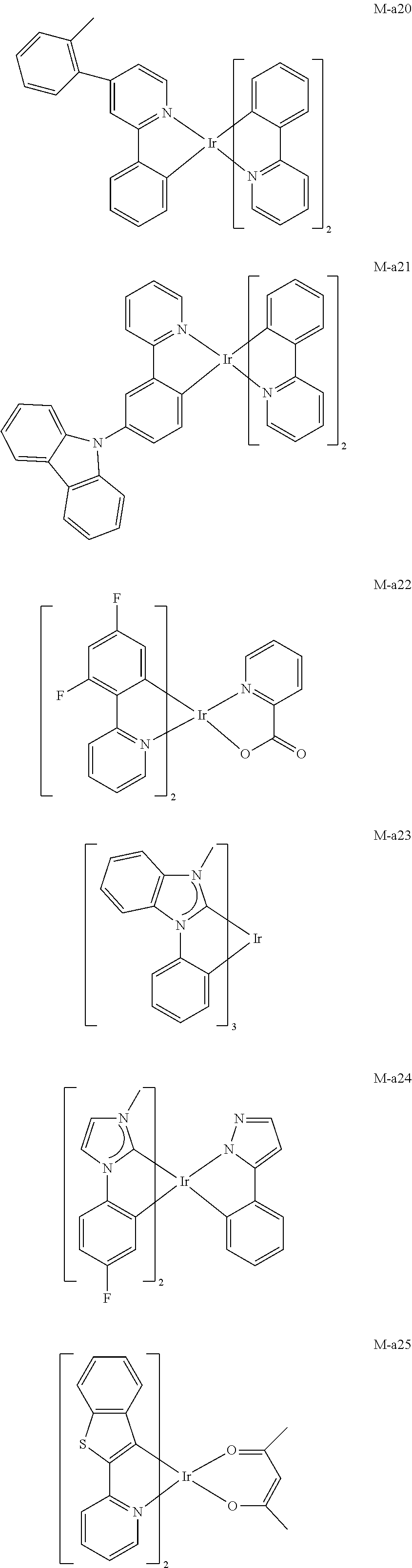

The emission layer EML may include a compound represented by any one among Formula F-a to Formula F-c below. The compound represented by Formula F-a to Formula F-c below may be used as a fluorescence dopant material.

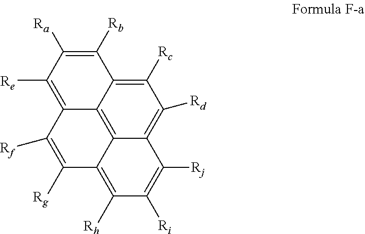

In Formula F-a above, two selected from among Rₐ to Rⱼ may each independently be substituted with *—NAr₁Ar₂. The others, which are not substituted with *—NAr₁Ar₂, among Rₐ to Rⱼ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

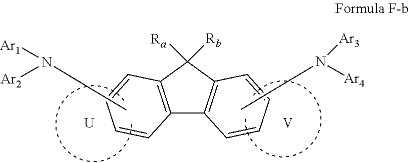

In Formula F-b above, Rₐ and R_{b} may be each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Ar₁ to Ar₄ may be each independently a substituted or unsubstituted aryl group having 6 to 30 ring-forming carbon atoms, or a substituted or unsubstituted heteroaryl group having 2 to 30 ring-forming carbon atoms.

In Formula F-b, U and V may be each independently a substituted or unsubstituted hydrocarbon ring having 5 to 30 ring-forming carbon atoms, or a substituted or unsubstituted heterocycle having 2 to 30 ring-forming carbon atoms. At least one among Ar₁ to Ar₄ may be a heteroaryl group containing O or S as a ring-forming atom.

In Formula F-b, the number of rings represented by U and V may be each independently 0 or 1. For example, in Formula F-b, it means that when the number of U or V is 1, one ring constitutes a fused ring at a portion indicated by U or V, and when the number of U or V is 0, a ring indicated by U or V does not exist. Specifically, when the number of U is 0 and the number of V is 1, or when the number of U is 1 and the number of V is 0, the fused ring having a fluorene core in Formula F-b may be a cyclic compound having four rings. In addition, when each number of U and V is 0, the fused ring in Formula F-b may be a cyclic compound having three rings. In addition, when each number of U and V is 1, the fused ring having a fluorene core in Formula F-b may be a cyclic compound having five rings.

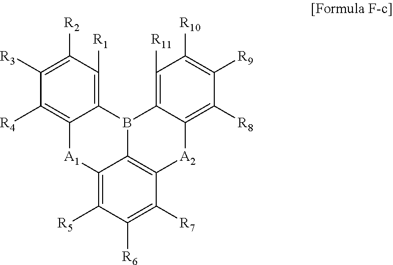

In Formula F-c, A₁ and A₂ may be each independently O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to substituents of an adjacent ring to form a fused ring. For example, when A₁ and A₂ are each independently NRₘ, A₁ may be bonded to R₄ or R₅ to form a ring. In addition, A₂ may be bonded to R₇ or R₅ to form a ring.

In an aspect, the emission layer EML may further include, as a known dopant material, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), or N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a known phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. Specifically, iridium(III) bis(4,6-difluorophenylpyridinato-N,C2) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, aspects of the present disclosure are not limited thereto.

The emission layer EML may include a quantum dot material. The core of the quantum dot may be selected from a Group II-VI compound, a Group III-VI compound, a Group I-III-IV compound, a Group III-V compound, a Group III-II-V compound, a Group IV-VI compound, a Group IV element, a Group IV compound, or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ or In₂Se₃, a ternary compound such as InGaS₃ or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound such as AgInGaS₂ or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAiP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. Meanwhile, the Group III-V compound may further include a Group II metal. For example, InZnP, etc., may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a polynary compound such as the binary compound, the ternary compound, or the quaternary compound may be present in a particle with a uniform or non-uniform concentration distribution. That is, the formulae mean the types of elements included in the compounds, and the elemental ratio in the compound may be different. For example, AgInGaS₂ may mean AgInₓGa₁₋ₓS₂ (where x is a real number of 0 to 1).

Meanwhile, the quantum dot may have a single structure or a double structure of core-shell in which the concentration of each element included in the quantum dot is uniform. For example, the material included in the core may be different from the material included in the shell.

The shell of the quantum dot may serve as a protection layer to prevent the chemical deformation of the core to maintain semiconductor properties, and/or a charging layer to impart electrophoresis properties to the quantum dot. The shell may be a single layer or multiple layers. An interface between the core and the shell may have a concentration gradient in which the concentration of an element present in the shell becomes lower towards the center.

In some aspects, the quantum dot may have the above-described core/shell structure including a core containing nanocrystals and a shell surrounding the core. The shell of the quantum dot may serve as a protection layer to prevent the chemical deformation of the core to maintain semiconductor properties, and/or a charging layer to impart electrophoresis properties to the quantum dot. The shell may be a single layer or multiple layers. An example of the shell of the quantum dots may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but aspects of the present disclosure are not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but aspects of the present disclosure are not limited thereto.

Each element included in a polynary compound such as the binary compound, or the ternary compound may be present in a particle with a uniform or non-uniform concentration distribution. That is, the formulae mean the types of elements included in the compounds, and the elemental ratio in the compound may be different.

The quantum dot may have a full width of half maximum (FWHM) of a light emitting wavelength spectrum of about 45 nm or less, preferably about 40 nm or less, and more preferably about 30 nm or less, and color purity or color reproducibility may be improved in the above range. In addition, light emitted through such quantum dot is emitted in all directions so that a wide viewing angle may be improved.

In addition, although the form of the quantum dot is not particularly limited as long as it is a form commonly used in the art, more specifically, the quantum dot in the form of spherical, pyramidal, multi-arm, or cubic nanoparticles, nanotubes, nanowires, nanofibers, nanoplate particles, etc. may be used.

As the size of the quantum dot is adjusted or the elemental ratio in the quantum dot compound is adjusted, it is possible to control the energy band gap, and thus light in various wavelength ranges may be obtained in the quantum dot emission layer. Therefore, the quantum dot as above (using different sizes of quantum dots or different elemental ratios in the quantum dot compound) is used, and thus the light emitting device, which emits light in various wavelengths, may be implemented. Specifically, the adjustment of the size of the quantum dot or the elemental ratio in the quantum dot compound may be selected to emit red, green, and/or blue light. In addition, the quantum dots may be configured to emit white light by combining various colors of light.

In each of the light emitting devices ED of aspects illustrated in FIGS. 3 to 6, the electron transport region ETR is provided on the emission layer EML. The electron transport region ETR may include at least one of the hole blocking layer HBL, the electron transport layer ETL, or the electron injection layer EIL, but aspects of the present disclosure are not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In addition, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but aspects of the present disclosure are not limited thereto. The electron transport region ETR may have a thickness, for example, from about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-2 below:

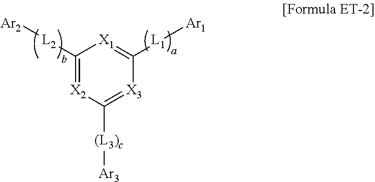

In Formula ET-2, at least one among X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may be each independently an integer of 0 to 10. In Formula ET-2, L₁ to L₃ may be each independently a direct linkage, a substituted or unsubstituted arylene group having 6 to 30 ring-forming carbon atoms, or a substituted or unsubstituted heteroarylene group having 2 to 30 ring-forming carbon atoms. Meanwhile, when a to c are each independently an integer of 2 or more, L₁ to L₃ may be each independently a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, aspects of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

The electron transport region ETR may include at least one among Compound ET1 to Compound ET36 below:

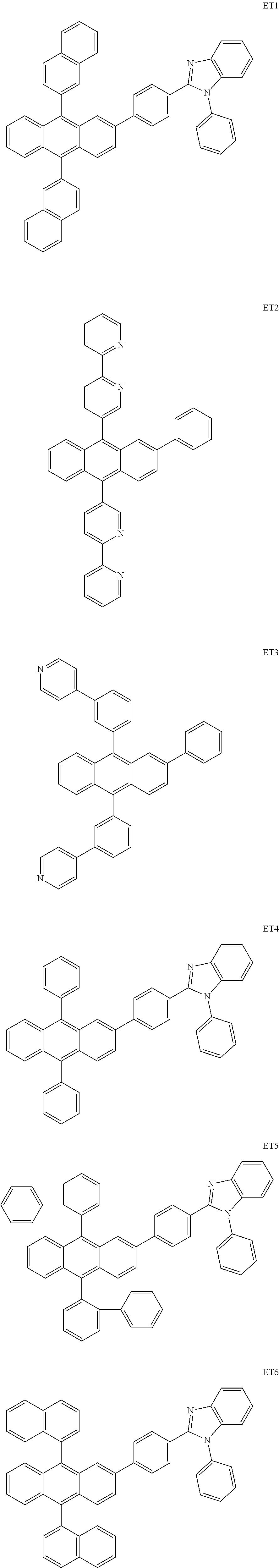

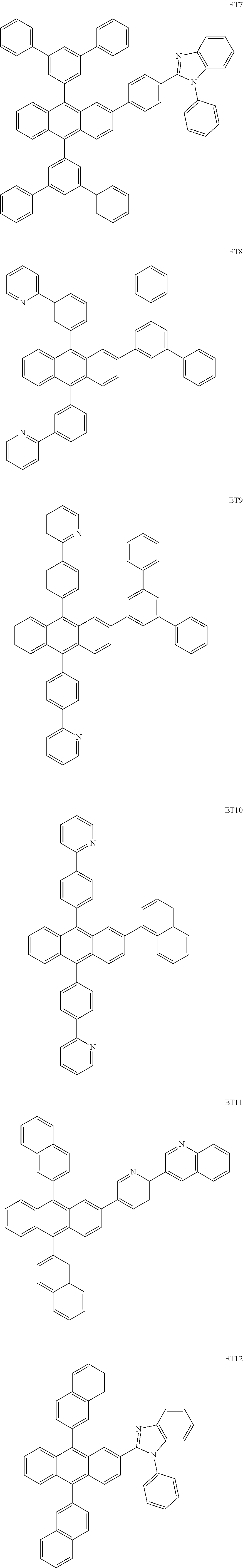

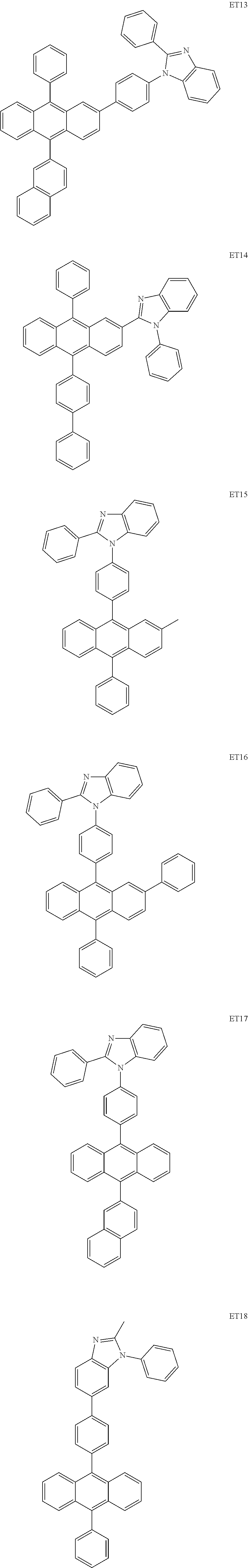 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

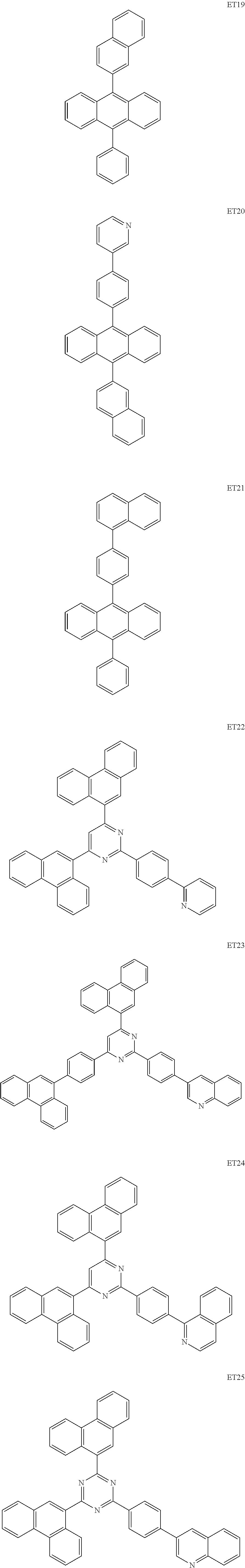

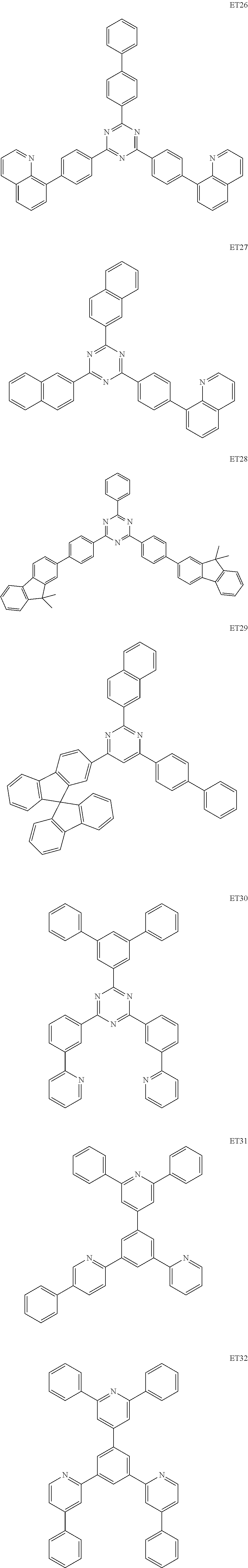

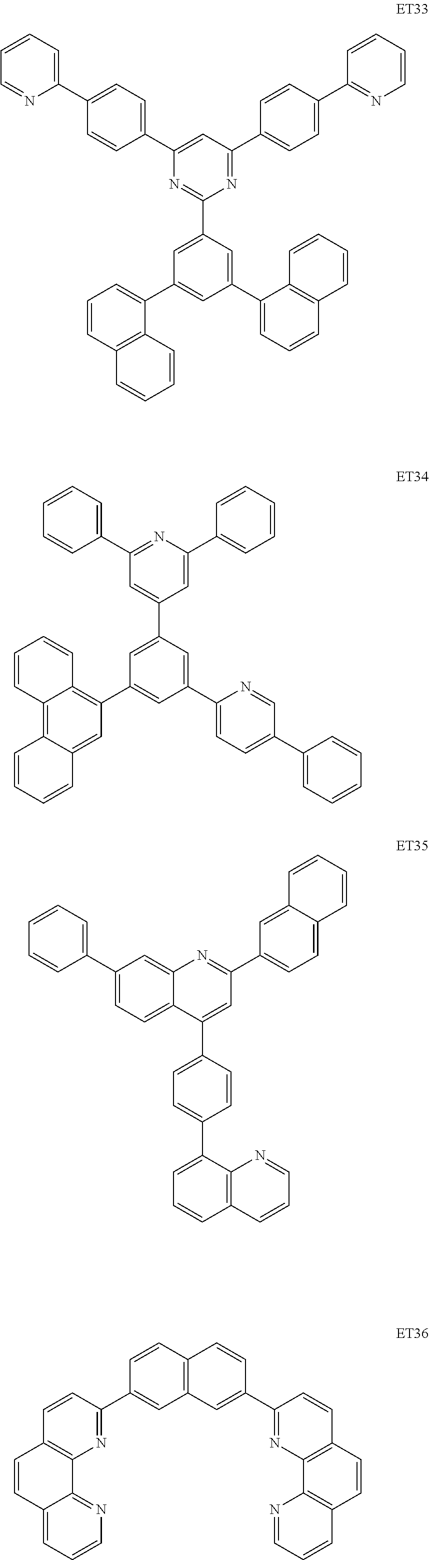 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In addition, the electron transport region ETR may include a metal halide such as LiF, NaCl, CsF, RbCl, RbI, CuI, or KI, a lanthanide metal such as Yb, or a co-deposited material of the metal halide and the lanthanide metal. For example, the electron transport region ETR may include KI:Yb, RbI:Yb, LiF:Yb, etc., as a co-deposited material. Meanwhile, the electron transport region ETR may be formed using a metal oxide such as Li₂O or BaO, or 8-hydroxyl-lithium quinolate (Liq), etc., but aspects of the present disclosure are not limited thereto. The electron transport region ETR may also be formed of a mixture material of an electron transport material and an insulating organometallic salt. The organometallic salt may be a material having an energy band gap of about 4 eV or more. Specifically, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but aspects of the present disclosure are not limited thereto.

The electron transport region ETR may include the above-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. If the thickness of the electron transport layer ETL satisfies the aforementioned range, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. If the thickness of the electron injection layer EIL satisfies the above-described range, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but aspects of the present disclosure are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgAg). Alternatively, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown, the second electrode EL2 may be connected with an auxiliary electrode. If the second electrode EL2 is connected with the auxiliary electrode, the resistance of the second electrode EL2 may be decreased.

Meanwhile, a capping layer CPL may further be disposed on the second electrode EL2 of the light emitting device ED of an aspect. The capping layer CPL may include a multilayer or a single layer.

In an aspect, the capping layer CPL may be an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or an epoxy resin, or acrylate such as methacrylate. However, aspects of the present disclosure are not limited thereto, and the capping layer CPL may include at least one among Compounds P1 to P5 below:

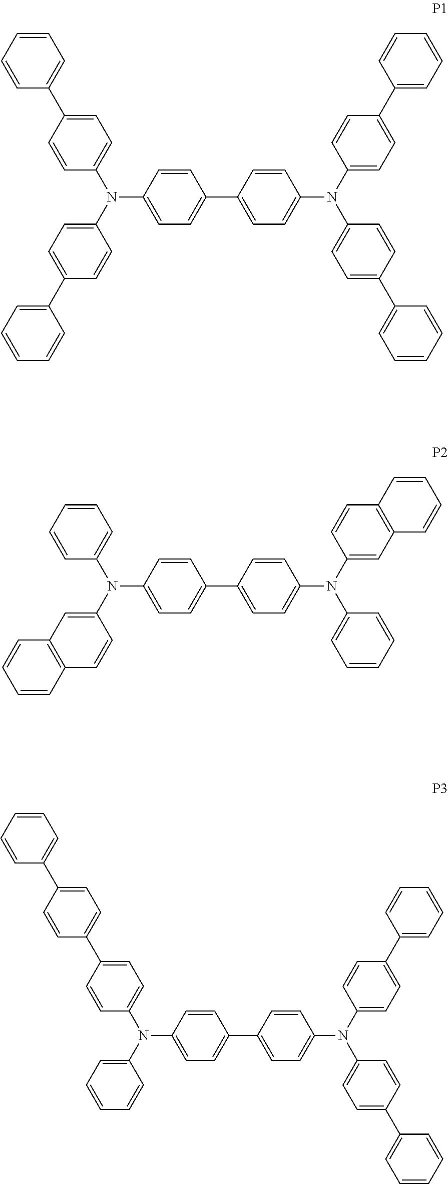 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

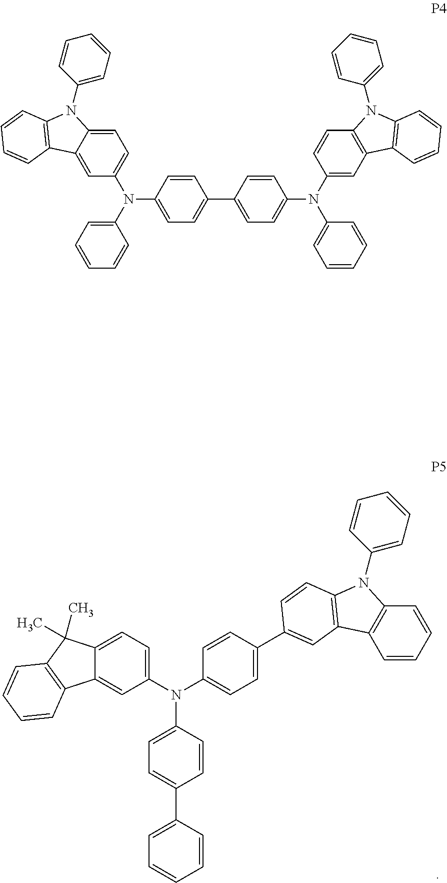 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

Meanwhile, the refractive index of the capping layer CPL may be about 1.6 or more. Specifically, the refractive index of the capping layer CPL may be about 1.6 or more with respect to light in a wavelength range of about 550 nm to about 660 nm.

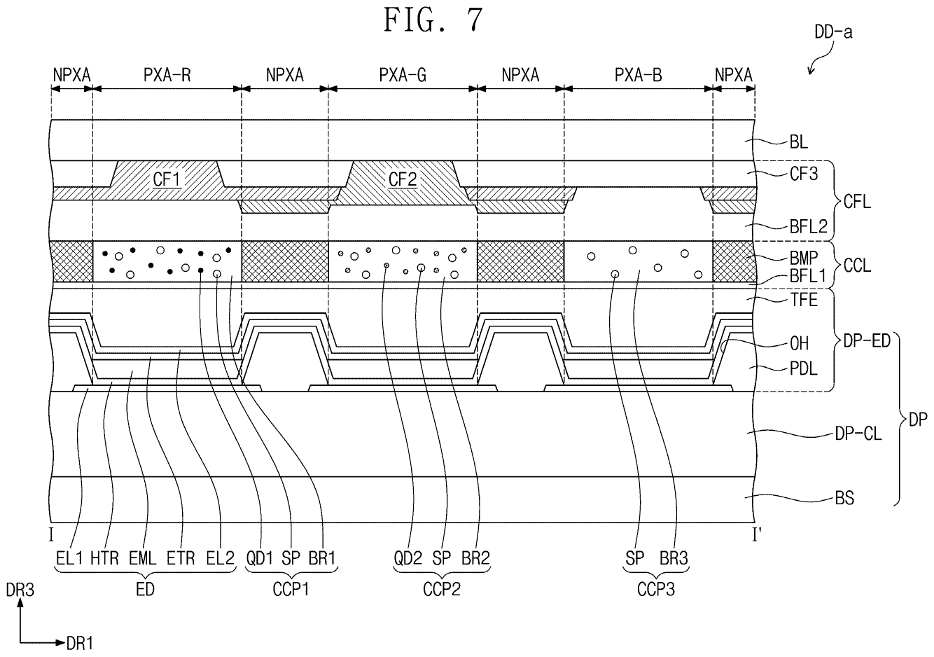

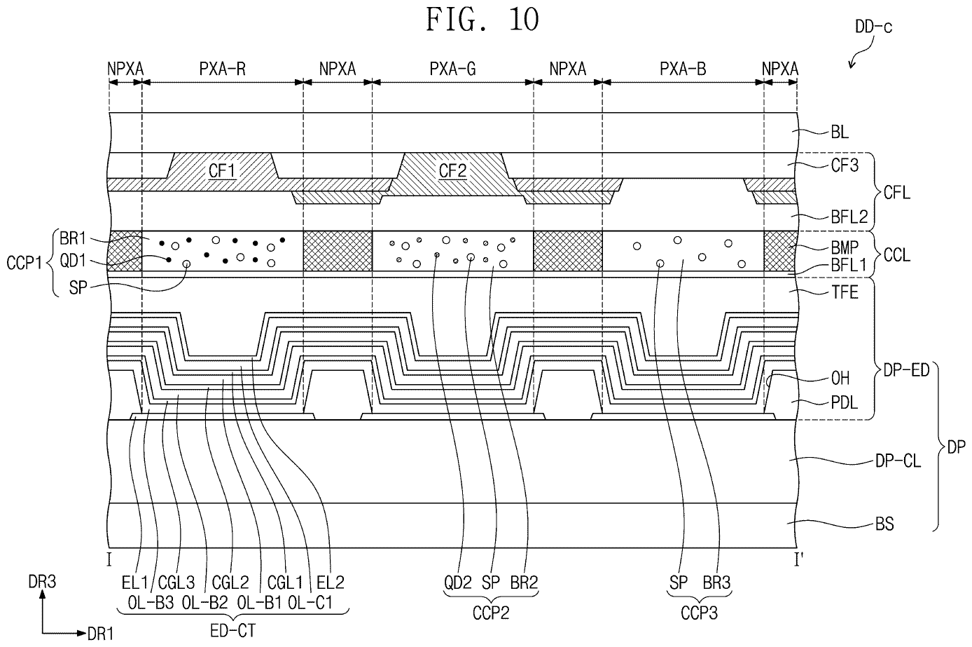

Each of FIGS. 7 to 10 is a cross-sectional view of a display apparatus according to an aspect of the present disclosure. Hereinafter, in describing the display apparatuses of aspects with reference to FIGS. 7 to 10, the duplicated features which have been described in FIGS. 1 to 6 are not described again, but their differences will be mainly described.

Referring to FIG. 7, the display apparatus DD-a according to an aspect may include a display panel DP including a display device layer DP-ED, a light control layer CCL disposed on the display panel DP, and a color filter layer CFL. In an aspect illustrated in FIG. 7, the display panel DP may include a base layer BS, a circuit layer DP-CL provided on the base layer BS, and the display device layer DP-ED, and the display device layer DP-ED may include a light emitting device ED.

A light-emitting element ED may include a first electrode EL1, a hole transport region HTR disposed on the first electrode EL1, an emission layer EML disposed on the hole transport region HTR, an electron transport region ETR disposed on the emission layer, and a second electrode EL2 disposed on the electron transport region ETR. Meanwhile, to the structure of the above-described light-emitting element, illustrated in FIG. 3 to FIG. 6, may be similarly applied to a structure of the light-emitting element ED illustrated in FIG. 7. The light-emitting element ED may include the nitrogen-containing element according to an aspect, and thus excellent reproductivity and long lifespan characteristics may be exhibited. Therefore, the display device according to an aspect may exhibit excellent display quality.

Referring to FIG. 7, the emission layer EML may be disposed in an opening OH defined in a pixel defining film PDL. For example, the emission layer EML which is divided by the pixel defining film PDL and provided corresponding to each light emitting regions PXA-R, PXA-G, and PXA-B may emit light in the same wavelength range. In the display apparatus DD-a of an aspect, the emission layer EML may emit blue light. Meanwhile, unlike the configuration illustrated, in an aspect, the emission layer EML may be provided as a common layer in the entire light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may emit provided light by converting the wavelength thereof. That is, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 7, divided patterns BMP may be disposed between the light control parts CCP1, CCP2 and CCP3 which are spaced apart from each other, but aspects of the present disclosure are not limited thereto. FIG. 7 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light emitting device ED into second color light, a second light control part CCP2 containing a second quantum dot QD2 which converts the first color light into third color light, and a third light control part CCP3 which transmits the first color light.

In an aspect, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The same as described above may be applied with respect to the quantum dots QD1 and QD2.

In addition, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one among TiO₂, ZnO, Al₂O₃, SiO₂, or hollow sphere silica, or may be a mixture of at least two materials selected from among TiO₂, ZnO, Al₂O₃, SiO₂, or hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In an aspect, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an aspect, the first base resin BR1, the second base resin BR2, and the third base resin BR3 may be the same as or different from each other.

The light control layer CCL may include a barrier layer BFL1. The barrier layer BFL1 may serve to prevent the penetration of moisture and/or oxygen (hereinafter, referred to as ‘moisture/oxygen’). The barrier layer BFL1 may block the light control parts CCP1, CCP2 and CCP3 from being exposed to moisture/oxygen. Meanwhile, the barrier layer BFL1 may cover the light control parts CCP1, CCP2, and CCP3. In addition, the barrier layer BFL2 may be provided between the light control parts CCP1, CCP2, and CCP3 and the color filter layer CFL.

The barrier layers BFL1 and BFL2 may include at least one inorganic layer. That is, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. Meanwhile, the barrier layers BFL1 and BFL2 may further include an organic film. The barrier layers BFL1 and BFL2 may be formed of a single layer or a plurality of layers.

In the display apparatus DD-a of an aspect, the color filter layer CFL may be disposed on the light control layer CCL. For example, the color filter layer CFL may be directly disposed on the light control layer CCL. In this case, the barrier layer BFL2 may be omitted.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

Meanwhile, aspects of the present disclosure are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

Furthermore, in an aspect, the first filter CF1 and the second filter CF2 may be a yellow filter. The first filter CF1 and the second filter CF2 may not be separated but be provided as one filter.

Although not illustrated, the color filter layer CFL may further include a light shielding part (not shown). The light shielding part may be a black matrix. The light shielding part may include an organic light shielding material or an inorganic light shielding material containing a black pigment or dye. The light shielding part may prevent light leakage, and may separate boundaries between the adjacent filters CF1, CF2, and CF3.

The first to third filters CF1, CF2, and CF3 may be disposed corresponding to the red light emitting region PXA-R, the green light emitting region PXA-G, and the blue light emitting region PXA-B, respectively.

A base substrate BL may be disposed on the color filter layer CFL. The base substrate BL may be a member which provides a base surface in which the color filter layer CFL, the light control layer CCL, and the like are disposed. The base substrate BL may be a glass substrate, a metal substrate, a plastic substrate, etc. However, aspects of the present disclosure are not limited thereto, and the base substrate BL may be an inorganic layer, an organic layer, or a composite material layer. In addition, unlike the configuration illustrated, in an aspect, the base substrate BL may be omitted.

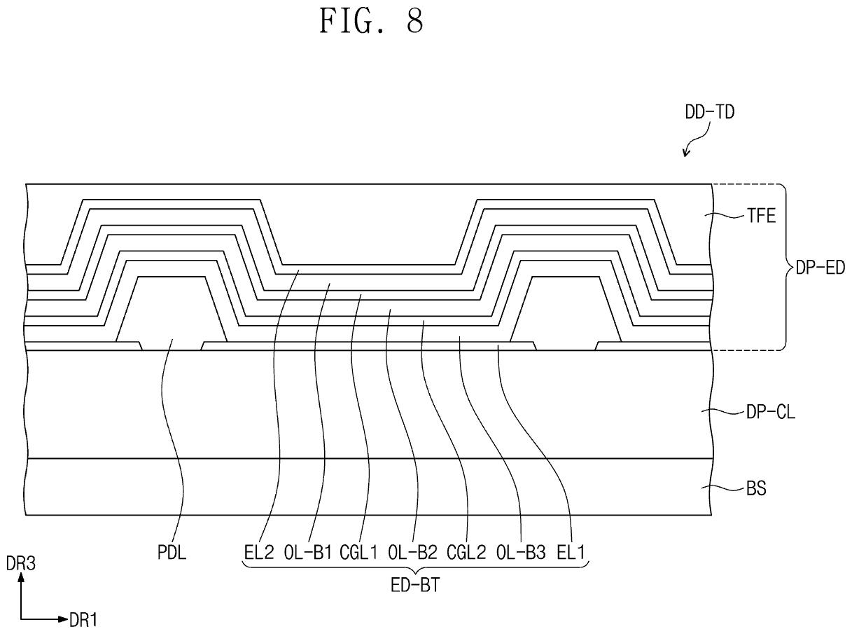

FIG. 8 is a cross-sectional view illustrating a portion of a display apparatus according to an aspect. In the display apparatus DD-TD of an aspect, the light emitting device ED-BT may include a plurality of light emitting structures OL-B1, OL-B2, and OL-B3. At least one among a plurality of emission structures OL-B1, OL-B2, and OL-B3 may include the nitrogen-containing compound according to an aspect. A light-emitting element ED-BT may exhibit excellent color reproductivity and long lifespan characteristics. A display device DD-TD according to an aspect includes the light-emitting element ED-BT containing the nitrogen-containing compound according to an aspect and thus may exhibit excellent display quality.

The light emitting device ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR disposed with the emission layer EML (FIG. 7) located therebetween.

That is, the light emitting device ED-BT included in the display apparatus DD-TD of an aspect may be a light emitting device having a tandem structure and including a plurality of emission layers.

In an aspect illustrated in FIG. 8, all light beams respectively emitted from the light emitting structures OL-B1, OL-B2, and OL-B3 may be blue light. However, aspects of the present disclosure are not limited thereto, and the light beams respectively emitted from the light emitting structures OL-B1, OL-B2, and OL-B3 may have wavelength ranges different from each other. For example, the light emitting device ED-BT including the plurality of light emitting structures OL-B1, OL-B2, and OL-B3 which emit light beams having wavelength ranges different from each other may emit white light.

Charge generation layers CGL1 and CGL2 may be respectively disposed between two of the neighboring light emitting structures OL-B1, OL-B2, and OL-B3. The charge generation layers CGL1 and CGL2 may include a p-type charge generation layer and/or an n-type charge generation layer.

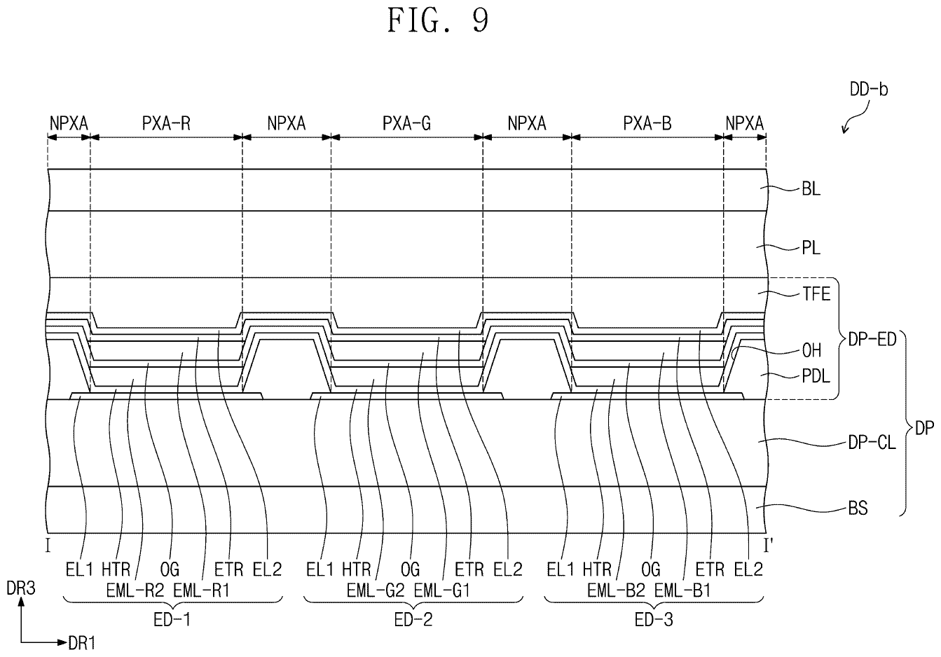

Referring to FIG. 9, the display apparatus DD-b according to an aspect may include light emitting devices ED-1, ED-2, and ED-3 in which two emission layers are stacked. At least one among the light-emitting elements ED-1, ED-2, and ED-3 may include the nitrogen-containing compound according to an aspect. Accordingly, the light-emitting elements ED-1, ED-2, and ED-3 may exhibit characteristics of excellent color reproductivity and long lifespan.

Compared with the display apparatus DD of an aspect illustrated in FIG. 2, an aspect illustrated in FIG. 9 has a difference in that the first to third light emitting devices ED-1, ED-2, and ED-3 each include two emission layers stacked in the thickness direction. In each of the first to third light emitting devices ED-1, ED-2, and ED-3, the two emission layers may emit light in the same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In addition, the third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light emitting devices ED-1, ED-2, and ED-3. However, aspects of the present disclosure are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be disposed between the hole transport region HTR and the emission auxiliary part OG. The second red emission layer EML-R2, the second green emission layer EML-G2, and the second blue emission layer EML-B2 may be disposed between the emission auxiliary part OG and the electron transport region ETR.

That is, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

Meanwhile, an optical auxiliary layer PL may be disposed on the display device layer DP-ED. The optical auxiliary layer PL may include a polarizing layer. The optical auxiliary layer PL may be disposed on the display panel DP and control reflected light in the display panel DP due to external light. Unlike the configuration illustrated, the optical auxiliary layer PL in the display apparatus according to an aspect may be omitted.

Unlike FIGS. 8 and 9, FIG. 10 illustrates that a display apparatus DD-c includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. At least one among the first to fourth emission structures OL-B1, OL-B2, OL-B3, and OL-C1 may include the nitrogen-containing compound according to an aspect. Therefore, the light-emitting element ED-CT may exhibit excellent color reproductivity and long lifespan characteristics.

Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may emit blue light, and the fourth light emitting structure OL-C1 may emit green light. However, aspects of the present disclosure are not limited thereto, and the first to fourth light emitting structures OL-B1, OL-B2, OL-B3, and OL-C1 may emit light beams in different wavelength regions. The charge generation layers CGL1, CGL2, and CGL3 disposed between adjacent light emitting structures OL-B1, OL-B2, OL-B3, and OL-C1 may include a p-type charge generation layer and/or an n-type charge generation layer.

In an aspect, an electronic apparatus may include a display device that includes multiple light-emitting elements, and a control part that controls the display device. The electronic apparatus according to an aspect may be activated in response to electrical signals. The electronic apparatus may include display devices according to various aspects. For example, the electronic apparatus may include small- and medium-sized display devices such as personal computers, laptop computers, personal digital assistants, display devices for vehicles, game consoles, portable electronic devices, or cameras, in addition to large-sized display devices such as televisions, monitors, or outdoor billboards.

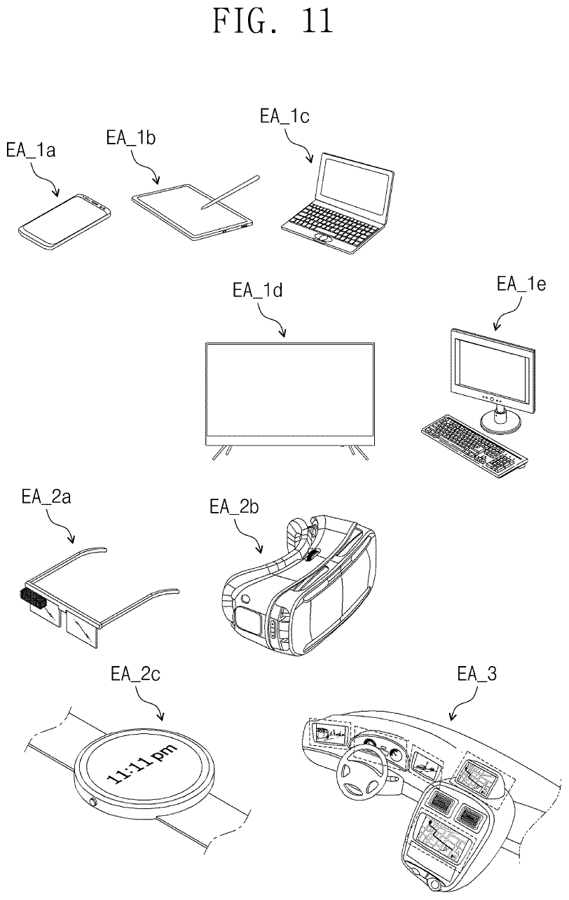

FIG. 11 is schematic views of electronic apparatuses according to various embodiments.

Referring to FIG. 11, the various electronic apparatuses in which a display device according to embodiments is applied may include, in addition to an electronic apparatus for displaying an image such as a smart phone EA_1a, a tablet EA_1b, a laptop computer EA_1c, TV EA_1d, and a desktop monitor EA_1e: a wearable electronic apparatus such as a smart glasses EA_2a, a head-mount display EA_2b, and a smart watch EA_2c; an electronic apparatus EA_3 for vehicles including a display module such as a center information display (CID) located on a vehicle's instrument cluster, center fascia, or dashboard, and a room mirror display; etc. The various electronic apparatuses EA_1a, EA_1b, EA_1c, EA_1d, EA_1e, EA_2a, EA_2b, EA_2c, and EA_3, illustrated in Table 11, may similarly include the configurations of the display devices DD, DD-TD, DD-a, DD-b, and DD-c according to embodiments, described with reference to FIGS. 1, 2, and 8 to 10. In addition, these apparatuses are merely suggested as embodiments, and other electronic apparatuses may also be employed as long as they do not depart from the concept of the inventive concept.

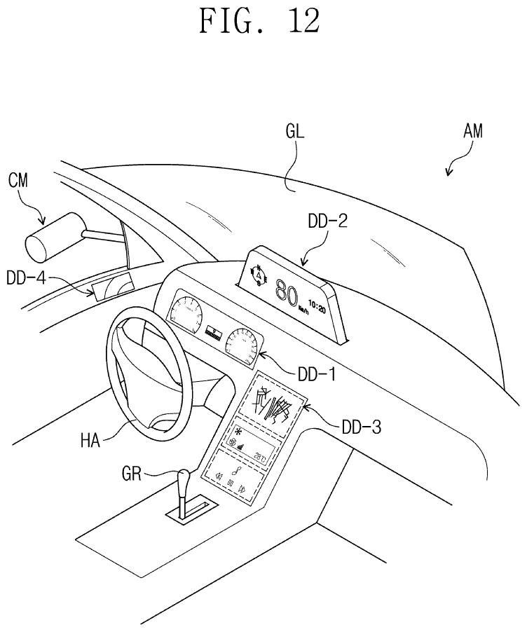

FIG. 12 is a view illustrating a vehicle AM in which the first to fourth display devices DD-1, DD-2, DD-3, and DD-4 are disposed. FIG. 12 illustrates, in detail, the display devices included in the electronic apparatus for vehicles in order to specifically explain. At least one among the first to fourth display devices DD-1, DD-2, DD-3, and DD-4 of the vehicle AM, illustrated in FIG. 12, may similarly include the configurations of the display devices DD, DD-TD, DD-a, DD-b, and DD-c according to aspects, described with reference to FIGS. 1, 2, and 8 to 10.

FIG. 12 illustrates a vehicle AM, but this is an example, and the first to fourth display apparatuses DD-1, DD-2, DD-3, and DD-4 may be disposed in another transportation means such as bicycles, motorcycles, trains, ships, or airplanes. In addition, at least one among the first to fourth display apparatuses DD-1, DD-2, DD-3, and DD-4 including the same configuration as the display apparatuses DD, DD-TD, DD-a, DD-b, and DD-c of an aspect may be employed in a personal computer, a laptop computer, a personal digital terminal, a game console, a portable electronic device, a television, a monitor, an outdoor billboard, or the like. In addition, these are merely provided as exemplary aspects, and thus may be employed in other electronic apparatuses unless departing from the scope of the present disclosure.

At least one among the first to fourth display apparatuses DD-1, DD-2, DD-3, and DD-4 may include the light emitting device ED of an aspect as described with reference to FIGS. 3 to 6.

Referring to FIG. 12, the vehicle AM may include a steering wheel HA and a gear GR for driving the vehicle AM. In addition, the vehicle AM may include a front window GL disposed so as to face the driver.

The first display apparatus DD-1 may be disposed in a first region overlapping the steering wheel HA. For example, the first display apparatus DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, etc. A first scale and a second scale may be indicated as a digital image.

The second display apparatus DD-2 may be disposed in a second region facing the driver's seat and overlapping the front window GL. The driver's seat may be a seat in which the steering wheel HA is disposed. For example, the second display apparatus DD-2 may be a head up display (HUD) which displays second information of the vehicle AM. The second display apparatus DD-2 may be optically transparent. The second information may include digital numbers which indicate a driving speed, and may further include information such as the current time. Unlike the configuration illustrated, the second information of the second display apparatus DD-2 may be projected to the front window GL to be displayed.

The third display apparatus DD-3 may be disposed in a third region adjacent to the gear GR. For example, the third display apparatus DD-3 may be disposed between the driver's seat and the passenger seat and may be a center information display (CID) for a vehicle for displaying third information. The passenger seat may be a seat spaced apart from the driver's seat with the gear GR disposed therebetween. The third information may include information about traffic (e.g., navigation information), playing music or radio or a video (or an image), temperatures inside the vehicle AM, etc.

The fourth display apparatus DD-4 may be spaced apart from the steering wheel HA and the gear GR, and may be disposed in a fourth region adjacent to the side of the vehicle AM. For example, the fourth display apparatus DD-4 may be a digital side-view mirror which displays fourth information. The fourth display apparatus DD-4 may display an image outside the vehicle AM taken by a camera module CM disposed outside the vehicle AM. The fourth information may include an image outside the vehicle AM.

The above-described first to fourth information may be examples, and the first to fourth display apparatuses DD-1, DD-2, DD-3, and DD-4 may further display information about the inside and outside of the vehicle AM. The first to fourth information may include different information. However, aspects of the present disclosure are not limited thereto, and a part of the first to fourth information may include the same information as one another.

Hereinafter, with reference to examples and comparative examples, a nitrogen-containing compound according to an aspect of the present disclosure and a light-emitting element according to an aspect will be specifically described. In addition, the following examples are suggested only for helping the understanding of the present disclosure, and the scope of the present disclosure is not limited thereto.

### EXAMPLES

### 1. Synthesis of Nitrogen-Containing Compound According to an Aspect

A synthetic method of a nitrogen-containing compound according to an aspect will be described in detail by exemplifying synthetic methods of Compounds 1, 25, 31, 61, 114, 165, 189 and 201. In addition, in the following descriptions, the synthetic method of the nitrogen-containing compound is provided as an example, but the synthetic method of the compound according to an aspect of the present disclosure is not limited to examples below.

### <Synthetic Method of Compounds>

### 1) Synthesis of Compound 1

### (Synthesis of Intermediate 1-1)

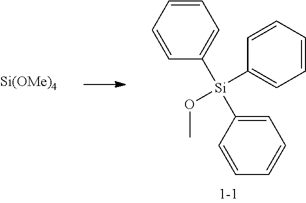 [SMILES: "Si(OMe)4" ; CO[Si](c1ccccc1)(c1ccccc1)c1ccccc1]

Under a nitrogen atmosphere, bromobenzene (3 eq) was dissolved in tetrahydrofuran, stirred at about 78° C. for about 30 minutes, and then n-butyllithium (3 eq) was added dropwise and stirred for about 1 hour. Thereafter, tetramethyl silicate (1 eq) was added dropwise and stirred for about 12 hours at a room temperature. Then, a dilute HCl aqueous solution (35%) of about 1 ml and DI water of about 100 ml were added and stirred for about 30 minutes. The resultant was washed with ethyl acetate and water three times, and then an organic layer obtained was dried over magnesium sulfate and then dried under reduced pressure. Subsequently, the resultant was purified by column chromatography to obtain Intermediate Compound 1-1 (yield of 45%).

### (Synthesis of Intermediate 1-2)

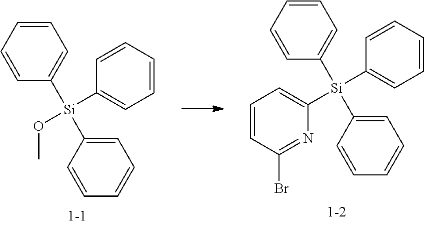 [SMILES: CO[Si](c1ccccc1)(c1ccccc1)c1ccccc1 ; Brc1cccc([Si](c2ccccc2)(c2ccccc2)c2ccccc2)n1]

Under a nitrogen atmosphere, 1,3-dibromobenzene (1 eq) was dissolved in tetrahydrofuran, stirred at about 78° C. for about 30 minutes, and then n-butyllithium (3 eq) was added dropwise and stirred for about 1 hour. Thereafter, tetramethyl silicate (1 eq) was added dropwise and stirred for about 12 hours at a room temperature. Then, a dilute HCl aqueous solution (35%) of about 1 ml and DI water of about 100 ml were added and stirred for about 30 minutes. The resultant was washed with ethyl acetate and water three times, then an obtained organic layer was dried over magnesium sulfate and then dried under reduced pressure. Subsequently, the resultant was purified by column chromatography to obtain Intermediate Compound 1-2 (yield of 45%).

### (Synthesis Compound 1)

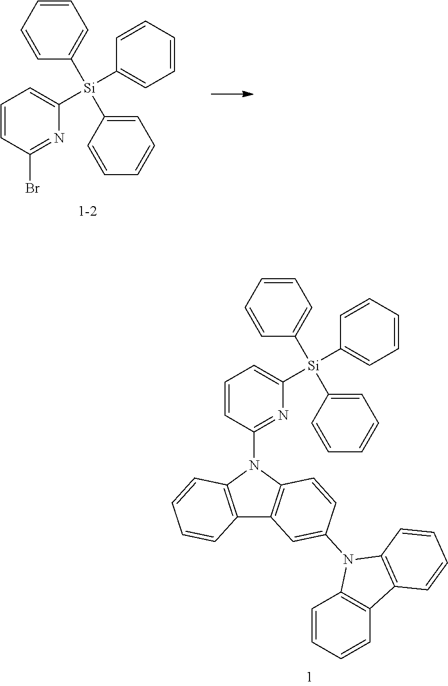 [SMILES: Brc1cccc([Si](c2ccccc2)(c2ccccc2)c2ccccc2)n1 ; c1ccc([Si](c2ccccc2)(c2ccccc2)c2cccc(-n3c4ccccc4c4cc(-n5c6ccccc6c6ccccc65)ccc43)n2)cc1]

Under a nitrogen atmosphere, Intermediate 1-2 (1 eq), 9H-3,9′-bicarbazole (1 eq), tris(dibenzylideneacetone)dipalladium(0) (0.05 eq), tri-tert-butylphosphine (0.1 eq), and sodium tert-butoxide (2 eq) were dissolved in toluene, stirred at about 80° C. for about 15 minutes. The obtained solution was washed with ethyl acetate and water three times, then an obtained organic layer was dried over magnesium sulfate and then dried under reduced pressure. Subsequently, the resultant was purified by column chromatography to obtain Compound 1 (yield of 72%).

### 2) Synthesis of Compound 25

### (Synthesis of Intermediate 25-1)

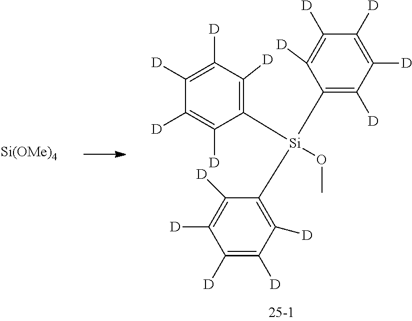 [SMILES: "Si(OMe)4" ; [2H]c1c([2H])c([2H])c([Si](OC)(c2c([2H])c([2H])c([2H])c([2H])c2[2H])c2c([2H])c([2H])c([2H])c([2H])c2[2H])c([2H])c1[2H]]

Intermediate 25-1 was obtained by carrying out a reaction under the same conditions as in the Synthesis of Intermediate 1-1 except that bromobenzene-d5 was used in place of bromobenzene, as a start material. (yield 39%)

### (Synthesis of Intermediate 25-2)

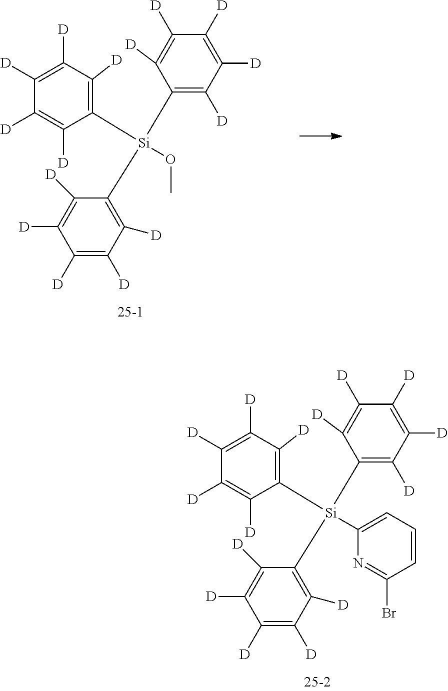 [SMILES: [2H]c1c([2H])c([2H])c([Si](OC)(c2c([2H])c([2H])c([2H])c([2H])c2[2H])c2c([2H])c([2H])c([2H])c([2H])c2[2H])c([2H])c1[2H] ; [2H]c1c([2H])c([2H])c([Si](c2cccc(Br)n2)(c2c([2H])c([2H])c([2H])c([2H])c2[2H])c2c([2H])c([2H])c([2H])c([2H])c2[2H])c([2H])c1[2H]]

Intermediate 25-2 was obtained by carrying out a reaction under the same conditions as in the Synthesis of Intermediate 1-2 except that Intermediate 25-1 was used in place of Intermediate 1-1, as a start material. (yield 41%)

### (Synthesis of Compound 25)

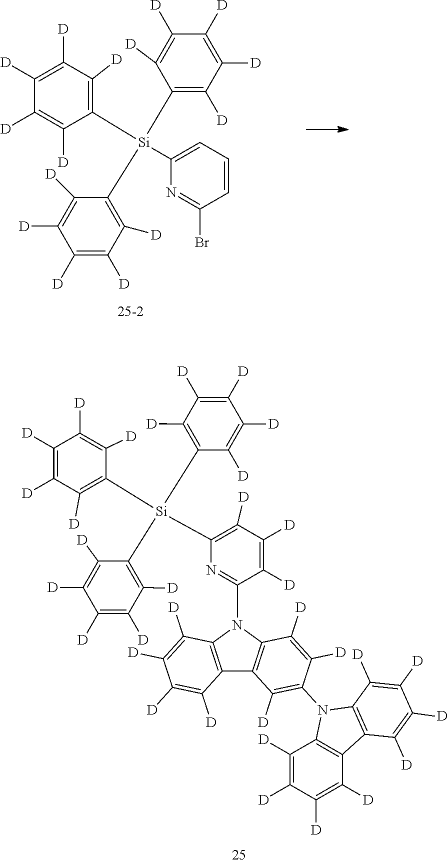 [SMILES: [2H]c1c([2H])c([2H])c([Si](c2cccc(Br)n2)(c2c([2H])c([2H])c([2H])c([2H])c2[2H])c2c([2H])c([2H])c([2H])c([2H])c2[2H])c([2H])c1[2H] ; [2H]c1c(-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)nc([Si](c2c([2H])c([2H])c([2H])c([2H])c2[2H])(c2c([2H])c([2H])c([2H])c([2H])c2[2H])c2c([2H])c([2H])c([2H])c([2H])c2[2H])c([2H])c1[2H]]

Compound 25 was obtained by carrying out a reaction under the same conditions as in the Synthesis of Compound 1 except that Intermediate 25-2 was used in place of Intermediate 1-2, and 9H-3,9′-bicarbazole-1,1′,2,2′,3′,4,4′,5,5′,6,6′,7,7′,8,8′-d15 was used in place of 9H-3,9′-bicarbazole as a start material. (yield of 67%)

### 3) Synthesis of Compound 31

### (Synthesis of Intermediate 31-1)

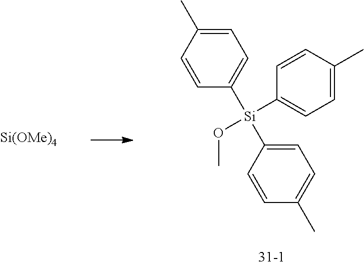 [SMILES: "Si(OMe)4" ; CO[Si](c1ccc(C)cc1)(c1ccc(C)cc1)c1ccc(C)cc1]

Intermediate 31-1 was obtained by carrying out a reaction under the same conditions as in the Synthesis of Intermediate 1-1 except that 1-bromo-4-methylbenzene was used in place of bromobenzene as a start material. (yield of 27%)

### (Synthesis of Intermediate 31-2)

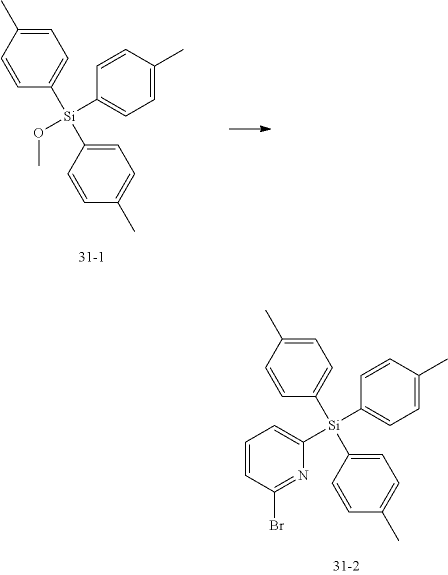 [SMILES: CO[Si](c1ccc(C)cc1)(c1ccc(C)cc1)c1ccc(C)cc1 ; Cc1ccc([Si](c2ccc(C)cc2)(c2ccc(C)cc2)c2cccc(Br)n2)cc1]

Intermediate 31-2 was obtained by carrying out a reaction under the same conditions as in the Synthesis of Intermediate 1-2 except that Intermediate 31-1 was used in place of Intermediate 1-1 as a start material. (yield of 30%)

### (Synthesis of Compound 31)

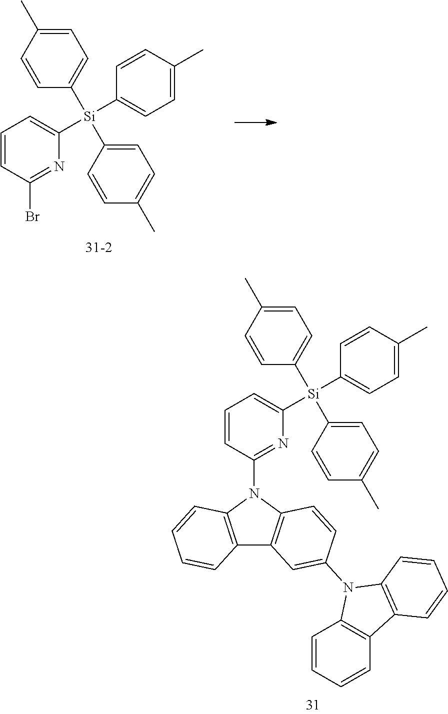 [SMILES: Cc1ccc([Si](c2ccc(C)cc2)(c2ccc(C)cc2)c2cccc(Br)n2)cc1 ; Cc1ccc([Si](c2ccc(C)cc2)(c2ccc(C)cc2)c2cccc(-n3c4ccccc4c4cc(-n5c6ccccc6c6ccccc65)ccc43)n2)cc1]

Compound 31 was obtained by carrying out a reaction under the same conditions as in the Synthesis of Compound 1 except that Intermediate 31-2 was used in place of Intermediate 1-2 as a start material. (yield of 38%)

### 4) Synthesis of Compound 61

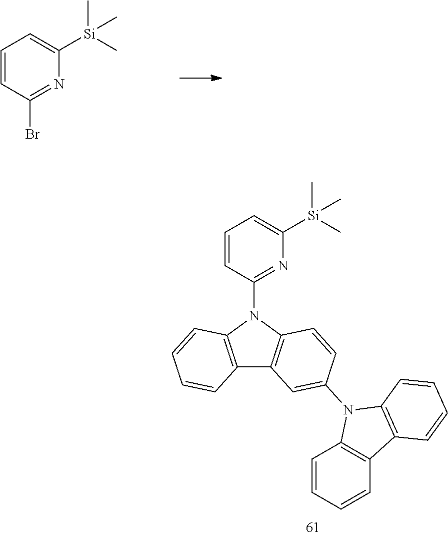 [SMILES: C[Si](C)(C)c1cccc(Br)n1 ; C[Si](C)(C)c1cccc(-n2c3ccccc3c3cc(-n4c5ccccc5c5ccccc54)ccc32)n1]

Compound 61 was obtained by carrying out a reaction under the same conditions as in the Synthesis of Compound 1 except that 2-bromo-6-(trimethylsilyl)pyridine was used in place of Intermediate 1-2 as a start material. (yield of 25%)

### 5) Synthesis of Compound 114

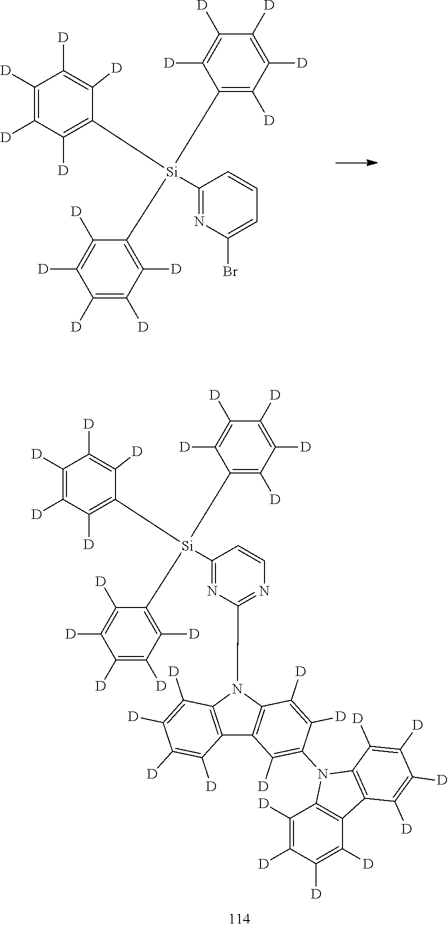 [SMILES: [2H]c1c([2H])c([2H])c([Si](c2cccc(Br)n2)(c2c([2H])c([2H])c([2H])c([2H])c2[2H])c2c([2H])c([2H])c([2H])c([2H])c2[2H])c([2H])c1[2H] ; [2H]c1c([2H])c([2H])c([Si](c2ccnc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)n2)(c2c([2H])c([2H])c([2H])c([2H])c2[2H])c2c([2H])c([2H])c([2H])c([2H])c2[2H])c([2H])c1[2H]]

Compound 114 was obtained by carrying out a reaction under the same conditions as in the Synthesis of Compound 1 except that 2-bromo-4-(tris(phenyl-d5)silyl)pyrimidine was used in place of Intermediate 1-2 as a start material. (yield of 25%)

### 6) Synthesis of Compound 165

### (Synthesis of Intermediate 165-1)

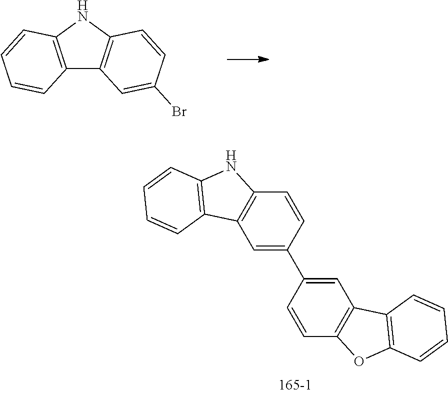 [SMILES: Brc1ccc2[nH]c3ccccc3c2c1 ; c1ccc2c(c1)[nH]c1ccc(-c3ccc4oc5ccccc5c4c3)cc12]

Under a nitrogen atmosphere, 3-bromo-9H-carbazole (1 eq), dibenzo[b,d]furan-2-ylboronic acid (1 eq), Pd(PPh3)4 (0.05 eq), and K3CO3 (3 eq) were dissolved in a solvent of tetrahydrofuran:H₂O=2:1, and then stirred at about 80° C. and for about 12 hours. The obtained solution was cooled to a room temperature, washed with ethyl acetate and water three times, then an obtained organic layer was dried over magnesium sulfate and then dried under reduced pressure. Subsequently, the resultant was purified by column chromatography to obtain Intermediate 165-1 (yield of 78%).

### (Synthesis of Compound 165)

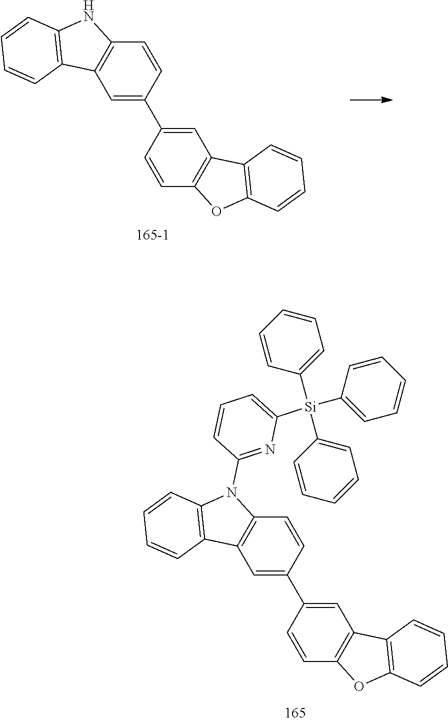 [SMILES: c1ccc2c(c1)[nH]c1ccc(-c3ccc4oc5ccccc5c4c3)cc12 ; c1ccc([Si](c2ccccc2)(c2ccccc2)c2cccc(-n3c4ccccc4c4cc(-c5ccc6oc7ccccc7c6c5)ccc43)n2)cc1]

Compound 165 was obtained by carrying out a reaction under the same conditions as in the Synthesis of Compound 1 except that Intermediate 165-1 was used in place of Intermediate 1-2 as a start material. (yield of 57%)

### 7) Synthesis of Compound 189

### (Synthesis of Intermediate 189-1)

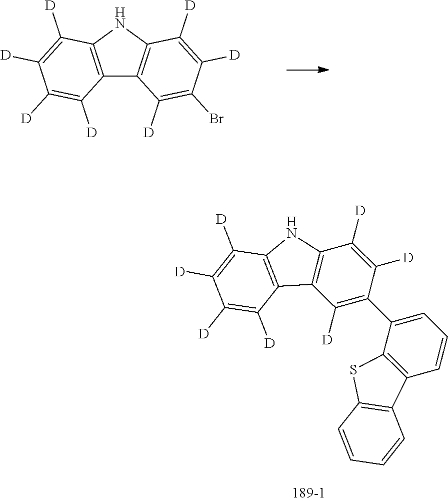 [SMILES: [2H]c1c([2H])c([2H])c2c([nH]c3c([2H])c([2H])c(Br)c([2H])c32)c1[2H] ; [2H]c1c([2H])c([2H])c2c([nH]c3c([2H])c([2H])c(-c4cccc5c4sc4ccccc45)c([2H])c32)c1[2H]]

Intermediate 189-1 was obtained by carrying out a reaction under the same conditions as in the Synthesis of Intermediate 165-1 except that 3-bromo-9H-carbazole-1,2,4,5,6,7,8-d7 was used in place of 3-bromo-9H-carbazole, and dibenzo[b,d]thiophen-4-ylboronic acid was used in place of dibenzo[b,d]furan-2-ylboronic acid as a start material. (yield of 51%)

### (Synthesis of Compound 189)

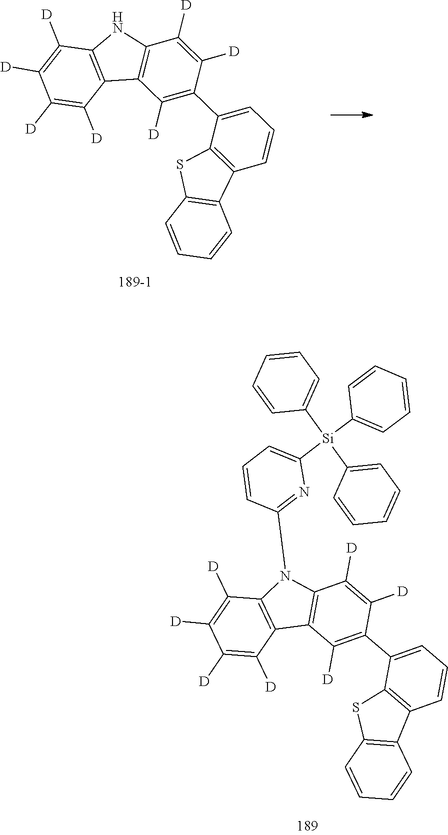 [SMILES: [2H]c1c([2H])c([2H])c2c([nH]c3c([2H])c([2H])c(-c4cccc5c4sc4ccccc45)c([2H])c32)c1[2H] ; [2H]c1c([2H])c([2H])c2c(c1[2H])c1c([2H])c(-c3cccc4c3sc3ccccc34)c([2H])c([2H])c1n2-c1cccc([Si](c2ccccc2)(c2ccccc2)c2ccccc2)n1]

Compound 189 was obtained by carrying out a reaction under the same conditions as in the Synthesis of Compound 1 except that Intermediate 189-1 was used in place of Intermediate 1-2 as a start material. (yield of 50%)

### 8) Synthesis of Compound 201

### (Synthesis of Intermediate 201-1)

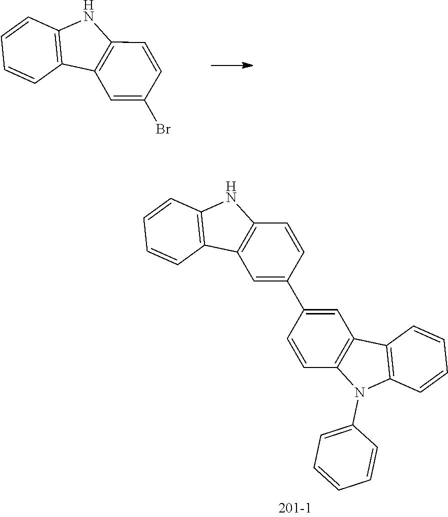 [SMILES: Brc1ccc2[nH]c3ccccc3c2c1 ; c1ccc(-n2c3ccccc3c3cc(-c4ccc5[nH]c6ccccc6c5c4)ccc32)cc1]

Intermediate 201-1 was obtained by carrying out a reaction under the same conditions as in the Synthesis of Intermediate 165-1 except that (9-phenyl-9H-carbazol-3-yl)boronic acid was used in place of dibenzo[b,d]furan-2-ylboronic acid as a start material. (yield of 68%)

### (Synthesis of Compound 201)

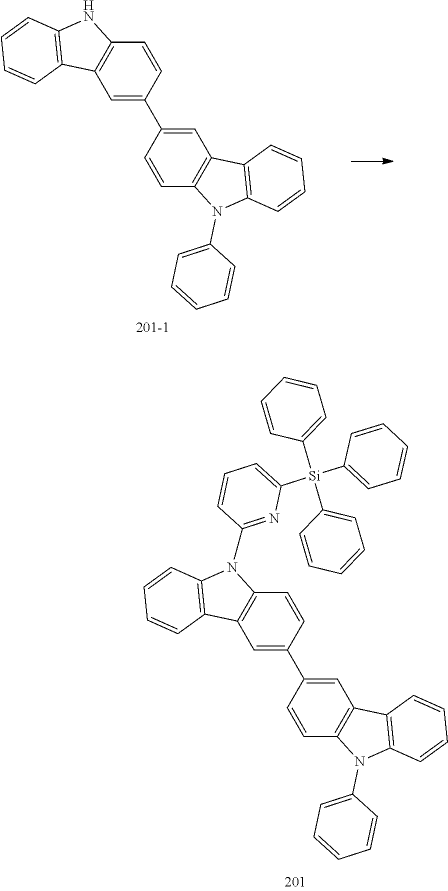 [SMILES: c1ccc(-n2c3ccccc3c3cc(-c4ccc5[nH]c6ccccc6c5c4)ccc32)cc1 ; c1ccc(-n2c3ccccc3c3cc(-c4ccc5c(c4)c4ccccc4n5-c4cccc([Si](c5ccccc5)(c5ccccc5)c5ccccc5)n4)ccc32)cc1]

Compound 201 was obtained by carrying out a reaction under the same conditions as in the Synthesis of Compound 1 except that Intermediate 201-1 was used in place of Intermediate 1-2 as a start material. (yield of 57%)

Values identified by NMR and MS/FAB analysis on each of Compounds 1, 25, 31, 61, 114, 165, 189, and 201, synthesized by the synthetic examples above, are as in Table 1 below.

TABLE 1

| | | MS/FAB | |
|---|---|---|---|
| Compounds | H NMR (δ) | Calc | Found |
| 1 | δ = 8.56(d, 2H), 8.19-8.11(m, 2H), | 667.24 | 667.33 |
| | 7.94-7.90(m, 3H), 7.65-7.52(m, 4H), | | |
| | 7.43-7.35(m, 19H), 7.20-7.16(m, 3H) | | |
| 25 | δ = no proton (all deuteriated) | 700.45 | 700.49 |
| 31 | δ = 8.55(d, 2H), 8.19-8.15(dd, 2H), | 752.28 | 752.27 |
| | 7.94-7.90(m, 3H), 7.72-7.58(m, 4H), | | |
| | 7.50-7.16(m, 19H), 2.37(s, 9H) | | |
| 61 | δ = 8.55(d, 2H), 8.20(d, 1H), 8.00- | 481.20 | 481.25 |
| | 7.94(m, 3H), 7.78-7.62(m, 3H), 7.56- | | |
| | 7.50 (m, 3H), 7.38-7.35(m, 3H), 7.20- | | |
| | 7.16(m, 3H), −0.33(s, 9H) | | |
| 114 | δ = 9.09(d, 1H), 7.60(d, 1H) | 698.43 | 698.49 |
| 165 | δ = 8.55(d, 1H), 8.12(d, 1H), | 668.23 | 668.18 |
| | 7.94-7.77(m, 9H), 7.62(d, 1H), 7.46- | | |
| | 7.31 (m, 19H), 7.16(m, 1H) | | |
| 189 | δ = 8.55(d, 1H), 8.45(d, 1H), | 691.25 | 691.33 |
| | 8.32(d, 1H), 8.12(d, 1H), 7.93-7.90 | | |
| | (m, 2H), 7.70(dd, 1H), 7.62-7.46(m, | | |
| | 18H) | | |
| 201 | δ = 8.55(d, 2H), 8.13(d, 1H), | 743.28 | 743.37 |
| | 7.99-7.89(m, 7H), 7.78-7.77(m, 2H), | | |
| | 7.62-7.36(m, 23H), 7.18-7.16(m, 2H) | | |

### 2. Manufacture and Evaluation of Light-Emitting Element

### (1) Manufacture of Light-Emitting Element

The light-emitting elements respectively including the nitrogen-containing compounds according to examples, or the comparative example compounds were manufactured by the following method.

### (Manufacture of the Light-Emitting Elements According to Example 1 to Example 8, and Comparative Example 1 to Example 7)

The light-emitting elements according to Example 1 to Example 8 were manufactured respectively including the nitrogen-containing compounds according to the examples as a host material in the emission layer. The light-emitting elements according to Comparative Example 1 and Comparative Example 7 were manufactured respectively using Comparative Example Compounds C-1 to C-7 as one among host materials in the emission layer.

A glass substrate (a product of Corning Inc.), on which an ITO electrode of about 15 Ω/cm² (1200 Å) was formed as a first electrode, was cut to a size of about 50 mm×50 mm×0.5 mm, cleansed by ultrasonic waves using isopropyl alcohol and pure water for about five minutes each, then irradiated with ultraviolet rays for about 30 minutes and exposed to ozone to be cleansed. Then, the glass substrate was mounted on a vacuum deposition apparatus.

HATCN was deposited on the first electrode to form a hole injection layer having a thickness of about 100 Å, and then H-1-1 was deposited at a thickness of about 600 Å on the hole injection layer to form a first hole transport layer, and then HT33 was deposited at a thickness of about 50 Å to form a second hole transport layer.

ETH68, Example Compound, and AD-41 were co-deposited on the hole transport layer at a weight ratio of about 60:27:13 to form an emission layer having a thickness of about 350 Å. The example compound or the comparative example compound was used as a hole transporting host, ETH68 was used as an electron transporting host, and AD-41 was used as a phosphorescent dopant.

ETH2 was deposited on the emission layer having a thickness of about 50 Å, and then ETH2 and LiQ were simultaneously deposited at a weight ratio of about 1:1 to form an electron transport layer with a thickness of about 350 Å. LiF was deposited to form an electron injection layer having a thickness of about 15 Å on the electron transport layer, and Al was deposited on the electron injection layer to form a second electrode having a thickness of about 80 Å, thereby manufacturing a light-emitting element.

### (Manufacture of the Light-Emitting Elements According to Example 9 and Example 10)

The light-emitting elements according to Example 9 and Example 10 were manufactured respectively including the nitrogen-containing compounds according to the examples as a host material in the emission layer and a material for the second hole transport layer in the hole transport region.

A glass substrate (a product of Corning Inc.), on which an ITO electrode of about 15 Ω/cm² (1200 Å) was formed as a first electrode, was cut to a size of about 50 mm×50 mm×0.5 mm, cleansed by ultrasonic waves using isopropyl alcohol and pure water for about five minutes each, then irradiated with ultraviolet rays for about 30 minutes and exposed to ozone to be cleansed. Then, the glass substrate was mounted on a vacuum deposition apparatus.

HATCN was deposited on the first electrode to form a hole injection layer having a thickness of about 100 Å, and then H-1-1 was deposited at a thickness of about 600 Å on the hole injection layer, and then the example compound or the comparative example compound was deposited at a thickness of about 50 Å to form a second hole transport layer.

ETH68, Example Compound, and AD-41 were co-deposited on the hole transport layer at a weight ratio of about 60:27:13 to form an emission layer having a thickness of about 350 Å. The example compound or the comparative example compound was used as a hole transporting host, ETH68 was used as an electron transporting host, and AD-41 was used as a phosphorescent dopant.

ETH2 was deposited on the emission layer having a thickness of about 50 Å, and then ETH2 and LiQ were simultaneously deposited at a weight ratio of about 1:1 to form an electron transport layer with a thickness of about 350 Å. LiF was deposited to form an electron injection layer having a thickness of about 15 Å on the electron transport layer, and Al was deposited on the electron injection layer to form a second electrode having a thickness of about 80 Å, thereby manufacturing a light-emitting element.

The compounds used in the manufacture of the light-emitting elements are as follows. The example compounds and comparative example compounds used in the manufacture of the light-emitting elements are listed in Table 2. (Common materials used in manufacture of light-emitting elements)

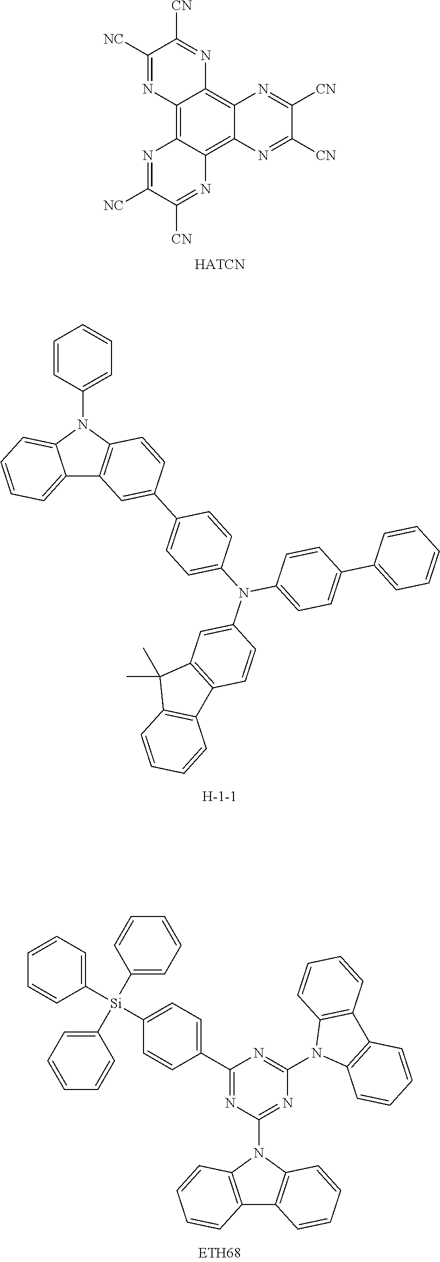

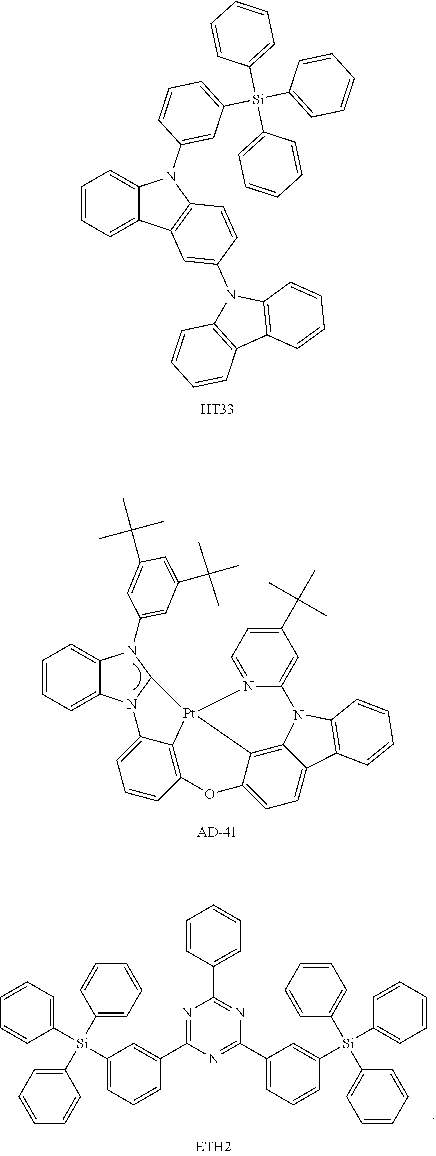

### [Example Compounds]

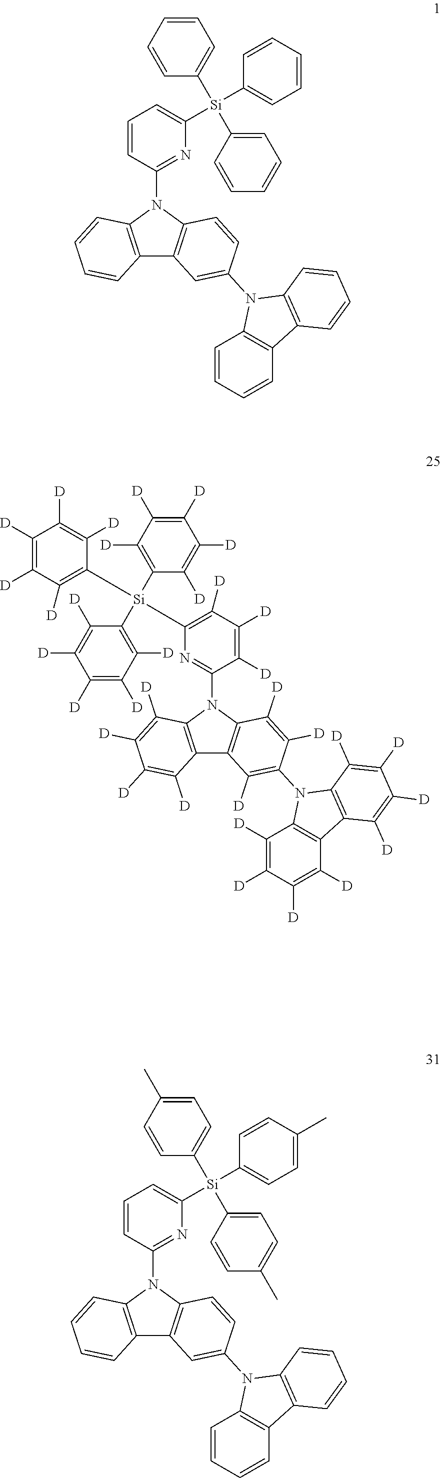 [SMILES: c1ccc([Si](c2ccccc2)(c2ccccc2)c2cccc(-n3c4ccccc4c4cc(-n5c6ccccc6c6ccccc65)ccc43)n2)cc1 ; [2H]c1c(-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)nc([Si](c2c([2H])c([2H])c([2H])c([2H])c2[2H])(c2c([2H])c([2H])c([2H])c([2H])c2[2H])c2c([2H])c([2H])c([2H])c([2H])c2[2H])c([2H])c1[2H] ; Cc1ccc([Si](c2ccc(C)cc2)(c2ccc(C)cc2)c2cccc(-n3c4ccccc4c4cc(-n5c6ccccc6c6ccccc65)ccc43)n2)cc1]

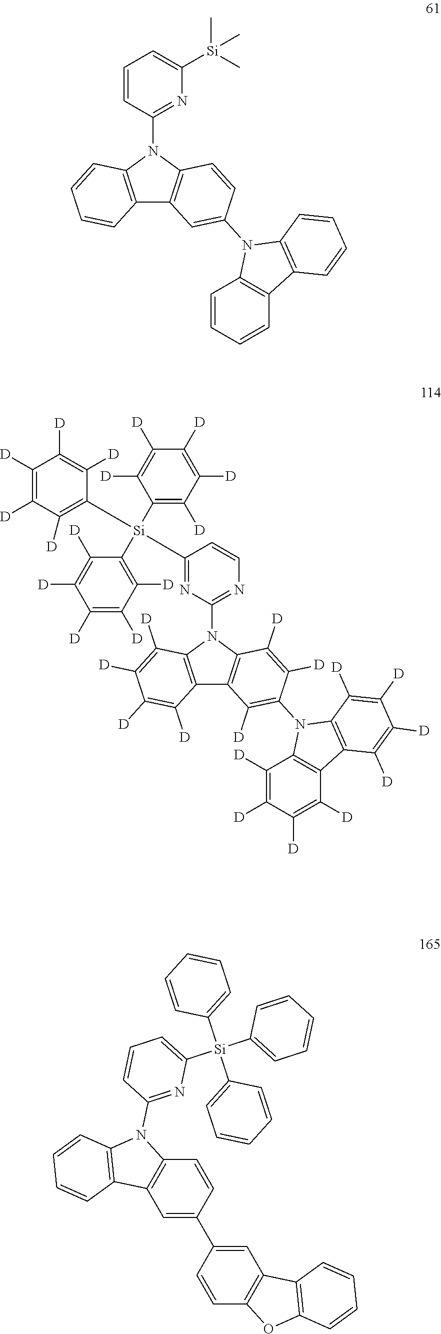 [SMILES: C[Si](C)(C)c1cccc(-n2c3ccccc3c3cc(-n4c5ccccc5c5ccccc54)ccc32)n1 ; [2H]c1c([2H])c([2H])c([Si](c2ccnc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)n2)(c2c([2H])c([2H])c([2H])c([2H])c2[2H])c2c([2H])c([2H])c([2H])c([2H])c2[2H])c([2H])c1[2H] ; c1ccc([Si](c2ccccc2)(c2ccccc2)c2cccc(-n3c4ccccc4c4cc(-c5ccc6oc7ccccc7c6c5)ccc43)n2)cc1]

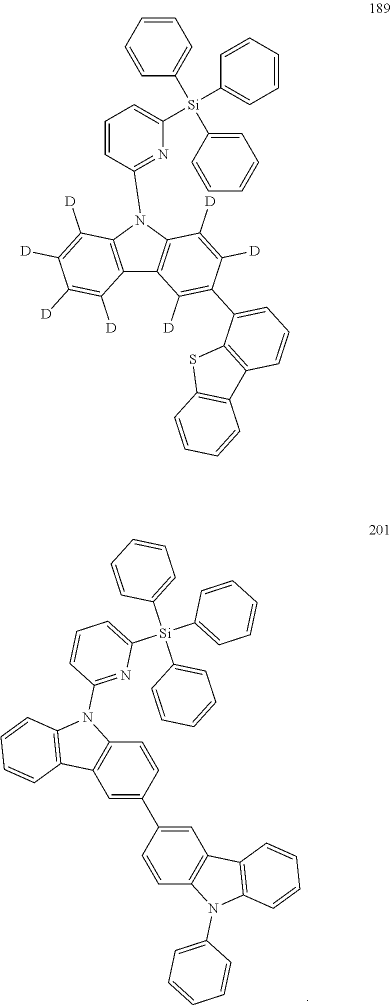 [SMILES: [2H]c1c([2H])c([2H])c2c(c1[2H])c1c([2H])c(-c3cccc4c3sc3ccccc34)c([2H])c([2H])c1n2-c1cccc([Si](c2ccccc2)(c2ccccc2)c2ccccc2)n1 ; c1ccc(-n2c3ccccc3c3cc(-c4ccc5c(c4)c4ccccc4n5-c4cccc([Si](c5ccccc5)(c5ccccc5)c5ccccc5)n4)ccc32)cc1]

### [Comparative Example Compounds]

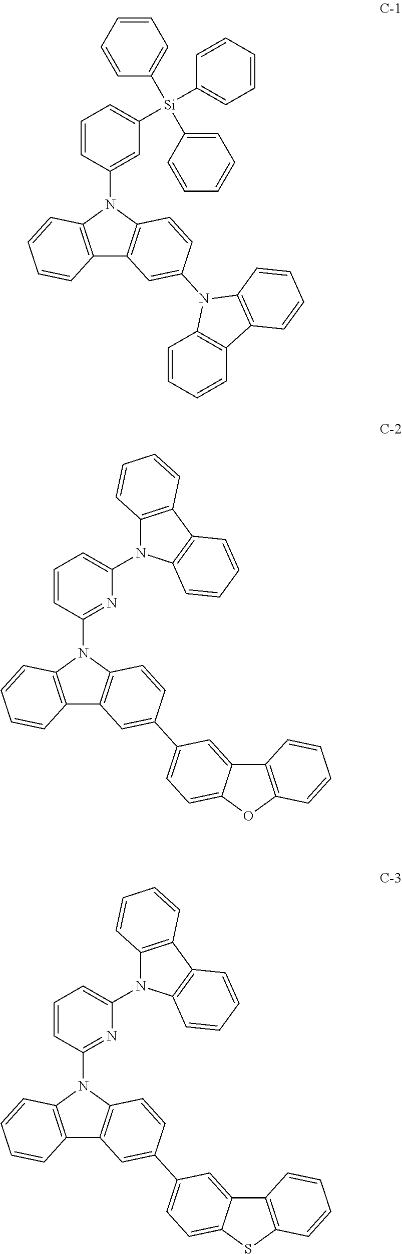 [SMILES: c1ccc([Si](c2ccccc2)(c2ccccc2)c2cccc(-n3c4ccccc4c4cc(-n5c6ccccc6c6ccccc65)ccc43)c2)cc1 ; c1cc(-n2c3ccccc3c3ccccc32)nc(-n2c3ccccc3c3cc(-c4ccc5oc6ccccc6c5c4)ccc32)c1 ; c1cc(-n2c3ccccc3c3ccccc32)nc(-n2c3ccccc3c3cc(-c4ccc5sc6ccccc6c5c4)ccc32)c1]

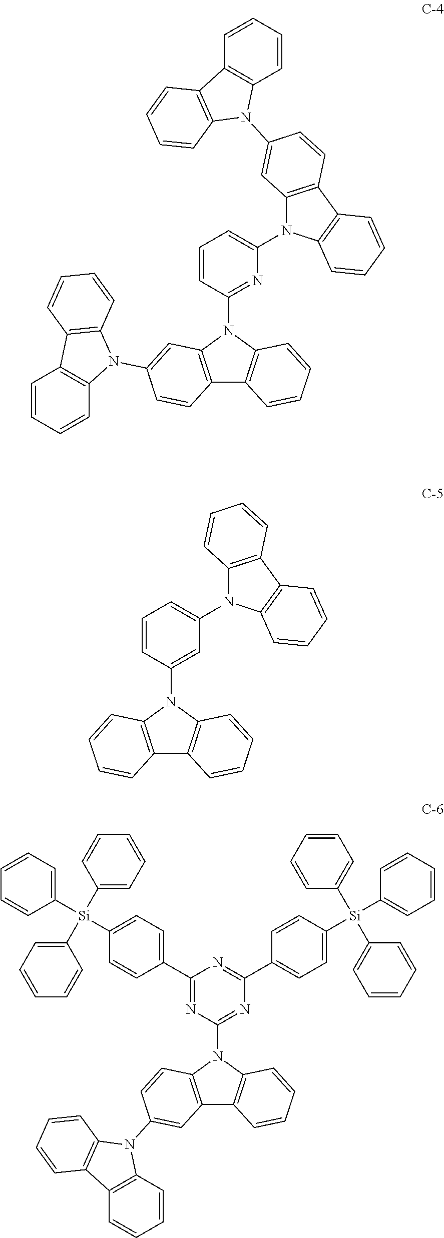 [SMILES: c1cc(-n2c3ccccc3c3ccc(-n4c5ccccc5c5ccccc54)cc32)nc(-n2c3ccccc3c3ccc(-n4c5ccccc5c5ccccc54)cc32)c1 ; c1cc(-n2c3ccccc3c3ccccc32)cc(-n2c3ccccc3c3ccccc32)c1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

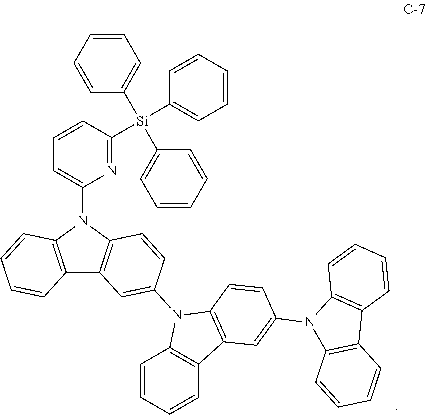 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)n2)cc1]

### (2) Evaluation of Light-Emitting Element Characteristics

For the light-emitting elements manufactured using the above-described Compounds 1, 25, 31, 61, 114, 165, 189, and 201, and Comparative Example Compounds C-1 to C-7, element efficiency and element lifespan were evaluated. In The evaluation results for the light-emitting elements according to Example 1 to Example 10, and Comparative Example 1 to Comparative Example are listed in Table 2. In the light-emitting elements according to the examples and the comparative examples, for evaluating characteristics of the light-emitting elements, a driving voltage, front luminous efficiency (Cd/A/y), and emission color (V) at a current density of 10 mA/cm² were each measured using Keithley MU 236 and luminance meter PR650. The time taken for luminance to deteriorate from an initial value to 97% was measured, for the evaluation of the lifespan (T97), and a relative lifespan was calculated based on the measured time value of the light-emitting element according to Comparative Example 1, and the result was listed as the lifespan (T97) in Table 2.

TABLE 2

| | | Second hole | Driving | | | |
|---|---|---|---|---|---|---|
| | Host material in | transport layer | Voltage | Efficiency | Lifespan | Emission |
| Classification | emission layer | material | (V) | (Cd/A/y) | (T97) | color |
| Example 1 | Compound 1 | HT33 | 4.7 | 21.1 | 24.4 | Blue |
| Example 2 | Compound 25 | HT33 | 4.8 | 20.8 | 24.0 | Blue |
| Example 3 | Compound 31 | HT33 | 4.5 | 21.5 | 19.7 | Blue |
| Example 4 | Compound 61 | HT33 | 4.5 | 20.9 | 18.9 | Blue |
| Example 5 | Compound 114 | HT33 | 5.0 | 19.7 | 20.4 | Blue |
| Example 6 | Compound 165 | HT33 | 4.9 | 20.4 | 20.8 | Blue |
| Example 7 | Compound 189 | HT33 | 5.1 | 19.9 | 21.7 | Blue |
| Example 8 | Compound 201 | HT33 | 4.8 | 21.0 | 21.5 | Blue |
| Example 9 | Compound 114 | Compound 25 | 4.7 | 21.4 | 23.8 | Blue |
| Example 10 | Compound 189 | Compound 25 | 4.9 | 20.1 | 21.9 | Blue |
| Comparative | Compound C-1 | HT33 | 5.2 | 18.2 | 17.2 | Blue |
| Example 1 | | | | | | |
| Comparative | Compound C-2 | HT33 | 5.0 | 17.9 | 16.4 | Blue |
| Example 2 | | | | | | |
| Comparative | Compound C-3 | HT33 | 5.0 | 17.6 | 16.7 | Blue |
| Example 3 | | | | | | |
| Comparative | Compound C-4 | HT33 | 5.1 | 16.7 | 15.8 | Blue |
| Example 4 | | | | | | |
| Comparative | Compound C-5 | HT33 | 5.0 | 16.8 | 15.8 | Blue |
| Example 5 | | | | | | |
| Comparative | Compound C-6 | HT33 | 5.5 | 15.5 | 14.9 | Blue |
| Example 6 | | | | | | |
| Comparative | Compound C-7 | HT33 | 5.4 | 16.1 | 14.8 | Blue |
| Example 7 | | | | | | |

Referring to the results in Table 2, it can be confirmed that the light-emitting elements according to the examples, which use the nitrogen-containing compounds according to aspects of the present disclosure as materials for the light-emitting elements, compared to the light-emitting elements according to the comparative examples, have relatively high luminous efficiency, low driving voltage, and long lifespan characteristics.

Referring Example 1 to Example 8, and Comparative Example 1 to Example 7, it can be confirmed that the light-emitting elements according to the examples, which use the nitrogen-containing compounds according to aspects of the present disclosure as hole transporting host materials in the emission layer, compared to the light-emitting elements according to the comparative examples, have relatively high luminous efficiency, low driving voltage, and long lifespan characteristics. Referring Example 9 to Example 10, and Comparative Example 1 to Example 7, it can be confirmed that the light-emitting elements according to the examples, which use the nitrogen-containing compounds according to aspects of the present disclosure as hole transporting host materials in the emission layer and materials for the second host transport layer of the hole transport region, compared to the light-emitting elements according to the comparative examples, have relatively high luminous efficiency, low driving voltage, and long lifespan characteristics.

The example compounds have a structure including a heterocyclic core in which one or more carbon atoms of a benzene ring are substituted with N, and includes a first substituent including a moiety such as bicarbazole and a second substituent of a silyl group, which are directly connected to arbitrary carbon atom in the heterocyclic core. Therefore, the example compounds, compared to the comparative example compounds, may have high T1 energy level characteristics and bipolar characteristics, thereby capable of having excellent material stability. Since the example compounds have relatively excellent material stability, the light-emitting elements including the example compounds as host materials in the emission layer or materials for the hole transport region, compared to the light-emitting elements including the comparative example compounds, may achieve improvements in high luminous efficiency and long lifespan in a short wavelength region, particularly, blue light wavelength region.

The nitrogen-containing compound according to an aspect may have excellent material stability, and the light-emitting element according to an aspect includes the nitrogen-containing compound according to an aspect and thus may exhibit long lifespan and excellent color reproductivity. In addition, the display device according to an aspect may exhibit improved display quality by including the light-emitting element having excellent color reproductivity and excellent efficiency and lifespan characteristics.

The light-emitting element according to an aspect may exhibit characteristics of excellent color reproductivity and long lifespan by containing the nitrogen-containing compound according to an aspect.

The nitrogen-containing compound according to an aspect may contribute to improvements in color purities and long lifespan of the light-emitting element.

The electronic apparatus according to an aspect may exhibit excellent display quality.

Hitherto, although the aspects of the present disclosure have been described, it is understood that the present disclosure should not be limited to these aspects, but various changes and modifications can be made by one ordinary skilled in the art within the spirit and scope of the present disclosure as hereinafter claimed.

Therefore, the technical scope of the present disclosure is not intended to be limited to the contents set forth in the detailed description of the specification but is intended to be defined by the appended claims.

What is claimed is:

1. A light-emitting element comprising:
a first electrode;
a second electrode facing the first electrode; and
at least one functional layer between the first electrode and the second electrode, the at least one functional layer comprising a nitrogen-containing compound represented by any one of Formula 1-1 to Formula 1-4: 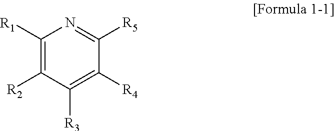
wherein, in Formula 1-1,
R₁ to R₅ are each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
any one of R₁ to R₅ is a substituent represented by Formula 2, and
at least one of R₁ to R₅ is a substituent represented by Formula 3; 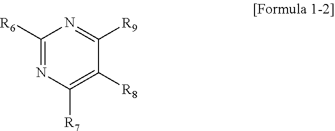
where, in Formula 1-2,
R₆ to R₉ are each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
any one of R₆ to R₉ is a substituent represented by Formula 2, and
at least one of R₆ to R₉ is a substituent represented by Formula 3; 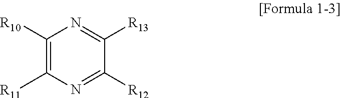
where, in Formula 1-3,
R₁₀ to R₁₃ are each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, a substituted or unsubstituted heteroaryl group having 2 to 30 ring-forming carbons, a substituent represented by Formula 2, or a substituent represented by Formula 3,
any one of R₁₀ to R₁₃ is a substituent represented by Formula 2, and
at least one of R₁₀ to R₁₃ is a substituent represented by Formula 3; 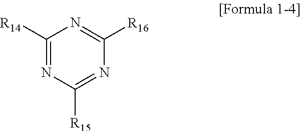
where, in Formula 1-4,
R₁₄ to R₁₆ are each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
any one of R₁₄ to R₁₆ is a substituent represented by Formula 2, and
at least one of R₁₄ to R₁₆ is a substituent represented by Formula 3; 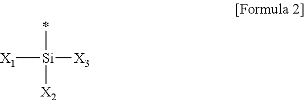
where, in Formula 2,
X₁ to X₃ are each independently a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and
*— is a portion to which any one of Formula 1-1 to Formula 1-4 above is connected; 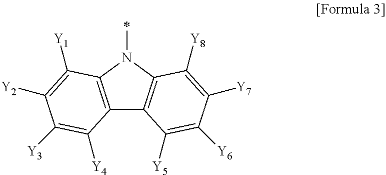
where, in Formula 3,
any one of Y₁ to Y₈ is a substituent represented by Formula 4,
a remainder of Y₁ to Y₈ are each independently a hydrogen atom, a deuterium atom, a halogen atom, a cyano group, a substituted or unsubstituted alkyl group having 1 to 20 carbons, or a substituted or unsubstituted aryl group having 6 to 30 ring-forming carbons, and
*— is a portion to which any one among Formula 1-1 to Formula 1-4 above is connected; 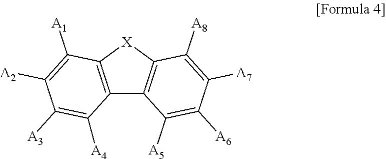
where, in Formula 4,
X is O, S, or NA₉,
any one of A₁ to A₉ is a portion to which Formula 3 above is connected, and
a remainder of A₁ to A₉ are each independently a hydrogen atom, a deuterium atom, a halogen atom, a cyano group, a substituted or unsubstituted alkyl group having 1 to 20 carbons, or a substituted or unsubstituted aryl group having 6 to 30 ring-forming carbons.

2. The light-emitting element of claim 1, wherein the at least one functional layer comprises:
a hole transport region disposed on the first electrode;
an emission layer disposed on the hole transport region; and
an electron transport region disposed on the emission layer,
wherein the hole transport region or the emission layer comprises the nitrogen-containing compound represented by any one of Formula 1-1 or Formula 1-4.

3. The light-emitting element of claim 2, wherein:
the hole transport region comprises a hole injection layer disposed on the first electrode, and a hole transport layer disposed on the hole injection layer; and
the hole transport layer comprises the nitrogen-containing compound represented by any one of Formula 1-1 to Formula 1-4.

4. The light-emitting element of claim 3, wherein:
the hole transport layer comprises a first hole transport layer disposed on the hole injection layer and a second hole transport layer disposed on the first hole transport layer; and
the second hole transport layer comprises the nitrogen-containing compound represented by any one of Formula 1-1 to Formula 1-4.

5. The light-emitting element of claim 4, wherein the first hole transport layer comprises a compound represented by Formula H-1: 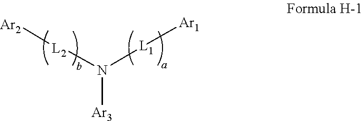
where, in Formula H-1,
L₁ and L₂ are each independently a direct linkage, a substituted or unsubstituted arylene group having 6 to 30 ring-forming carbons, or a substituted or unsubstituted heteroarylene group having 2 to 30 ring-forming carbons,
Ar₁ and Ar₂ are each independently a substituted or unsubstituted aryl group having 6 to 30 ring-forming carbons, or a substituted or unsubstituted heteroaryl group having 2 to 30 ring-forming carbons,
Ar₃ is a substituted or unsubstituted aryl group having 6 to 30 ring-forming carbons, and
a and b are each independently an integer of 0 to 10.

6. The light-emitting element of claim 2, wherein:
the emission layer comprises a host and a dopant; and
the host comprises the nitrogen-containing compound represented by any one of Formula 1-1 to Formula 1-4.

7. The light-emitting element of claim 6, wherein:
the host further comprises a second compound different from the nitrogen-containing compound represented by any one of Formula 1-1 to 1-4; and
the second compound is represented by Formula ET-1: 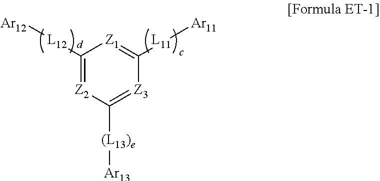
where, in Formula ET-1 above,
Z₁ to Z₃ are all N,
L₁₁ to L₁₃ are each independently a direct linkage, a substituted or unsubstituted arylene group having 6 to 30 ring-forming carbons, or a substituted or unsubstituted heteroarylene group having 2 to 30 ring-forming carbons,
Ar₁₁ to Ar₁₃ are each independently a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and
c to e are each independently an integer of 0 to 10.

8. The light-emitting element of claim 1, wherein the substituent represented by Formula 3 is represented by Formula 3-1 or Formula 3-2: 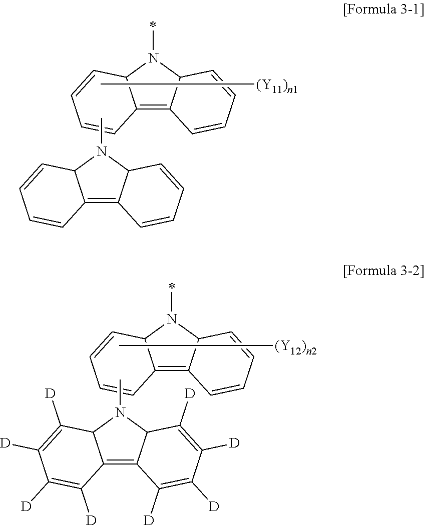
where, in Formula 3-1 and Formula 3-2,
Y₁₁ and Y₁₂ are each independently a hydrogen atom, a deuterium atom, or a substituted or unsubstituted alkyl group having 1 to 10 carbons,
n1 and n2 are each independently an integer of 0 to 7, and
“D” is a deuterium atom.

9. The light-emitting element of claim 1, wherein the substituent represented by Formula 2 is represented by any one of Formula 2-1 to Formula 2-6: 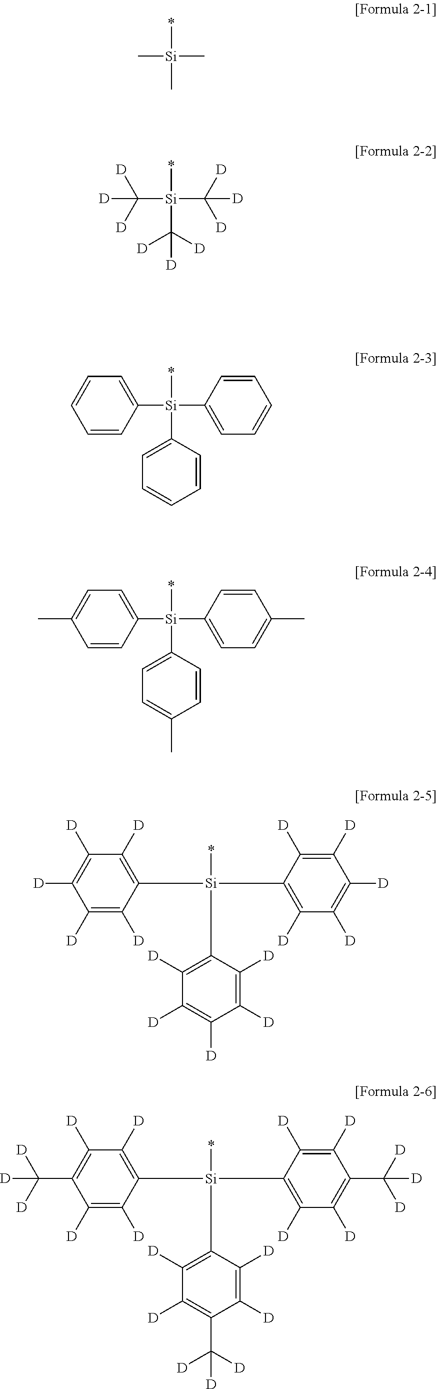
where, in Formula 2-1 to Formula 2-6, “D” is a deuterium atom.

10. The light-emitting element of claim 1, wherein the at least one functional layer comprises the nitrogen-containing compound represented by Formula 1-1, and wherein the nitrogen-containing compound represented by Formula 1-1 is represented by any one of Formula 1-1-1 to Formula 1-1-6: 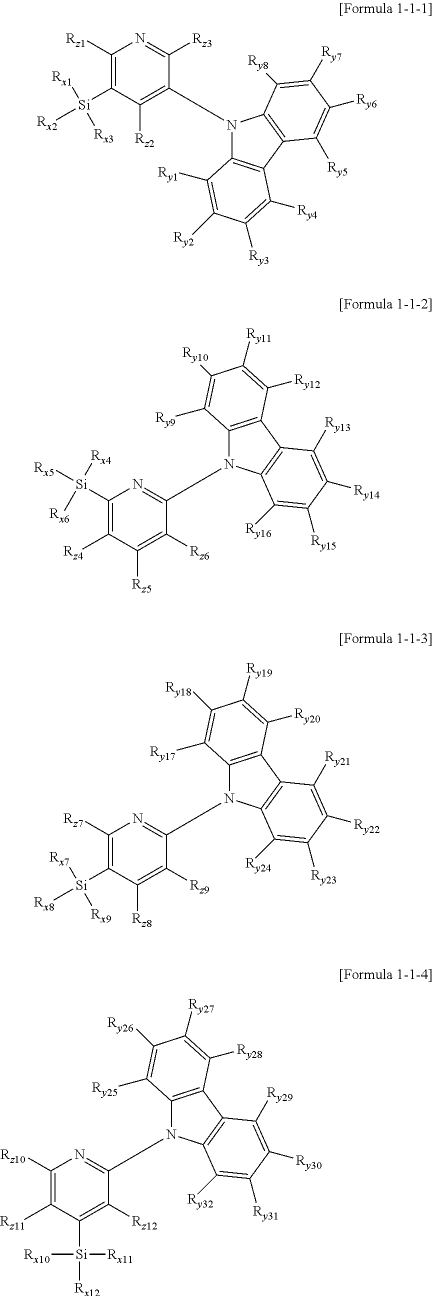 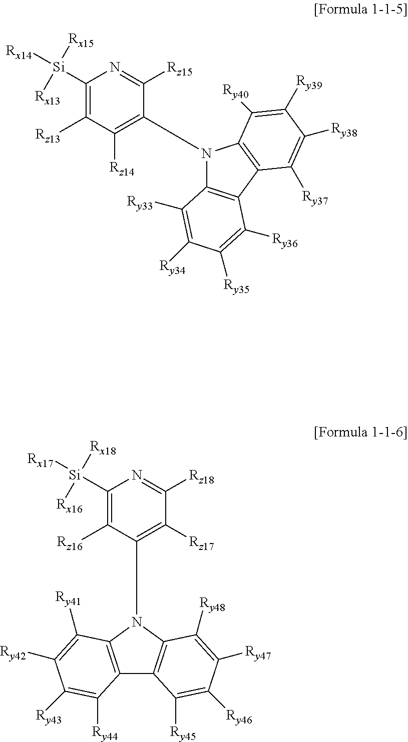
where, in Formula 1-1-1 to Formula 1-1-6 above,
Rₓ₁ to Rₓ₁₈ are each independently, a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
R_{z1} to R_{z18} are each independently, a hydrogen atom, a deuterium atom, a halogen atom, a cyano group, or a substituted or unsubstituted alkyl group having 1 to 20 carbons,
in Formula 1-1-1, any one of R_{y1} to R_{y8} is a substituent represented by Formula 4, and a remainder of R_{y1} to R_{y8} are each independently a hydrogen atom, or a deuterium atom,
in Formula 1-1-2, any one of R_{y9} to R_{y16} is a substituent represented by Formula 4, and a remainder of R_{y9} to R_{y16} are each independently a hydrogen atom, or a deuterium atom,
in Formula 1-1-3, any one of R_{y17} to R_{y24} is a substituent represented by Formula 4, and a remainder of R_{y17} to R_{y24} are each independently a hydrogen atom, or a deuterium atom,
in Formula 1-1-4, any one of R_{y25} to R_{y32} is a substituent represented by Formula 4, and a remainder of R_{y25} to R_{y32} are each independently a hydrogen atom, or a deuterium atom,
in Formula 1-1-5, any one of R_{y33} to R_{y40} is a substituent represented by Formula 4, and a remainder of R_{y33} to R_{y40} are each independently a hydrogen atom, or a deuterium atom, and
in Formula 1-1-6, any one of R_{y41} to R_{y48} is a substituent represented by Formula 4, and a remainder of R_{y41} to R_{y48} are each independently a hydrogen atom, or a deuterium atom.

11. The light-emitting element of claim 1, wherein the at least one functional layer comprises the nitrogen-containing compound represented by Formula 1-2, and wherein the nitrogen-containing compound represented by Formula 1-2 is represented by any one of Formula 1-2-1 to Formula 1-2-4: 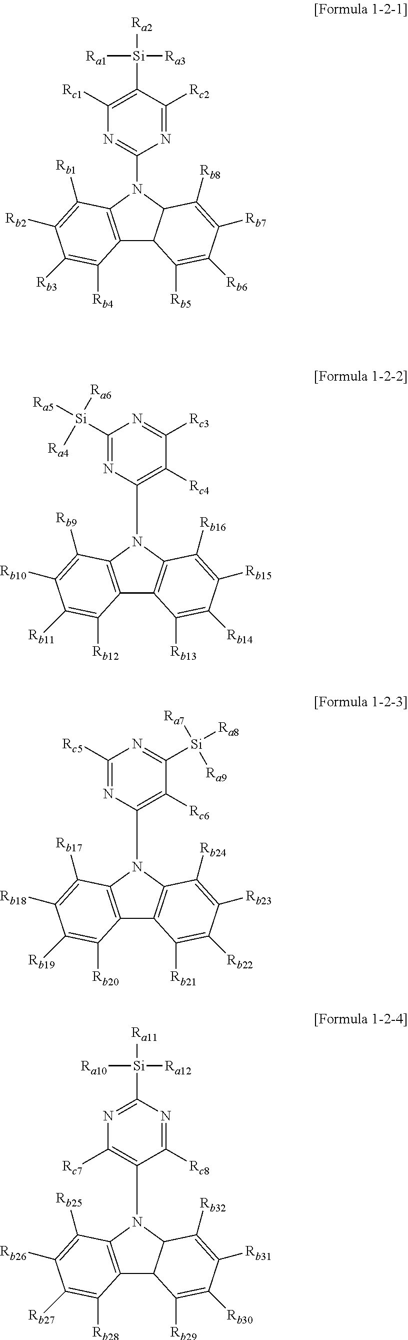
where, in Formula 1-2-1 to Formula 1-2-4,
Rₐ₁ to Rₐ₁₂ are each independently, a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
R_{c1} to R_{c8} are each independently, a hydrogen atom, a deuterium atom, a halogen atom, a cyano group, or a substituted or unsubstituted alkyl group having 1 to 20 carbons,
in Formula 1-2-1, any one of R_{b1} to R_{b}s is a substituent represented by Formula 4, and a remainder of R_{b1} to R_{b8} are each independently a hydrogen atom, or a deuterium atom,
in Formula 1-2-2, any one of R_{b9} to R_{b16} is a substituent represented by Formula 4, and a remainder of R_{b9} to R_{b16} are each independently a hydrogen atom, or a deuterium atom,
in Formula 1-2-3, any one of R_{b17} to R_{b24} is a substituent represented by Formula 4, and a remainder of R_{b17} to R_{b24} are each independently a hydrogen atom, or a deuterium atom, and
in Formula 1-2-4, any one of R_{b25} to R_{b32} is a substituent represented by Formula 4, and a remainder of R_{b25} to R_{b32} are each independently a hydrogen atom, or a deuterium atom.

12. The light-emitting element of claim 1, wherein the at least one functional layer comprises the nitrogen-containing compound represented by Formula 1-3, and wherein the nitrogen-containing compound represented by Formula 1-3 is represented by Formula 1-3-1: 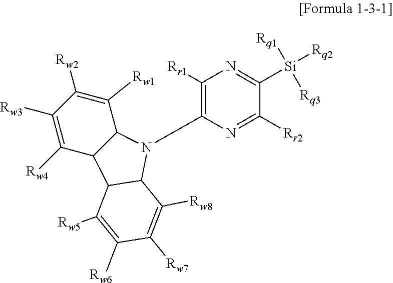
where, in Formula 1-3-1,
Rᵣ₁ and Rᵣ₂ are each independently, a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
R_{q1} to R_{q3} are each independently, a hydrogen atom, a deuterium atom, a halogen atom, a cyano group, or a substituted or unsubstituted alkyl group having 1 to 20 carbons, and
any one of Rᵥ₁ to Rᵥ₈ is a substituent represented by Formula 4, and a remainder of Rᵥ₁ to Rᵥ₈ are each independently a hydrogen atom, or a deuterium atom.

13. The light-emitting element of claim 1, wherein the nitrogen-containing compound is represented by any compound in Compound Group 1:

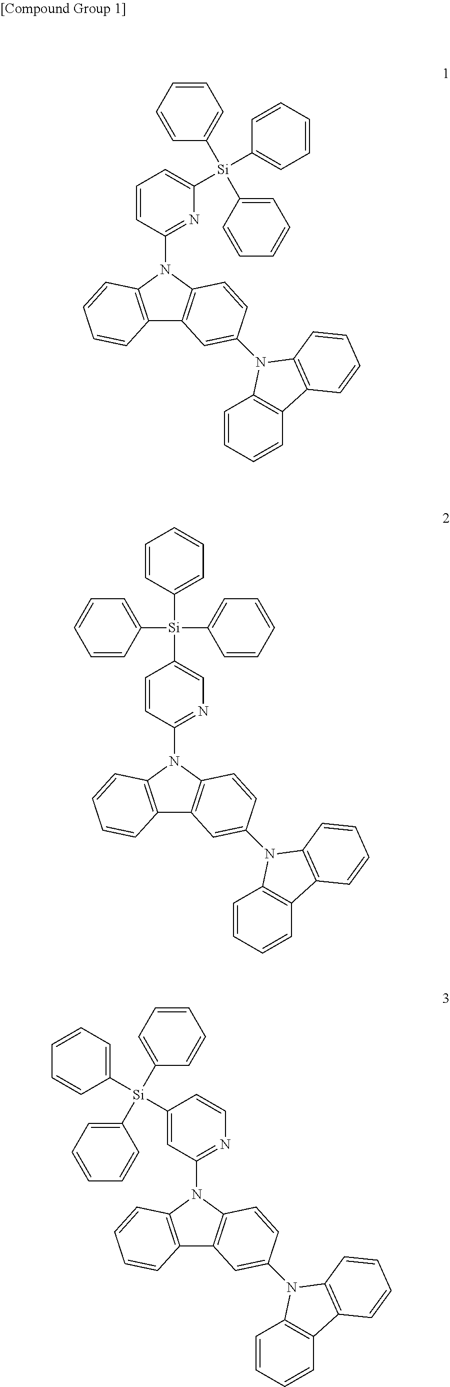 [SMILES: c1ccc([Si](c2ccccc2)(c2ccccc2)c2cccc(-n3c4ccccc4c4cc(-n5c6ccccc6c6ccccc65)ccc43)n2)cc1 ; c1ccc([Si](c2ccccc2)(c2ccccc2)c2ccc(-n3c4ccccc4c4cc(-n5c6ccccc6c6ccccc65)ccc43)nc2)cc1 ; c1ccc([Si](c2ccccc2)(c2ccccc2)c2ccnc(-n3c4ccccc4c4cc(-n5c6ccccc6c6ccccc65)ccc43)c2)cc1]

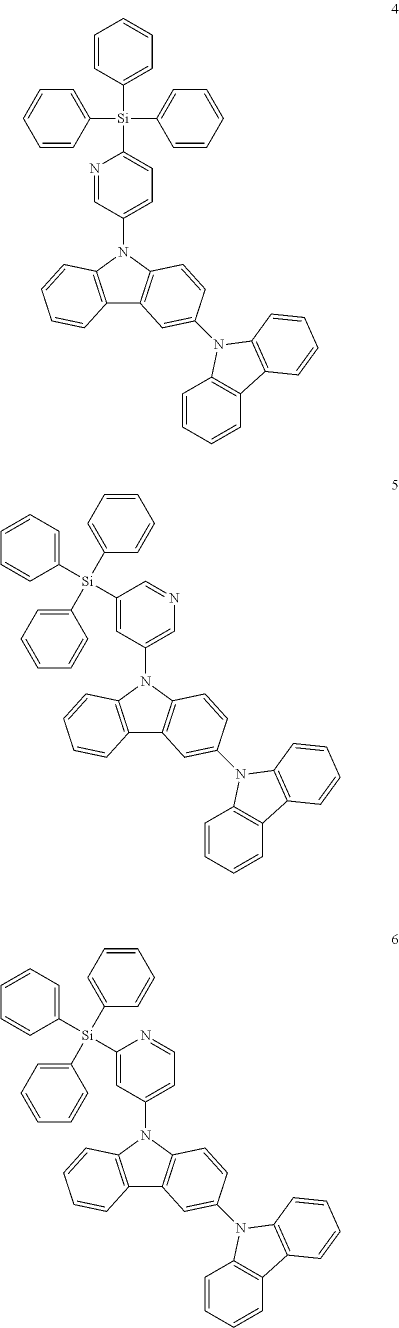 [SMILES: c1ccc([Si](c2ccccc2)(c2ccccc2)c2ccc(-n3c4ccccc4c4cc(-n5c6ccccc6c6ccccc65)ccc43)cn2)cc1 ; c1ccc([Si](c2ccccc2)(c2ccccc2)c2cncc(-n3c4ccccc4c4cc(-n5c6ccccc6c6ccccc65)ccc43)c2)cc1 ; c1ccc([Si](c2ccccc2)(c2ccccc2)c2cc(-n3c4ccccc4c4cc(-n5c6ccccc6c6ccccc65)ccc43)ccn2)cc1]

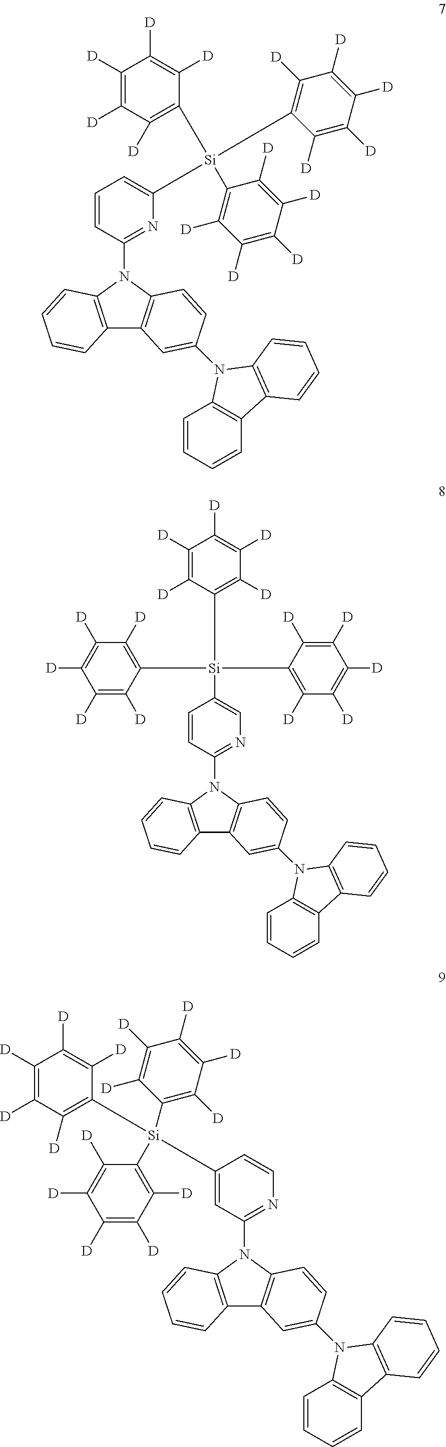

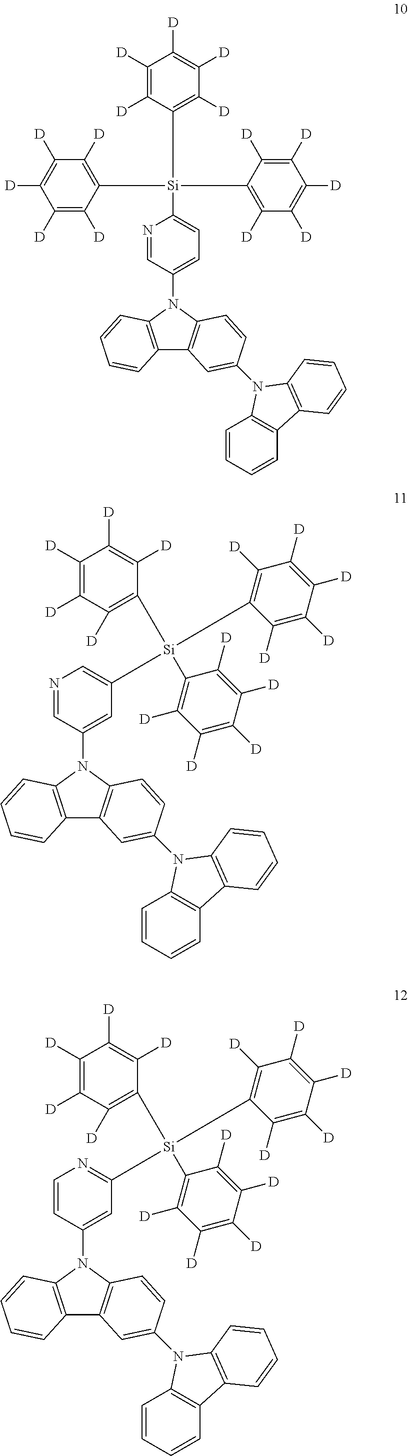

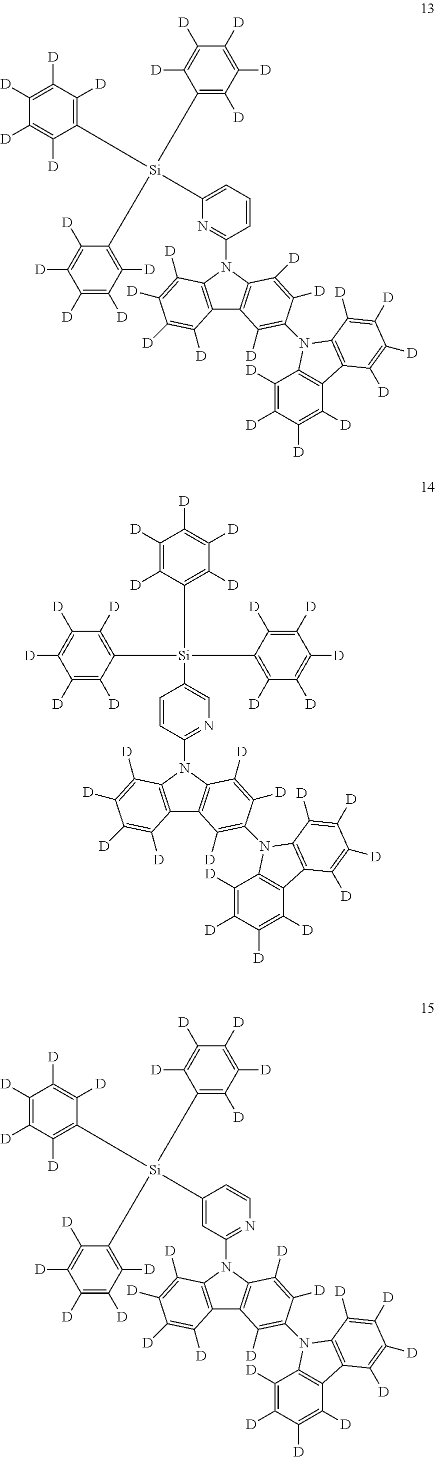

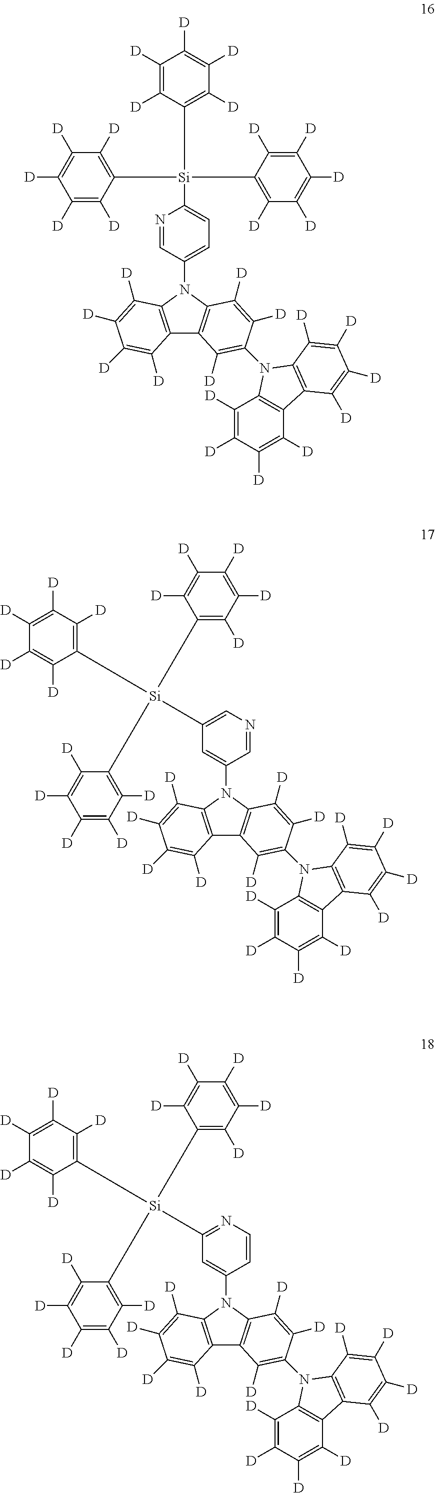

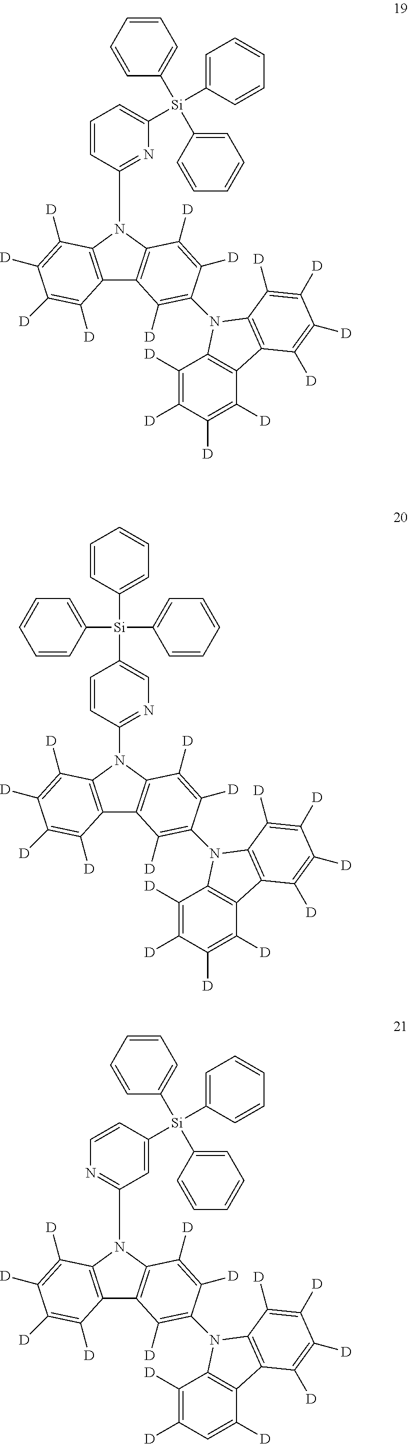

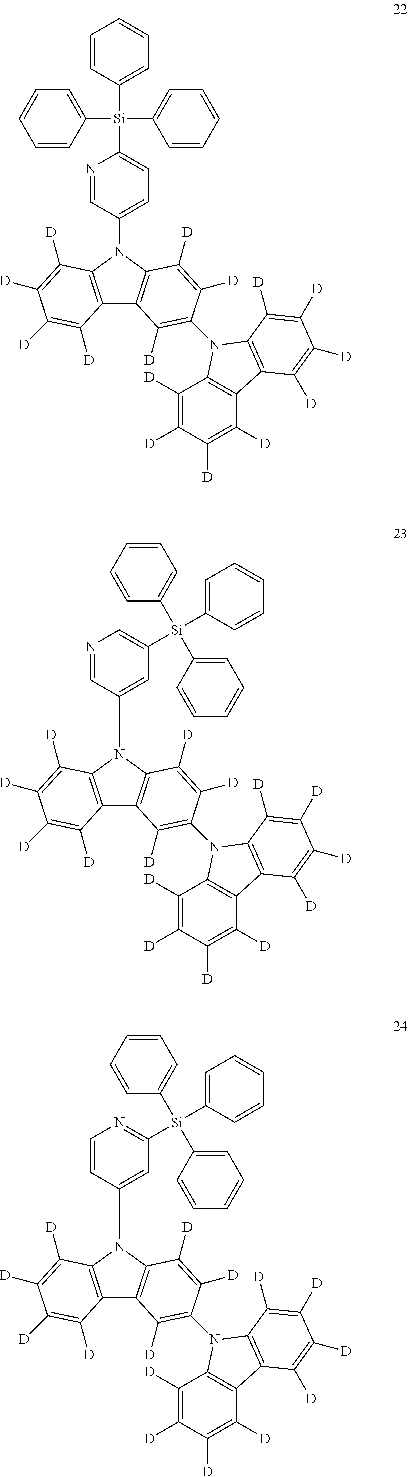

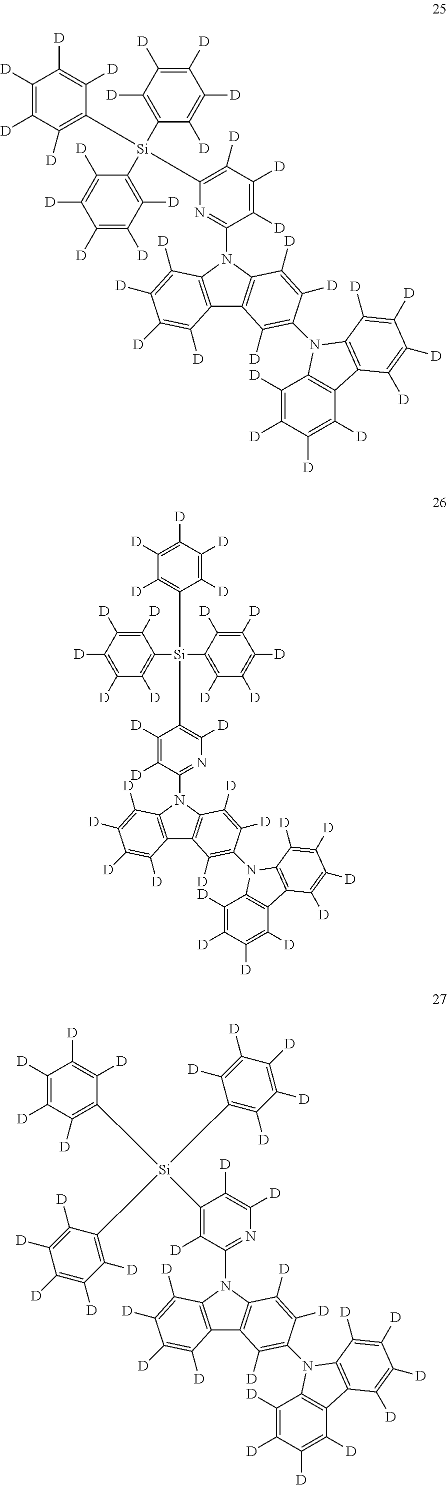

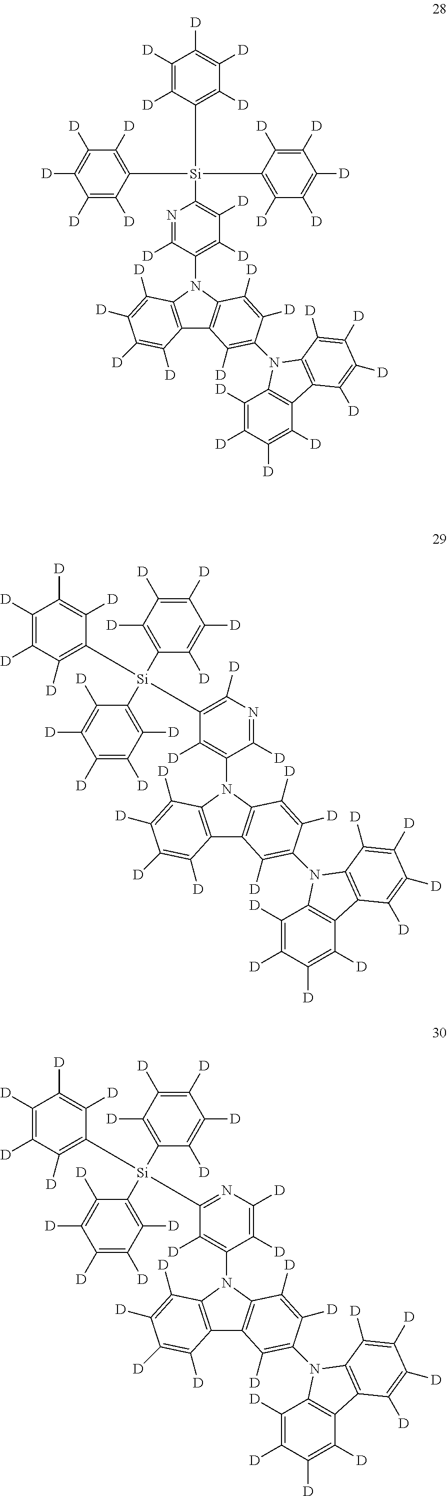

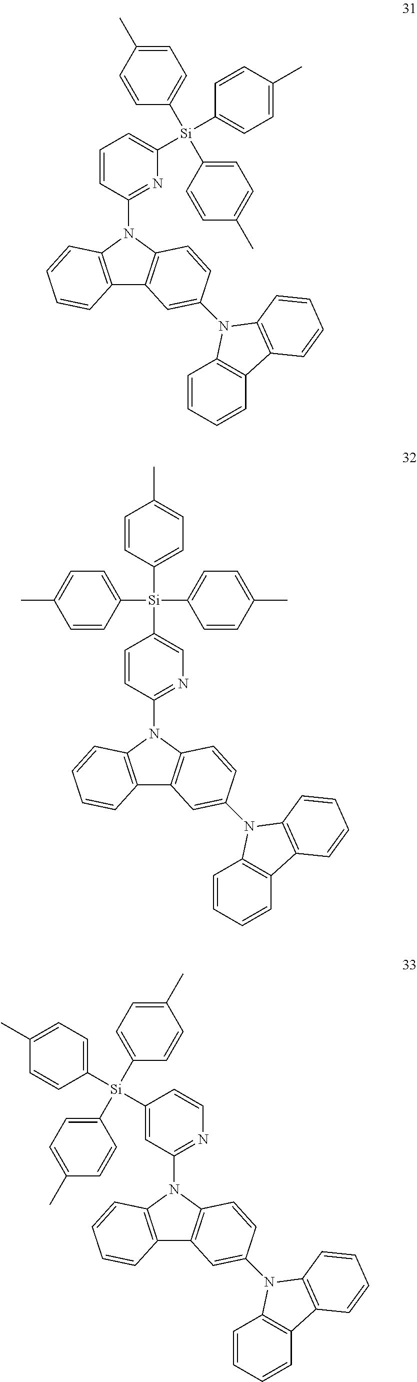 [SMILES: Cc1ccc([Si](c2ccc(C)cc2)(c2ccc(C)cc2)c2cccc(-n3c4ccccc4c4cc(-n5c6ccccc6c6ccccc65)ccc43)n2)cc1 ; Cc1ccc([Si](c2ccc(C)cc2)(c2ccc(C)cc2)c2ccc(-n3c4ccccc4c4cc(-n5c6ccccc6c6ccccc65)ccc43)nc2)cc1 ; Cc1ccc([Si](c2ccc(C)cc2)(c2ccc(C)cc2)c2ccnc(-n3c4ccccc4c4cc(-n5c6ccccc6c6ccccc65)ccc43)c2)cc1]

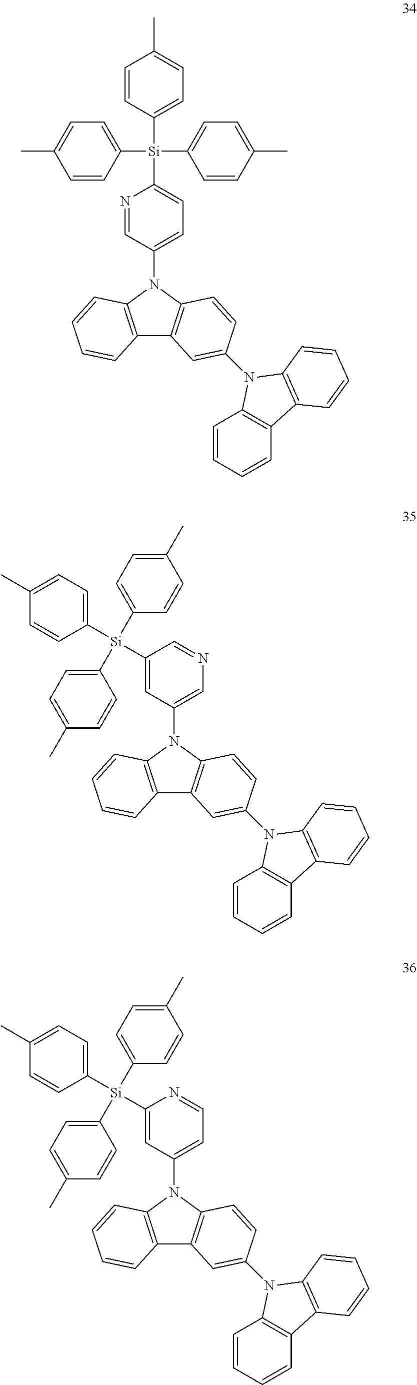 [SMILES: Cc1ccc([Si](c2ccc(C)cc2)(c2ccc(C)cc2)c2ccc(-n3c4ccccc4c4cc(-n5c6ccccc6c6ccccc65)ccc43)cn2)cc1 ; Cc1ccc([Si](c2ccc(C)cc2)(c2ccc(C)cc2)c2cncc(-n3c4ccccc4c4cc(-n5c6ccccc6c6ccccc65)ccc43)c2)cc1 ; Cc1ccc([Si](c2ccc(C)cc2)(c2ccc(C)cc2)c2cc(-n3c4ccccc4c4cc(-n5c6ccccc6c6ccccc65)ccc43)ccn2)cc1]

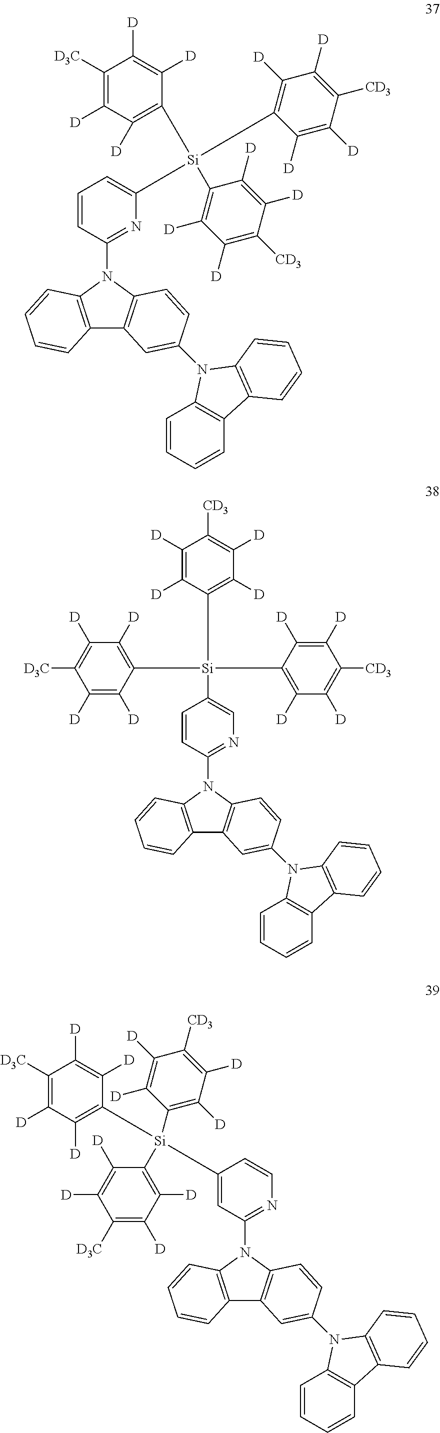

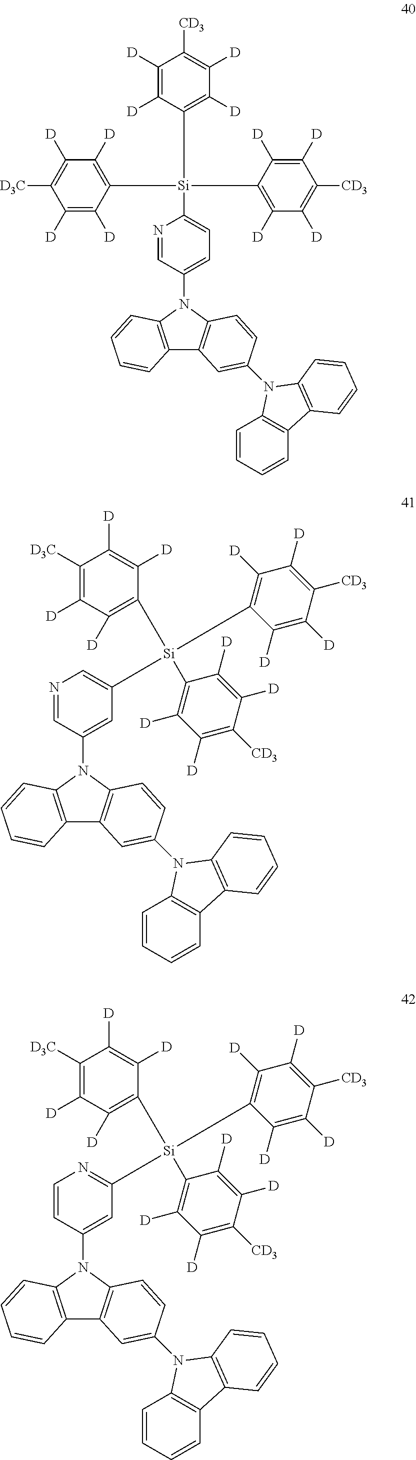

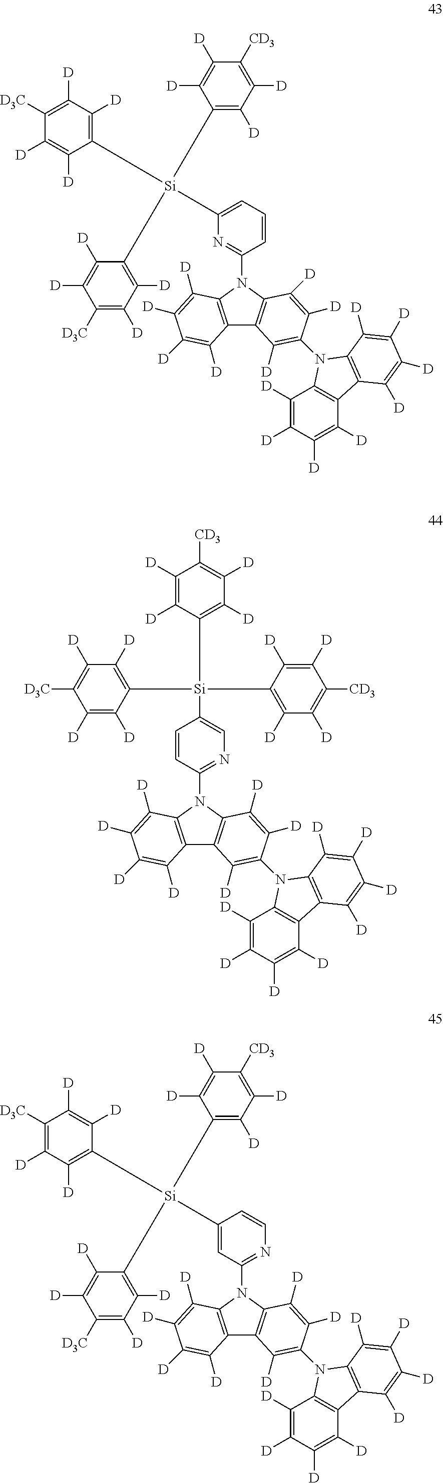

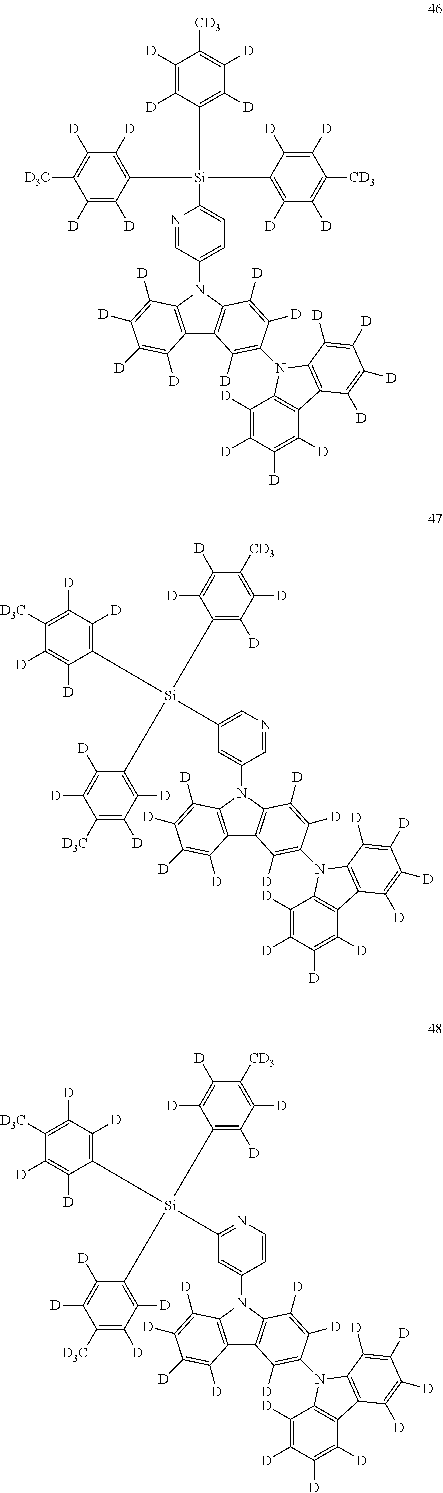

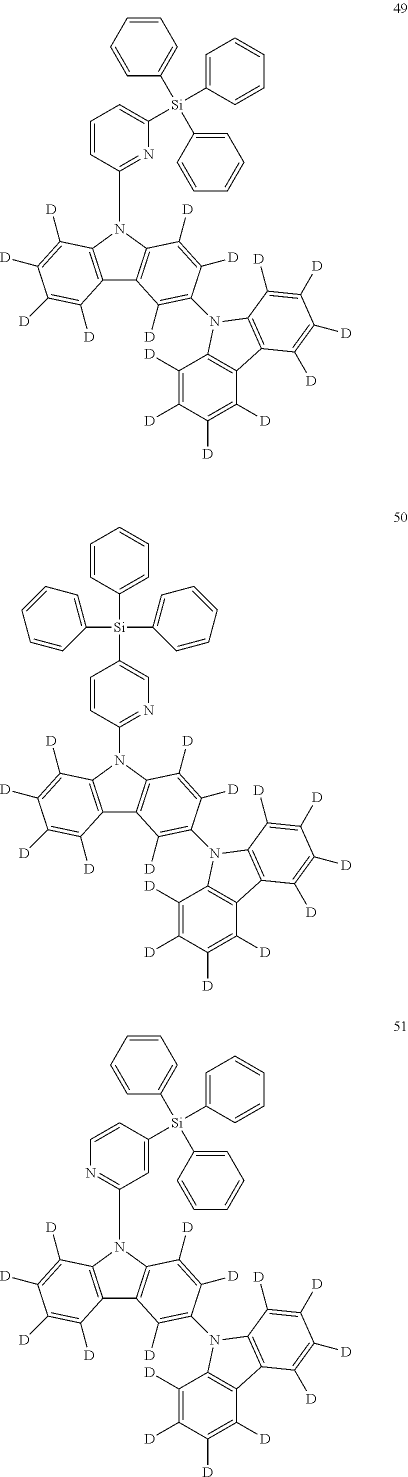

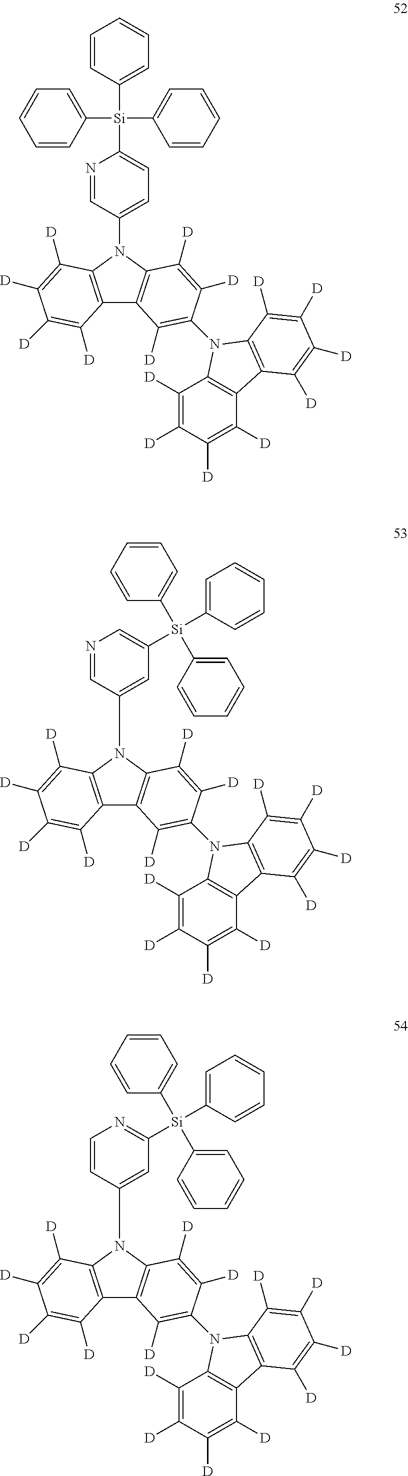

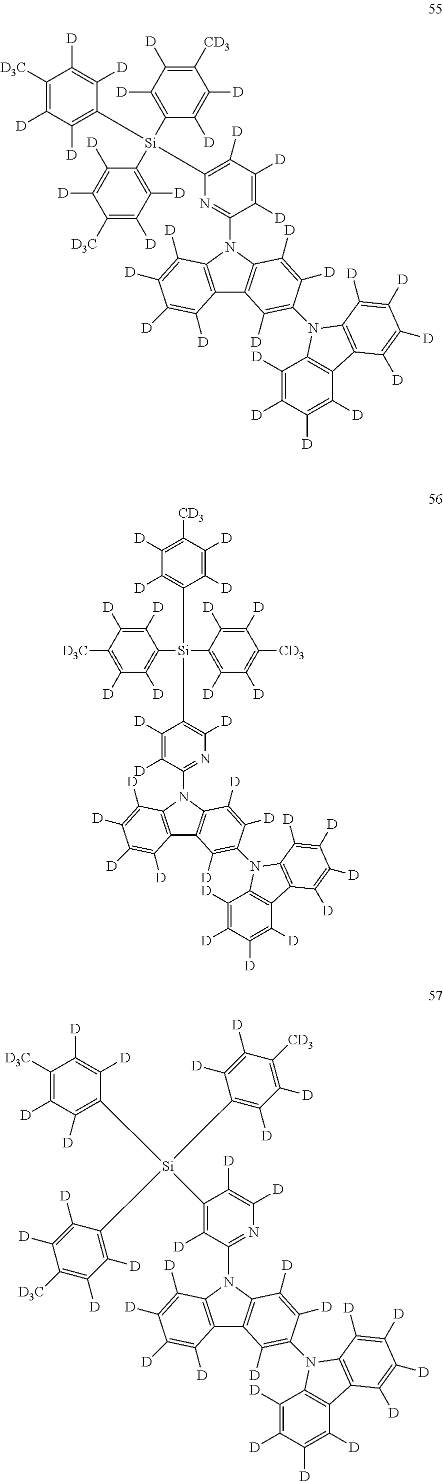

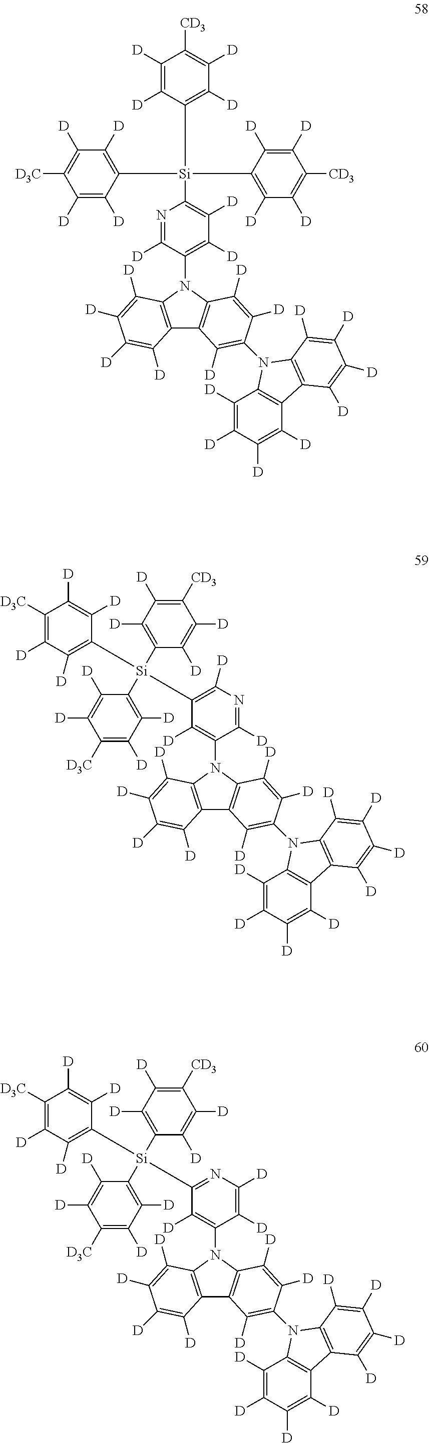

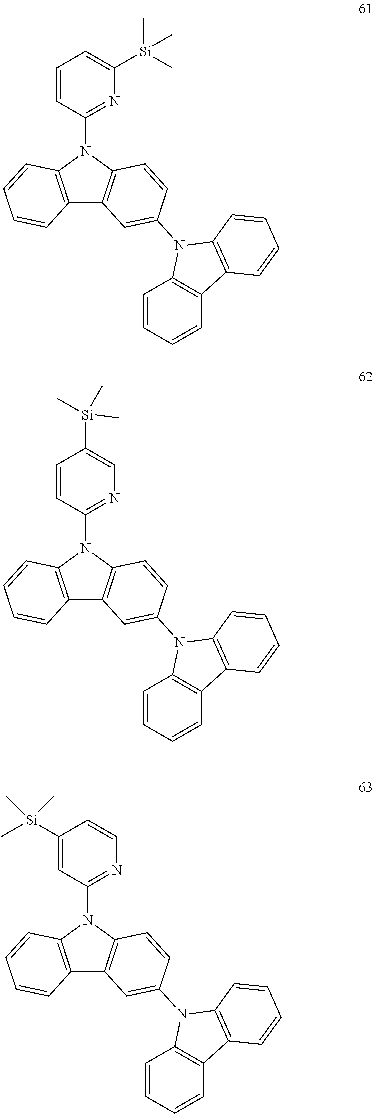 [SMILES: C[Si](C)(C)c1cccc(-n2c3ccccc3c3cc(-n4c5ccccc5c5ccccc54)ccc32)n1 ; C[Si](C)(C)c1ccc(-n2c3ccccc3c3cc(-n4c5ccccc5c5ccccc54)ccc32)nc1 ; C[Si](C)(C)c1ccnc(-n2c3ccccc3c3cc(-n4c5ccccc5c5ccccc54)ccc32)c1]

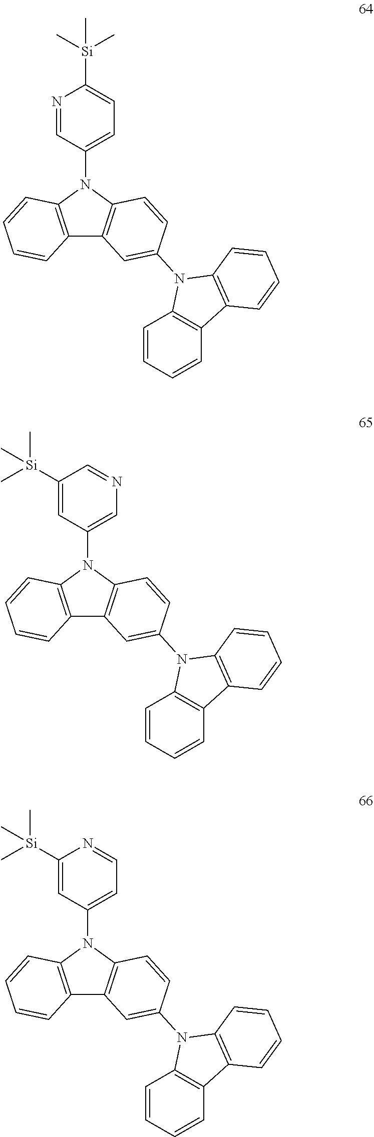 [SMILES: C[Si](C)(C)c1ccc(-n2c3ccccc3c3cc(-n4c5ccccc5c5ccccc54)ccc32)cn1 ; C[Si](C)(C)c1cncc(-n2c3ccccc3c3cc(-n4c5ccccc5c5ccccc54)ccc32)c1 ; C[Si](C)(C)c1cc(-n2c3ccccc3c3cc(-n4c5ccccc5c5ccccc54)ccc32)ccn1]

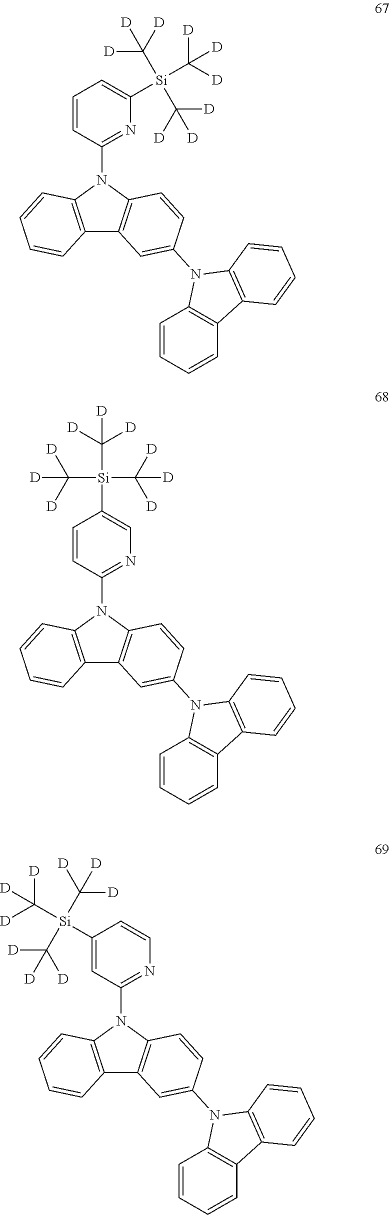 [SMILES: [2H]C([2H])([2H])[Si](c1cccc(-n2c3ccccc3c3cc(-n4c5ccccc5c5ccccc54)ccc32)n1)(C([2H])([2H])[2H])C([2H])([2H])[2H] ; [2H]C([2H])([2H])[Si](c1ccc(-n2c3ccccc3c3cc(-n4c5ccccc5c5ccccc54)ccc32)nc1)(C([2H])([2H])[2H])C([2H])([2H])[2H] ; [2H]C([2H])([2H])[Si](c1ccnc(-n2c3ccccc3c3cc(-n4c5ccccc5c5ccccc54)ccc32)c1)(C([2H])([2H])[2H])C([2H])([2H])[2H]]

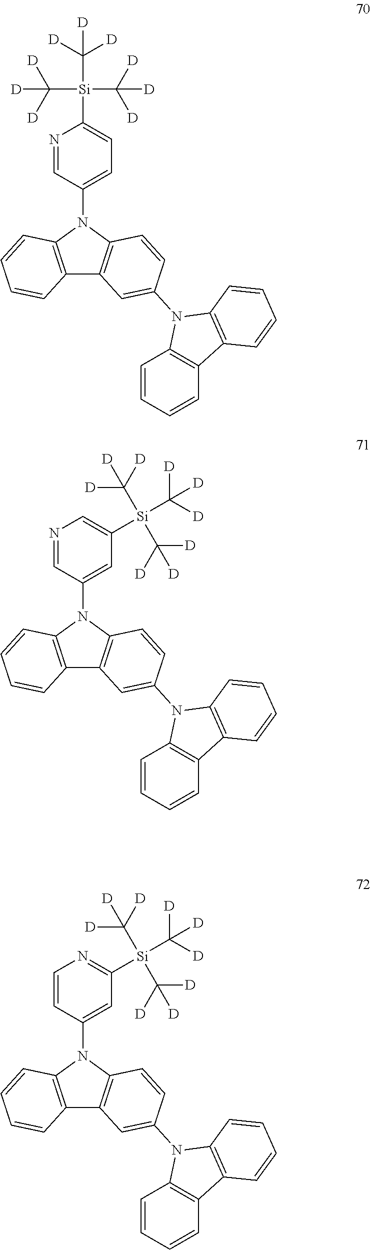 [SMILES: [2H]C([2H])([2H])[Si](c1ccc(-n2c3ccccc3c3cc(-n4c5ccccc5c5ccccc54)ccc32)cn1)(C([2H])([2H])[2H])C([2H])([2H])[2H] ; [2H]C([2H])([2H])[Si](c1cncc(-n2c3ccccc3c3cc(-n4c5ccccc5c5ccccc54)ccc32)c1)(C([2H])([2H])[2H])C([2H])([2H])[2H] ; [2H]C([2H])([2H])[Si](c1cc(-n2c3ccccc3c3cc(-n4c5ccccc5c5ccccc54)ccc32)ccn1)(C([2H])([2H])[2H])C([2H])([2H])[2H]]

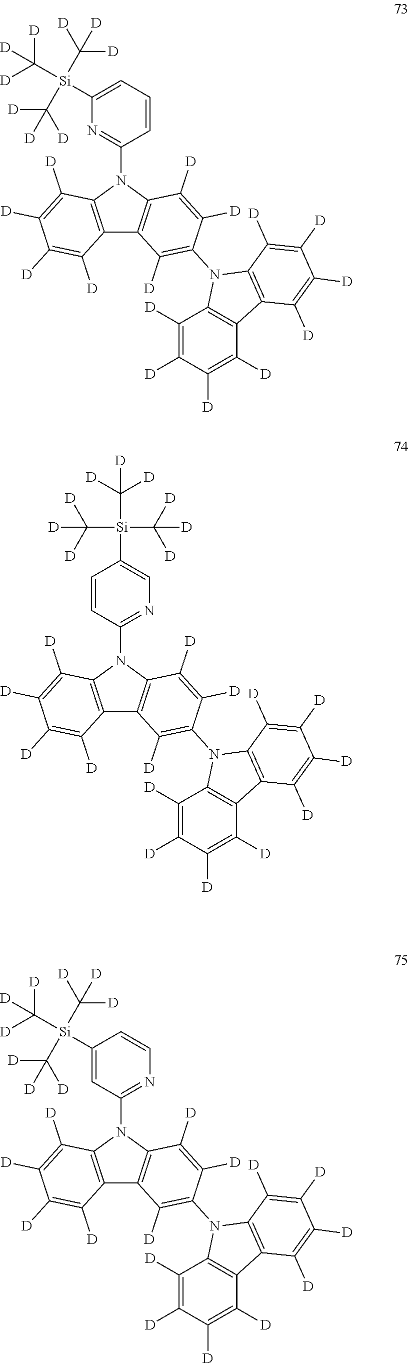

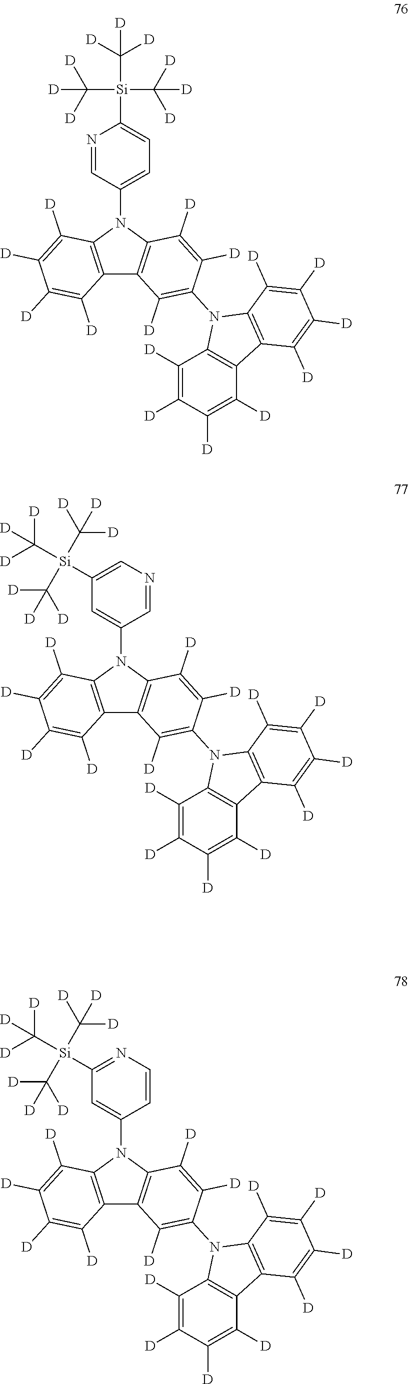

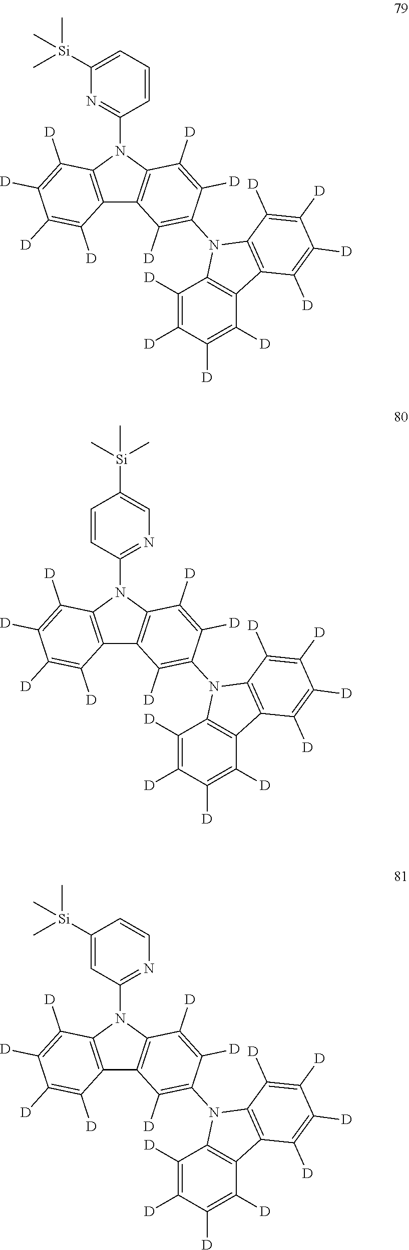 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cccc([Si](C)(C)C)n1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccc([Si](C)(C)C)cn1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cc([Si](C)(C)C)ccn1]

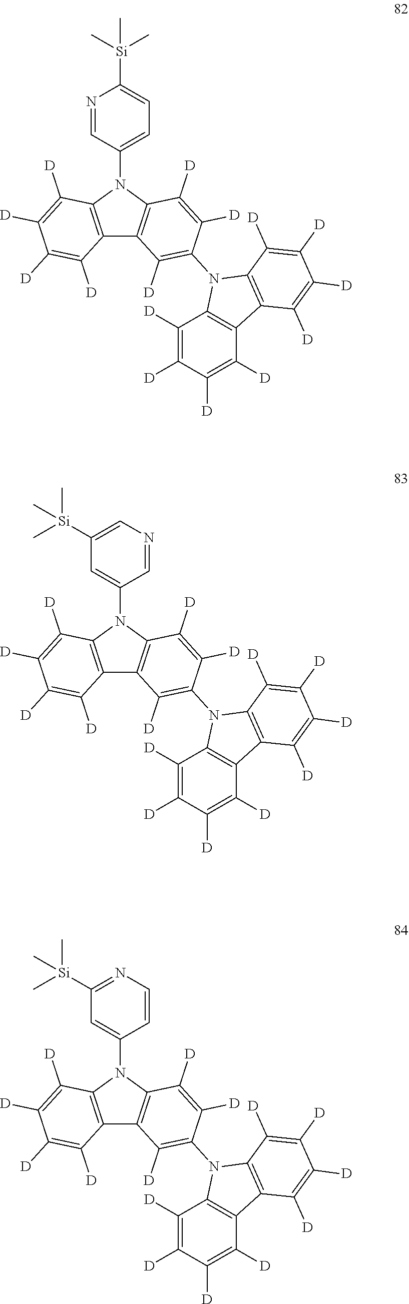 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccc([Si](C)(C)C)nc1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cncc([Si](C)(C)C)c1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccnc([Si](C)(C)C)c1]

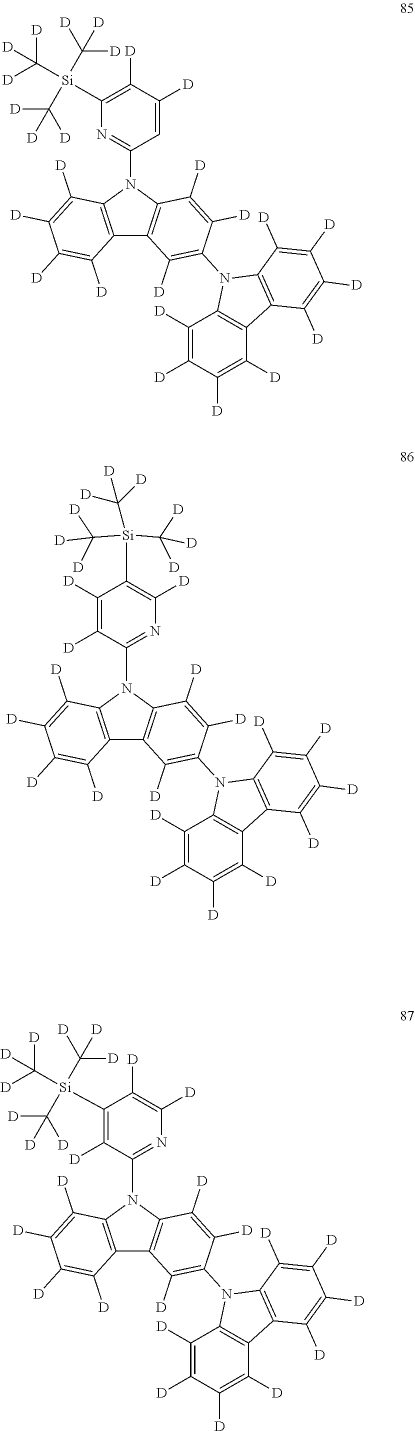

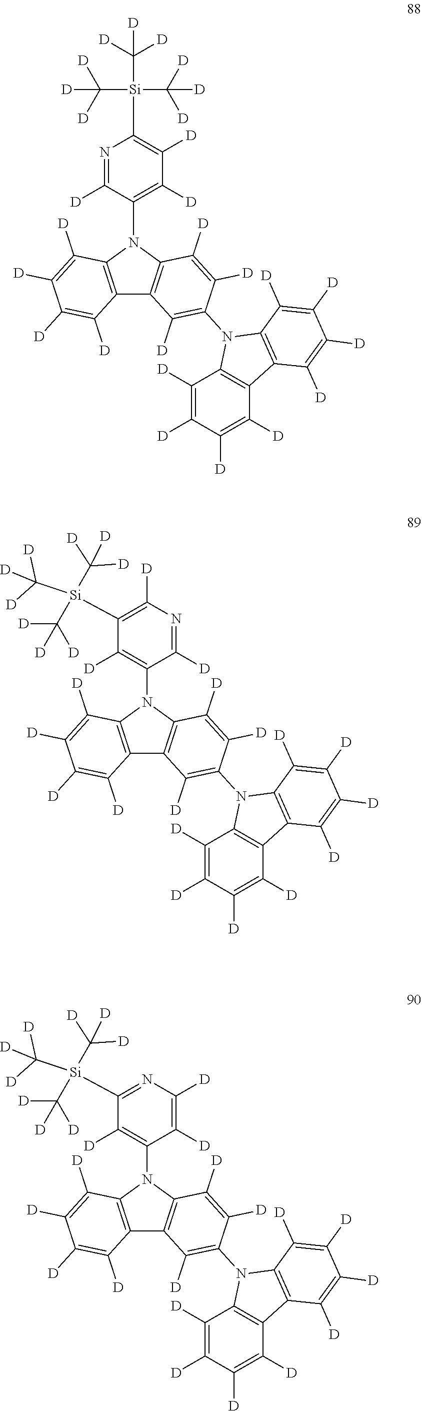

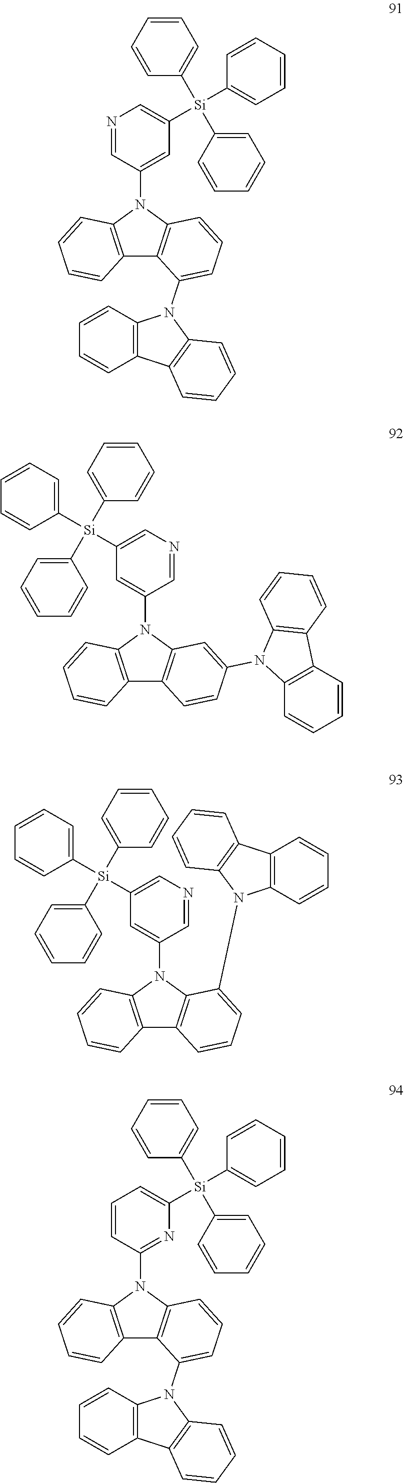 [SMILES: c1ccc([Si](c2ccccc2)(c2ccccc2)c2cncc(-n3c4ccccc4c4c(-n5c6ccccc6c6ccccc65)cccc43)c2)cc1 ; c1ccc([Si](c2ccccc2)(c2ccccc2)c2cncc(-n3c4ccccc4c4ccc(-n5c6ccccc6c6ccccc65)cc43)c2)cc1 ; c1ccc([Si](c2ccccc2)(c2ccccc2)c2cncc(-n3c4ccccc4c4cccc(-n5c6ccccc6c6ccccc65)c43)c2)cc1 ; c1ccc([Si](c2ccccc2)(c2ccccc2)c2cccc(-n3c4ccccc4c4c(-n5c6ccccc6c6ccccc65)cccc43)n2)cc1]

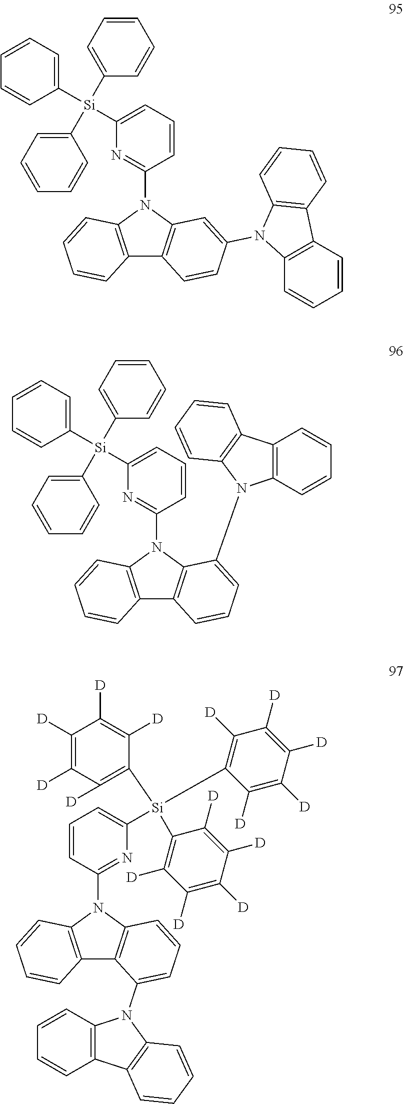 [SMILES: c1ccc([Si](c2ccccc2)(c2ccccc2)c2cccc(-n3c4ccccc4c4ccc(-n5c6ccccc6c6ccccc65)cc43)n2)cc1 ; c1ccc([Si](c2ccccc2)(c2ccccc2)c2cccc(-n3c4ccccc4c4cccc(-n5c6ccccc6c6ccccc65)c43)n2)cc1 ; [2H]c1c([2H])c([2H])c([Si](c2cccc(-n3c4ccccc4c4c(-n5c6ccccc6c6ccccc65)cccc43)n2)(c2c([2H])c([2H])c([2H])c([2H])c2[2H])c2c([2H])c([2H])c([2H])c([2H])c2[2H])c([2H])c1[2H]]

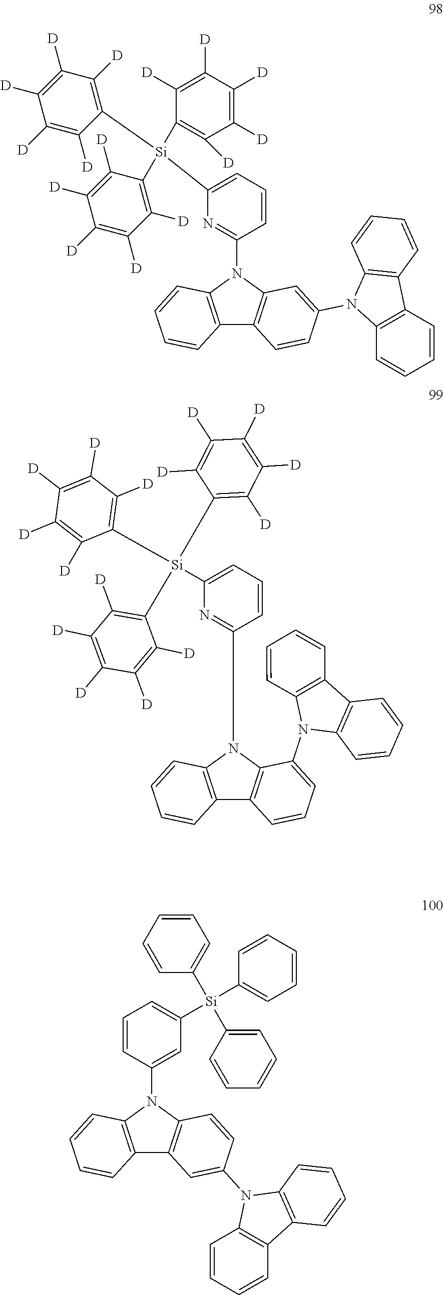 [SMILES: [2H]c1c([2H])c([2H])c([Si](c2cccc(-n3c4ccccc4c4ccc(-n5c6ccccc6c6ccccc65)cc43)n2)(c2c([2H])c([2H])c([2H])c([2H])c2[2H])c2c([2H])c([2H])c([2H])c([2H])c2[2H])c([2H])c1[2H] ; [2H]c1c([2H])c([2H])c([Si](c2cccc(-n3c4ccccc4c4cccc(-n5c6ccccc6c6ccccc65)c43)n2)(c2c([2H])c([2H])c([2H])c([2H])c2[2H])c2c([2H])c([2H])c([2H])c([2H])c2[2H])c([2H])c1[2H] ; c1ccc([Si](c2ccccc2)(c2ccccc2)c2cccc(-n3c4ccccc4c4cc(-n5c6ccccc6c6ccccc65)ccc43)c2)cc1]

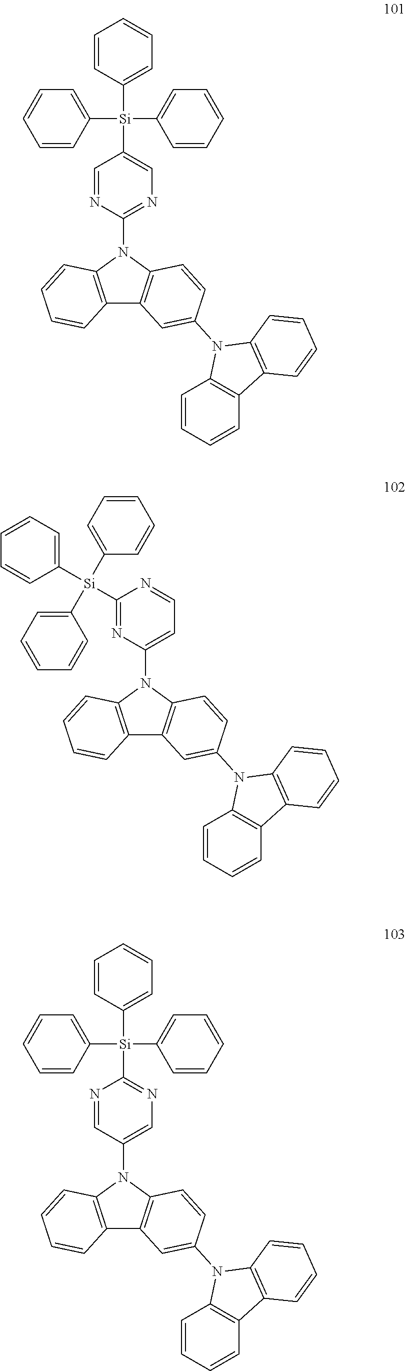 [SMILES: c1ccc([Si](c2ccccc2)(c2ccccc2)c2cnc(-n3c4ccccc4c4cc(-n5c6ccccc6c6ccccc65)ccc43)nc2)cc1 ; c1ccc([Si](c2ccccc2)(c2ccccc2)c2nccc(-n3c4ccccc4c4cc(-n5c6ccccc6c6ccccc65)ccc43)n2)cc1 ; c1ccc([Si](c2ccccc2)(c2ccccc2)c2ncc(-n3c4ccccc4c4cc(-n5c6ccccc6c6ccccc65)ccc43)cn2)cc1]

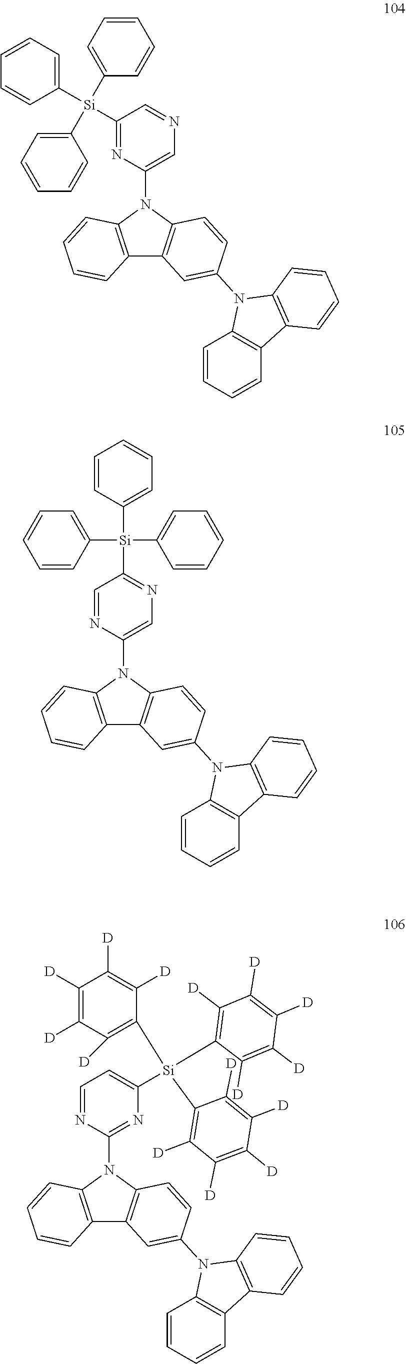 [SMILES: c1ccc([Si](c2ccccc2)(c2ccccc2)c2cncc(-n3c4ccccc4c4cc(-n5c6ccccc6c6ccccc65)ccc43)n2)cc1 ; c1ccc([Si](c2ccccc2)(c2ccccc2)c2cnc(-n3c4ccccc4c4cc(-n5c6ccccc6c6ccccc65)ccc43)cn2)cc1 ; [2H]c1c([2H])c([2H])c([Si](c2ccnc(-n3c4ccccc4c4cc(-n5c6ccccc6c6ccccc65)ccc43)n2)(c2c([2H])c([2H])c([2H])c([2H])c2[2H])c2c([2H])c([2H])c([2H])c([2H])c2[2H])c([2H])c1[2H]]

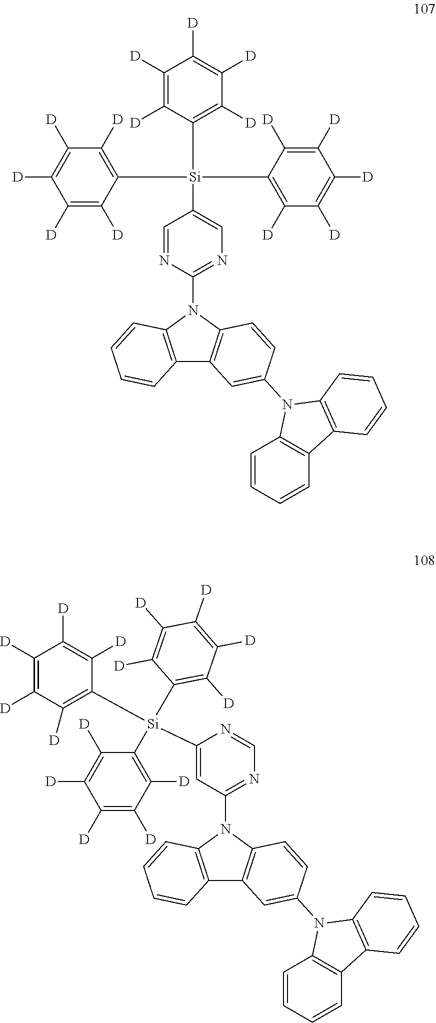 [SMILES: [2H]c1c([2H])c([2H])c([Si](c2cnc(-n3c4ccccc4c4cc(-n5c6ccccc6c6ccccc65)ccc43)nc2)(c2c([2H])c([2H])c([2H])c([2H])c2[2H])c2c([2H])c([2H])c([2H])c([2H])c2[2H])c([2H])c1[2H] ; [2H]c1c([2H])c([2H])c([Si](c2cc(-n3c4ccccc4c4cc(-n5c6ccccc6c6ccccc65)ccc43)ncn2)(c2c([2H])c([2H])c([2H])c([2H])c2[2H])c2c([2H])c([2H])c([2H])c([2H])c2[2H])c([2H])c1[2H]]

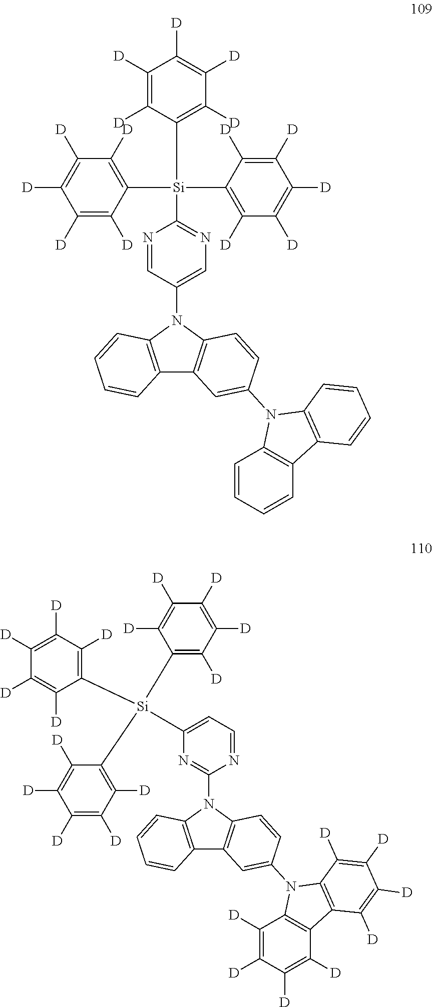 [SMILES: [2H]c1c([2H])c([2H])c([Si](c2ncc(-n3c4ccccc4c4cc(-n5c6ccccc6c6ccccc65)ccc43)cn2)(c2c([2H])c([2H])c([2H])c([2H])c2[2H])c2c([2H])c([2H])c([2H])c([2H])c2[2H])c([2H])c1[2H] ; [2H]c1c([2H])c([2H])c([Si](c2ccnc(-n3c4ccccc4c4cc(-n5c6c([2H])c([2H])c([2H])c([2H])c6c6c([2H])c([2H])c([2H])c([2H])c65)ccc43)n2)(c2c([2H])c([2H])c([2H])c([2H])c2[2H])c2c([2H])c([2H])c([2H])c([2H])c2[2H])c([2H])c1[2H]]

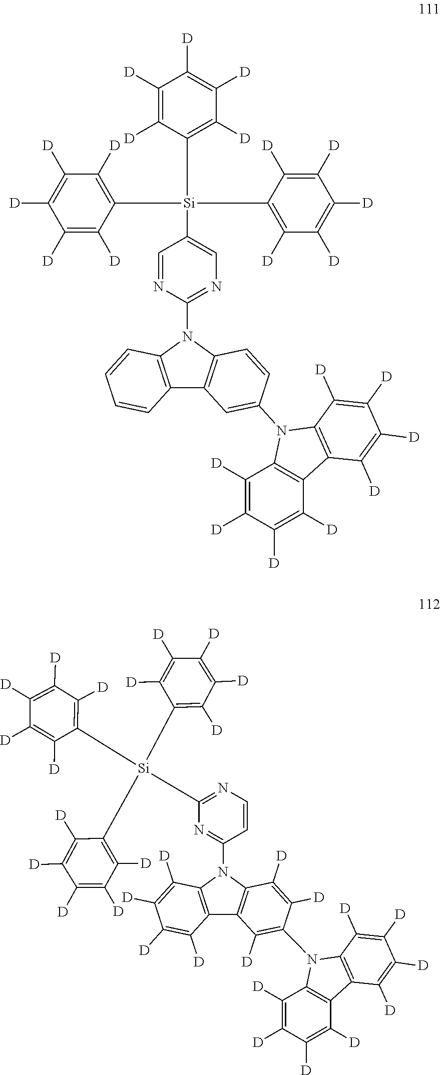 [SMILES: [2H]c1c([2H])c([2H])c([Si](c2cnc(-n3c4ccccc4c4cc(-n5c6c([2H])c([2H])c([2H])c([2H])c6c6c([2H])c([2H])c([2H])c([2H])c65)ccc43)nc2)(c2c([2H])c([2H])c([2H])c([2H])c2[2H])c2c([2H])c([2H])c([2H])c([2H])c2[2H])c([2H])c1[2H] ; [2H]c1c([2H])c([2H])c([Si](c2nccc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)n2)(c2c([2H])c([2H])c([2H])c([2H])c2[2H])c2c([2H])c([2H])c([2H])c([2H])c2[2H])c([2H])c1[2H]]

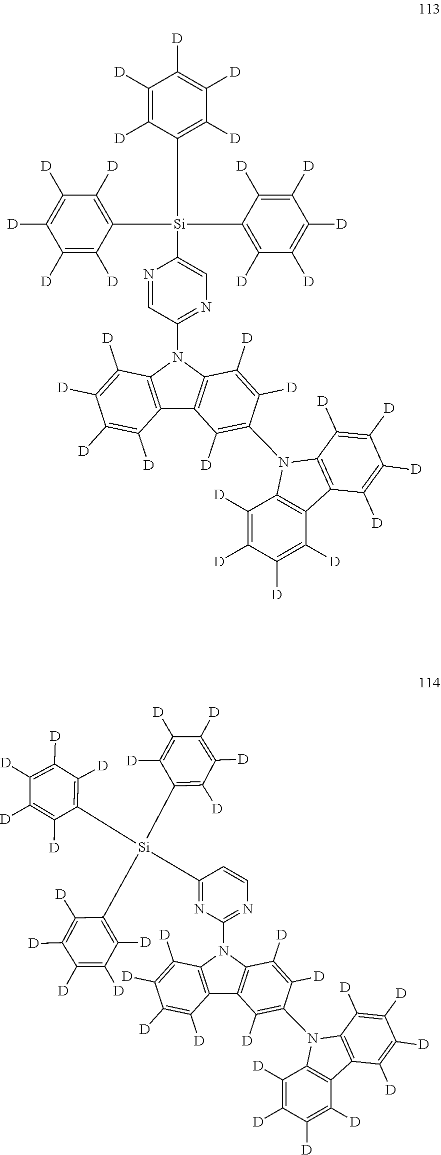

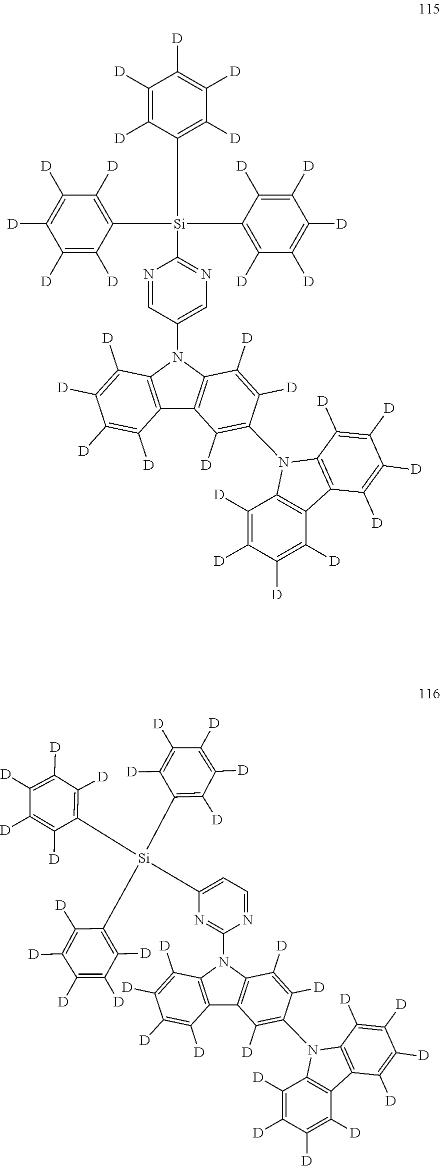

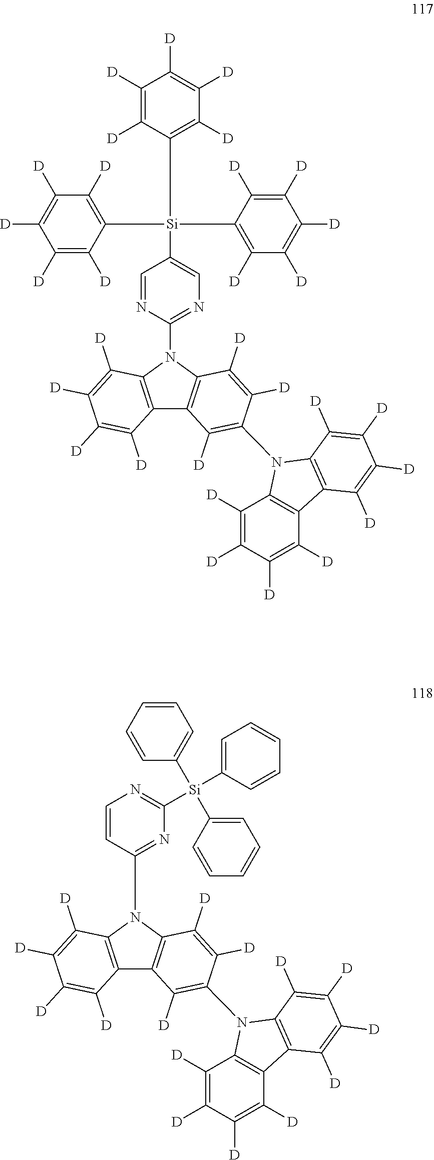 [SMILES: [2H]c1c([2H])c([2H])c([Si](c2cnc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)nc2)(c2c([2H])c([2H])c([2H])c([2H])c2[2H])c2c([2H])c([2H])c([2H])c([2H])c2[2H])c([2H])c1[2H] ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccnc([Si](c2ccccc2)(c2ccccc2)c2ccccc2)n1]

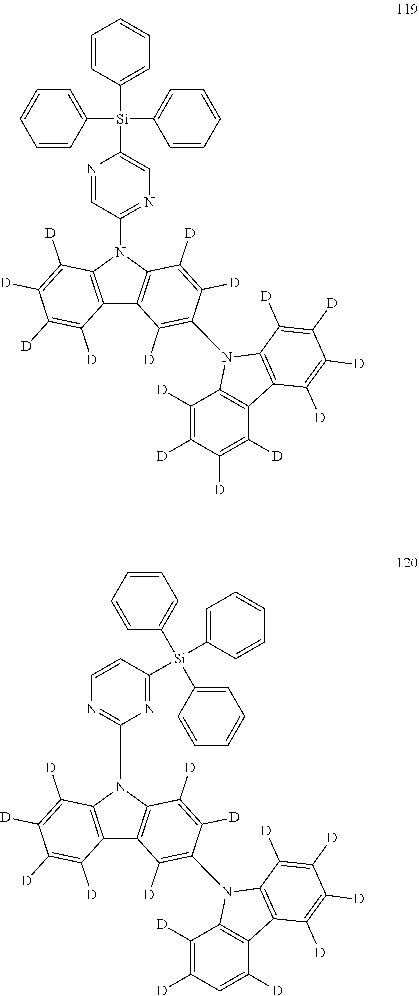 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cnc([Si](c2ccccc2)(c2ccccc2)c2ccccc2)cn1 ; [2H]c1cc([2H])c2c3c([2H])c([2H])c([2H])c([2H])c3n(-c3c([2H])c([2H])c4c(c3[2H])c3c([2H])c([2H])c([2H])c([2H])c3n4-c3nccc([Si](c4ccccc4)(c4ccccc4)c4ccccc4)n3)c2c1[2H]]

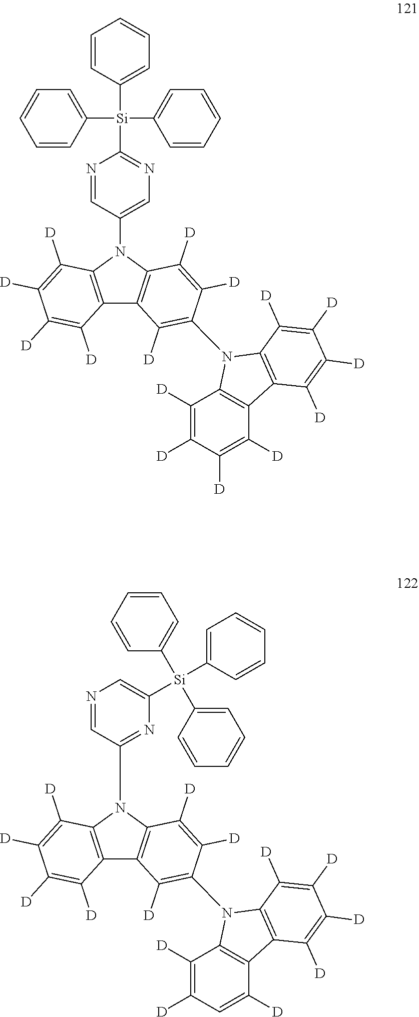 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cnc([Si](c2ccccc2)(c2ccccc2)c2ccccc2)nc1 ; [2H]c1cc([2H])c2c3c([2H])c([2H])c([2H])c([2H])c3n(-c3c([2H])c([2H])c4c(c3[2H])c3c([2H])c([2H])c([2H])c([2H])c3n4-c3cncc([Si](c4ccccc4)(c4ccccc4)c4ccccc4)n3)c2c1[2H]]

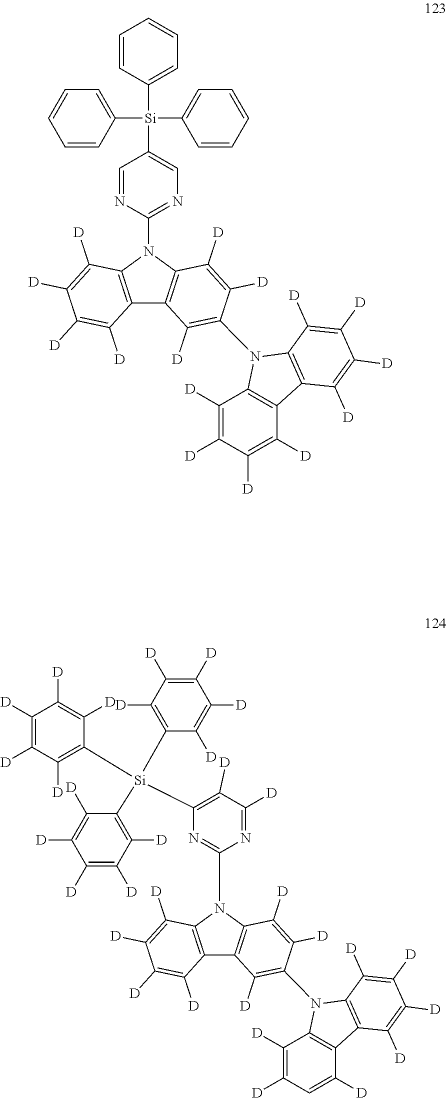 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ncc([Si](c2ccccc2)(c2ccccc2)c2ccccc2)cn1 ; [2H]c1cc([2H])c2c3c([2H])c([2H])c([2H])c([2H])c3n(-c3c([2H])c([2H])c4c(c3[2H])c3c([2H])c([2H])c([2H])c([2H])c3n4-c3nc([2H])c([2H])c([Si](c4c([2H])c([2H])c([2H])c([2H])c4[2H])(c4c([2H])c([2H])c([2H])c([2H])c4[2H])c4c([2H])c([2H])c([2H])c([2H])c4[2H])n3)c2c1[2H]]

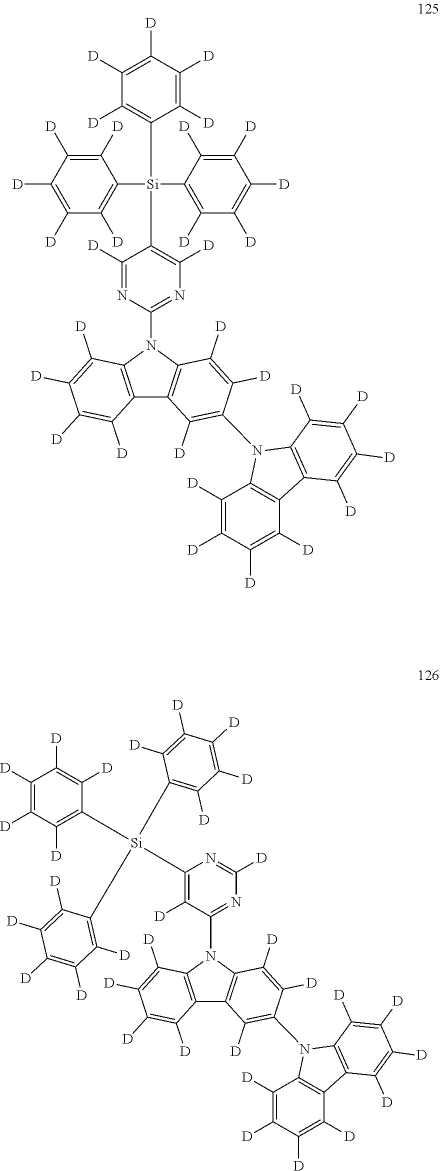

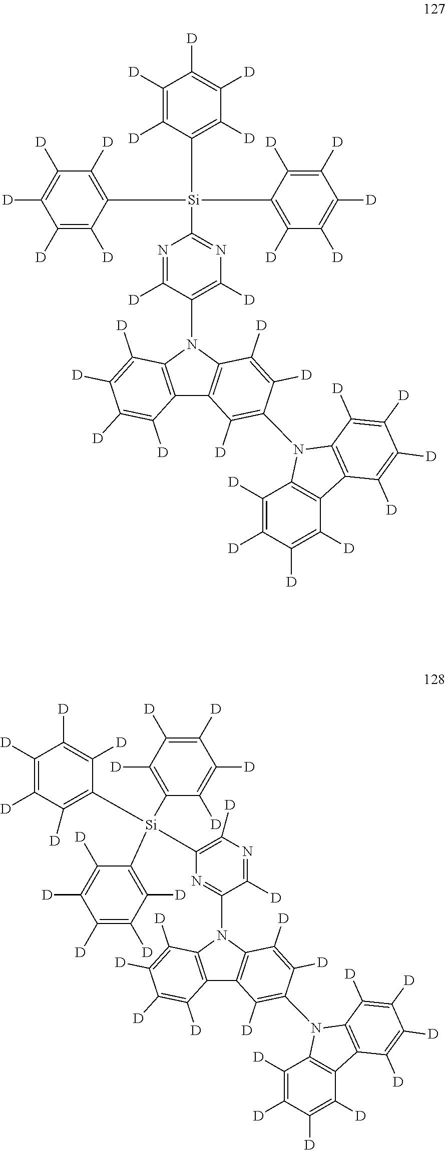

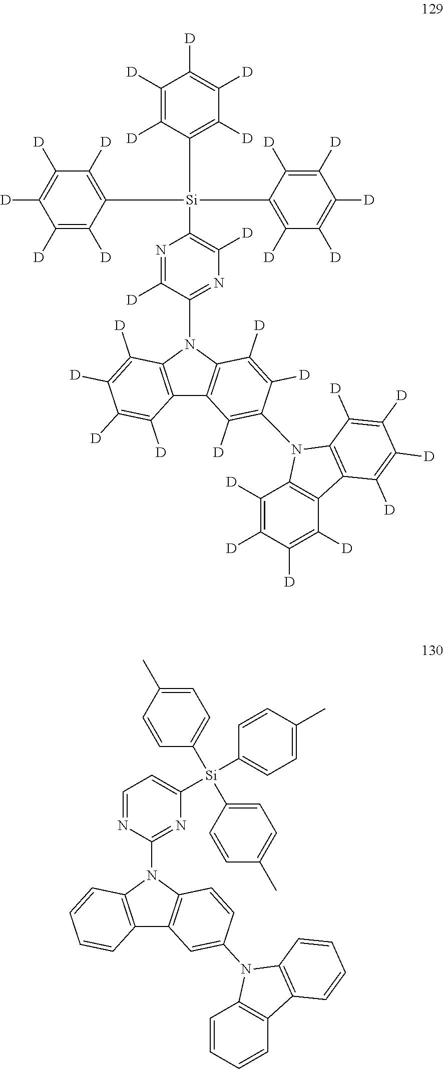 [SMILES: [2H]c1nc([Si](c2c([2H])c([2H])c([2H])c([2H])c2[2H])(c2c([2H])c([2H])c([2H])c([2H])c2[2H])c2c([2H])c([2H])c([2H])c([2H])c2[2H])c([2H])nc1-n1c2c([2H])c([2H])c([2H])c([2H])c2c2c([2H])c(-n3c4c([2H])c([2H])c([2H])c([2H])c4c4c([2H])c([2H])c([2H])c([2H])c43)c([2H])c([2H])c21 ; Cc1ccc([Si](c2ccc(C)cc2)(c2ccc(C)cc2)c2ccnc(-n3c4ccccc4c4cc(-n5c6ccccc6c6ccccc65)ccc43)n2)cc1]

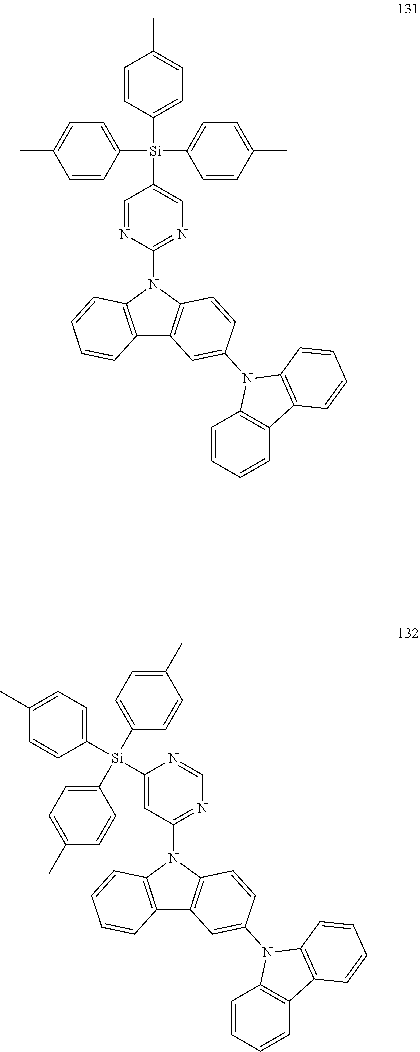 [SMILES: Cc1ccc([Si](c2ccc(C)cc2)(c2ccc(C)cc2)c2cnc(-n3c4ccccc4c4cc(-n5c6ccccc6c6ccccc65)ccc43)nc2)cc1 ; Cc1ccc([Si](c2ccc(C)cc2)(c2ccc(C)cc2)c2cc(-n3c4ccccc4c4cc(-n5c6ccccc6c6ccccc65)ccc43)ncn2)cc1]

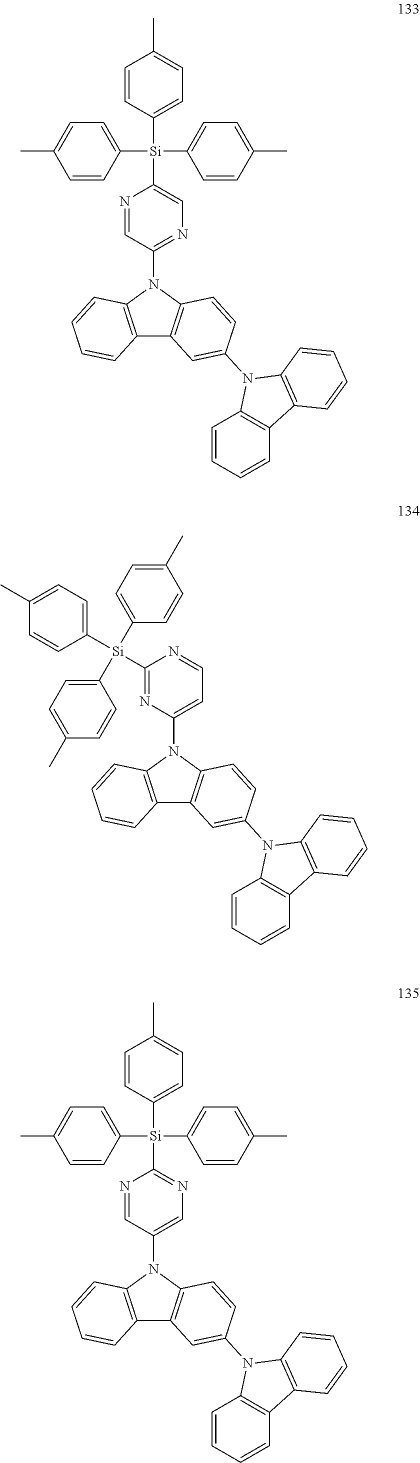 [SMILES: Cc1ccc([Si](c2ccc(C)cc2)(c2ccc(C)cc2)c2cnc(-n3c4ccccc4c4cc(-n5c6ccccc6c6ccccc65)ccc43)cn2)cc1 ; Cc1ccc([Si](c2ccc(C)cc2)(c2ccc(C)cc2)c2nccc(-n3c4ccccc4c4cc(-n5c6ccccc6c6ccccc65)ccc43)n2)cc1 ; Cc1ccc([Si](c2ccc(C)cc2)(c2ccc(C)cc2)c2ncc(-n3c4ccccc4c4cc(-n5c6ccccc6c6ccccc65)ccc43)cn2)cc1]

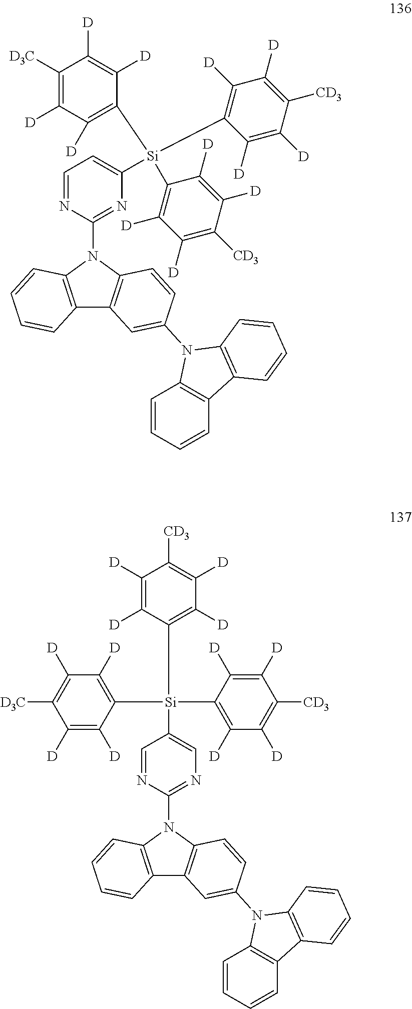 [SMILES: [2H]c1c([2H])c([Si](c2ccnc(-n3c4ccccc4c4cc(-n5c6ccccc6c6ccccc65)ccc43)n2)(c2c([2H])c([2H])c(C([2H])([2H])[2H])c([2H])c2[2H])c2c([2H])c([2H])c(C([2H])([2H])[2H])c([2H])c2[2H])c([2H])c([2H])c1C([2H])([2H])[2H] ; [2H]c1c([2H])c([Si](c2cnc(-n3c4ccccc4c4cc(-n5c6ccccc6c6ccccc65)ccc43)nc2)(c2c([2H])c([2H])c(C([2H])([2H])[2H])c([2H])c2[2H])c2c([2H])c([2H])c(C([2H])([2H])[2H])c([2H])c2[2H])c([2H])c([2H])c1C([2H])([2H])[2H]]

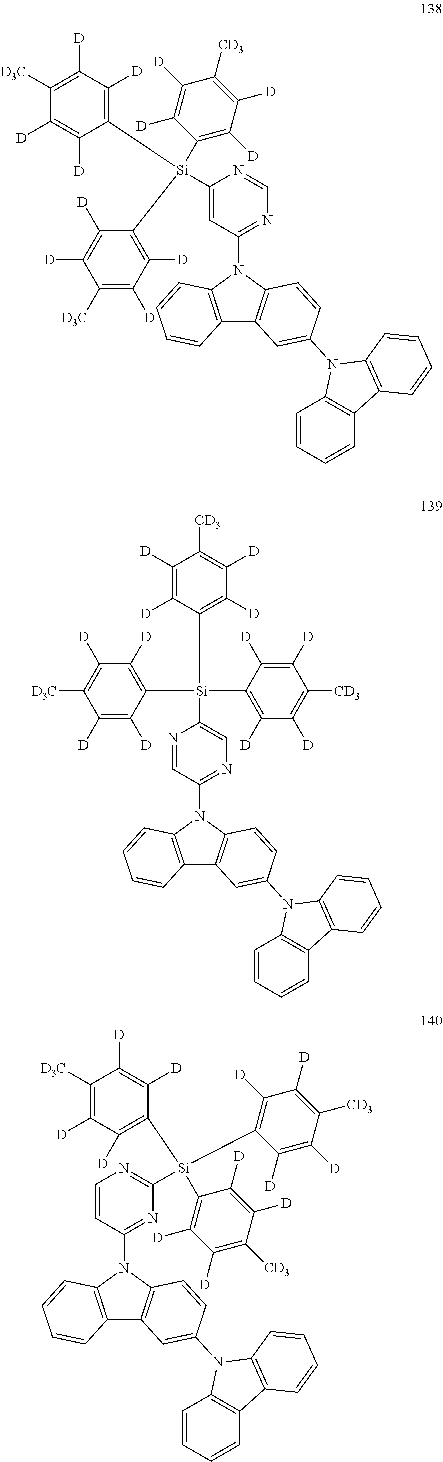

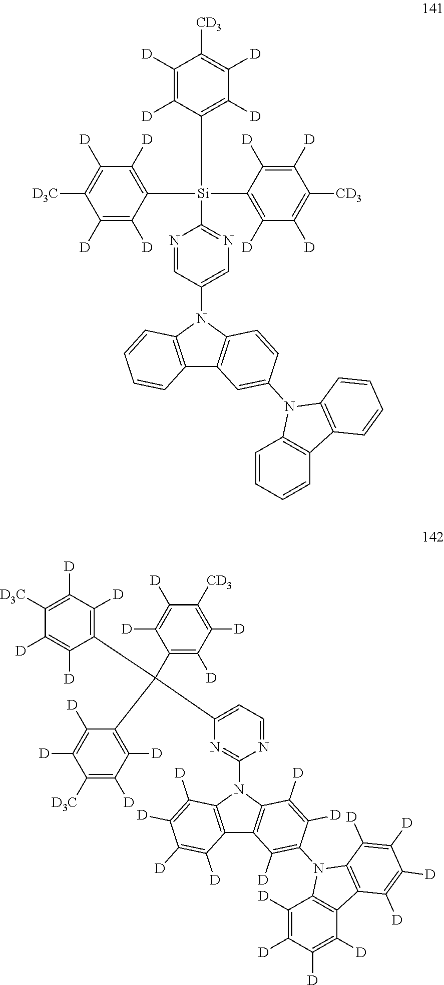

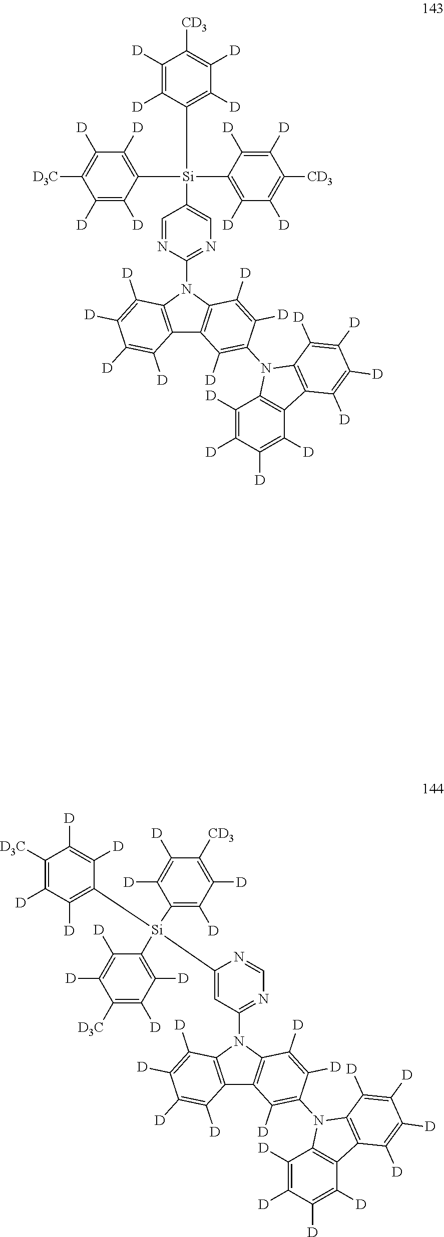

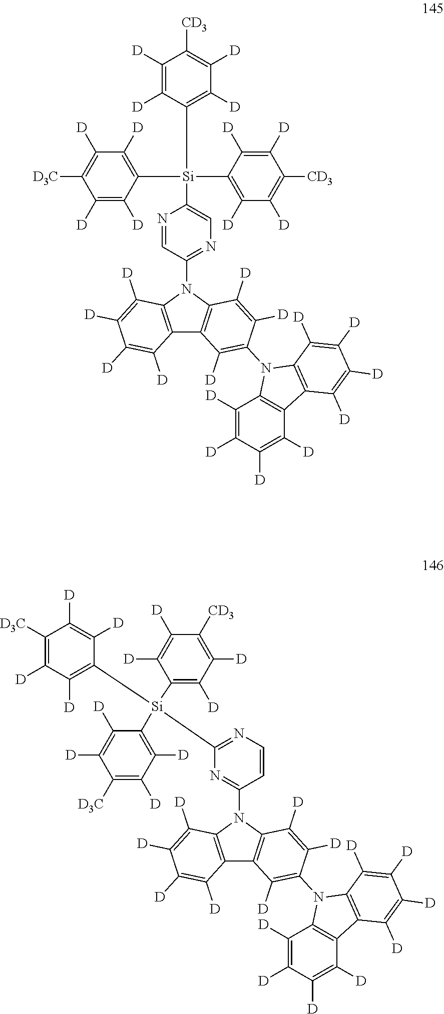

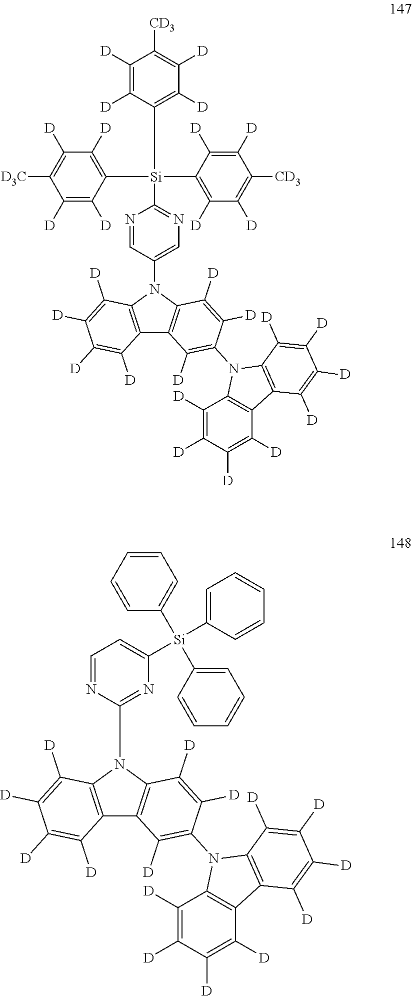 [SMILES: [2H]c1c([2H])c([Si](c2ncc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)cn2)(c2c([2H])c([2H])c(C([2H])([2H])[2H])c([2H])c2[2H])c2c([2H])c([2H])c(C([2H])([2H])[2H])c([2H])c2[2H])c([2H])c([2H])c1C([2H])([2H])[2H] ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1nccc([Si](c2ccccc2)(c2ccccc2)c2ccccc2)n1]

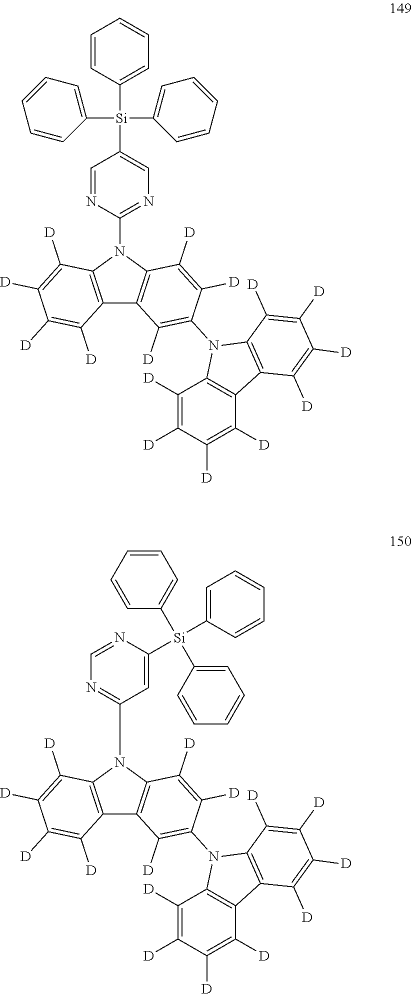 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ncc([Si](c2ccccc2)(c2ccccc2)c2ccccc2)cn1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cc([Si](c2ccccc2)(c2ccccc2)c2ccccc2)ncn1]

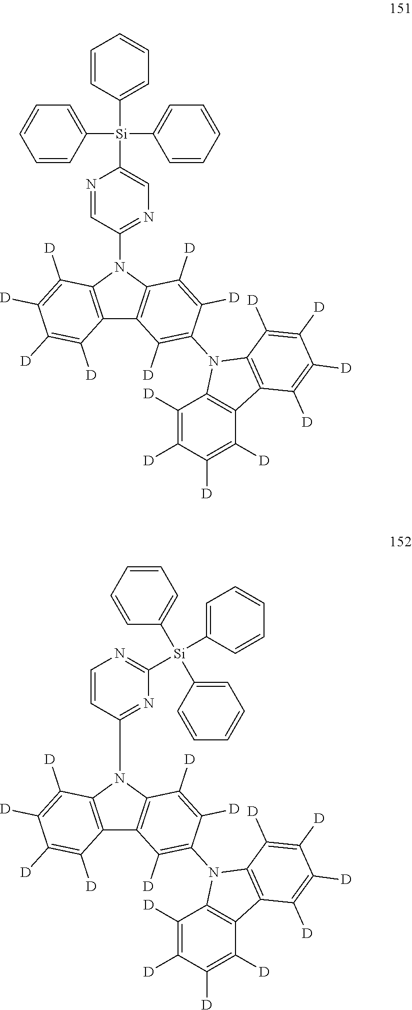 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cnc([Si](c2ccccc2)(c2ccccc2)c2ccccc2)cn1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccnc([Si](c2ccccc2)(c2ccccc2)c2ccccc2)n1]

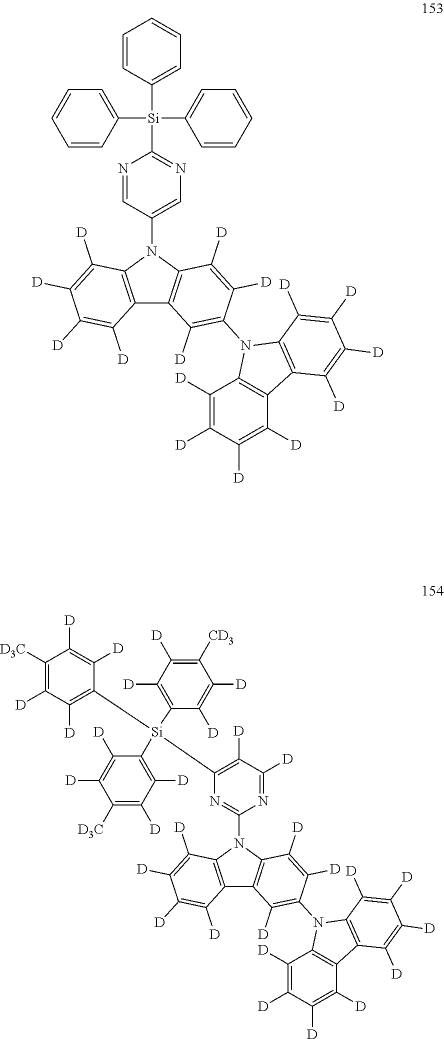 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cnc([Si](c2ccccc2)(c2ccccc2)c2ccccc2)nc1 ; [2H]c1nc(-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)nc([Si](c2c([2H])c([2H])c(C([2H])([2H])[2H])c([2H])c2[2H])(c2c([2H])c([2H])c(C([2H])([2H])[2H])c([2H])c2[2H])c2c([2H])c([2H])c(C([2H])([2H])[2H])c([2H])c2[2H])c1[2H]]

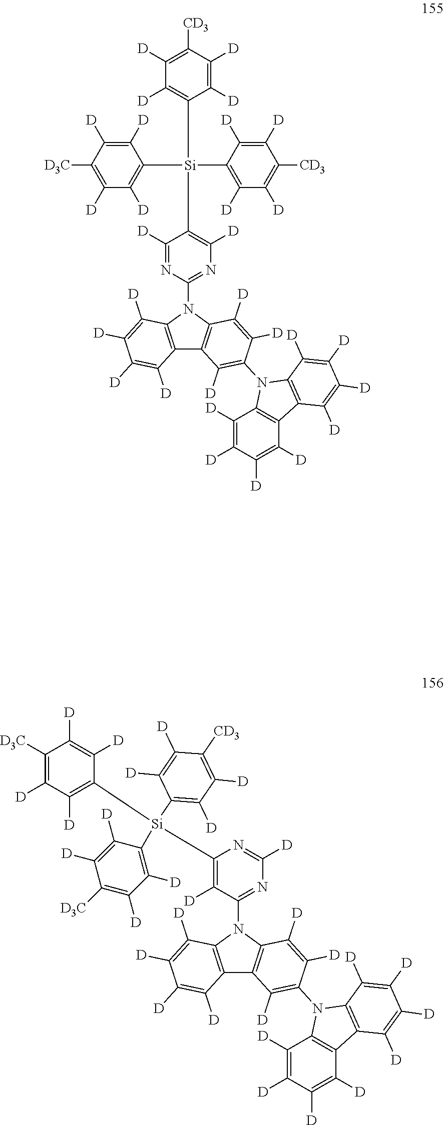

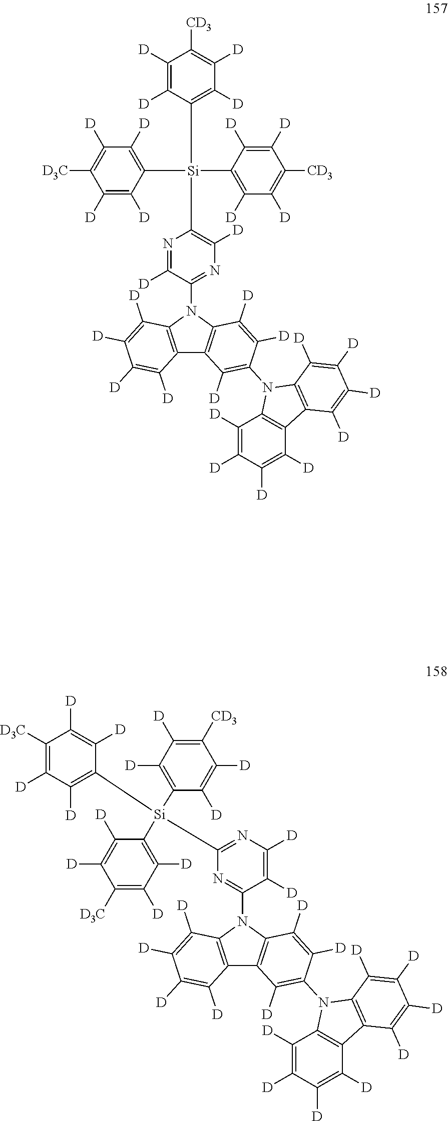

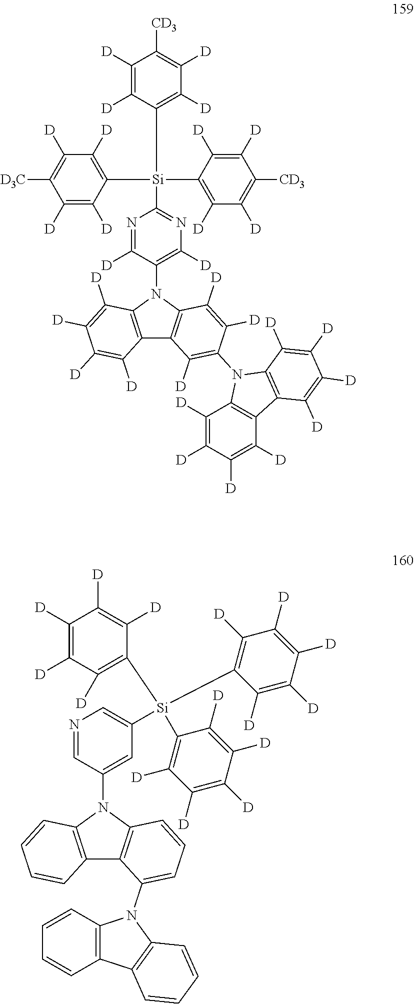 [SMILES: [2H]c1nc([Si](c2c([2H])c([2H])c(C([2H])([2H])[2H])c([2H])c2[2H])(c2c([2H])c([2H])c(C([2H])([2H])[2H])c([2H])c2[2H])c2c([2H])c([2H])c(C([2H])([2H])[2H])c([2H])c2[2H])nc([2H])c1-n1c2c([2H])c([2H])c([2H])c([2H])c2c2c([2H])c(-n3c4c([2H])c([2H])c([2H])c([2H])c4c4c([2H])c([2H])c([2H])c([2H])c43)c([2H])c([2H])c21 ; [2H]c1c([2H])c([2H])c([Si](c2cncc(-n3c4ccccc4c4c(-n5c6ccccc6c6ccccc65)cccc43)c2)(c2c([2H])c([2H])c([2H])c([2H])c2[2H])c2c([2H])c([2H])c([2H])c([2H])c2[2H])c([2H])c1[2H]]

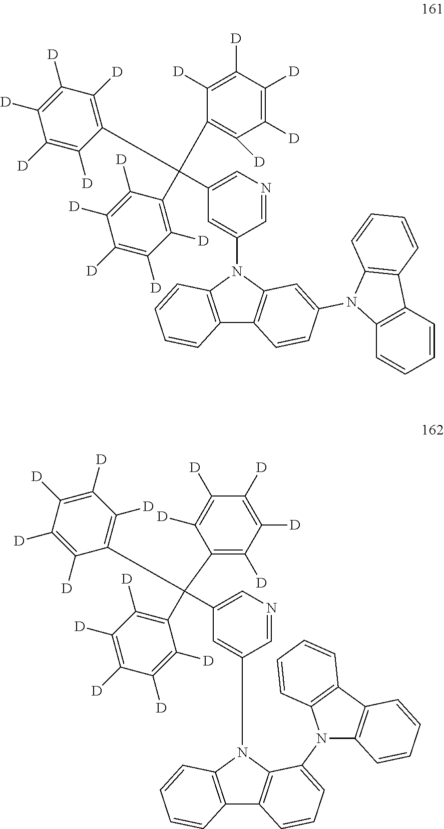 [SMILES: [2H]c1c([2H])c([2H])c(C(c2cncc(-n3c4ccccc4c4ccc(-n5c6ccccc6c6ccccc65)cc43)c2)(c2c([2H])c([2H])c([2H])c([2H])c2[2H])c2c([2H])c([2H])c([2H])c([2H])c2[2H])c([2H])c1[2H] ; [2H]c1c([2H])c([2H])c(C(c2cncc(-n3c4ccccc4c4cccc(-n5c6ccccc6c6ccccc65)c43)c2)(c2c([2H])c([2H])c([2H])c([2H])c2[2H])c2c([2H])c([2H])c([2H])c([2H])c2[2H])c([2H])c1[2H]]

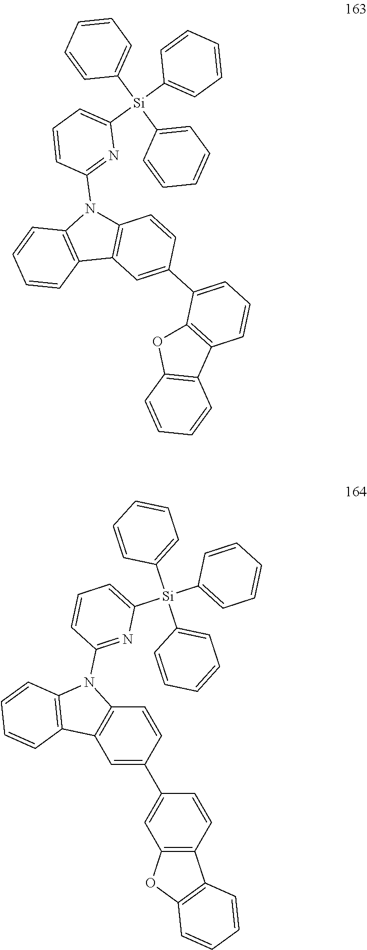 [SMILES: c1ccc([Si](c2ccccc2)(c2ccccc2)c2cccc(-n3c4ccccc4c4cc(-c5cccc6c5oc5ccccc56)ccc43)n2)cc1 ; c1ccc([Si](c2ccccc2)(c2ccccc2)c2cccc(-n3c4ccccc4c4cc(-c5ccc6c(c5)oc5ccccc56)ccc43)n2)cc1]

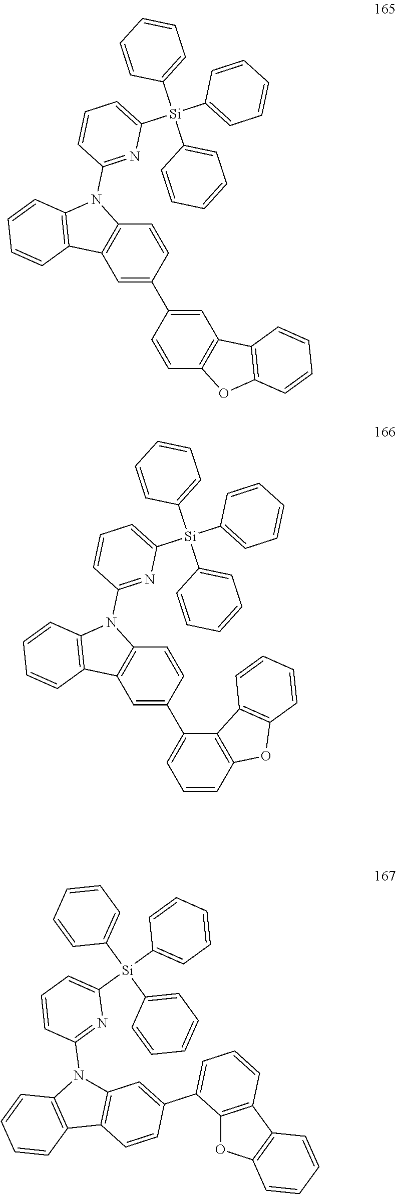 [SMILES: c1ccc([Si](c2ccccc2)(c2ccccc2)c2cccc(-n3c4ccccc4c4cc(-c5ccc6oc7ccccc7c6c5)ccc43)n2)cc1 ; c1ccc([Si](c2ccccc2)(c2ccccc2)c2cccc(-n3c4ccccc4c4cc(-c5cccc6oc7ccccc7c56)ccc43)n2)cc1 ; c1ccc([Si](c2ccccc2)(c2ccccc2)c2cccc(-n3c4ccccc4c4ccc(-c5cccc6c5oc5ccccc56)cc43)n2)cc1]

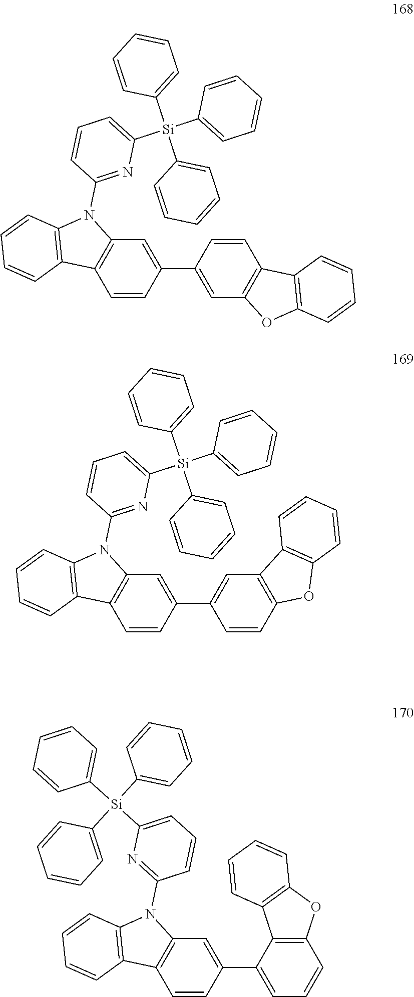 [SMILES: c1ccc([Si](c2ccccc2)(c2ccccc2)c2cccc(-n3c4ccccc4c4ccc(-c5ccc6c(c5)oc5ccccc56)cc43)n2)cc1 ; c1ccc([Si](c2ccccc2)(c2ccccc2)c2cccc(-n3c4ccccc4c4ccc(-c5ccc6oc7ccccc7c6c5)cc43)n2)cc1 ; c1ccc([Si](c2ccccc2)(c2ccccc2)c2cccc(-n3c4ccccc4c4ccc(-c5cccc6oc7ccccc7c56)cc43)n2)cc1]

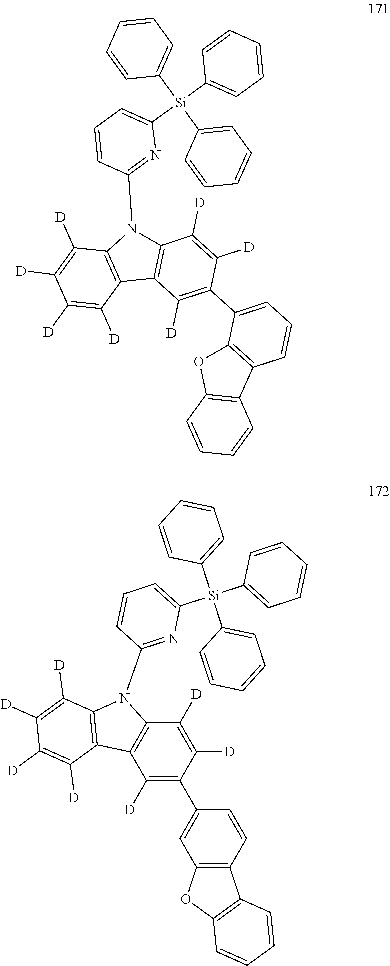 [SMILES: [2H]c1c([2H])c([2H])c2c(c1[2H])c1c([2H])c(-c3cccc4c3oc3ccccc34)c([2H])c([2H])c1n2-c1cccc([Si](c2ccccc2)(c2ccccc2)c2ccccc2)n1 ; [2H]c1c([2H])c([2H])c2c(c1[2H])c1c([2H])c(-c3ccc4c(c3)oc3ccccc34)c([2H])c([2H])c1n2-c1cccc([Si](c2ccccc2)(c2ccccc2)c2ccccc2)n1]

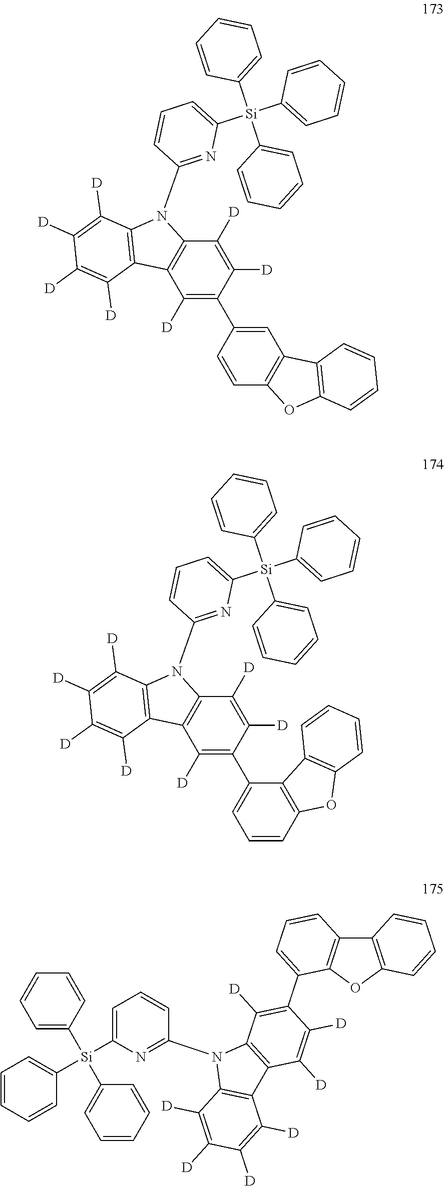 [SMILES: [2H]c1c([2H])c([2H])c2c(c1[2H])c1c([2H])c(-c3ccc4oc5ccccc5c4c3)c([2H])c([2H])c1n2-c1cccc([Si](c2ccccc2)(c2ccccc2)c2ccccc2)n1 ; [2H]c1c([2H])c([2H])c2c(c1[2H])c1c([2H])c(-c3cccc4oc5ccccc5c34)c([2H])c([2H])c1n2-c1cccc([Si](c2ccccc2)(c2ccccc2)c2ccccc2)n1 ; [2H]c1c([2H])c([2H])c2c(c1[2H])c1c([2H])c([2H])c(-c3cccc4c3oc3ccccc34)c([2H])c1n2-c1cccc([Si](c2ccccc2)(c2ccccc2)c2ccccc2)n1]

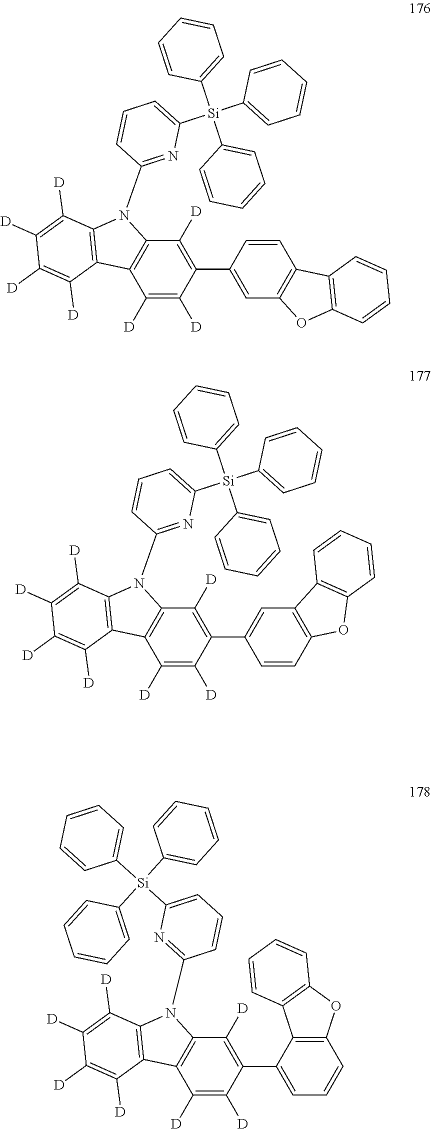 [SMILES: [2H]c1c([2H])c([2H])c2c(c1[2H])c1c([2H])c([2H])c(-c3ccc4c(c3)oc3ccccc34)c([2H])c1n2-c1cccc([Si](c2ccccc2)(c2ccccc2)c2ccccc2)n1 ; [2H]c1c([2H])c([2H])c2c(c1[2H])c1c([2H])c([2H])c(-c3ccc4oc5ccccc5c4c3)c([2H])c1n2-c1cccc([Si](c2ccccc2)(c2ccccc2)c2ccccc2)n1 ; [2H]c1c([2H])c([2H])c2c(c1[2H])c1c([2H])c([2H])c(-c3cccc4oc5ccccc5c34)c([2H])c1n2-c1cccc([Si](c2ccccc2)(c2ccccc2)c2ccccc2)n1]

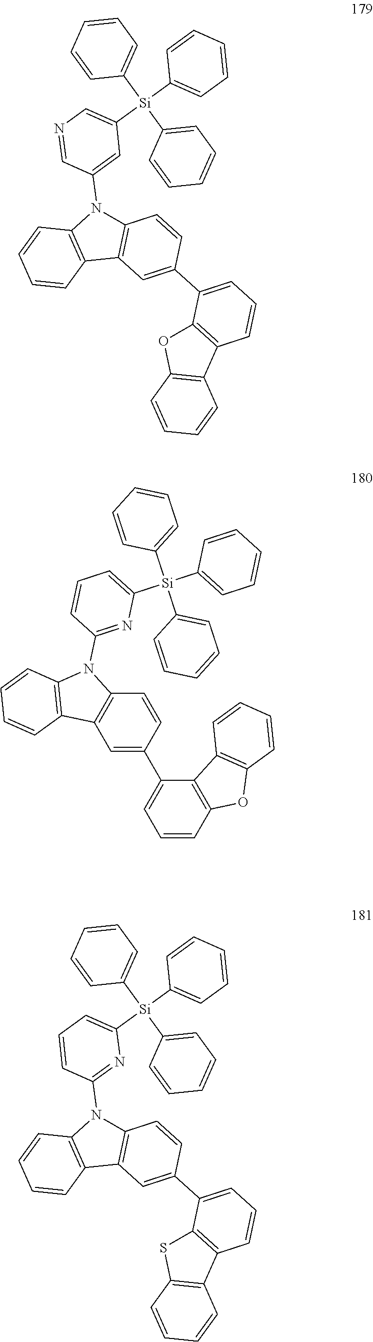 [SMILES: c1ccc([Si](c2ccccc2)(c2ccccc2)c2cncc(-n3c4ccccc4c4cc(-c5cccc6c5oc5ccccc56)ccc43)c2)cc1 ; c1ccc([Si](c2ccccc2)(c2ccccc2)c2cccc(-n3c4ccccc4c4cc(-c5cccc6oc7ccccc7c56)ccc43)n2)cc1 ; c1ccc([Si](c2ccccc2)(c2ccccc2)c2cccc(-n3c4ccccc4c4cc(-c5cccc6c5sc5ccccc56)ccc43)n2)cc1]

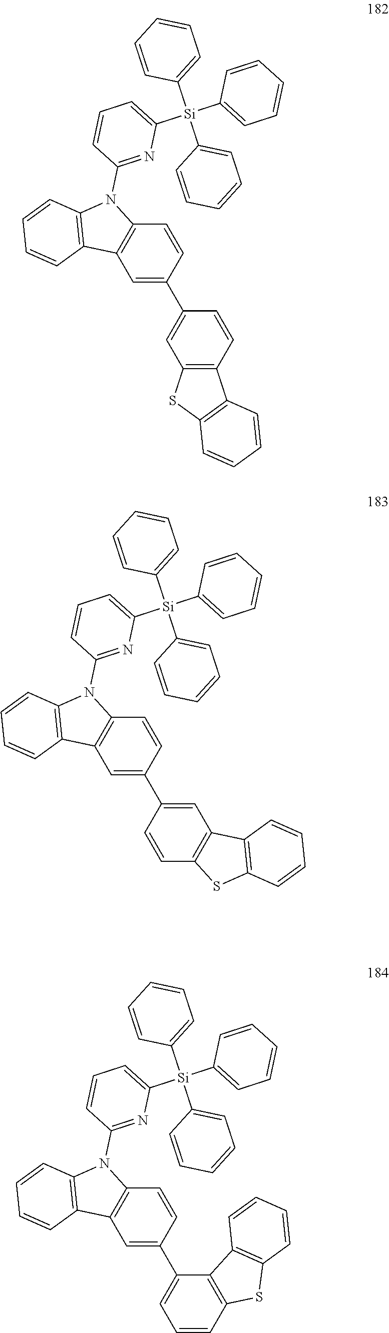 [SMILES: c1ccc([Si](c2ccccc2)(c2ccccc2)c2cccc(-n3c4ccccc4c4cc(-c5ccc6c(c5)sc5ccccc56)ccc43)n2)cc1 ; c1ccc([Si](c2ccccc2)(c2ccccc2)c2cccc(-n3c4ccccc4c4cc(-c5ccc6sc7ccccc7c6c5)ccc43)n2)cc1 ; c1ccc([Si](c2ccccc2)(c2ccccc2)c2cccc(-n3c4ccccc4c4cc(-c5cccc6sc7ccccc7c56)ccc43)n2)cc1]

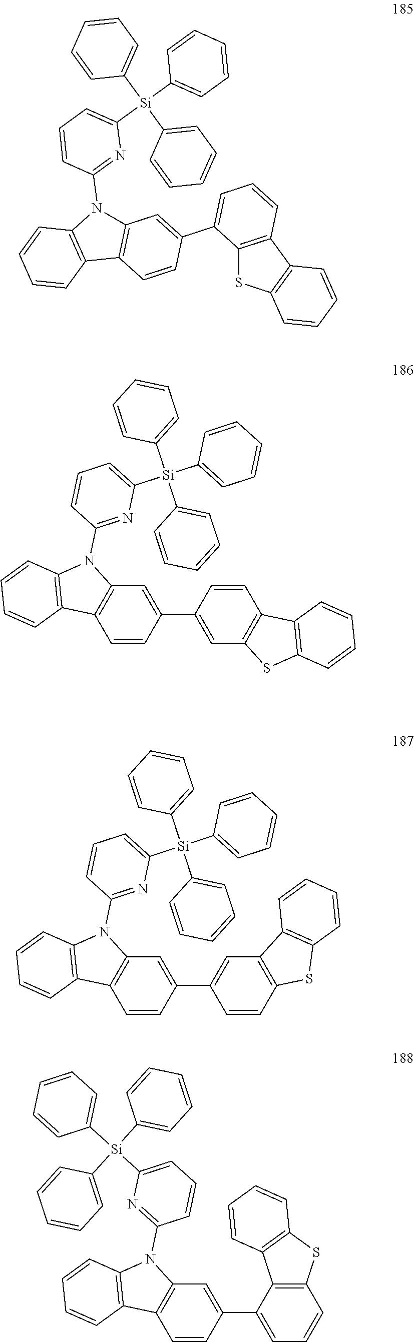 [SMILES: c1ccc([Si](c2ccccc2)(c2ccccc2)c2cccc(-n3c4ccccc4c4ccc(-c5cccc6c5sc5ccccc56)cc43)n2)cc1 ; c1ccc([Si](c2ccccc2)(c2ccccc2)c2cccc(-n3c4ccccc4c4ccc(-c5ccc6c(c5)sc5ccccc56)cc43)n2)cc1 ; c1ccc([Si](c2ccccc2)(c2ccccc2)c2cccc(-n3c4ccccc4c4ccc(-c5ccc6sc7ccccc7c6c5)cc43)n2)cc1 ; c1ccc([Si](c2ccccc2)(c2ccccc2)c2cccc(-n3c4ccccc4c4ccc(-c5cccc6sc7ccccc7c56)cc43)n2)cc1]

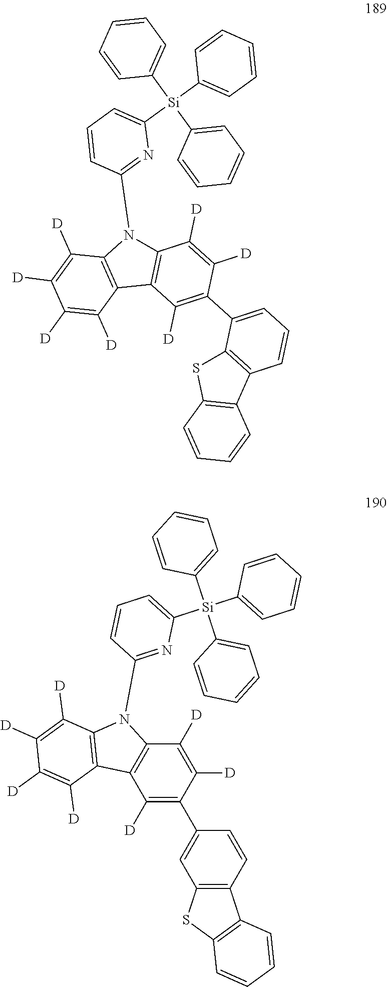 [SMILES: [2H]c1c([2H])c([2H])c2c(c1[2H])c1c([2H])c(-c3cccc4c3sc3ccccc34)c([2H])c([2H])c1n2-c1cccc([Si](c2ccccc2)(c2ccccc2)c2ccccc2)n1 ; [2H]c1c([2H])c([2H])c2c(c1[2H])c1c([2H])c(-c3ccc4c(c3)sc3ccccc34)c([2H])c([2H])c1n2-c1cccc([Si](c2ccccc2)(c2ccccc2)c2ccccc2)n1]

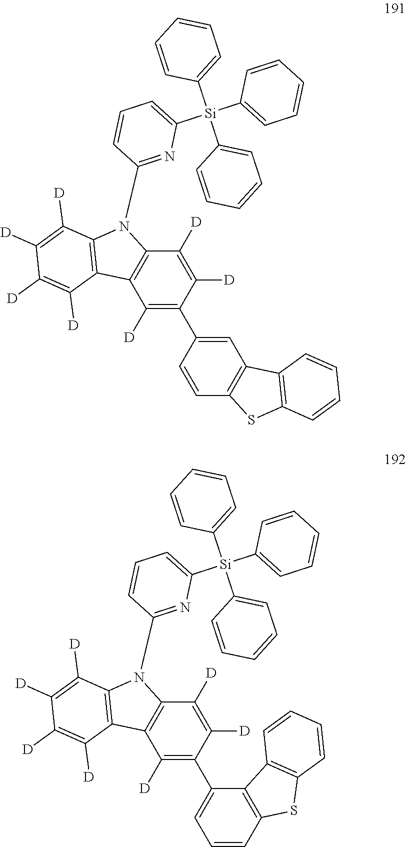 [SMILES: [2H]c1c([2H])c([2H])c2c(c1[2H])c1c([2H])c(-c3ccc4sc5ccccc5c4c3)c([2H])c([2H])c1n2-c1cccc([Si](c2ccccc2)(c2ccccc2)c2ccccc2)n1 ; [2H]c1c([2H])c([2H])c2c(c1[2H])c1c([2H])c(-c3cccc4sc5ccccc5c34)c([2H])c([2H])c1n2-c1cccc([Si](c2ccccc2)(c2ccccc2)c2ccccc2)n1]

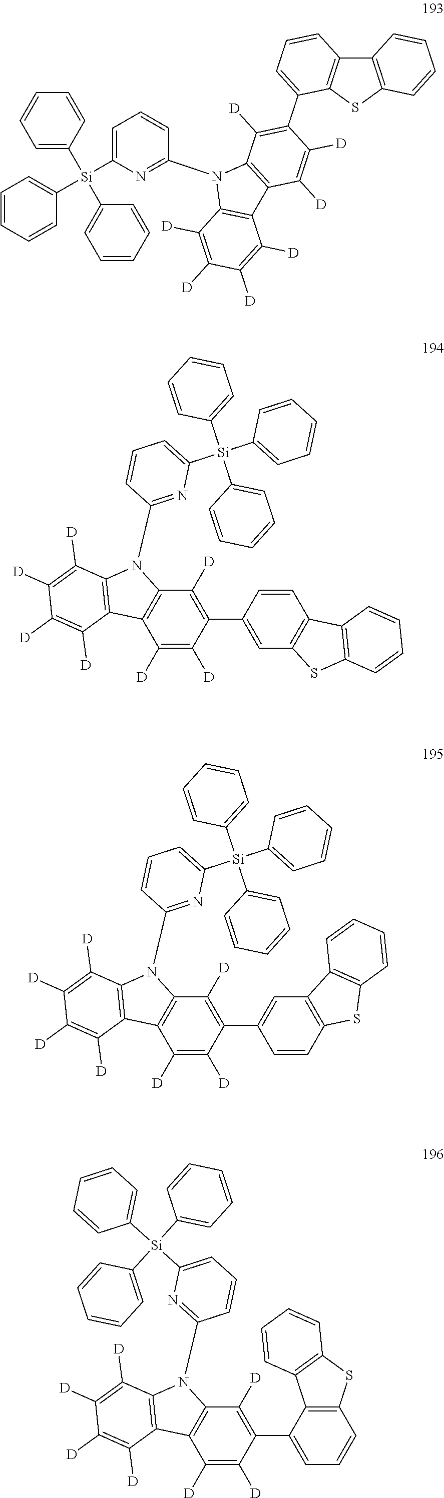

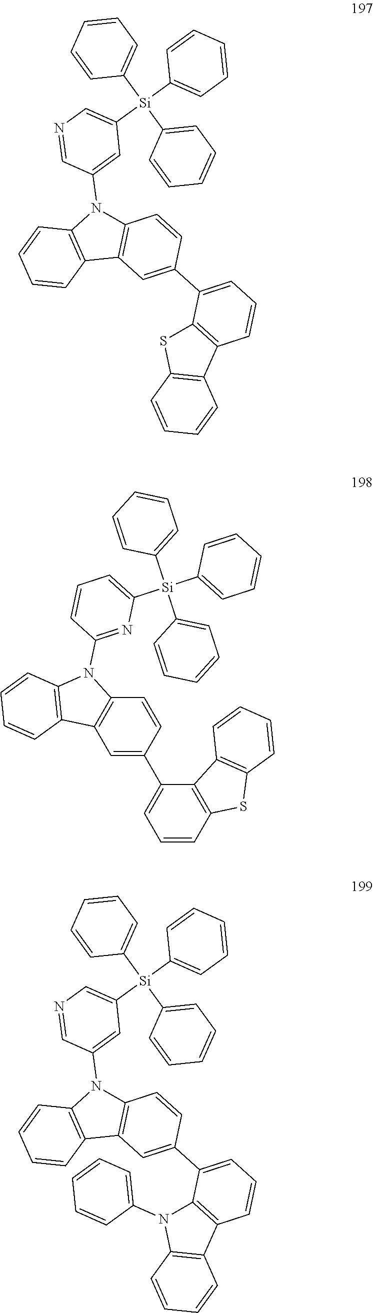 [SMILES: c1ccc([Si](c2ccccc2)(c2ccccc2)c2cncc(-n3c4ccccc4c4cc(-c5cccc6c5sc5ccccc56)ccc43)c2)cc1 ; c1ccc([Si](c2ccccc2)(c2ccccc2)c2cccc(-n3c4ccccc4c4cc(-c5cccc6sc7ccccc7c56)ccc43)n2)cc1 ; c1ccc(-n2c3ccccc3c3cccc(-c4ccc5c(c4)c4ccccc4n5-c4cncc([Si](c5ccccc5)(c5ccccc5)c5ccccc5)c4)c32)cc1]

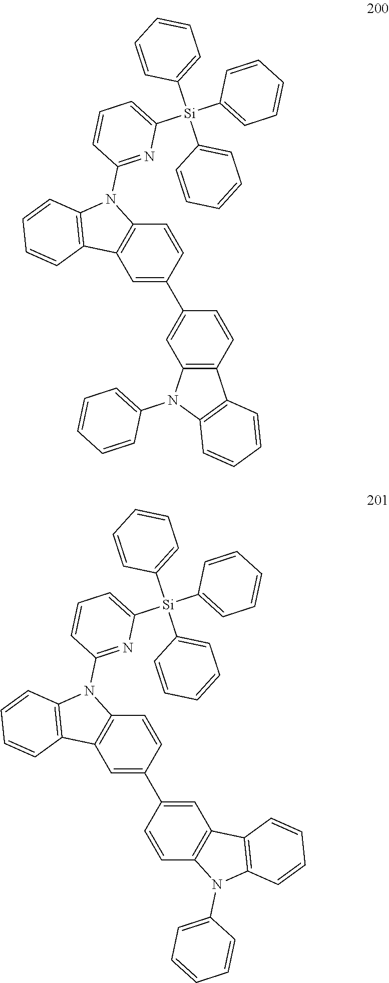 [SMILES: c1ccc(-n2c3ccccc3c3ccc(-c4ccc5c(c4)c4ccccc4n5-c4cccc([Si](c5ccccc5)(c5ccccc5)c5ccccc5)n4)cc32)cc1 ; c1ccc(-n2c3ccccc3c3cc(-c4ccc5c(c4)c4ccccc4n5-c4cccc([Si](c5ccccc5)(c5ccccc5)c5ccccc5)n4)ccc32)cc1]

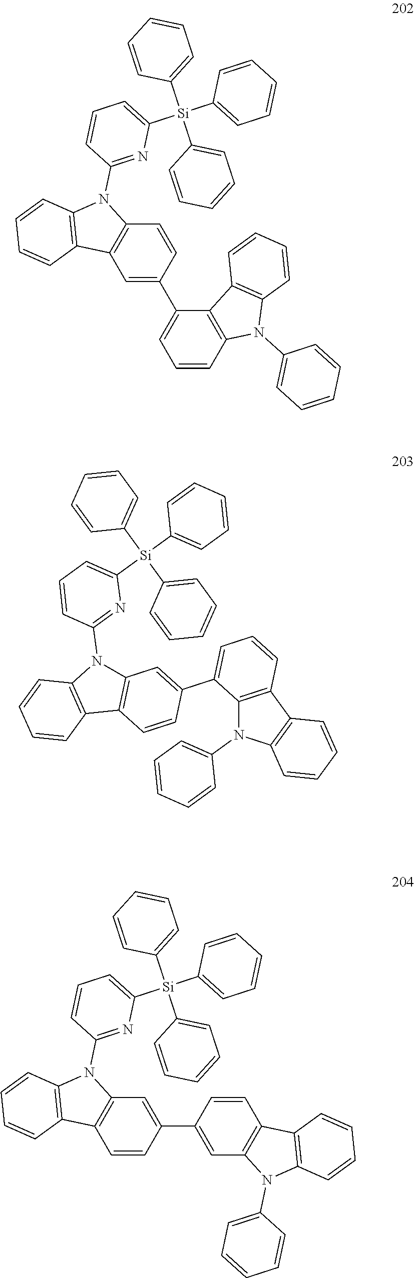 [SMILES: c1ccc(-n2c3ccccc3c3c(-c4ccc5c(c4)c4ccccc4n5-c4cccc([Si](c5ccccc5)(c5ccccc5)c5ccccc5)n4)cccc32)cc1 ; c1ccc(-n2c3ccccc3c3cccc(-c4ccc5c6ccccc6n(-c6cccc([Si](c7ccccc7)(c7ccccc7)c7ccccc7)n6)c5c4)c32)cc1 ; c1ccc(-n2c3ccccc3c3ccc(-c4ccc5c6ccccc6n(-c6cccc([Si](c7ccccc7)(c7ccccc7)c7ccccc7)n6)c5c4)cc32)cc1]

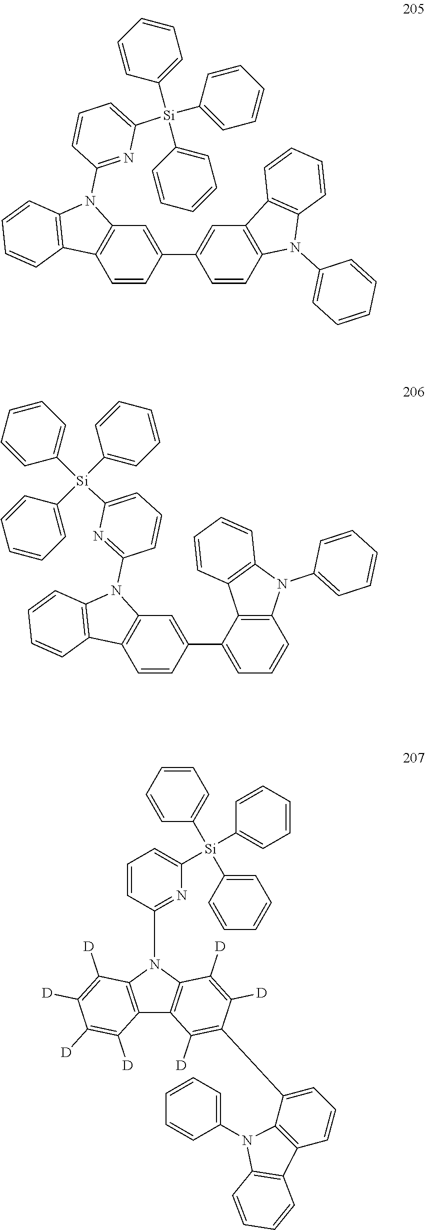 [SMILES: c1ccc(-n2c3ccccc3c3cc(-c4ccc5c6ccccc6n(-c6cccc([Si](c7ccccc7)(c7ccccc7)c7ccccc7)n6)c5c4)ccc32)cc1 ; c1ccc(-n2c3ccccc3c3c(-c4ccc5c6ccccc6n(-c6cccc([Si](c7ccccc7)(c7ccccc7)c7ccccc7)n6)c5c4)cccc32)cc1 ; [2H]c1c([2H])c([2H])c2c(c1[2H])c1c([2H])c(-c3cccc4c5ccccc5n(-c5ccccc5)c34)c([2H])c([2H])c1n2-c1cccc([Si](c2ccccc2)(c2ccccc2)c2ccccc2)n1]

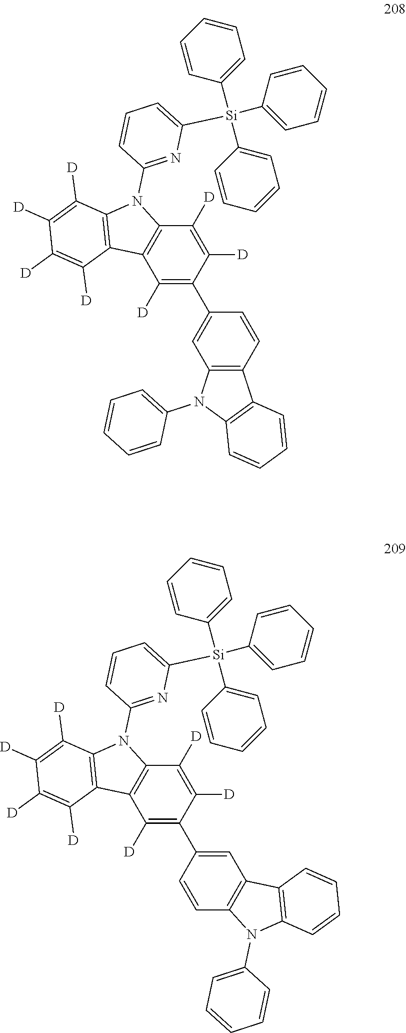 [SMILES: [2H]c1c([2H])c([2H])c2c(c1[2H])c1c([2H])c(-c3ccc4c5ccccc5n(-c5ccccc5)c4c3)c([2H])c([2H])c1n2-c1cccc([Si](c2ccccc2)(c2ccccc2)c2ccccc2)n1 ; [2H]c1c([2H])c([2H])c2c(c1[2H])c1c([2H])c(-c3ccc4c(c3)c3ccccc3n4-c3ccccc3)c([2H])c([2H])c1n2-c1cccc([Si](c2ccccc2)(c2ccccc2)c2ccccc2)n1]

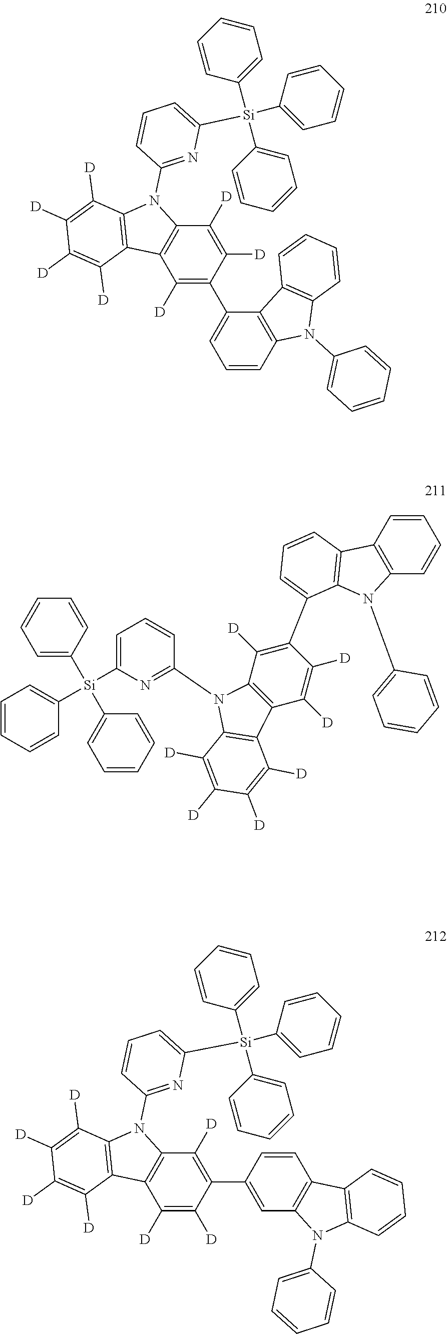 [SMILES: [2H]c1c([2H])c([2H])c2c(c1[2H])c1c([2H])c(-c3cccc4c3c3ccccc3n4-c3ccccc3)c([2H])c([2H])c1n2-c1cccc([Si](c2ccccc2)(c2ccccc2)c2ccccc2)n1 ; [2H]c1c([2H])c([2H])c2c(c1[2H])c1c([2H])c([2H])c(-c3cccc4c5ccccc5n(-c5ccccc5)c34)c([2H])c1n2-c1cccc([Si](c2ccccc2)(c2ccccc2)c2ccccc2)n1 ; [2H]c1c([2H])c([2H])c2c(c1[2H])c1c([2H])c([2H])c(-c3ccc4c5ccccc5n(-c5ccccc5)c4c3)c([2H])c1n2-c1cccc([Si](c2ccccc2)(c2ccccc2)c2ccccc2)n1]

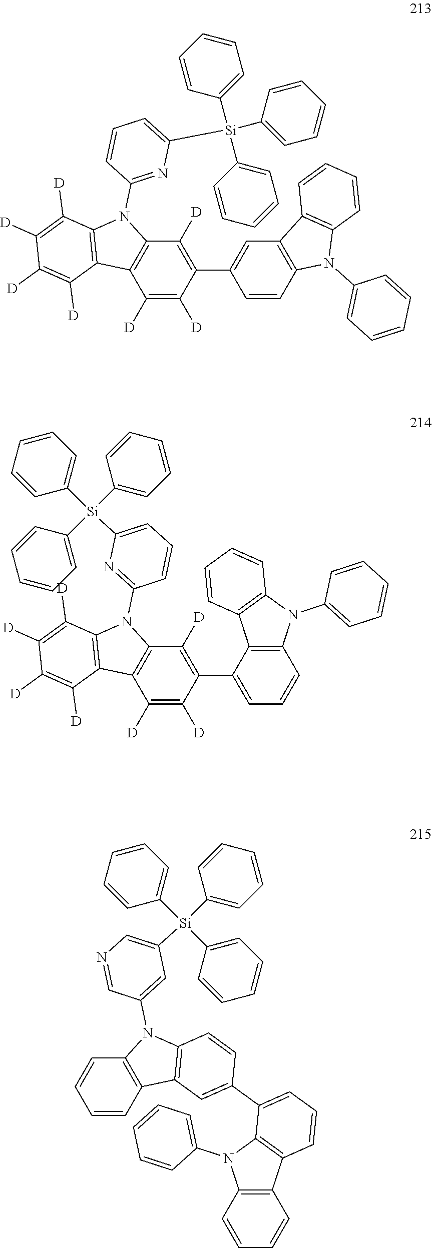 [SMILES: [2H]c1c([2H])c([2H])c2c(c1[2H])c1c([2H])c([2H])c(-c3ccc4c(c3)c3ccccc3n4-c3ccccc3)c([2H])c1n2-c1cccc([Si](c2ccccc2)(c2ccccc2)c2ccccc2)n1 ; [2H]c1c([2H])c([2H])c2c(c1[2H])c1c([2H])c([2H])c(-c3cccc4c3c3ccccc3n4-c3ccccc3)c([2H])c1n2-c1cccc([Si](c2ccccc2)(c2ccccc2)c2ccccc2)n1 ; c1ccc(-n2c3ccccc3c3cccc(-c4ccc5c(c4)c4ccccc4n5-c4cncc([Si](c5ccccc5)(c5ccccc5)c5ccccc5)c4)c32)cc1]

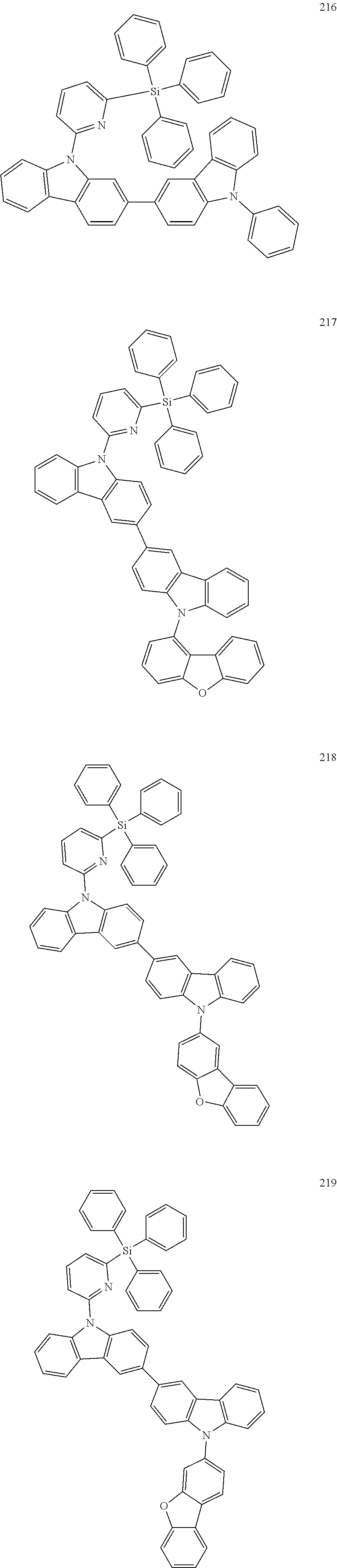 [SMILES: c1ccc(-n2c3ccccc3c3cc(-c4ccc5c6ccccc6n(-c6cccc([Si](c7ccccc7)(c7ccccc7)c7ccccc7)n6)c5c4)ccc32)cc1 ; c1ccc([Si](c2ccccc2)(c2ccccc2)c2cccc(-n3c4ccccc4c4cc(-c5ccc6c(c5)c5ccccc5n6-c5cccc6oc7ccccc7c56)ccc43)n2)cc1 ; c1ccc([Si](c2ccccc2)(c2ccccc2)c2cccc(-n3c4ccccc4c4cc(-c5ccc6c(c5)c5ccccc5n6-c5ccc6oc7ccccc7c6c5)ccc43)n2)cc1 ; c1ccc([Si](c2ccccc2)(c2ccccc2)c2cccc(-n3c4ccccc4c4cc(-c5ccc6c(c5)c5ccccc5n6-c5ccc6c(c5)oc5ccccc56)ccc43)n2)cc1]

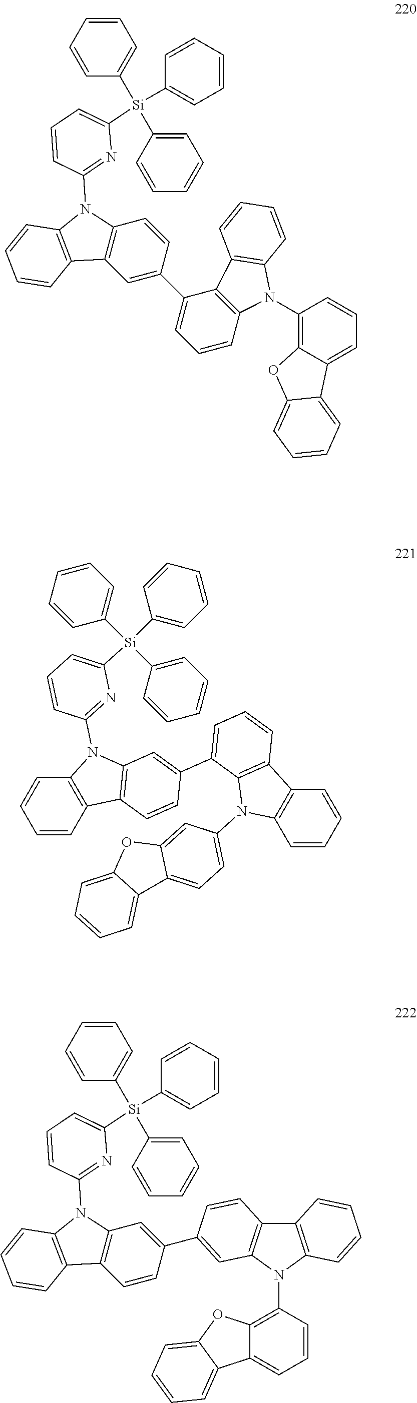 [SMILES: c1ccc([Si](c2ccccc2)(c2ccccc2)c2cccc(-n3c4ccccc4c4cc(-c5cccc6c5c5ccccc5n6-c5cccc6c5oc5ccccc56)ccc43)n2)cc1 ; c1ccc([Si](c2ccccc2)(c2ccccc2)c2cccc(-n3c4ccccc4c4ccc(-c5cccc6c7ccccc7n(-c7ccc8c(c7)oc7ccccc78)c56)cc43)n2)cc1 ; c1ccc([Si](c2ccccc2)(c2ccccc2)c2cccc(-n3c4ccccc4c4ccc(-c5ccc6c7ccccc7n(-c7cccc8c7oc7ccccc78)c6c5)cc43)n2)cc1]

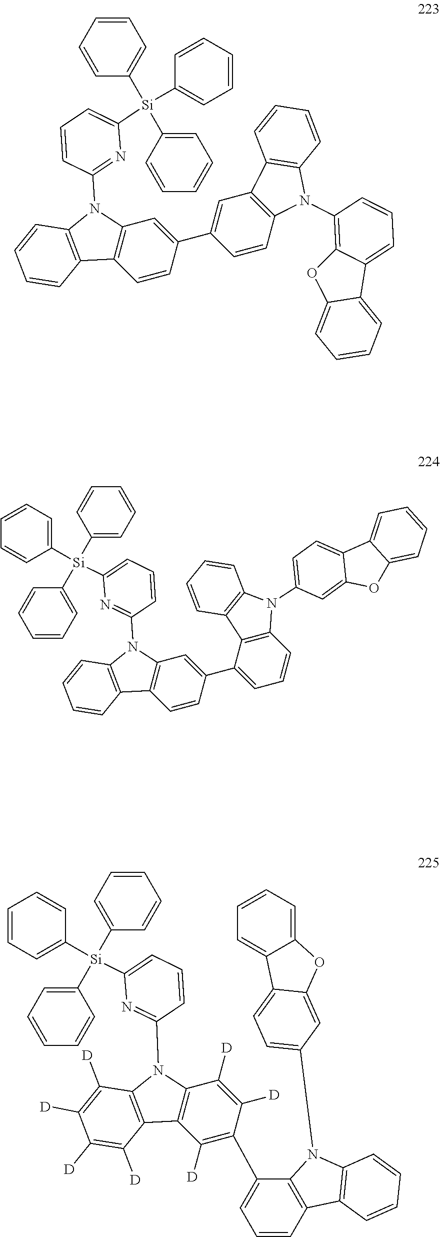 [SMILES: c1ccc([Si](c2ccccc2)(c2ccccc2)c2cccc(-n3c4ccccc4c4ccc(-c5ccc6c(c5)c5ccccc5n6-c5cccc6c5oc5ccccc56)cc43)n2)cc1 ; c1ccc([Si](c2ccccc2)(c2ccccc2)c2cccc(-n3c4ccccc4c4ccc(-c5cccc6c5c5ccccc5n6-c5ccc6c(c5)oc5ccccc56)cc43)n2)cc1 ; [2H]c1c([2H])c([2H])c2c(c1[2H])c1c([2H])c(-c3cccc4c5ccccc5n(-c5ccc6c(c5)oc5ccccc56)c34)c([2H])c([2H])c1n2-c1cccc([Si](c2ccccc2)(c2ccccc2)c2ccccc2)n1]

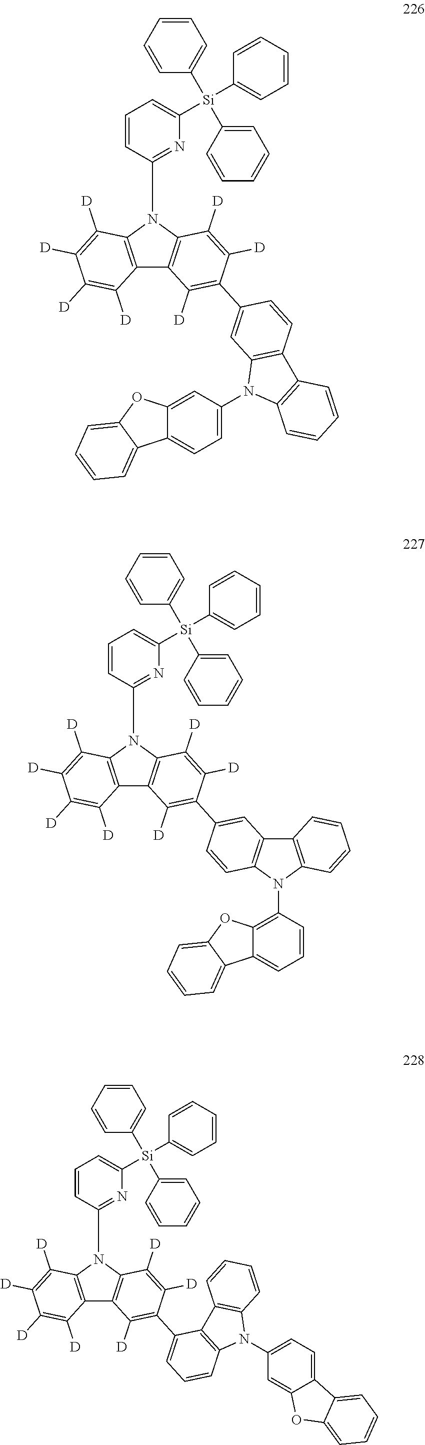 [SMILES: [2H]c1c([2H])c([2H])c2c(c1[2H])c1c([2H])c(-c3ccc4c5ccccc5n(-c5ccc6c(c5)oc5ccccc56)c4c3)c([2H])c([2H])c1n2-c1cccc([Si](c2ccccc2)(c2ccccc2)c2ccccc2)n1 ; [2H]c1c([2H])c([2H])c2c(c1[2H])c1c([2H])c(-c3ccc4c(c3)c3ccccc3n4-c3cccc4c3oc3ccccc34)c([2H])c([2H])c1n2-c1cccc([Si](c2ccccc2)(c2ccccc2)c2ccccc2)n1 ; [2H]c1c([2H])c([2H])c2c(c1[2H])c1c([2H])c(-c3cccc4c3c3ccccc3n4-c3ccc4c(c3)oc3ccccc34)c([2H])c([2H])c1n2-c1cccc([Si](c2ccccc2)(c2ccccc2)c2ccccc2)n1]

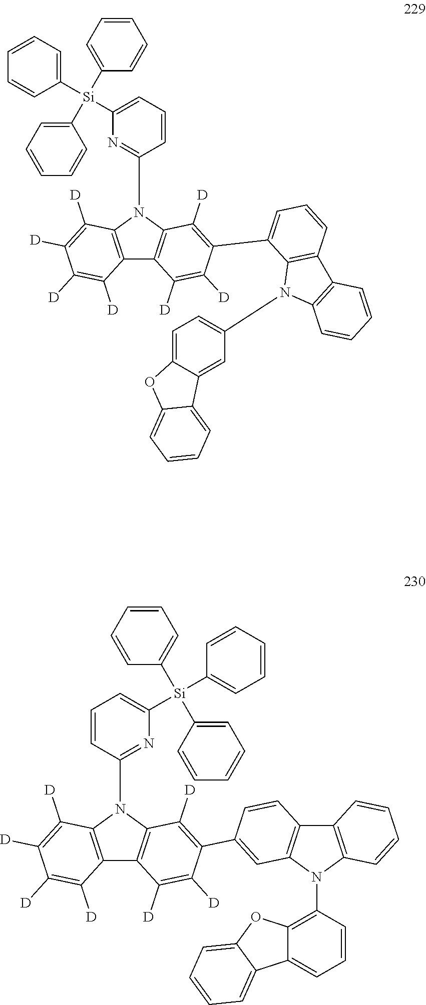 [SMILES: [2H]c1c([2H])c([2H])c2c(c1[2H])c1c([2H])c([2H])c(-c3cccc4c5ccccc5n(-c5ccc6oc7ccccc7c6c5)c34)c([2H])c1n2-c1cccc([Si](c2ccccc2)(c2ccccc2)c2ccccc2)n1 ; [2H]c1c([2H])c([2H])c2c(c1[2H])c1c([2H])c([2H])c(-c3ccc4c5ccccc5n(-c5cccc6c5oc5ccccc56)c4c3)c([2H])c1n2-c1cccc([Si](c2ccccc2)(c2ccccc2)c2ccccc2)n1]

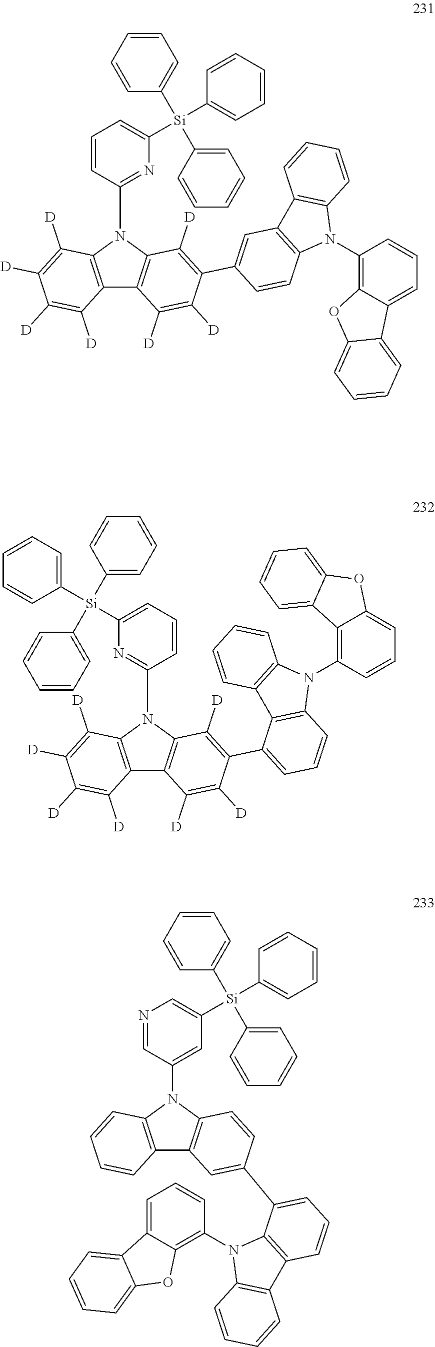 [SMILES: [2H]c1c([2H])c([2H])c2c(c1[2H])c1c([2H])c([2H])c(-c3ccc4c(c3)c3ccccc3n4-c3cccc4c3oc3ccccc34)c([2H])c1n2-c1cccc([Si](c2ccccc2)(c2ccccc2)c2ccccc2)n1 ; [2H]c1c([2H])c([2H])c2c(c1[2H])c1c([2H])c([2H])c(-c3cccc4c3c3ccccc3n4-c3cccc4oc5ccccc5c34)c([2H])c1n2-c1cccc([Si](c2ccccc2)(c2ccccc2)c2ccccc2)n1 ; c1ccc([Si](c2ccccc2)(c2ccccc2)c2cncc(-n3c4ccccc4c4cc(-c5cccc6c7ccccc7n(-c7cccc8c7oc7ccccc78)c56)ccc43)c2)cc1]

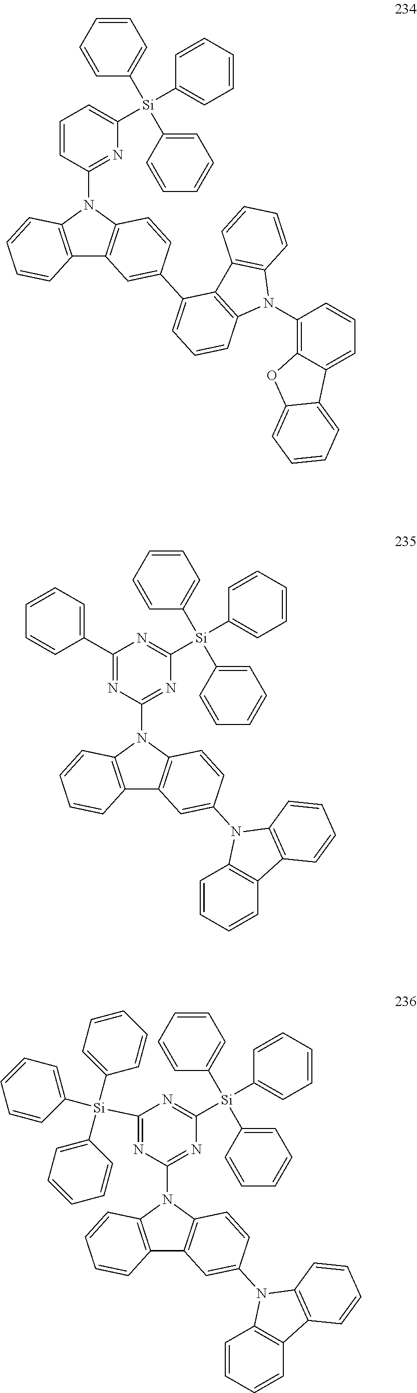 [SMILES: c1ccc([Si](c2ccccc2)(c2ccccc2)c2cccc(-n3c4ccccc4c4cc(-c5cccc6c5c5ccccc5n6-c5cccc6c5oc5ccccc56)ccc43)n2)cc1 ; c1ccc(-c2nc(-n3c4ccccc4c4cc(-n5c6ccccc6c6ccccc65)ccc43)nc([Si](c3ccccc3)(c3ccccc3)c3ccccc3)n2)cc1 ; c1ccc([Si](c2ccccc2)(c2ccccc2)c2nc(-n3c4ccccc4c4cc(-n5c6ccccc6c6ccccc65)ccc43)nc([Si](c3ccccc3)(c3ccccc3)c3ccccc3)n2)cc1]

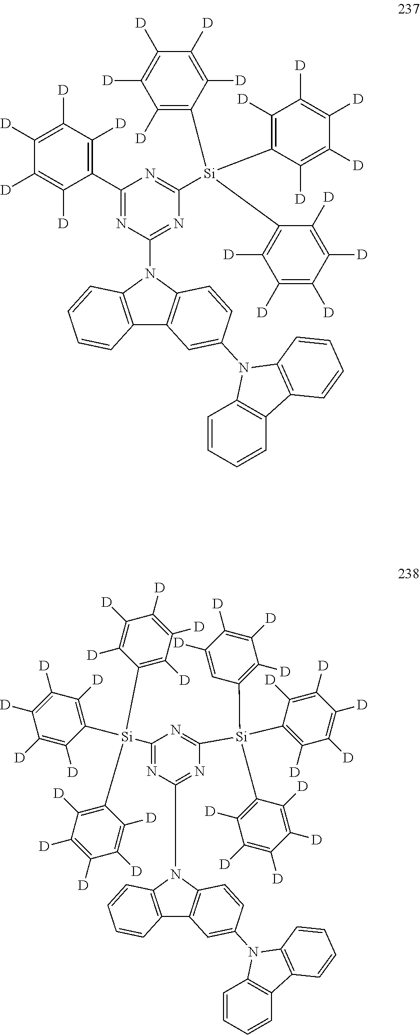 [SMILES: [2H]c1c([2H])c([2H])c(-c2nc(-n3c4ccccc4c4cc(-n5c6ccccc6c6ccccc65)ccc43)nc([Si](c3c([2H])c([2H])c([2H])c([2H])c3[2H])(c3c([2H])c([2H])c([2H])c([2H])c3[2H])c3c([2H])c([2H])c([2H])c([2H])c3[2H])n2)c([2H])c1[2H] ; [2H]c1cc([Si](c2nc(-n3c4ccccc4c4cc(-n5c6ccccc6c6ccccc65)ccc43)nc([Si](c3c([2H])c([2H])c([2H])c([2H])c3[2H])(c3c([2H])c([2H])c([2H])c([2H])c3[2H])c3c([2H])c([2H])c([2H])c([2H])c3[2H])n2)(c2c([2H])c([2H])c([2H])c([2H])c2[2H])c2c([2H])c([2H])c([2H])c([2H])c2[2H])c([2H])c([2H])c1[2H]]

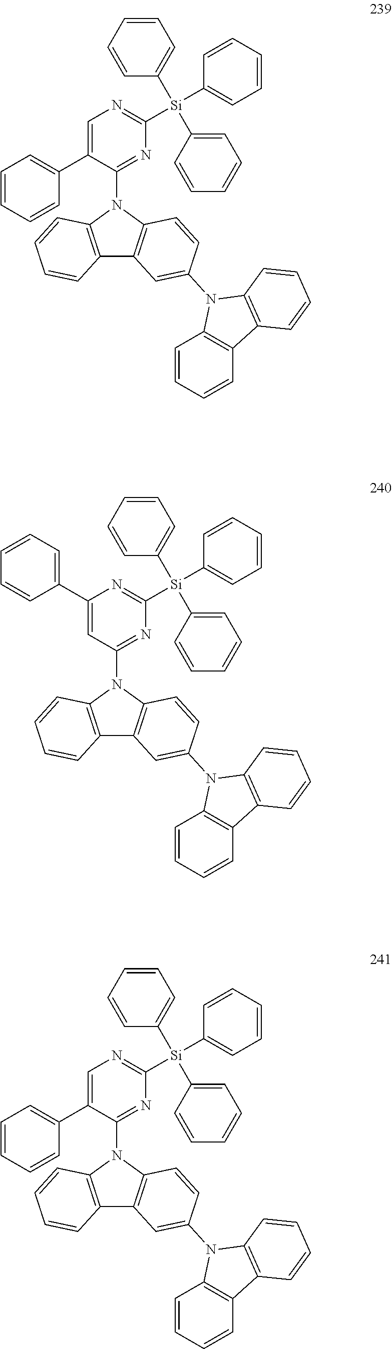 [SMILES: c1ccc(-c2cnc([Si](c3ccccc3)(c3ccccc3)c3ccccc3)nc2-n2c3ccccc3c3cc(-n4c5ccccc5c5ccccc54)ccc32)cc1 ; c1ccc(-c2cc(-n3c4ccccc4c4cc(-n5c6ccccc6c6ccccc65)ccc43)nc([Si](c3ccccc3)(c3ccccc3)c3ccccc3)n2)cc1 ; c1ccc(-c2cnc([Si](c3ccccc3)(c3ccccc3)c3ccccc3)nc2-n2c3ccccc3c3cc(-n4c5ccccc5c5ccccc54)ccc32)cc1]

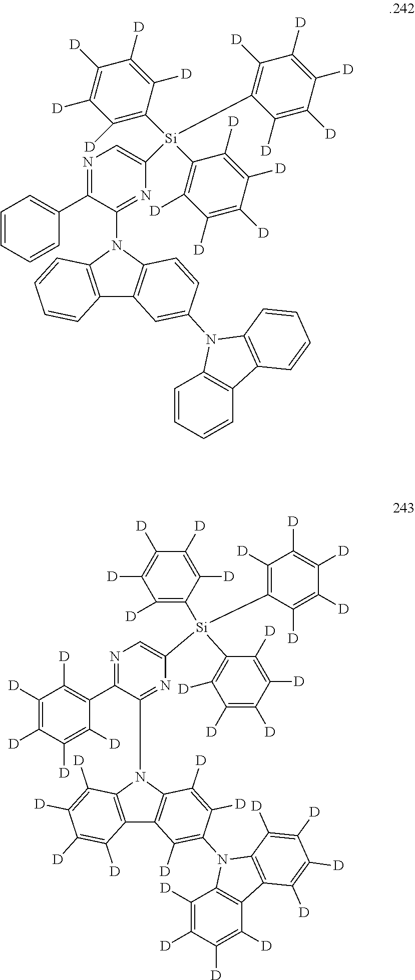 [SMILES: [2H]c1c([2H])c([2H])c([Si](c2cnc(-c3ccccc3)c(-n3c4ccccc4c4cc(-n5c6ccccc6c6ccccc65)ccc43)n2)(c2c([2H])c([2H])c([2H])c([2H])c2[2H])c2c([2H])c([2H])c([2H])c([2H])c2[2H])c([2H])c1[2H] ; [2H]c1c([2H])c([2H])c(-c2ncc([Si](c3c([2H])c([2H])c([2H])c([2H])c3[2H])(c3c([2H])c([2H])c([2H])c([2H])c3[2H])c3c([2H])c([2H])c([2H])c([2H])c3[2H])nc2-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)c([2H])c1[2H]]

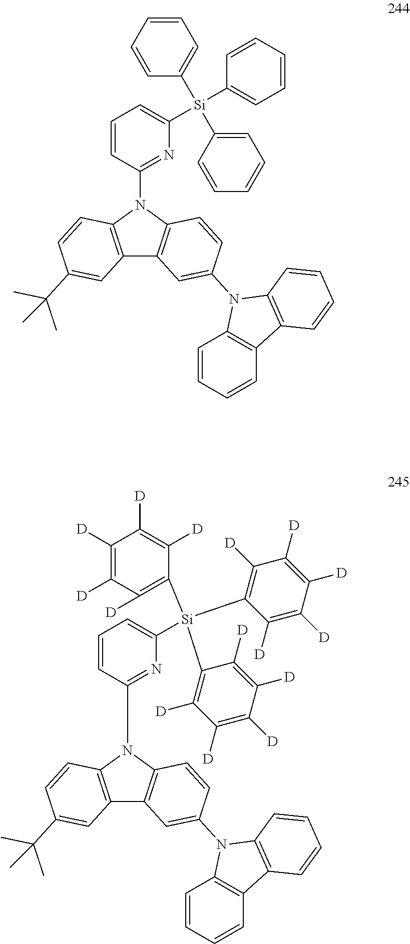 [SMILES: CC(C)(C)c1ccc2c(c1)c1cc(-n3c4ccccc4c4ccccc43)ccc1n2-c1cccc([Si](c2ccccc2)(c2ccccc2)c2ccccc2)n1 ; [2H]c1c([2H])c([2H])c([Si](c2cccc(-n3c4ccc(-n5c6ccccc6c6ccccc65)cc4c4cc(C(C)(C)C)ccc43)n2)(c2c([2H])c([2H])c([2H])c([2H])c2[2H])c2c([2H])c([2H])c([2H])c([2H])c2[2H])c([2H])c1[2H]]

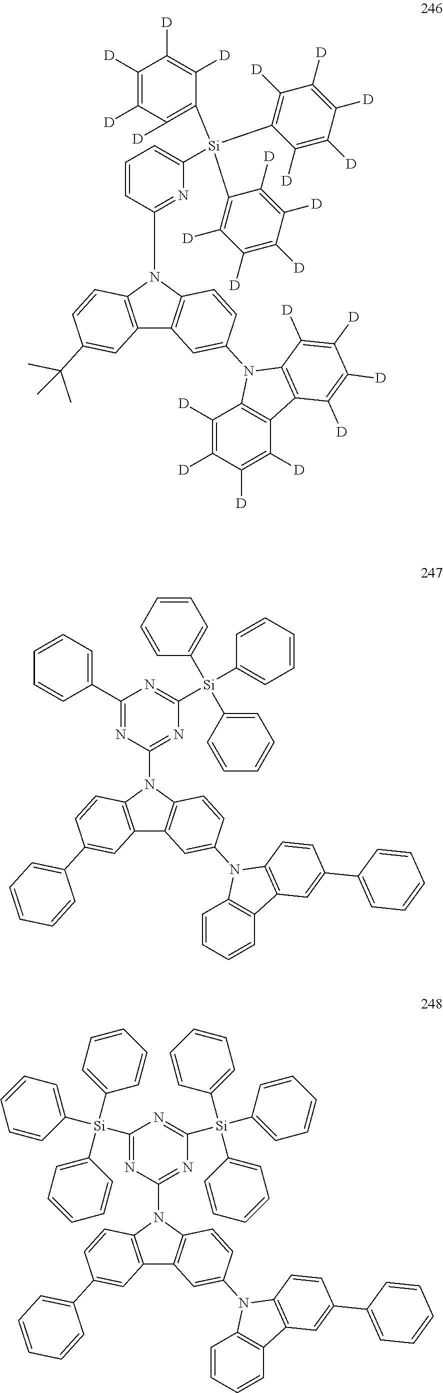 [SMILES: [2H]c1c([2H])c([2H])c([Si](c2cccc(-n3c4ccc(-n5c6c([2H])c([2H])c([2H])c([2H])c6c6c([2H])c([2H])c([2H])c([2H])c65)cc4c4cc(C(C)(C)C)ccc43)n2)(c2c([2H])c([2H])c([2H])c([2H])c2[2H])c2c([2H])c([2H])c([2H])c([2H])c2[2H])c([2H])c1[2H] ; c1ccc(-c2ccc3c(c2)c2ccccc2n3-c2ccc3c(c2)c2cc(-c4ccccc4)ccc2n3-c2nc(-c3ccccc3)nc([Si](c3ccccc3)(c3ccccc3)c3ccccc3)n2)cc1 ; c1ccc(-c2ccc3c(c2)c2ccccc2n3-c2ccc3c(c2)c2cc(-c4ccccc4)ccc2n3-c2nc([Si](c3ccccc3)(c3ccccc3)c3ccccc3)nc([Si](c3ccccc3)(c3ccccc3)c3ccccc3)n2)cc1]

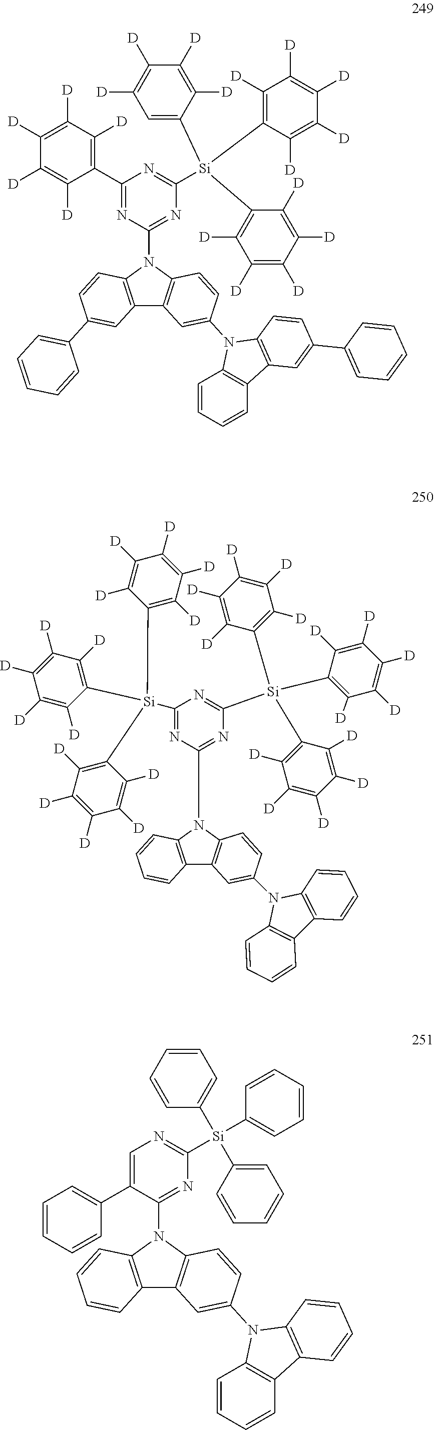

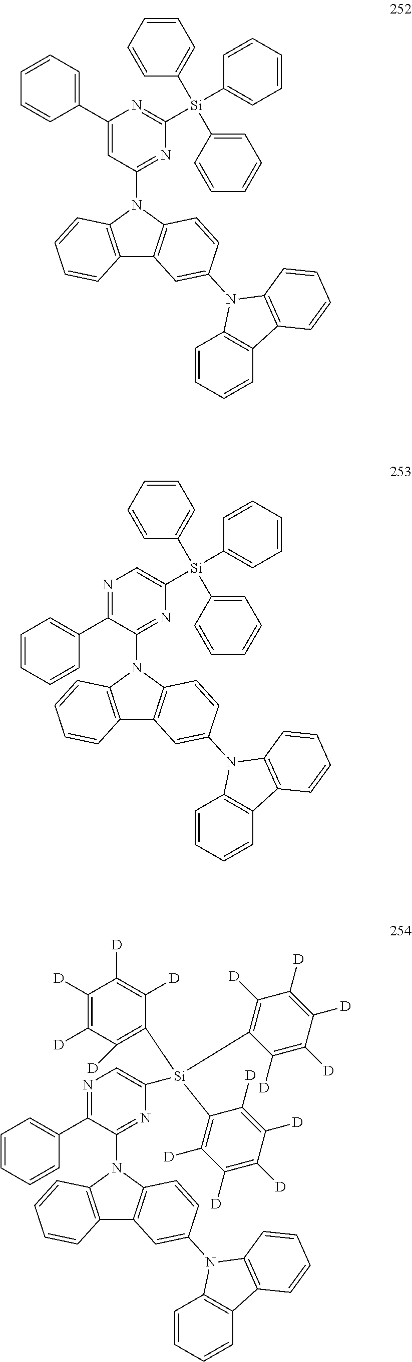 [SMILES: c1ccc(-c2cc(-n3c4ccccc4c4cc(-n5c6ccccc6c6ccccc65)ccc43)nc([Si](c3ccccc3)(c3ccccc3)c3ccccc3)n2)cc1 ; c1ccc(-c2ncc([Si](c3ccccc3)(c3ccccc3)c3ccccc3)nc2-n2c3ccccc3c3cc(-n4c5ccccc5c5ccccc54)ccc32)cc1 ; [2H]c1c([2H])c([2H])c([Si](c2cnc(-c3ccccc3)c(-n3c4ccccc4c4cc(-n5c6ccccc6c6ccccc65)ccc43)n2)(c2c([2H])c([2H])c([2H])c([2H])c2[2H])c2c([2H])c([2H])c([2H])c([2H])c2[2H])c([2H])c1[2H]]

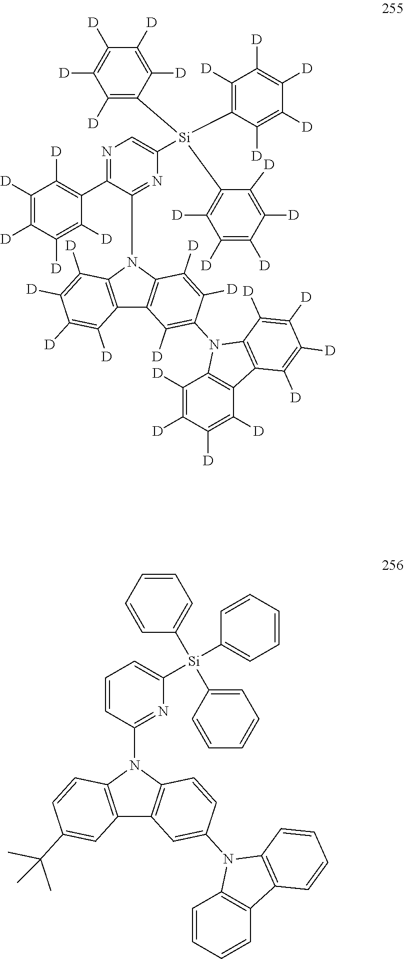 [SMILES: [2H]c1c([2H])c([2H])c(-c2ncc([Si](c3c([2H])c([2H])c([2H])c([2H])c3[2H])(c3c([2H])c([2H])c([2H])c([2H])c3[2H])c3c([2H])c([2H])c([2H])c([2H])c3[2H])nc2-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)c([2H])c1[2H] ; CC(C)(C)c1ccc2c(c1)c1cc(-n3c4ccccc4c4ccccc43)ccc1n2-c1cccc([Si](c2ccccc2)(c2ccccc2)c2ccccc2)n1]

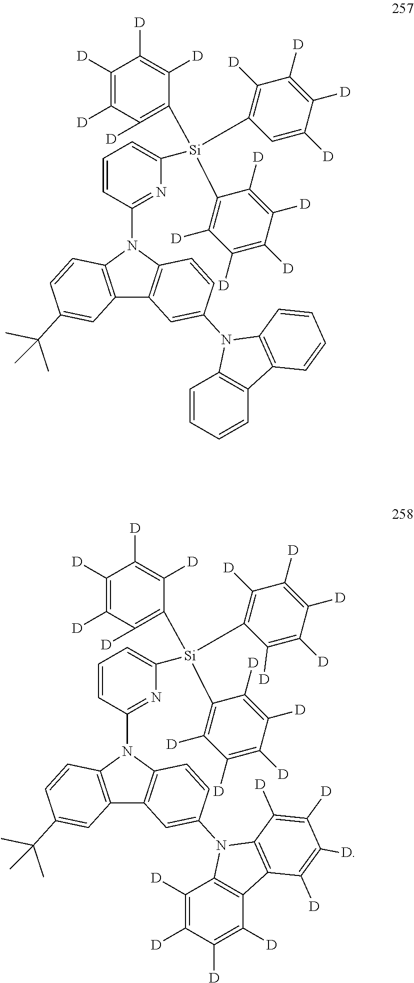

14. A nitrogen-containing compound represented by any one of Formula 1-1 to Formula 1-4: 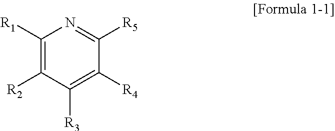
wherein, in Formula 1-1,
R₁ to R₅ are each independently, a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
any one of R₁ to R₅ is a substituent represented by Formula 2, and
at least one of R₁ to R₅ is a substituent represented by Formula 3; 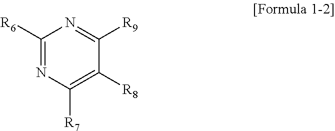
where, in Formula 1-2,
R₆ to R₉ are each independently, a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
any one of R₆ to R₉ is a substituent represented by Formula 2, and
at least one of R₆ to R₉ is a substituent represented by Formula 3; 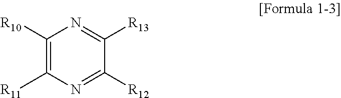
where, in Formula 1-3,
R₁₀ to R₁₃ are each independently, a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, a substituted or unsubstituted heteroaryl group having 2 to 30 ring-forming carbons, a substituent represented by Formula 2, or a substituent represented by Formula 3,
any one of R₁₀ to R₁₃ is a substituent represented by Formula 2, and
at least one of R₁₀ to R₁₃ is a substituent represented by Formula 3; 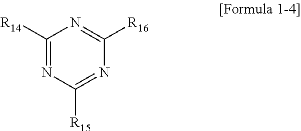
where, in Formula 1-4,
R₁₄ to R₁₆ are each independently, a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
any one of R₁₄ to R₁₆ is a substituent represented by Formula 2, and
at least one of R₁₄ to R₁₆ is a substituent represented by Formula 3; 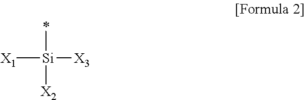
where, in Formula 2,
X₁ to X₃ are each independently, a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and
*— is a portion to which any one among Formula 1-1 to Formula 1-4 above is connected; 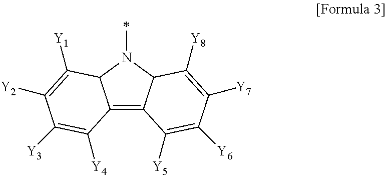
where, in Formula 3,
any one of Y₁ to Y₈ is a substituent represented by Formula 4,
a remainder of Y₁ to Y₈ are each independently, a hydrogen atom, a deuterium atom, a halogen atom, a cyano group, a substituted or unsubstituted alkyl group having 1 to 20 carbons, or a substituted or unsubstituted aryl group having 6 to 30 ring-forming carbons, and
*— is a portion to which any one of Formula 1-1 to Formula 1-4 above is connected: 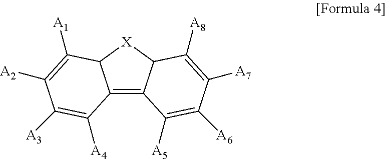
where, in Formula 4,
X is O, S, or NA₉,
any one of A₁ to A₉ is a portion to which Formula 3 above is connected,
a remainder of A₁ to A₉ are each independently a hydrogen atom, a deuterium atom, a halogen atom, a cyano group, a substituted or unsubstituted alkyl group having 1 to 20 carbons, or a substituted or unsubstituted aryl group having 6 to 30 ring-forming carbons.

15. The nitrogen-containing compound of claim 14, wherein the substituent represented by Formula 3 is represented by Formula 3-1 or Formula 3-2: 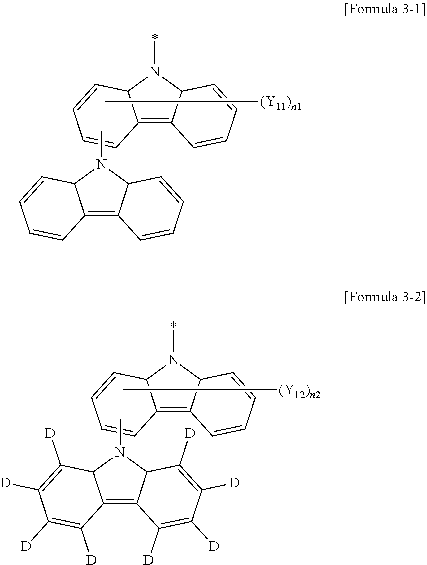
where, in Formula 3-1 and Formula 3-2,
Y₁₁ and Y₁₂ are each independently, a hydrogen atom, a deuterium atom, or a substituted or unsubstituted alkyl group having 1 to 20 carbons,
n1 and n2 are each independently an integer of 0 to 7, and
“D” is a deuterium atom.

16. The nitrogen-containing compound of claim 14, wherein the nitrogen-containing compound is represented by any one of Formula 1-1-1 to Formula 1-1-6: 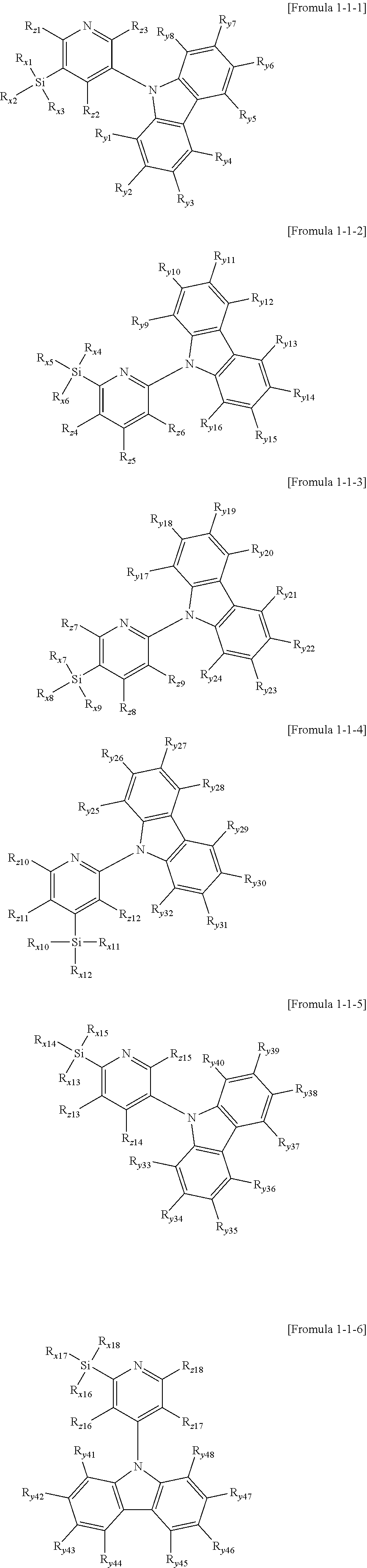
wherein, in Formula 1-1-1 to Formula 1-1-6,
Rₓ₁ to Rₓ₁₈ are each independently, a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
R_{z1} to R_{z18} are each independently, a hydrogen atom, a deuterium atom, a halogen atom, a cyano group, or a substituted or unsubstituted alkyl group having 1 to 20 carbons,
in Formula 1-1-1, any one of R_{y1} to R_{y8} is a substituent represented by Formula 4, and a remainder of R_{y1} to R_{y8} are each independently a hydrogen atom, or a deuterium atom,
in Formula 1-1-2, any one of R_{y9} to R_{y16} is a substituent represented by Formula 4, and a remainder of R_{y9} to R_{y16} are each independently a hydrogen atom, or a deuterium atom,
in Formula 1-1-3, any one of R_{y17} to R_{y24} is a substituent represented by Formula 4, and a remainder of R_{y17} to R_{y24} are each independently a hydrogen atom, or a deuterium atom,
in Formula 1-1-4, any one of R_{y25} to R_{y32} is a substituent represented by Formula 4, and a remainder of R_{y25} to R_{y32} are each independently a hydrogen atom, or a deuterium atom,
in Formula 1-1-5, any one of R_{y33} to R_{y40} is a substituent represented by Formula 4, and a remainder of R_{y33} to R_{y40} are each independently a hydrogen atom, or a deuterium atom, and
in Formula 1-1-6, any one of R_{y41} to R_{y48} is a substituent represented by Formula 4, and a remainder of R_{y41} to R_{y48} are each independently a hydrogen atom, or a deuterium atom.

17. The nitrogen-containing compound of claim 14, wherein the nitrogen-containing compound is represented by any one among Formula 1-2-1 to Formula 1-2-4 below: 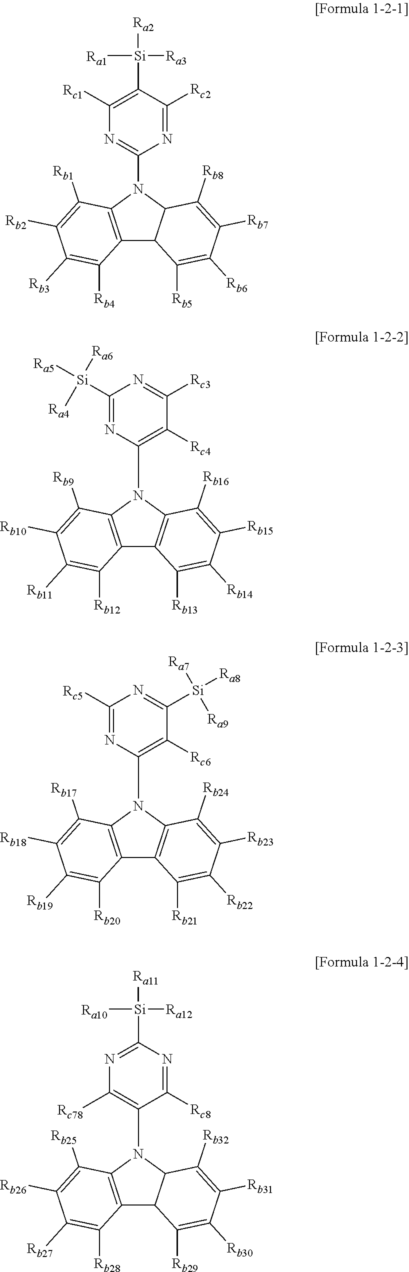
wherein, in Formula 1-2-1 to Formula 1-2-4,
Rₐ₁ to Rₐ₁₂ are each independently a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
R_{c1} to R_{c8} are each independently a hydrogen atom, a deuterium atom, a halogen atom, a cyano group, or a substituted or unsubstituted alkyl group having 1 to 20 carbons,
in Formula 1-2-1, any one of R_{b1} to R_{b8} is a substituent represented by Formula 4, and a remainder of R_{b1} to R_{b8} are each independently a hydrogen atom, or a deuterium atom
in Formula 1-2-2, any one of R_{b9} to R_{b16} is a substituent represented by Formula 4, and a remainder of R_{b9} to R_{b16} are each independently a hydrogen atom, or a deuterium atom,
in Formula 1-2-3, any one of R_{b17} to R_{b24} is a substituent represented by Formula 4, and a remainder of R_{b17} to R_{b24} are each independently a hydrogen atom, or a deuterium atom, and
in Formula 1-2-4, any one of R_{b25} to R_{b32} is a substituent represented by Formula 4, and a remainder of R_{b25} to R_{b32} are each independently a hydrogen atom, or a deuterium atom.

18. The nitrogen-containing compound of claim 14, wherein the nitrogen-containing compound is represented by Formula 1-3-1: 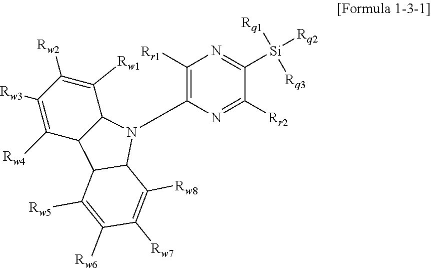
wherein, in Formula 1-3-1,
Rᵣ₁ and Rᵣ₂ are each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
R_{q1} to R_{q3} are each independently a hydrogen atom, a deuterium atom, a halogen atom, a cyano group, or a substituted or unsubstituted alkyl group having 1 to 20 carbons, and
any one of R_{w1} to R_{w8} is a substituent represented by Formula 4, and a remainder of R_{w1} to R_{w8} are each independently a hydrogen atom, or a deuterium atom.

19. The nitrogen-containing compound of claim 14, wherein the nitrogen-containing compound is represented by any compound in Compound Group 1 below:

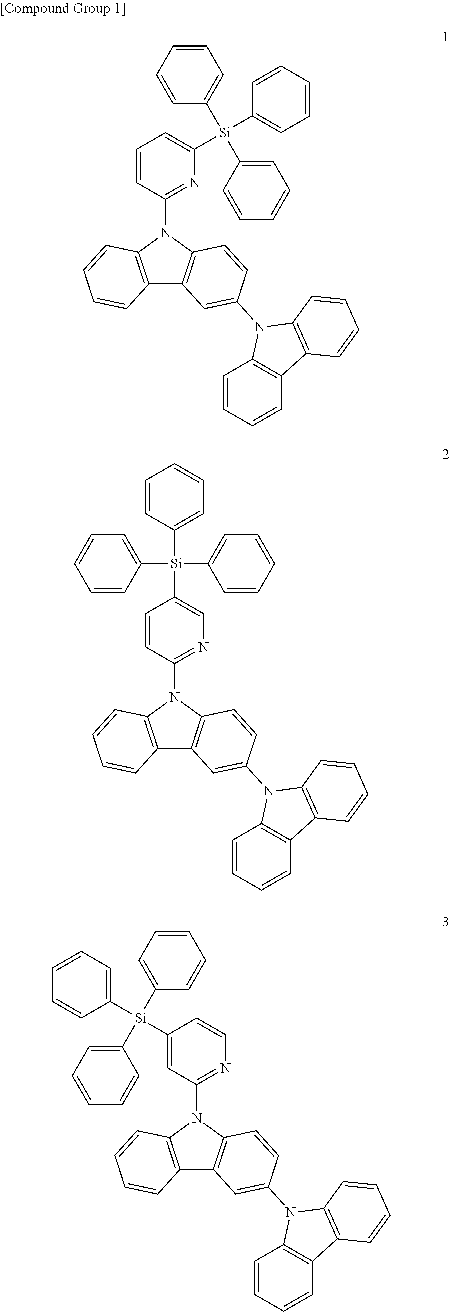 [SMILES: c1ccc([Si](c2ccccc2)(c2ccccc2)c2cccc(-n3c4ccccc4c4cc(-n5c6ccccc6c6ccccc65)ccc43)n2)cc1 ; c1ccc([Si](c2ccccc2)(c2ccccc2)c2ccc(-n3c4ccccc4c4cc(-n5c6ccccc6c6ccccc65)ccc43)nc2)cc1 ; c1ccc([Si](c2ccccc2)(c2ccccc2)c2ccnc(-n3c4ccccc4c4cc(-n5c6ccccc6c6ccccc65)ccc43)c2)cc1]

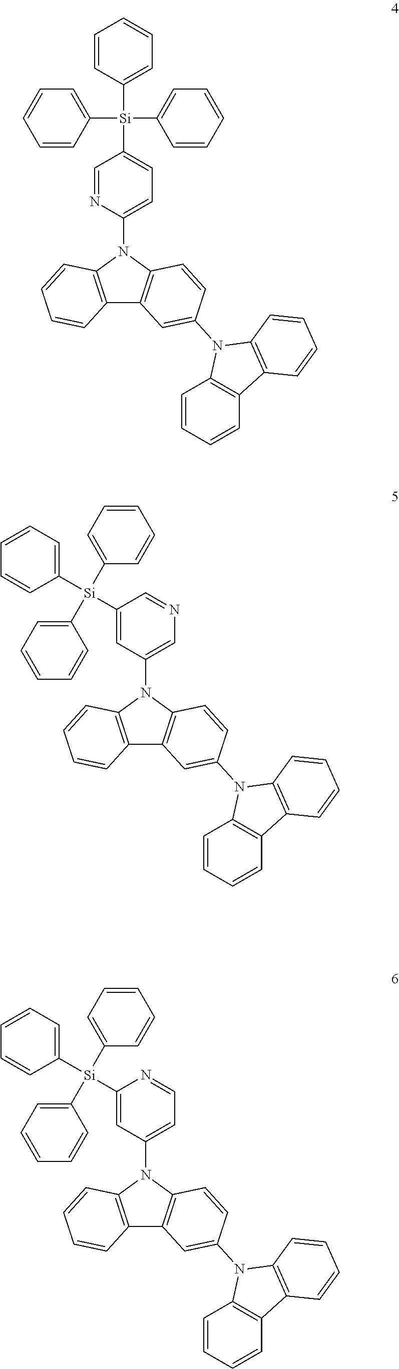 [SMILES: c1ccc([Si](c2ccccc2)(c2ccccc2)c2ccc(-n3c4ccccc4c4cc(-n5c6ccccc6c6ccccc65)ccc43)nc2)cc1 ; c1ccc([Si](c2ccccc2)(c2ccccc2)c2cncc(-n3c4ccccc4c4cc(-n5c6ccccc6c6ccccc65)ccc43)c2)cc1 ; c1ccc([Si](c2ccccc2)(c2ccccc2)c2cc(-n3c4ccccc4c4cc(-n5c6ccccc6c6ccccc65)ccc43)ccn2)cc1]

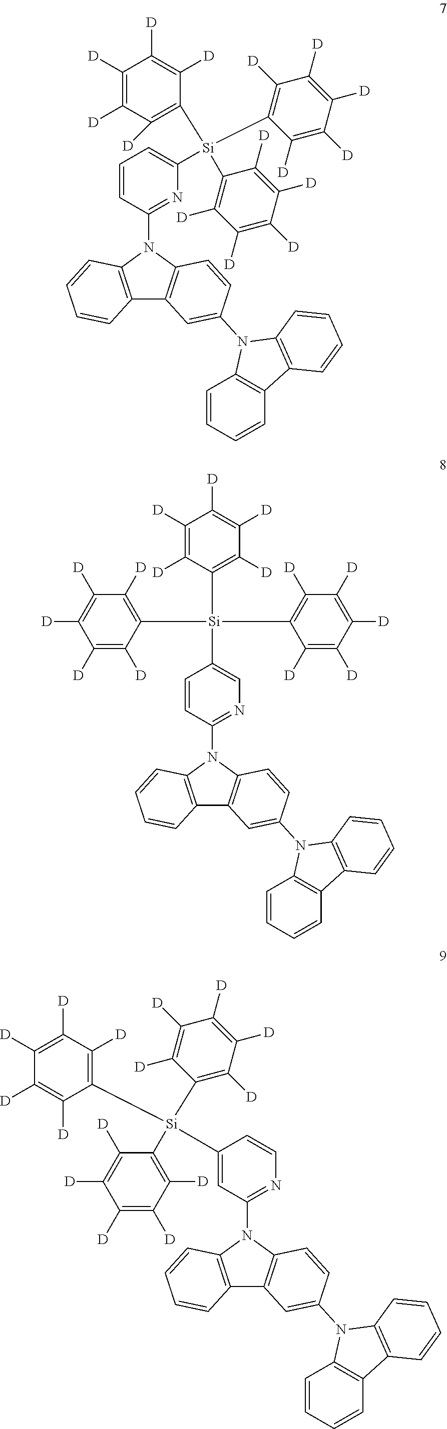

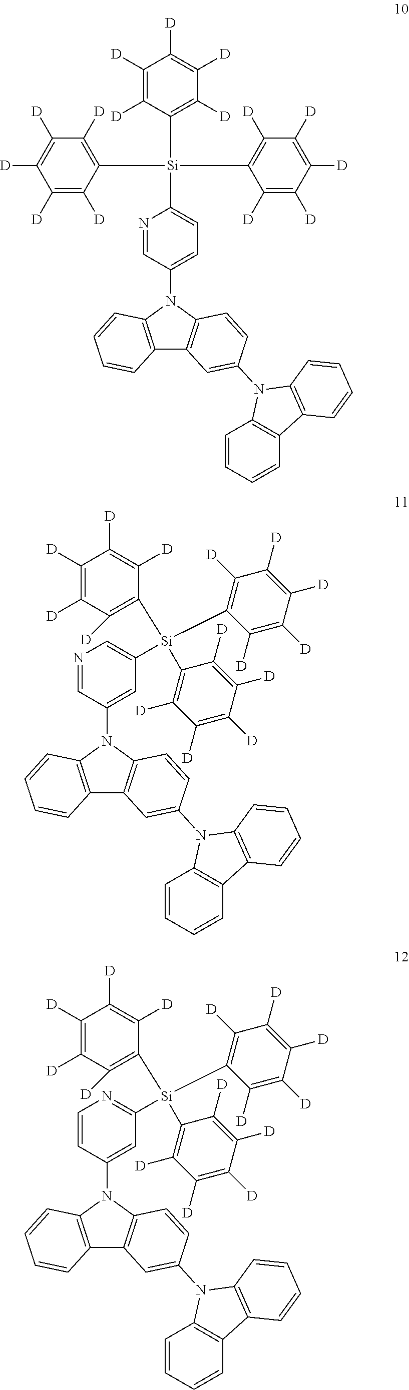

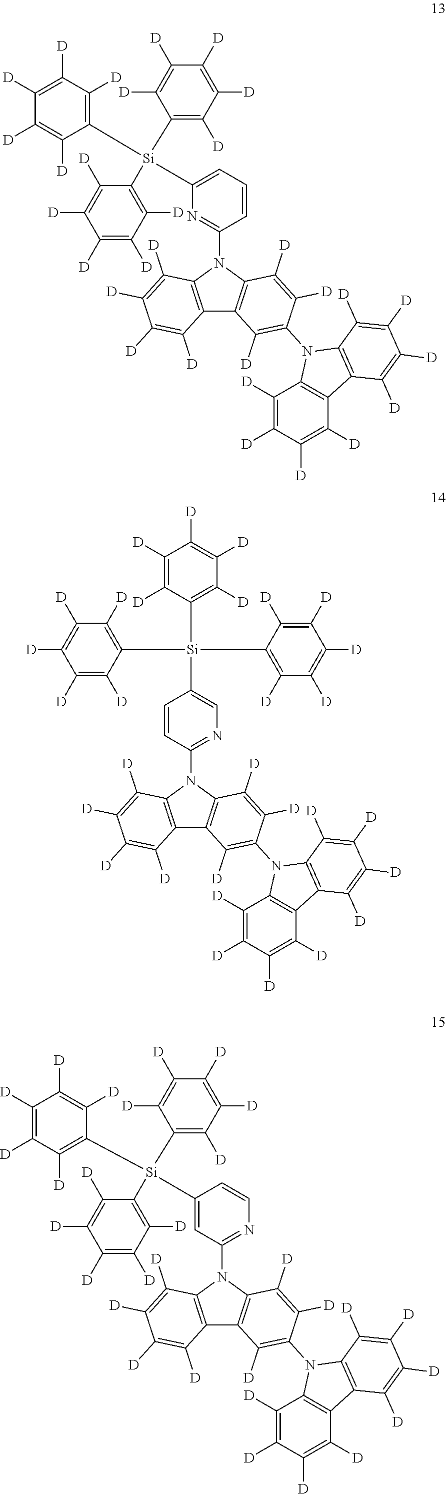

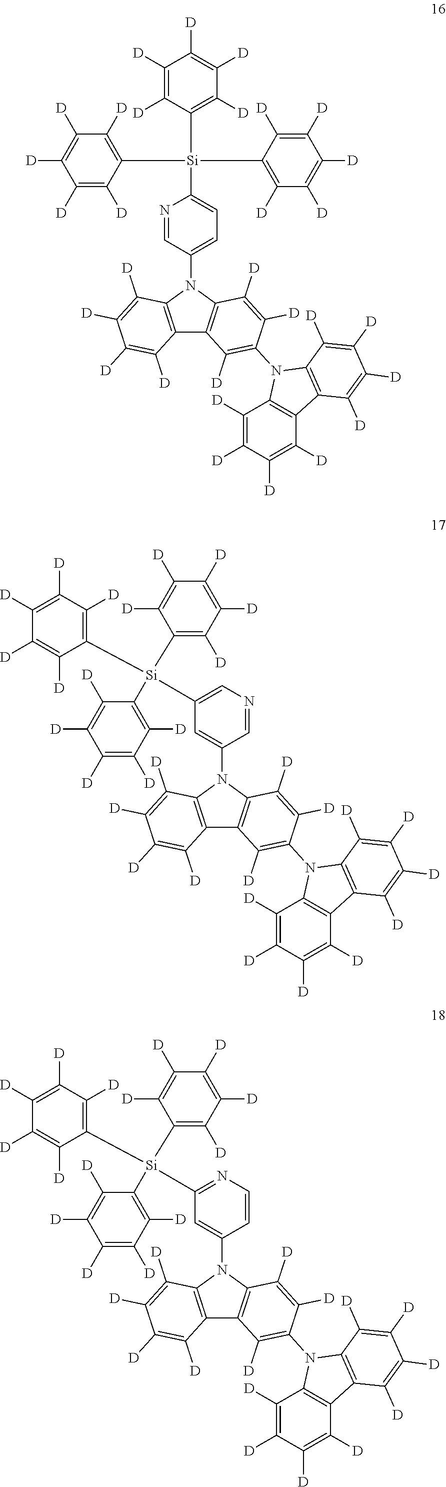

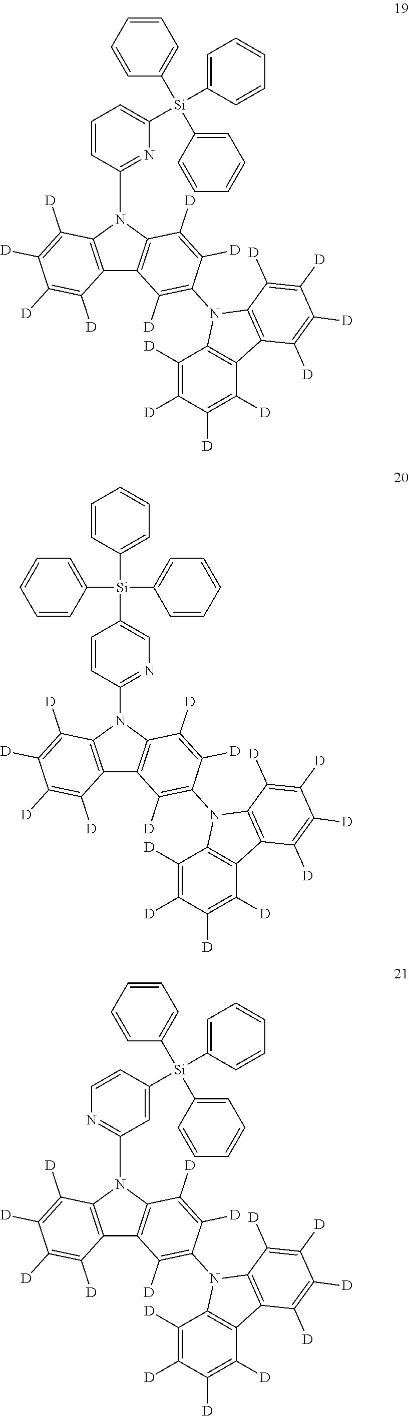

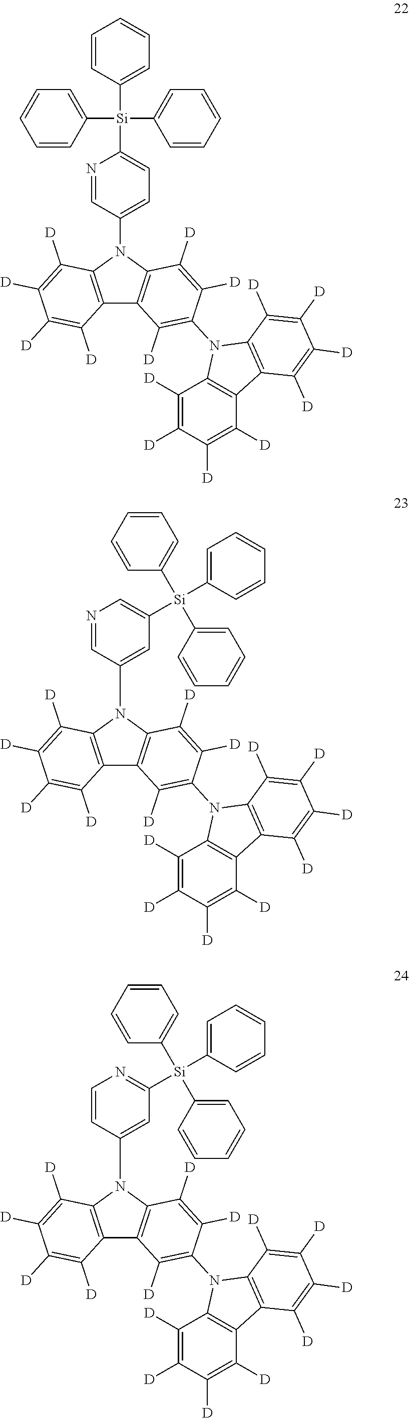

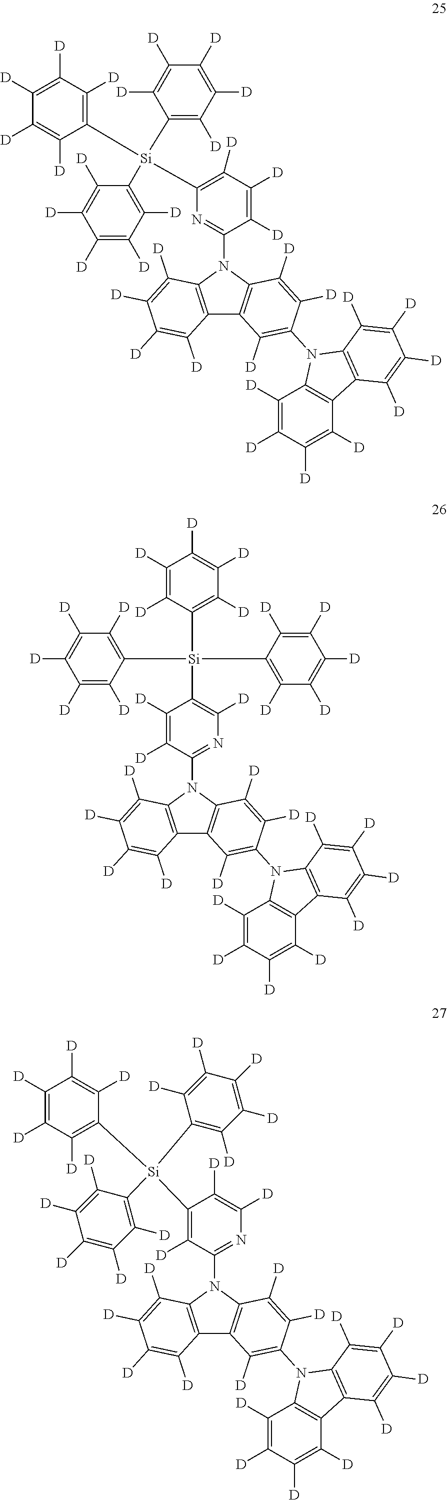

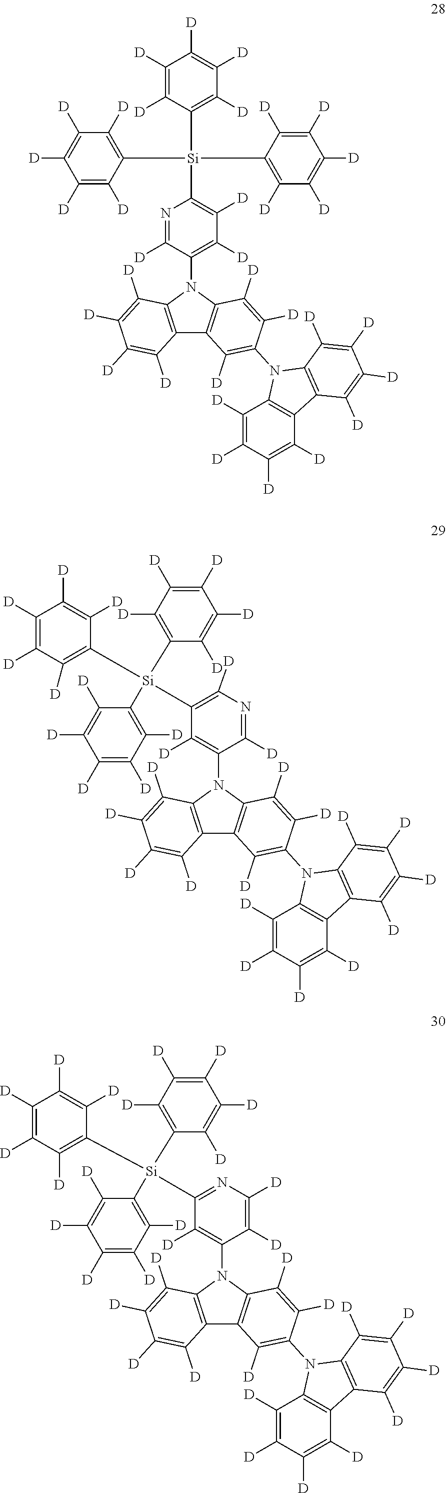

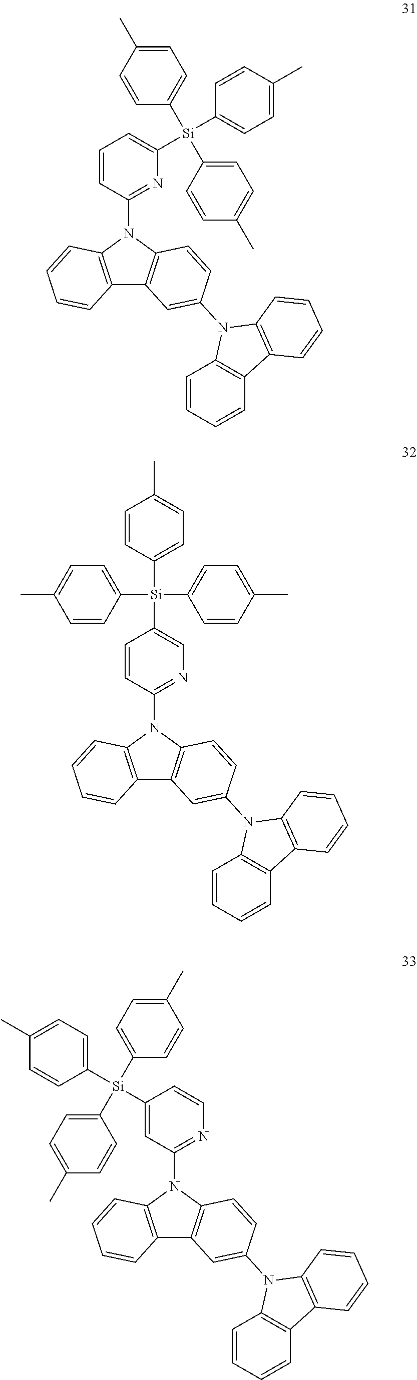 [SMILES: Cc1ccc([Si](c2ccc(C)cc2)(c2ccc(C)cc2)c2cccc(-n3c4ccccc4c4cc(-n5c6ccccc6c6ccccc65)ccc43)n2)cc1 ; Cc1ccc([Si](c2ccc(C)cc2)(c2ccc(C)cc2)c2ccc(-n3c4ccccc4c4cc(-n5c6ccccc6c6ccccc65)ccc43)nc2)cc1 ; Cc1ccc([Si](c2ccc(C)cc2)(c2ccc(C)cc2)c2ccnc(-n3c4ccccc4c4cc(-n5c6ccccc6c6ccccc65)ccc43)c2)cc1]

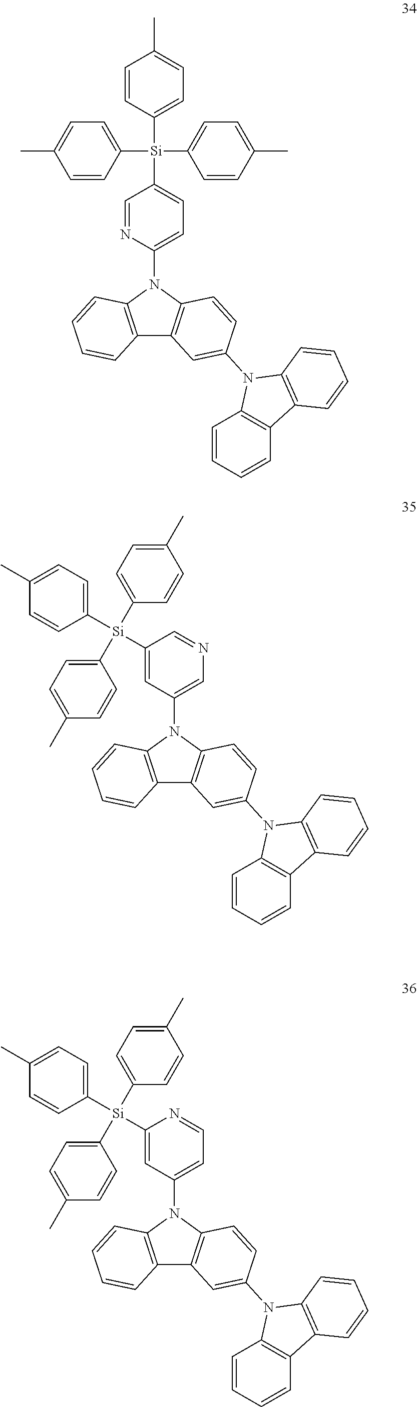 [SMILES: Cc1ccc([Si](c2ccc(C)cc2)(c2ccc(C)cc2)c2ccc(-n3c4ccccc4c4cc(-n5c6ccccc6c6ccccc65)ccc43)nc2)cc1 ; Cc1ccc([Si](c2ccc(C)cc2)(c2ccc(C)cc2)c2cncc(-n3c4ccccc4c4cc(-n5c6ccccc6c6ccccc65)ccc43)c2)cc1 ; Cc1ccc([Si](c2ccc(C)cc2)(c2ccc(C)cc2)c2cc(-n3c4ccccc4c4cc(-n5c6ccccc6c6ccccc65)ccc43)ccn2)cc1]

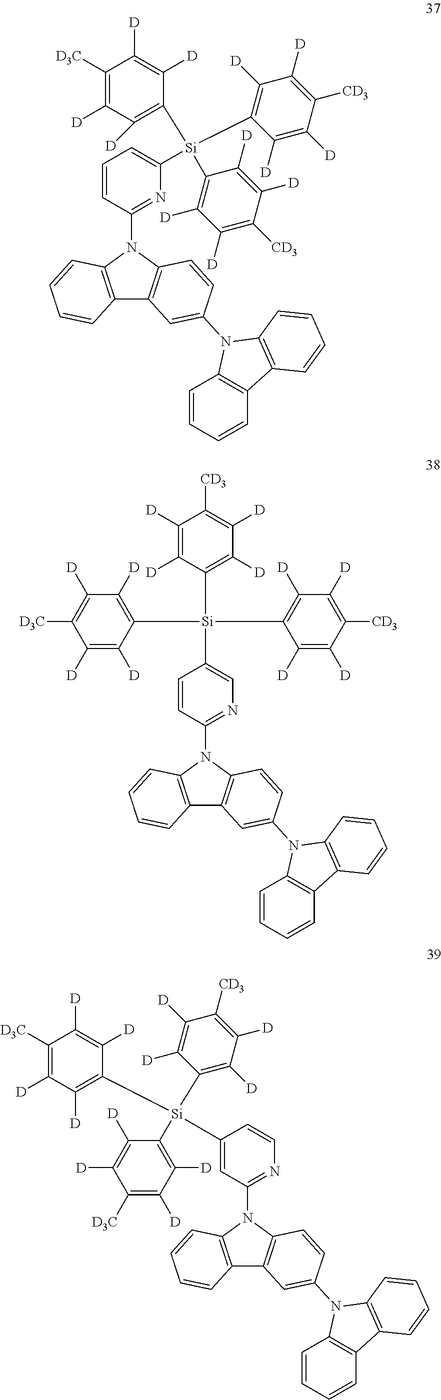

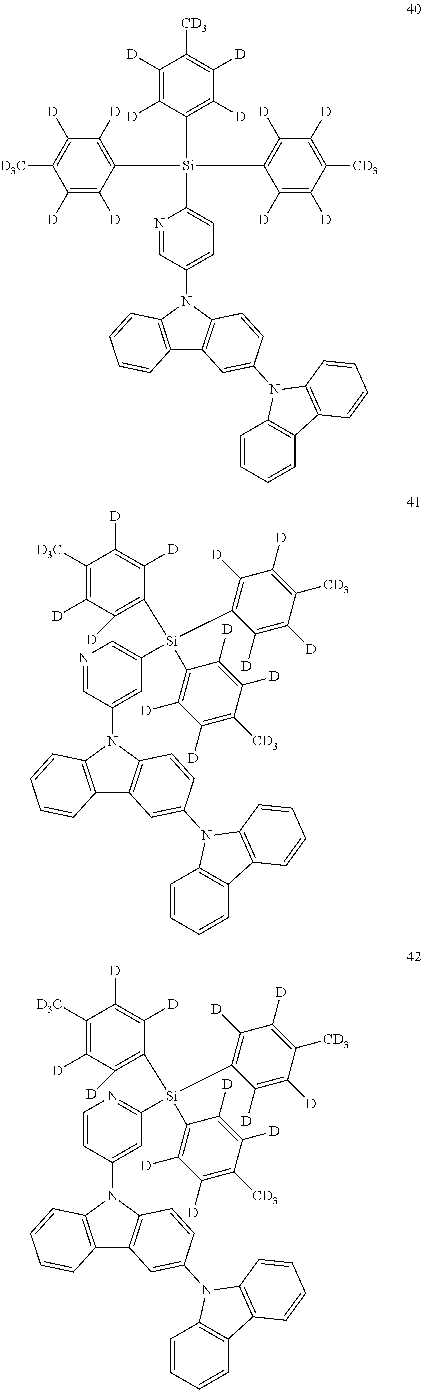

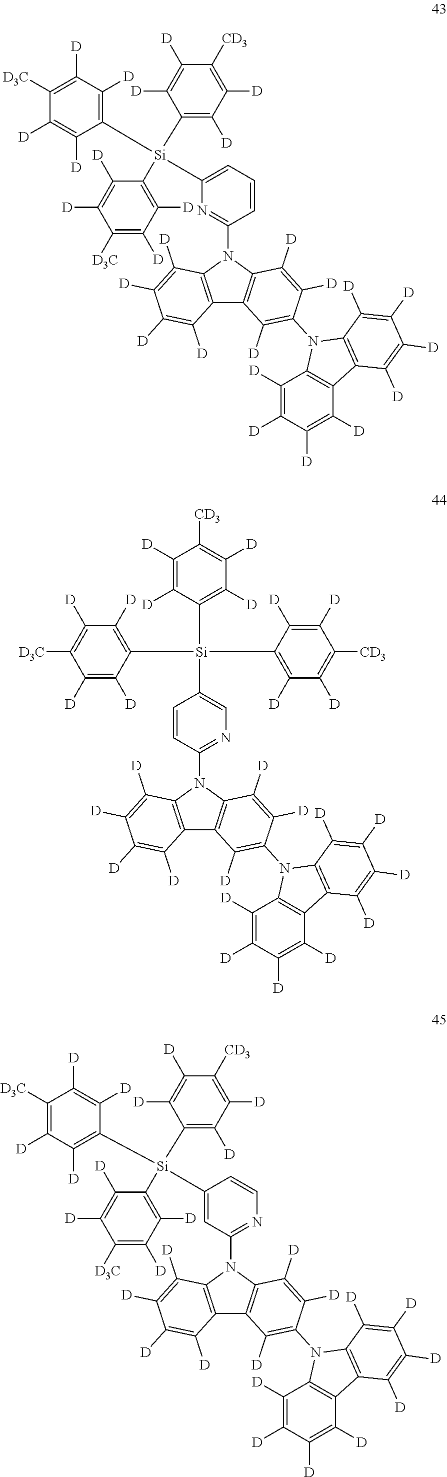

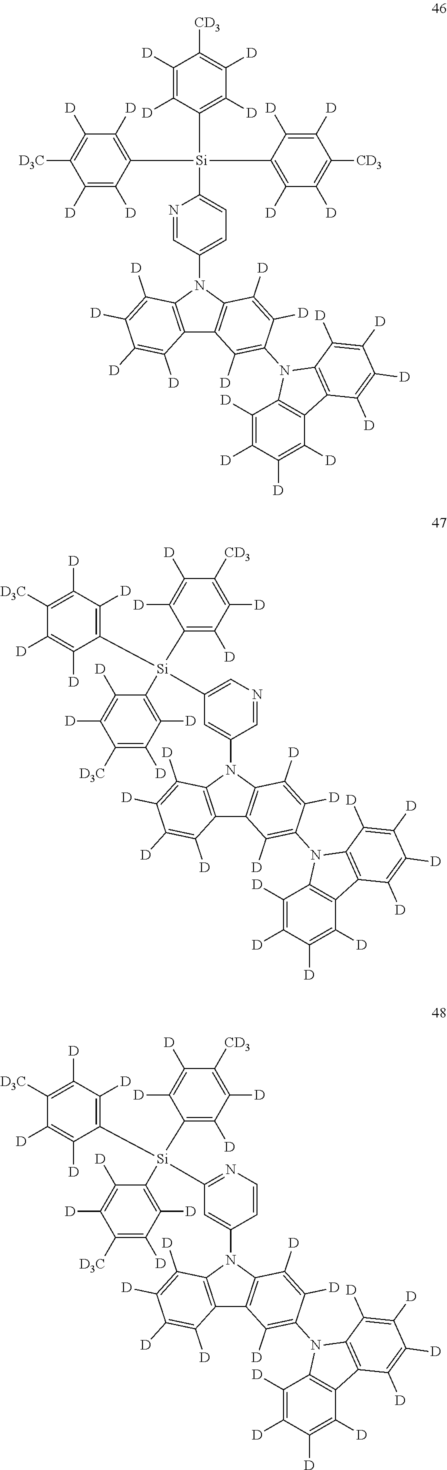

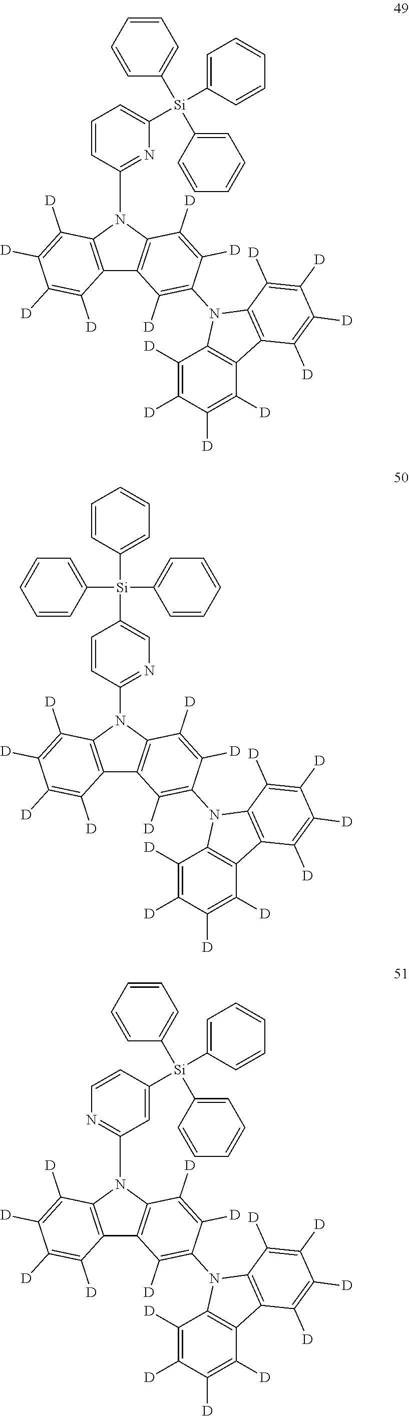

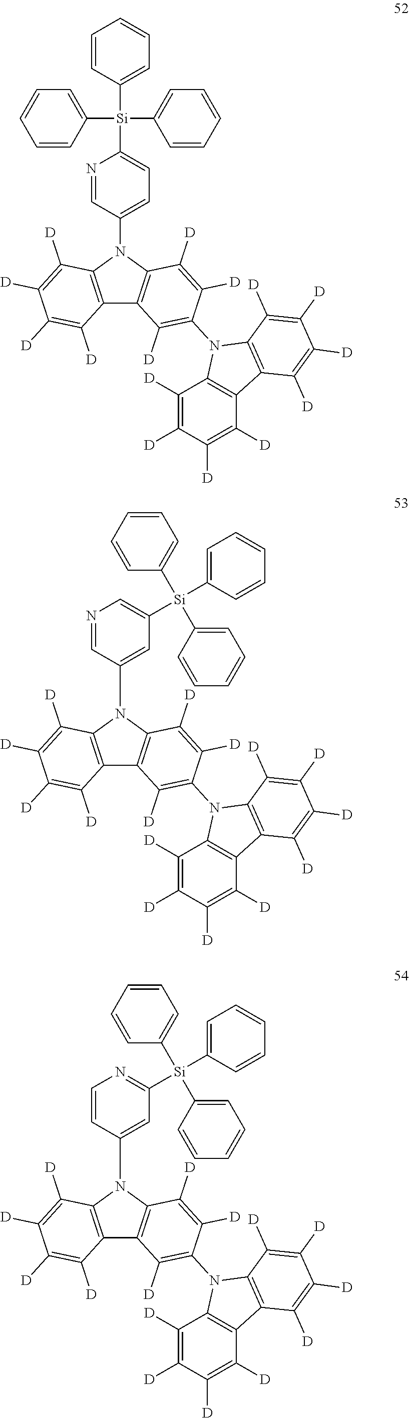

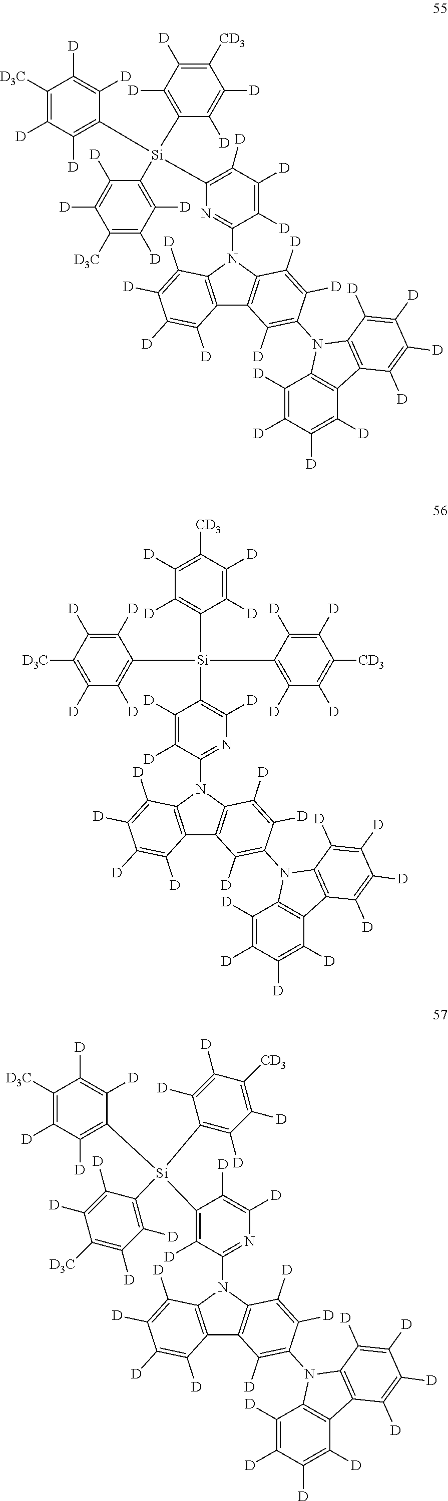

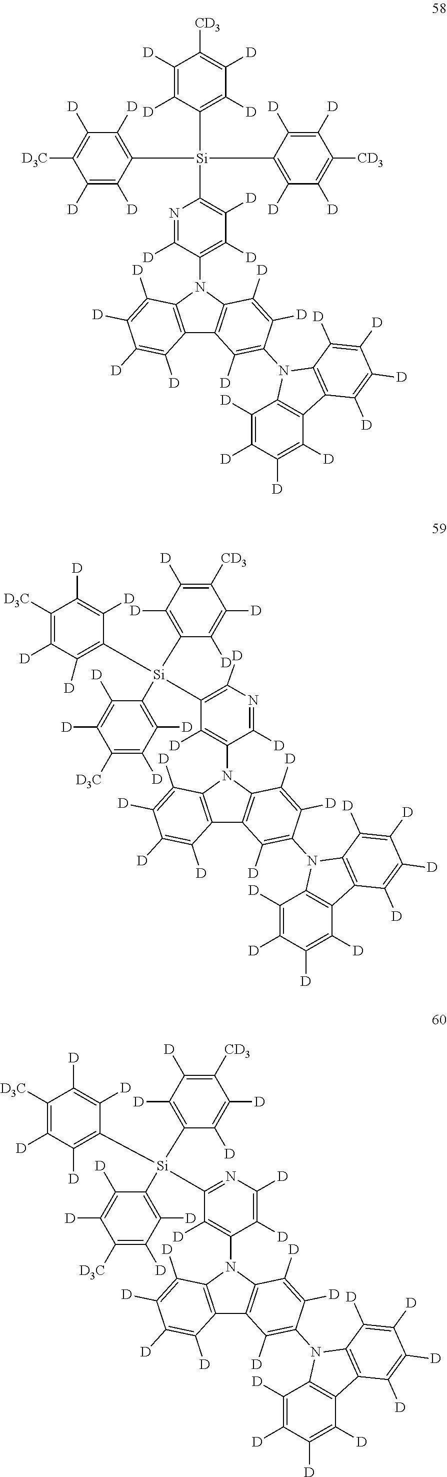

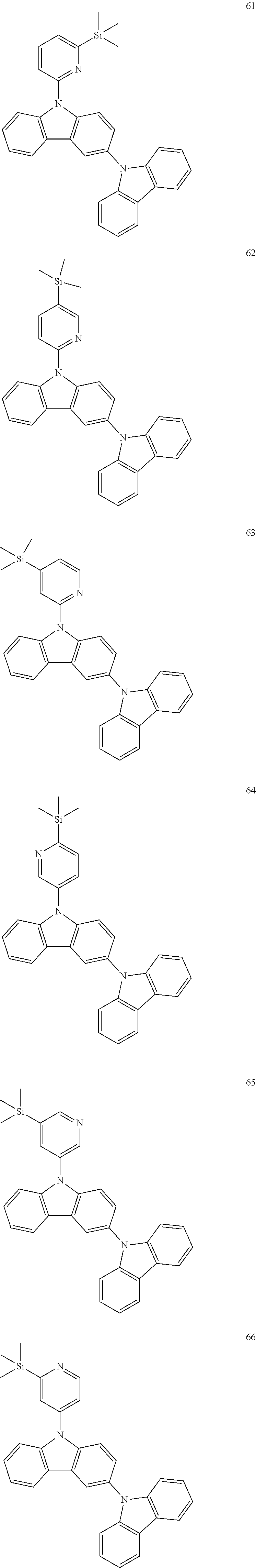 [SMILES: C[Si](C)(C)c1cccc(-n2c3ccccc3c3cc(-n4c5ccccc5c5ccccc54)ccc32)n1 ; C[Si](C)(C)c1ccc(-n2c3ccccc3c3cc(-n4c5ccccc5c5ccccc54)ccc32)nc1 ; C[Si](C)(C)c1ccnc(-n2c3ccccc3c3cc(-n4c5ccccc5c5ccccc54)ccc32)c1 ; C[Si](C)(C)c1ccc(-n2c3ccccc3c3cc(-n4c5ccccc5c5ccccc54)ccc32)cn1 ; C[Si](C)(C)c1cncc(-n2c3ccccc3c3cc(-n4c5ccccc5c5ccccc54)ccc32)c1 ; C[Si](C)(C)c1cc(-n2c3ccccc3c3cc(-n4c5ccccc5c5ccccc54)ccc32)ccn1]

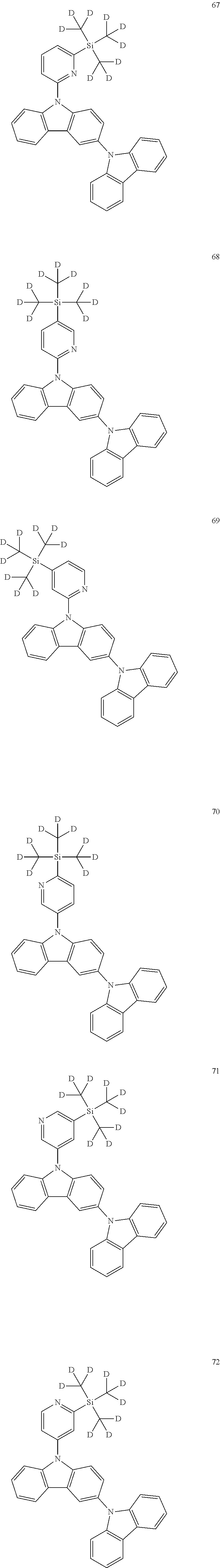

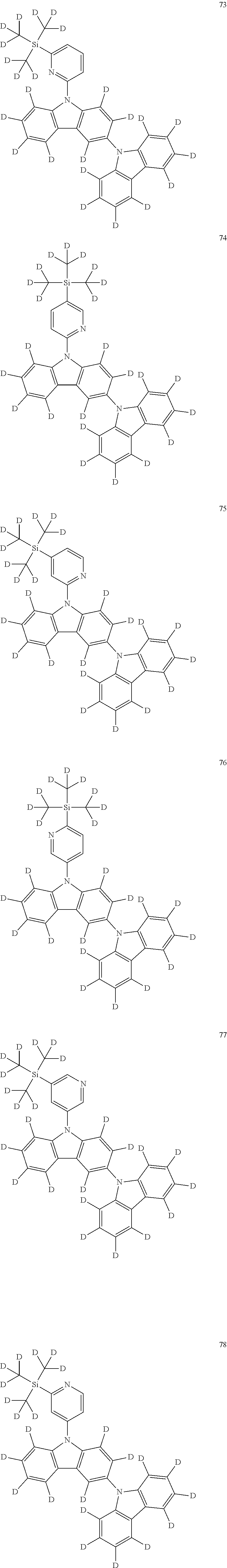

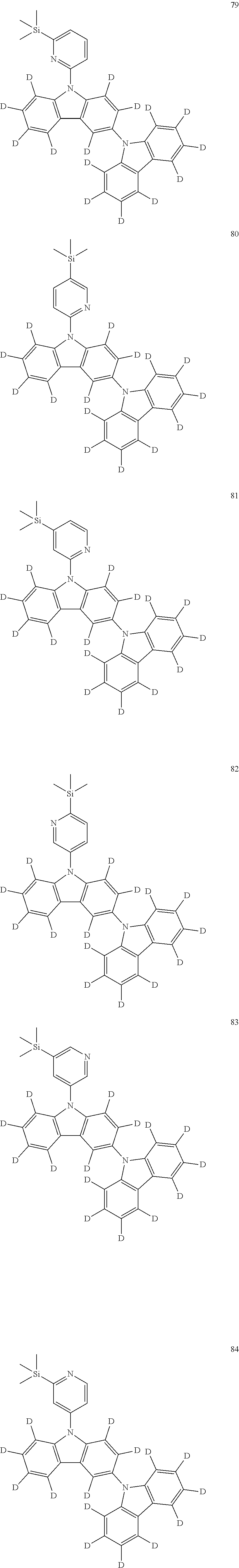

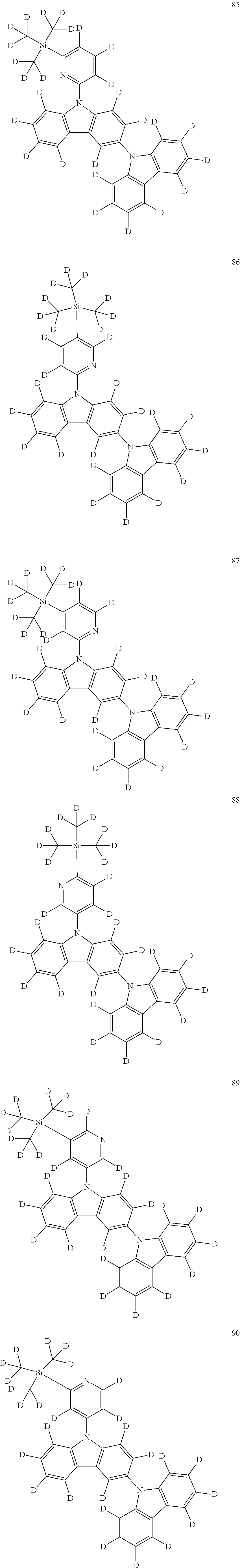

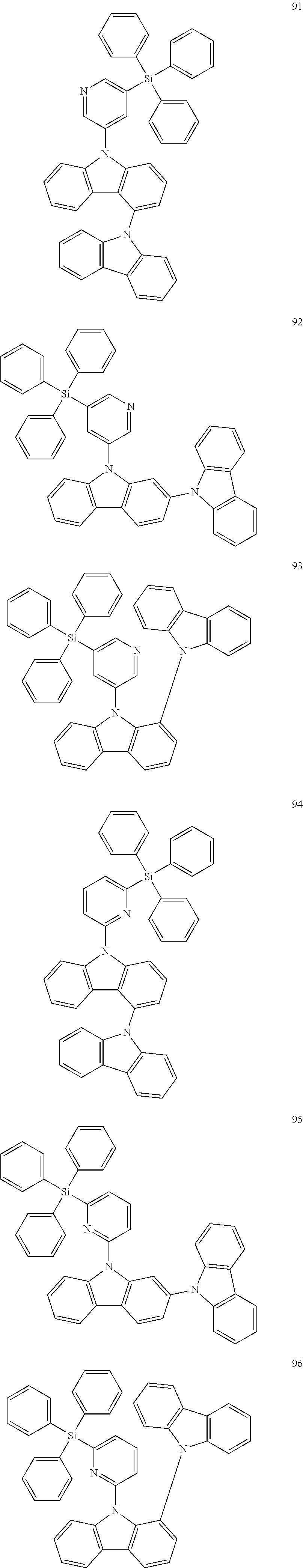

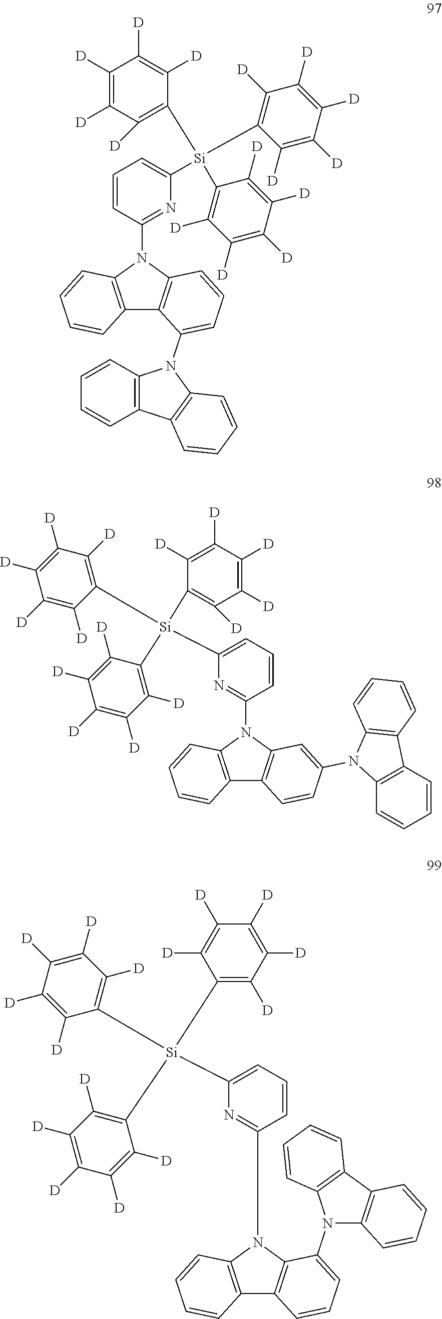

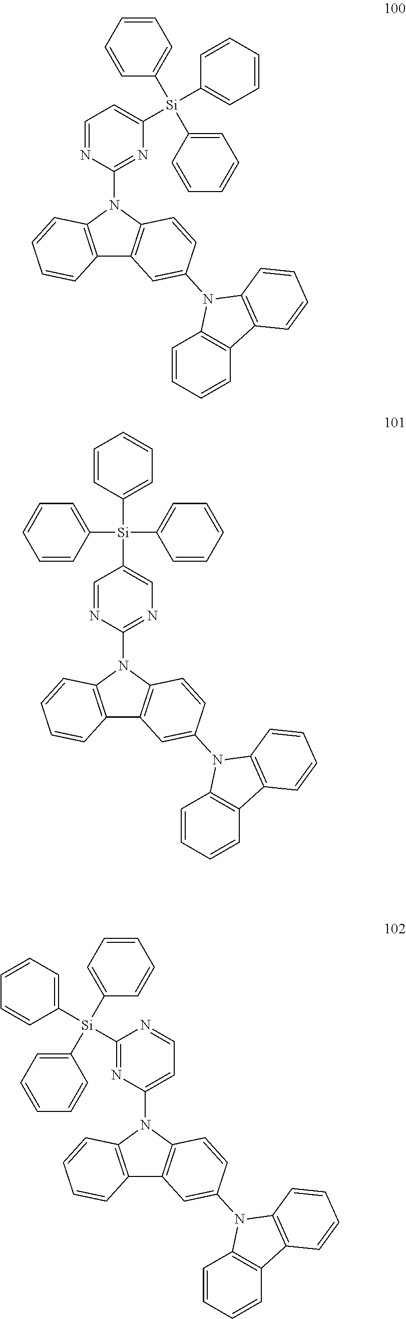 [SMILES: c1ccc([Si](c2ccccc2)(c2ccccc2)c2ccnc(-n3c4ccccc4c4cc(-n5c6ccccc6c6ccccc65)ccc43)n2)cc1 ; c1ccc([Si](c2ccccc2)(c2ccccc2)c2cnc(-n3c4ccccc4c4cc(-n5c6ccccc6c6ccccc65)ccc43)nc2)cc1 ; c1ccc([Si](c2ccccc2)(c2ccccc2)c2nccc(-n3c4ccccc4c4cc(-n5c6ccccc6c6ccccc65)ccc43)n2)cc1]

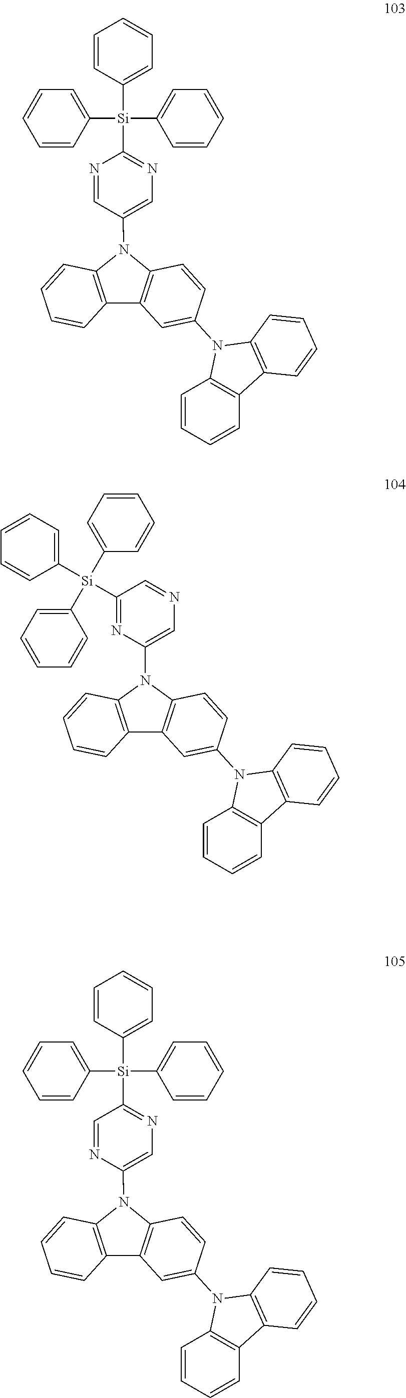 [SMILES: c1ccc([Si](c2ccccc2)(c2ccccc2)c2ncc(-n3c4ccccc4c4cc(-n5c6ccccc6c6ccccc65)ccc43)cn2)cc1 ; c1ccc([Si](c2ccccc2)(c2ccccc2)c2cncc(-n3c4ccccc4c4cc(-n5c6ccccc6c6ccccc65)ccc43)n2)cc1 ; c1ccc([Si](c2ccccc2)(c2ccccc2)c2cnc(-n3c4ccccc4c4cc(-n5c6ccccc6c6ccccc65)ccc43)cn2)cc1]

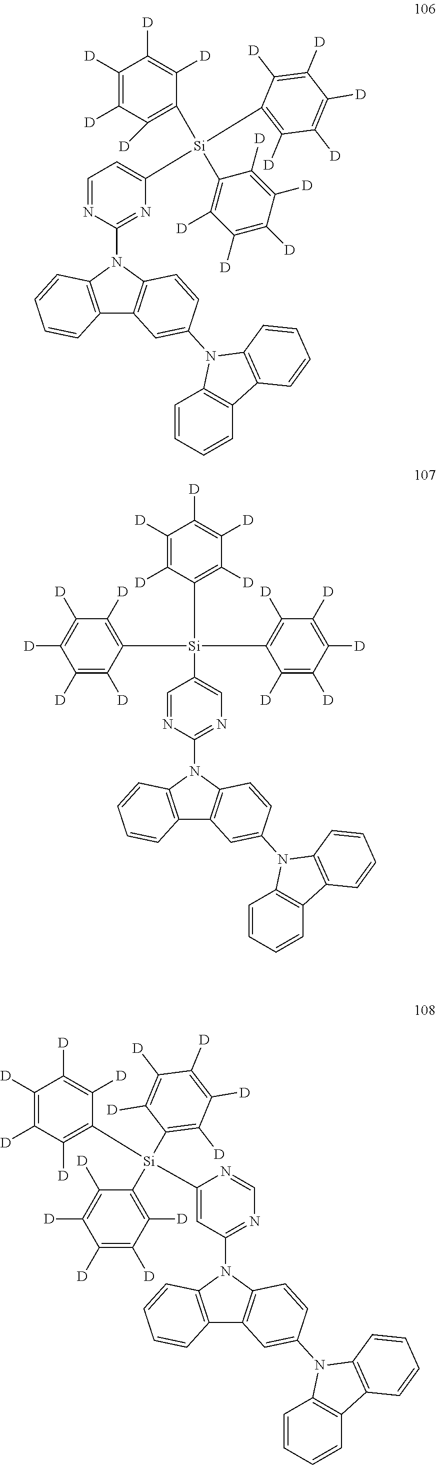

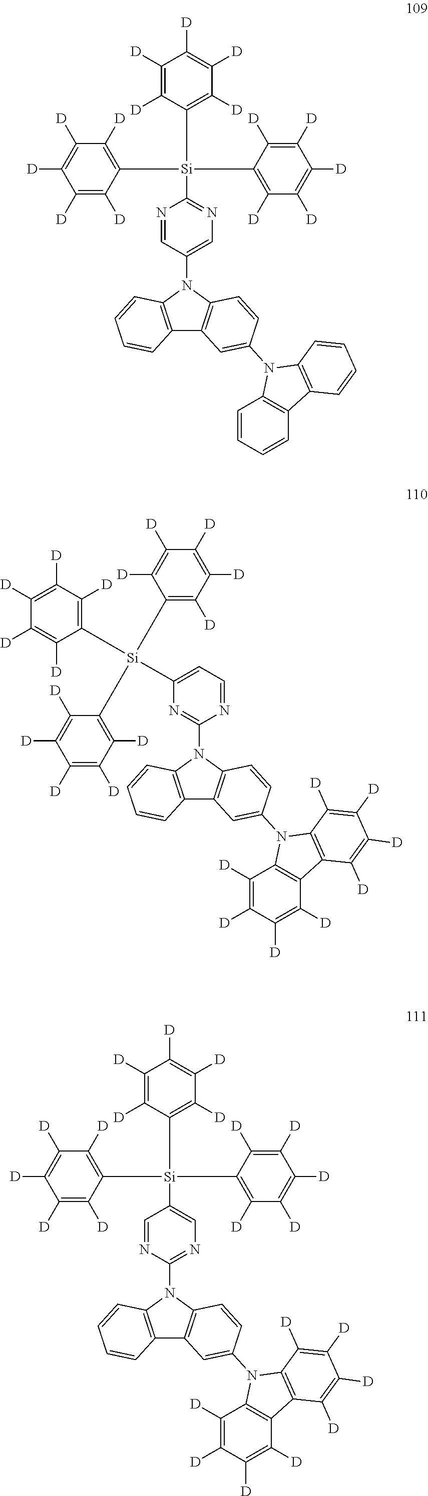

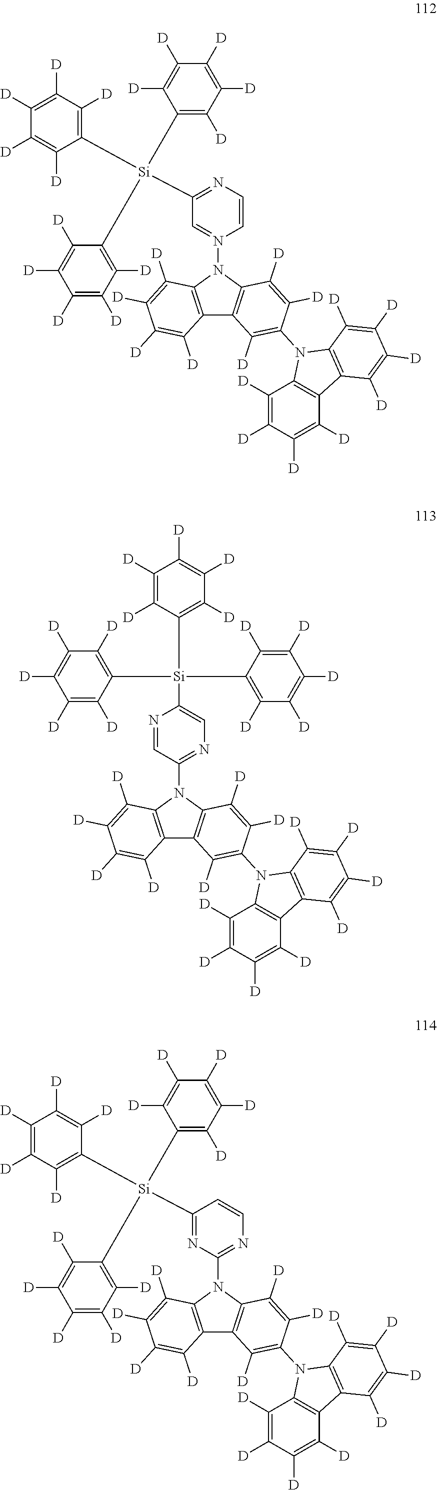

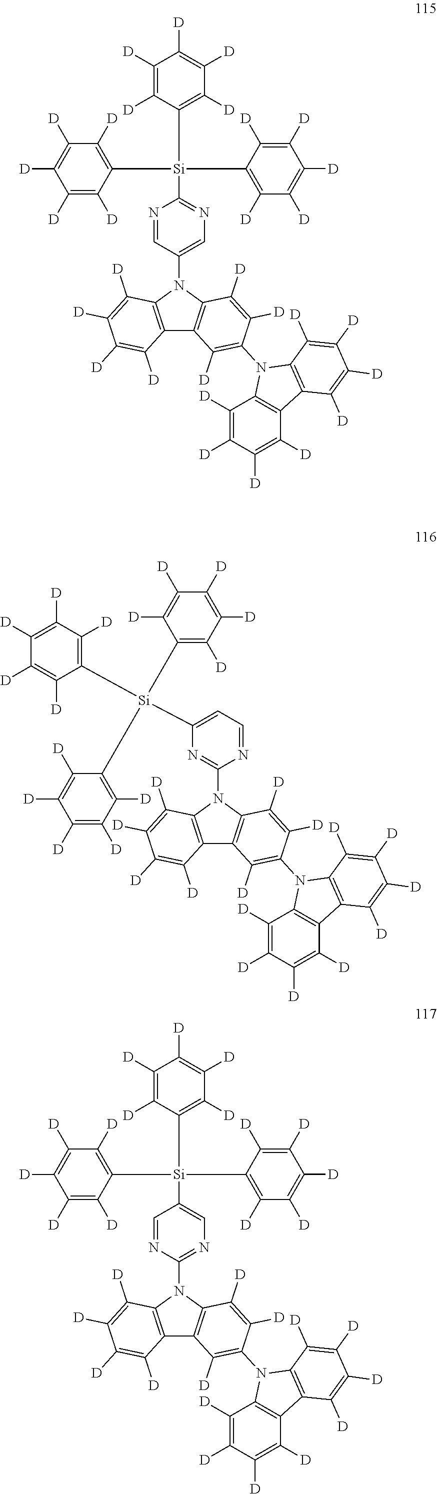

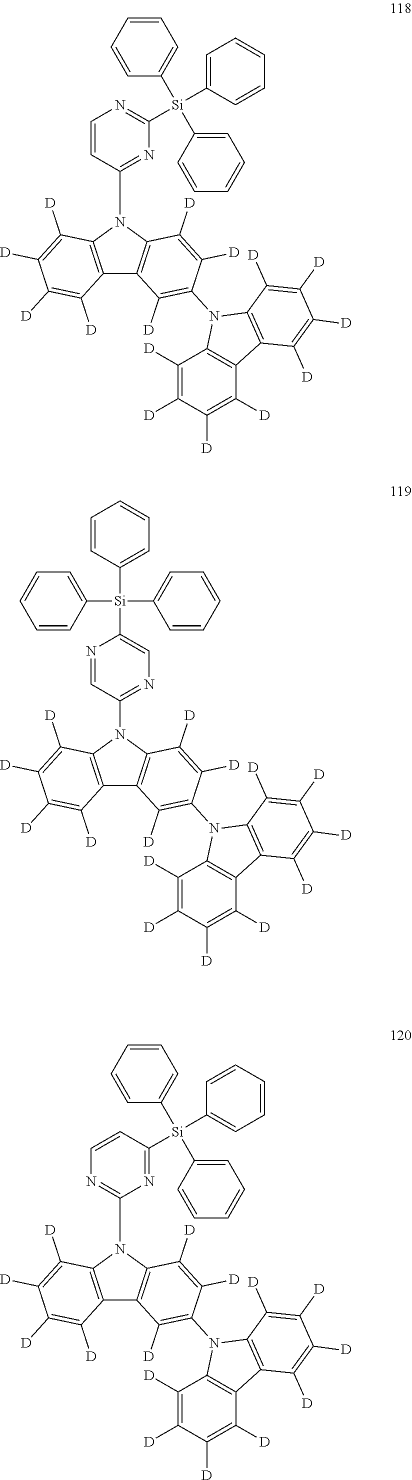

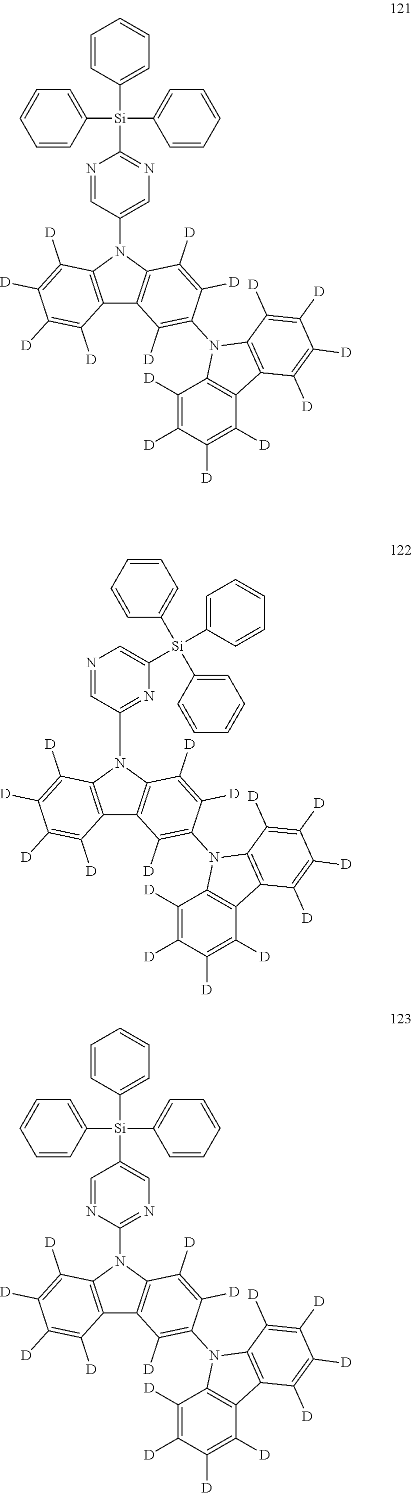

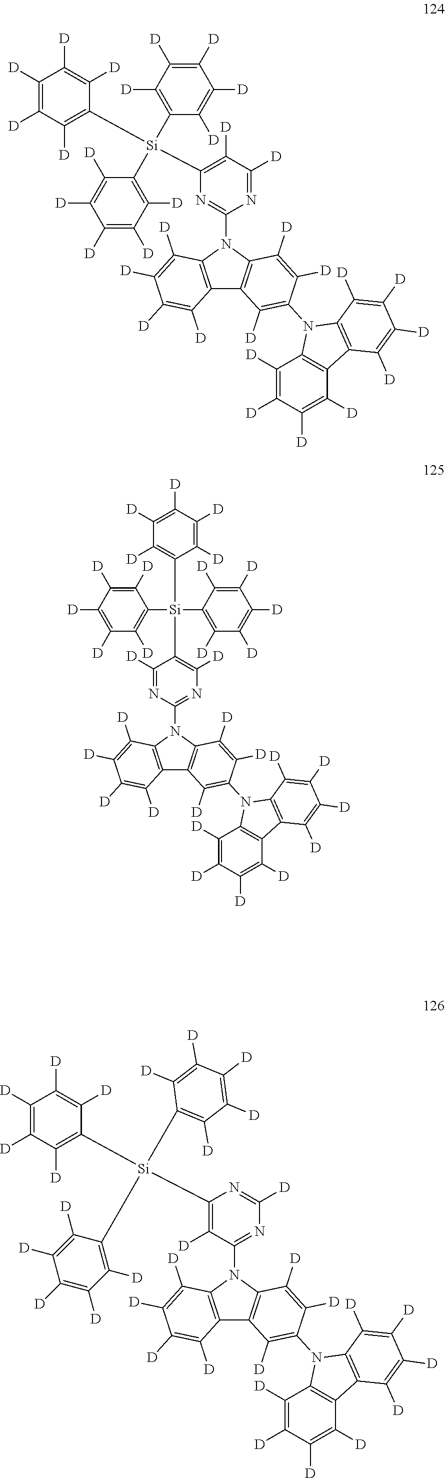

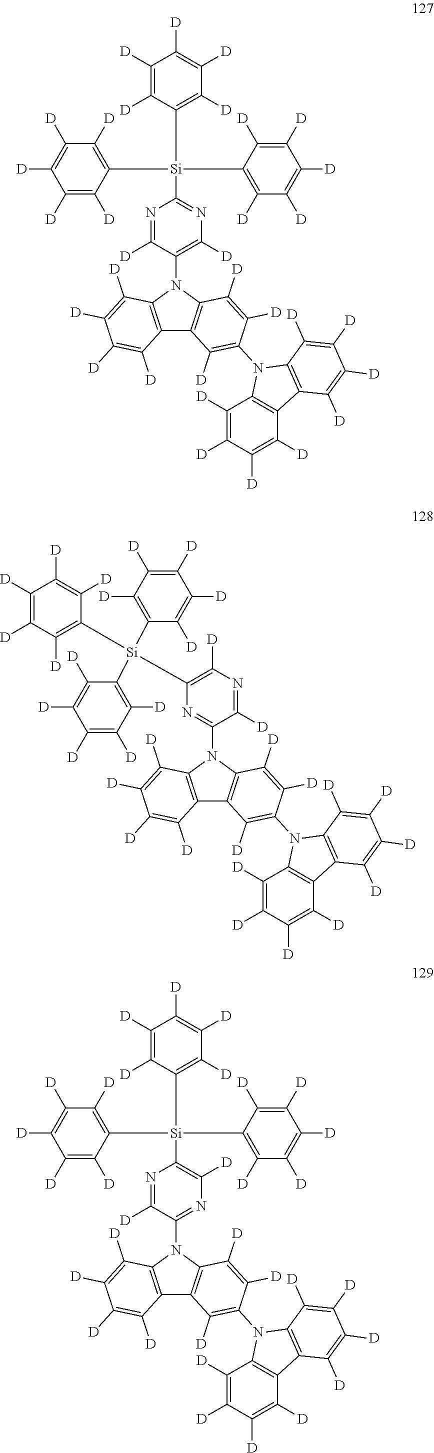

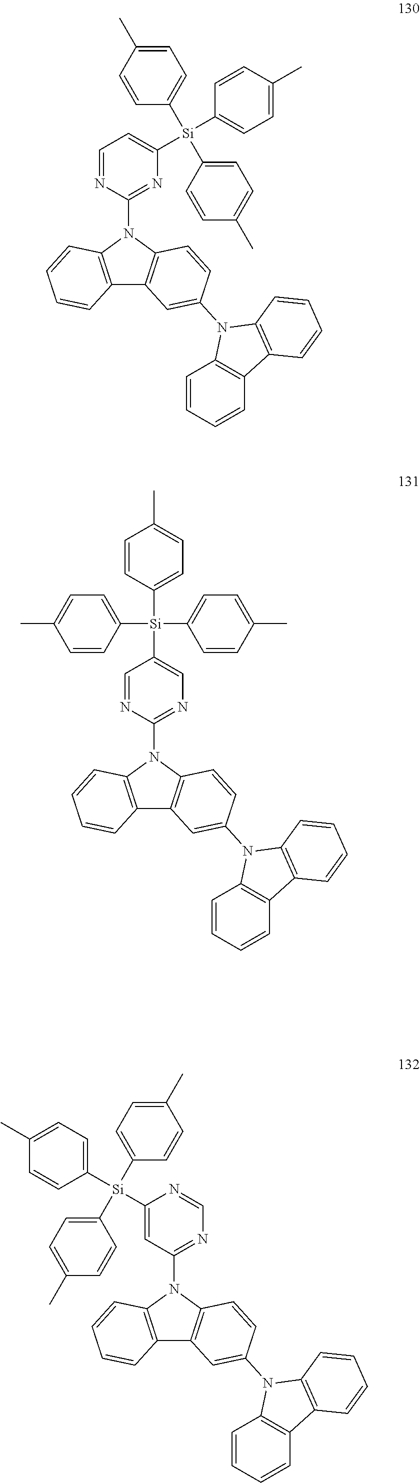 [SMILES: Cc1ccc([Si](c2ccc(C)cc2)(c2ccc(C)cc2)c2ccnc(-n3c4ccccc4c4cc(-n5c6ccccc6c6ccccc65)ccc43)n2)cc1 ; Cc1ccc([Si](c2ccc(C)cc2)(c2ccc(C)cc2)c2cnc(-n3c4ccccc4c4cc(-n5c6ccccc6c6ccccc65)ccc43)nc2)cc1 ; Cc1ccc([Si](c2ccc(C)cc2)(c2ccc(C)cc2)c2cc(-n3c4ccccc4c4cc(-n5c6ccccc6c6ccccc65)ccc43)ncn2)cc1]

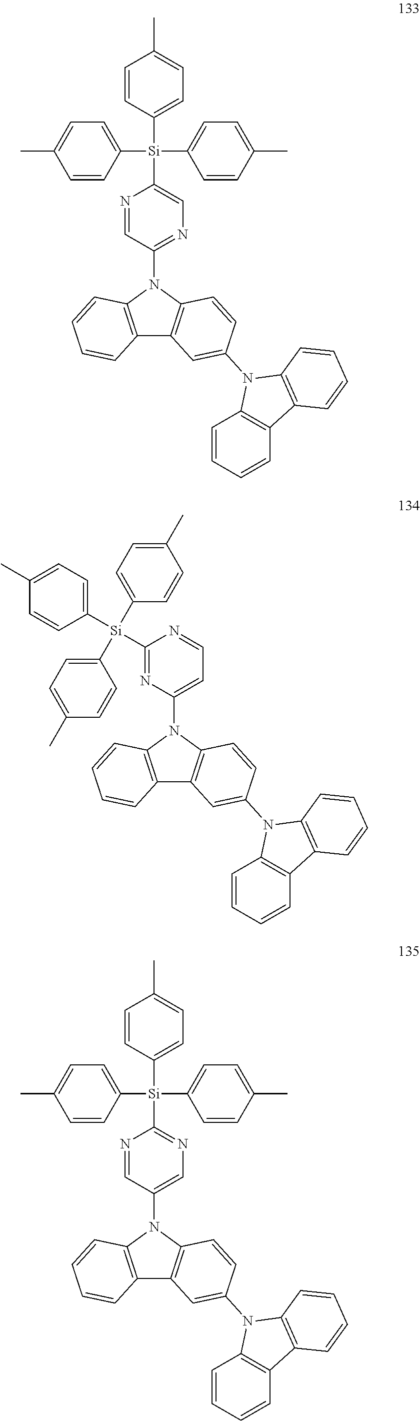 [SMILES: Cc1ccc([Si](c2ccc(C)cc2)(c2ccc(C)cc2)c2cnc(-n3c4ccccc4c4cc(-n5c6ccccc6c6ccccc65)ccc43)cn2)cc1 ; Cc1ccc([Si](c2ccc(C)cc2)(c2ccc(C)cc2)c2nccc(-n3c4ccccc4c4cc(-n5c6ccccc6c6ccccc65)ccc43)n2)cc1 ; Cc1ccc([Si](c2ccc(C)cc2)(c2ccc(C)cc2)c2ncc(-n3c4ccccc4c4cc(-n5c6ccccc6c6ccccc65)ccc43)cn2)cc1]

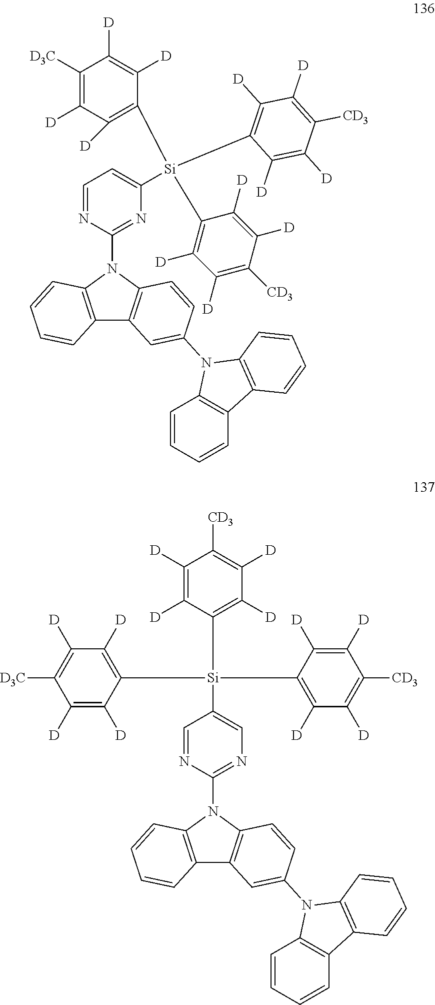 [SMILES: [2H]c1c([2H])c([Si](c2ccnc(-n3c4ccccc4c4cc(-n5c6ccccc6c6ccccc65)ccc43)n2)(c2c([2H])c([2H])c(C([2H])([2H])[2H])c([2H])c2[2H])c2c([2H])c([2H])c(C([2H])([2H])[2H])c([2H])c2[2H])c([2H])c([2H])c1C([2H])([2H])[2H] ; [2H]c1c([2H])c([Si](c2cnc(-n3c4ccccc4c4cc(-n5c6ccccc6c6ccccc65)ccc43)nc2)(c2c([2H])c([2H])c(C([2H])([2H])[2H])c([2H])c2[2H])c2c([2H])c([2H])c(C([2H])([2H])[2H])c([2H])c2[2H])c([2H])c([2H])c1C([2H])([2H])[2H]]

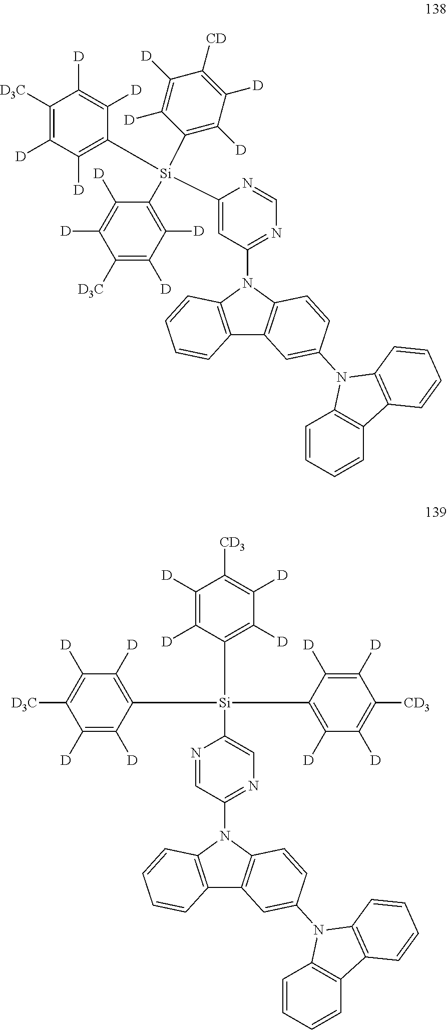

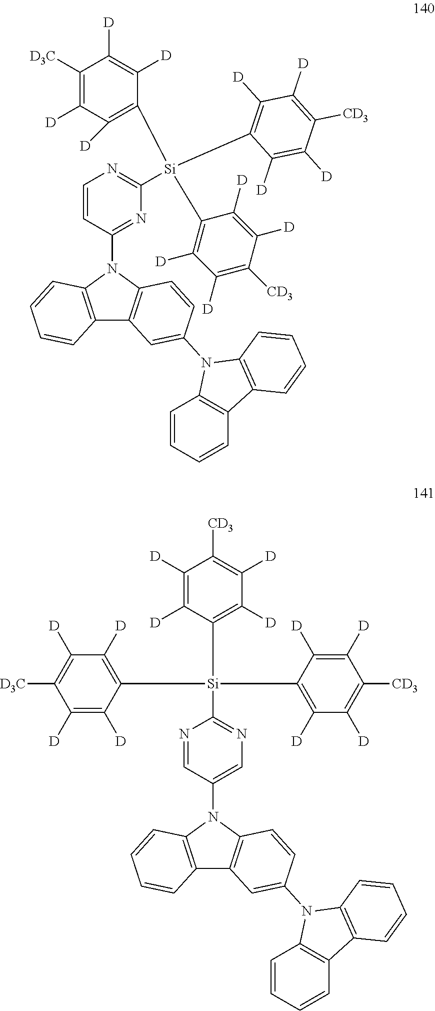 [SMILES: [2H]c1c([2H])c([Si](c2nccc(-n3c4ccccc4c4cc(-n5c6ccccc6c6ccccc65)ccc43)n2)(c2c([2H])c([2H])c(C([2H])([2H])[2H])c([2H])c2[2H])c2c([2H])c([2H])c(C([2H])([2H])[2H])c([2H])c2[2H])c([2H])c([2H])c1C([2H])([2H])[2H] ; [2H]c1c([2H])c([Si](c2ncc(-n3c4ccccc4c4cc(-n5c6ccccc6c6ccccc65)ccc43)cn2)(c2c([2H])c([2H])c(C([2H])([2H])[2H])c([2H])c2[2H])c2c([2H])c([2H])c(C([2H])([2H])[2H])c([2H])c2[2H])c([2H])c([2H])c1C([2H])([2H])[2H]]

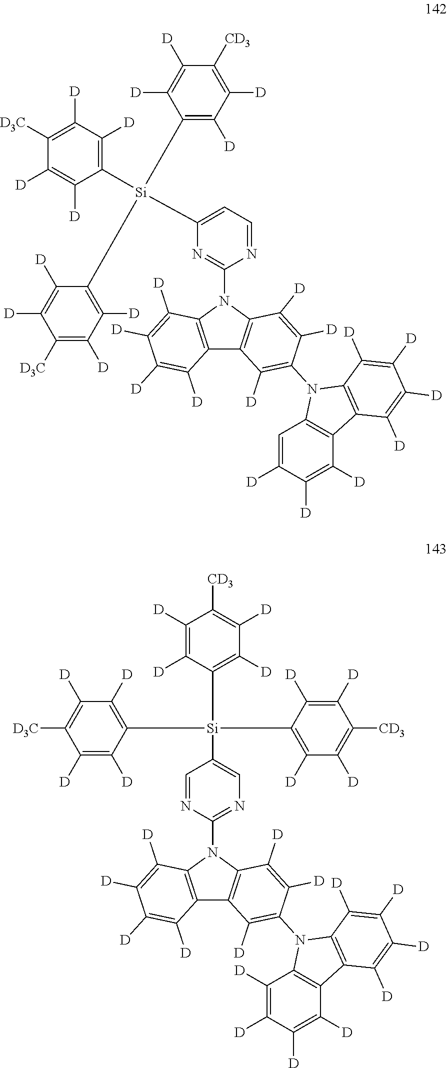

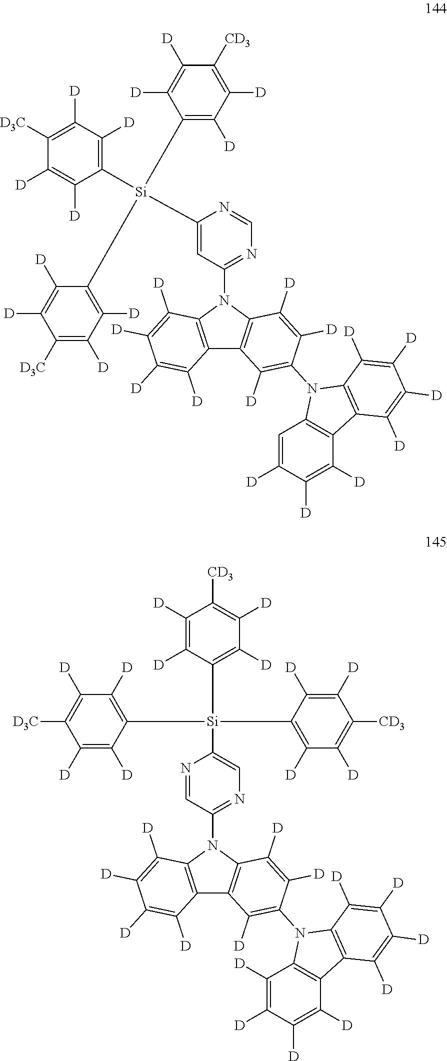

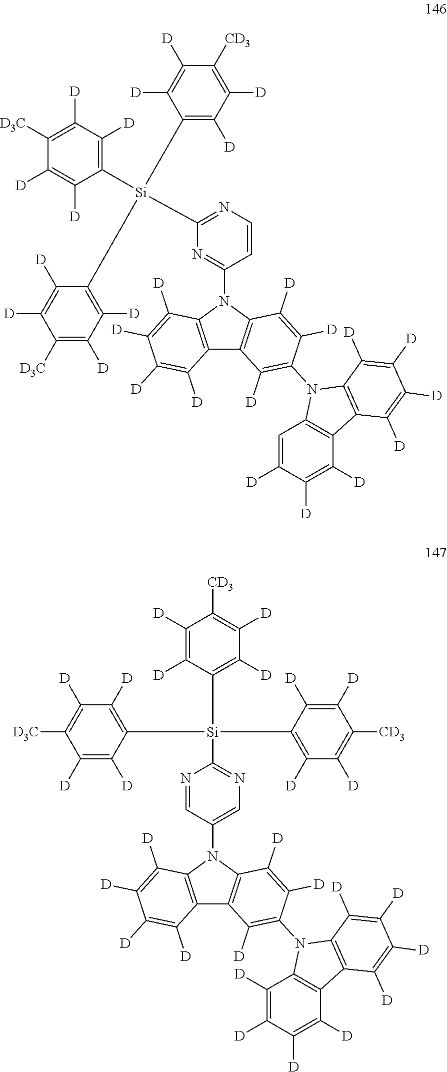

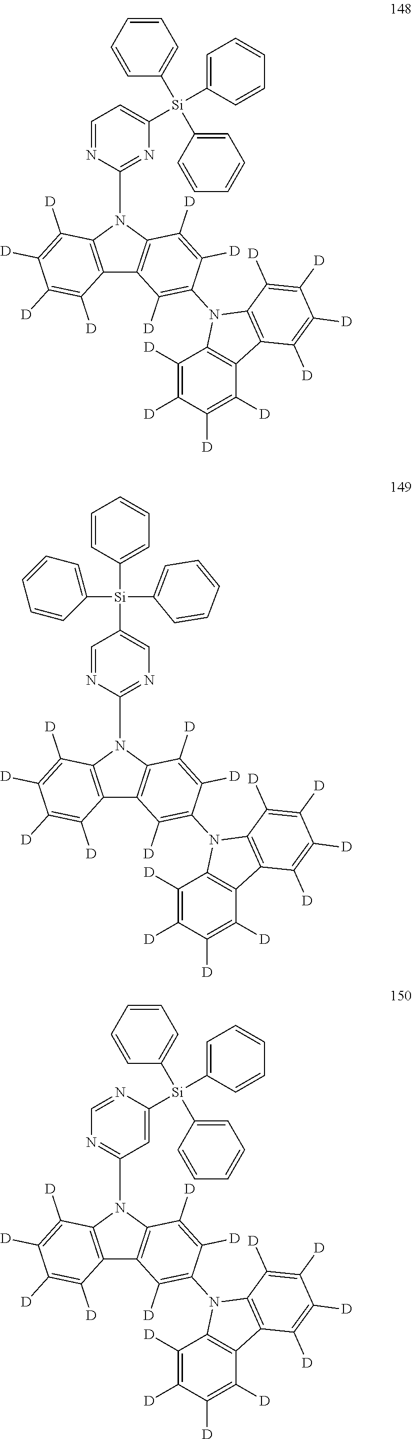

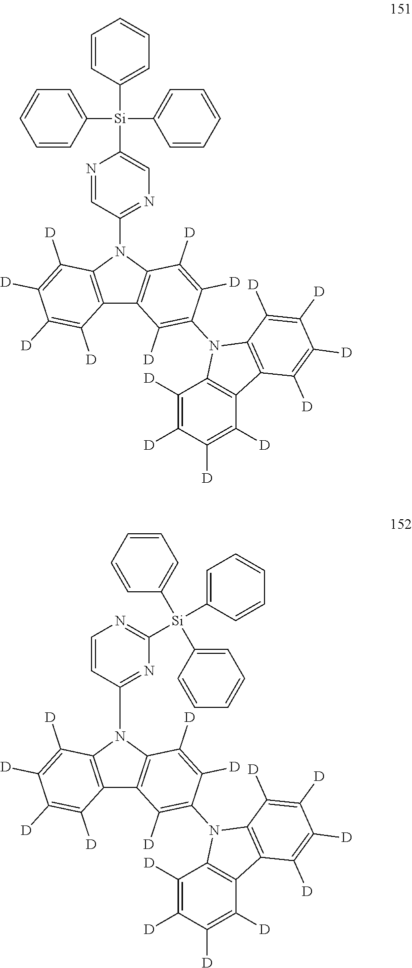 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cnc([Si](c2ccccc2)(c2ccccc2)c2ccccc2)cn1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccnc([Si](c2ccccc2)(c2ccccc2)c2ccccc2)n1]

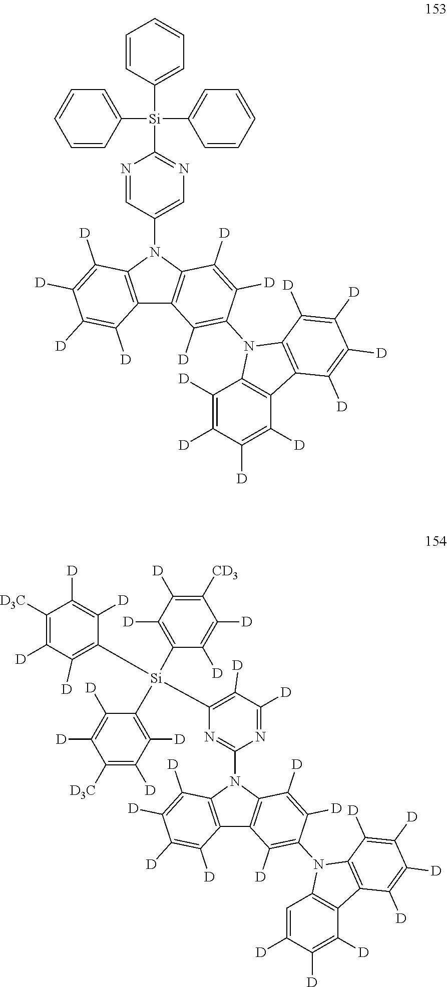 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cnc([Si](c2ccccc2)(c2ccccc2)c2ccccc2)nc1 ; [2H]c1cc2c(c([2H])c1[2H])c1c([2H])c([2H])c([2H])c([2H])c1n2-c1c([2H])c([2H])c2c(c1[2H])c1c([2H])c([2H])c([2H])c([2H])c1n2-c1nc([2H])c([2H])c([Si](c2c([2H])c([2H])c(C([2H])([2H])[2H])c([2H])c2[2H])(c2c([2H])c([2H])c(C([2H])([2H])[2H])c([2H])c2[2H])c2c([2H])c([2H])c(C([2H])([2H])[2H])c([2H])c2[2H])n1]

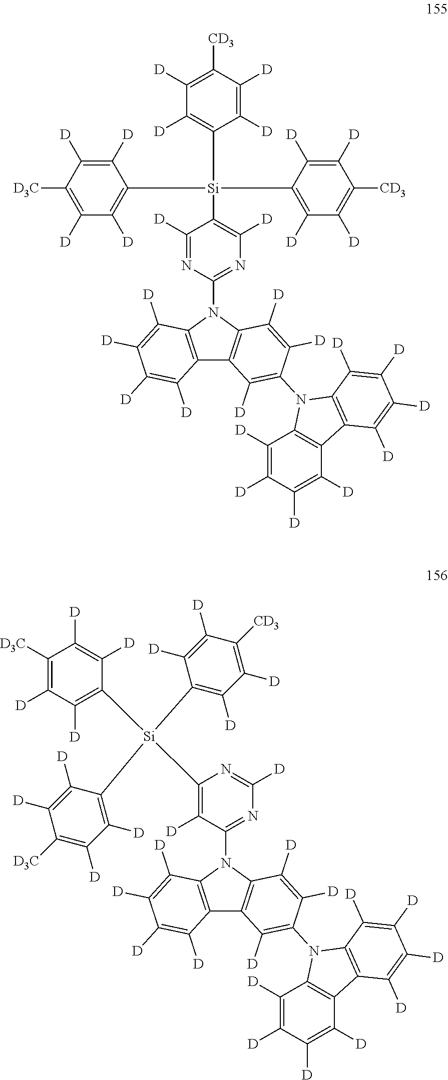

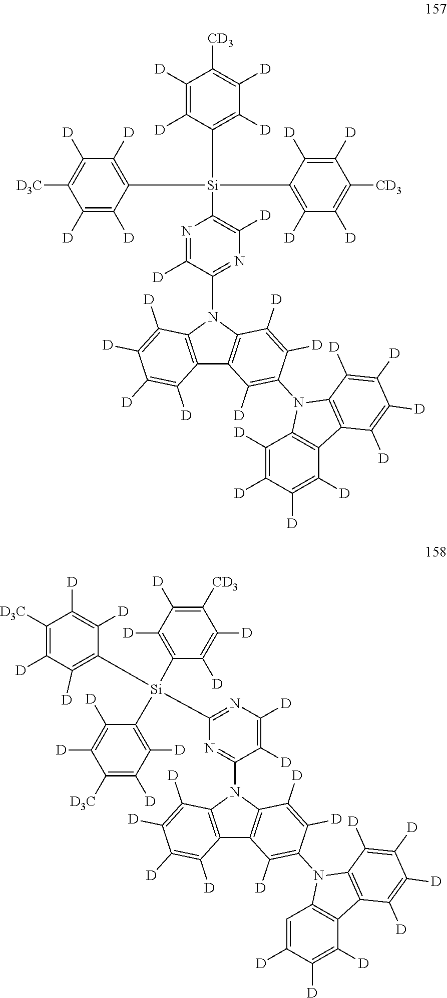

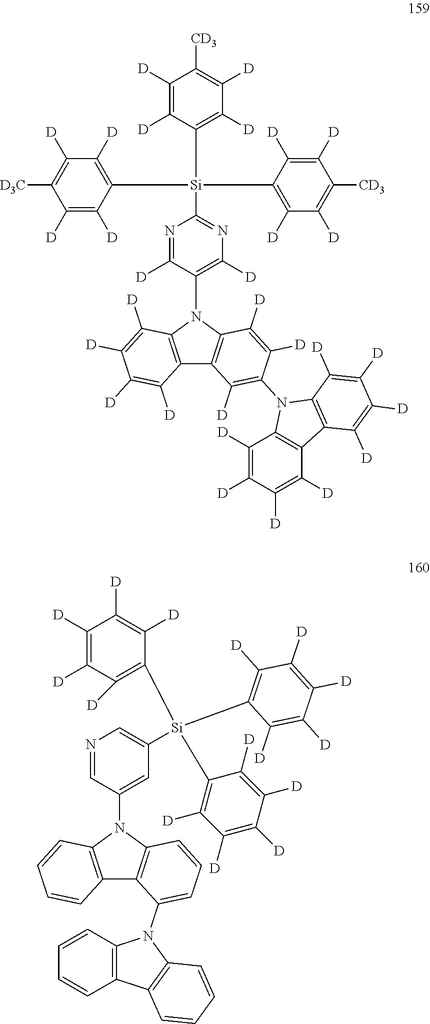 [SMILES: [2H]c1nc([Si](c2c([2H])c([2H])c(C([2H])([2H])[2H])c([2H])c2[2H])(c2c([2H])c([2H])c(C([2H])([2H])[2H])c([2H])c2[2H])c2c([2H])c([2H])c(C([2H])([2H])[2H])c([2H])c2[2H])nc([2H])c1-n1c2c([2H])c([2H])c([2H])c([2H])c2c2c([2H])c(-n3c4c([2H])c([2H])c([2H])c([2H])c4c4c([2H])c([2H])c([2H])c([2H])c43)c([2H])c([2H])c21 ; [2H]c1c([2H])c([2H])c([Si](c2cncc(-n3c4ccccc4c4c(-n5c6ccccc6c6ccccc65)cccc43)c2)(c2c([2H])c([2H])c([2H])c([2H])c2[2H])c2c([2H])c([2H])c([2H])c([2H])c2[2H])c([2H])c1[2H]]

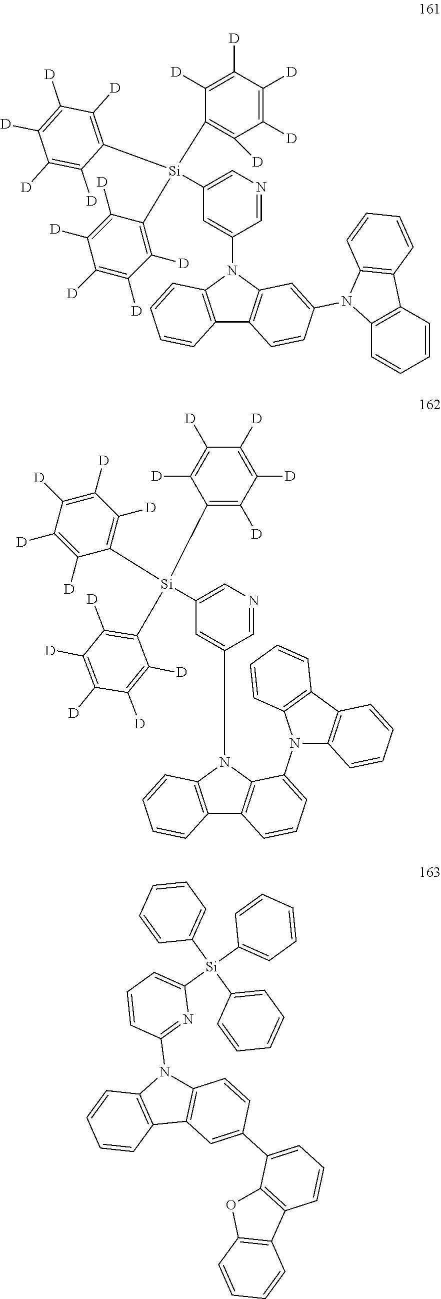

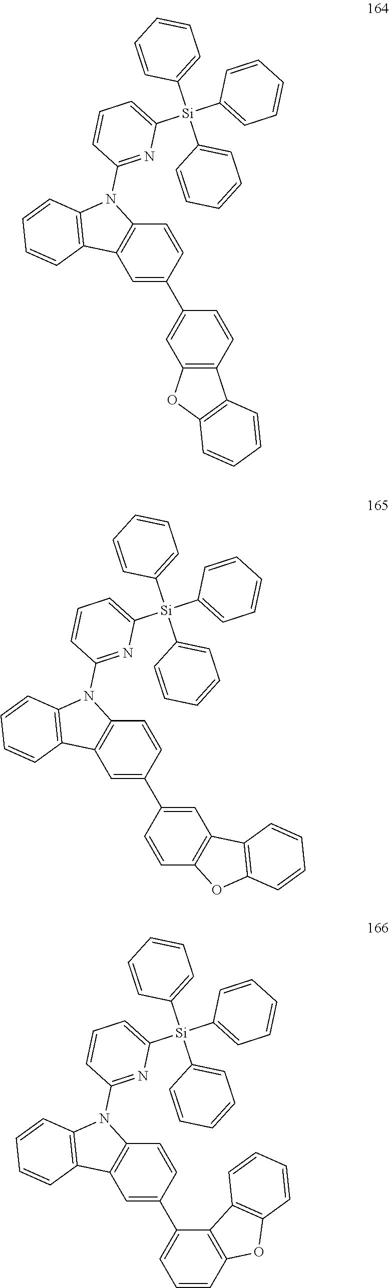 [SMILES: c1ccc([Si](c2ccccc2)(c2ccccc2)c2cccc(-n3c4ccccc4c4cc(-c5ccc6c(c5)oc5ccccc56)ccc43)n2)cc1 ; c1ccc([Si](c2ccccc2)(c2ccccc2)c2cccc(-n3c4ccccc4c4cc(-c5ccc6oc7ccccc7c6c5)ccc43)n2)cc1 ; c1ccc([Si](c2ccccc2)(c2ccccc2)c2cccc(-n3c4ccccc4c4cc(-c5cccc6oc7ccccc7c56)ccc43)n2)cc1]

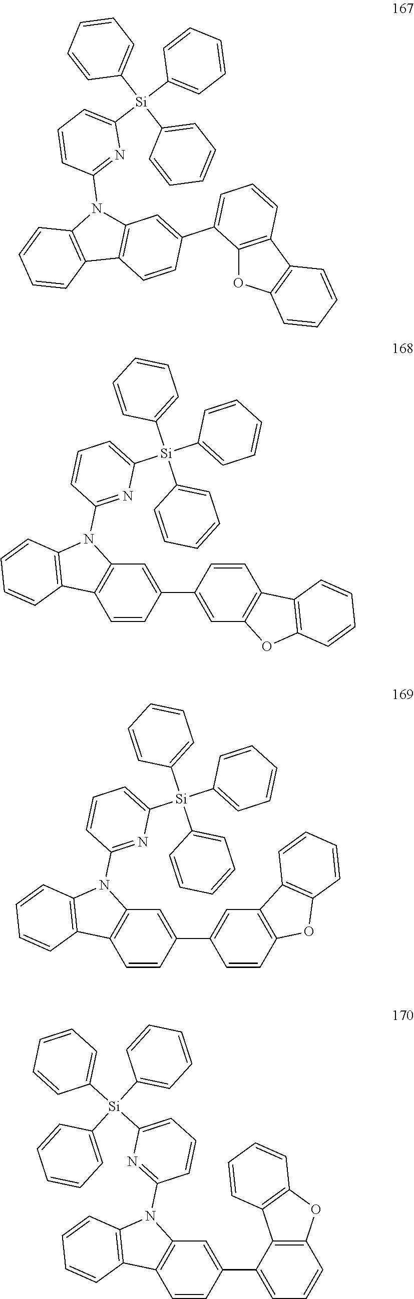 [SMILES: c1ccc([Si](c2ccccc2)(c2ccccc2)c2cccc(-n3c4ccccc4c4ccc(-c5cccc6c5oc5ccccc56)cc43)n2)cc1 ; c1ccc([Si](c2ccccc2)(c2ccccc2)c2cccc(-n3c4ccccc4c4ccc(-c5ccc6c(c5)oc5ccccc56)cc43)n2)cc1 ; c1ccc([Si](c2ccccc2)(c2ccccc2)c2cccc(-n3c4ccccc4c4ccc(-c5ccc6oc7ccccc7c6c5)cc43)n2)cc1 ; c1ccc([Si](c2ccccc2)(c2ccccc2)c2cccc(-n3c4ccccc4c4ccc(-c5cccc6oc7ccccc7c56)cc43)n2)cc1]

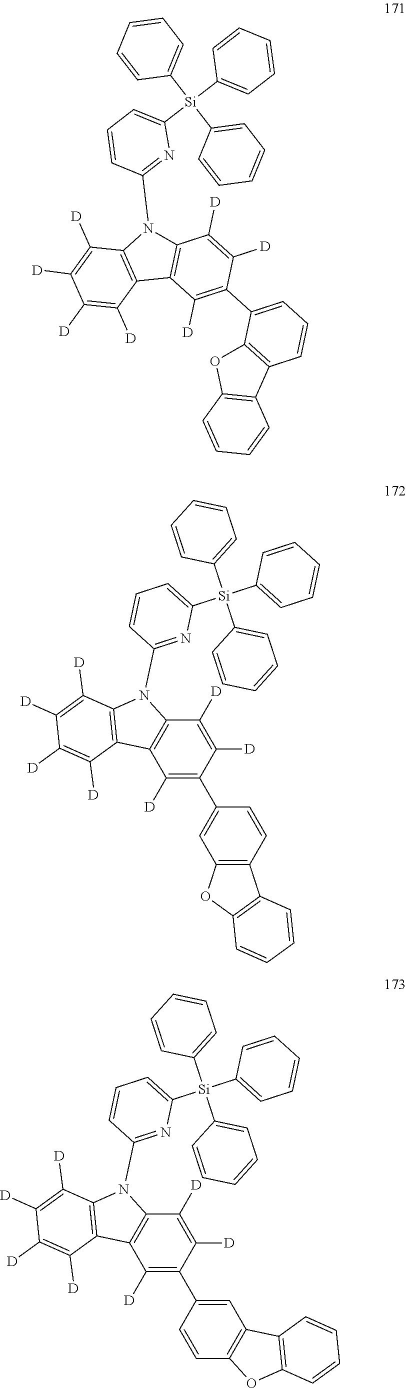 [SMILES: [2H]c1c([2H])c([2H])c2c(c1[2H])c1c([2H])c(-c3cccc4c3oc3ccccc34)c([2H])c([2H])c1n2-c1cccc([Si](c2ccccc2)(c2ccccc2)c2ccccc2)n1 ; [2H]c1c([2H])c([2H])c2c(c1[2H])c1c([2H])c(-c3ccc4c(c3)oc3ccccc34)c([2H])c([2H])c1n2-c1cccc([Si](c2ccccc2)(c2ccccc2)c2ccccc2)n1 ; [2H]c1c([2H])c([2H])c2c(c1[2H])c1c([2H])c(-c3ccc4oc5ccccc5c4c3)c([2H])c([2H])c1n2-c1cccc([Si](c2ccccc2)(c2ccccc2)c2ccccc2)n1]

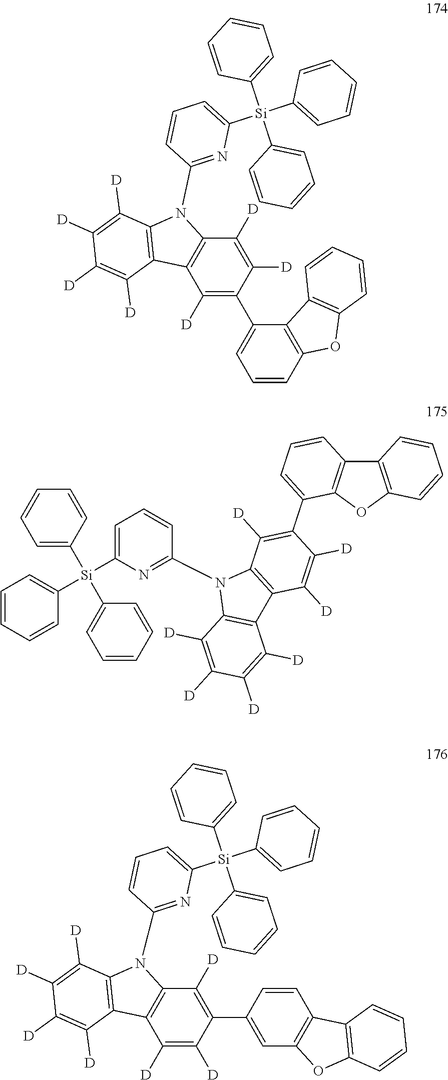 [SMILES: [2H]c1c([2H])c([2H])c2c(c1[2H])c1c([2H])c(-c3cccc4oc5ccccc5c34)c([2H])c([2H])c1n2-c1cccc([Si](c2ccccc2)(c2ccccc2)c2ccccc2)n1 ; [2H]c1c([2H])c([2H])c2c(c1[2H])c1c([2H])c([2H])c(-c3cccc4c3oc3ccccc34)c([2H])c1n2-c1cccc([Si](c2ccccc2)(c2ccccc2)c2ccccc2)n1 ; [2H]c1c([2H])c([2H])c2c(c1[2H])c1c([2H])c([2H])c(-c3ccc4c(c3)oc3ccccc34)c([2H])c1n2-c1cccc([Si](c2ccccc2)(c2ccccc2)c2ccccc2)n1]

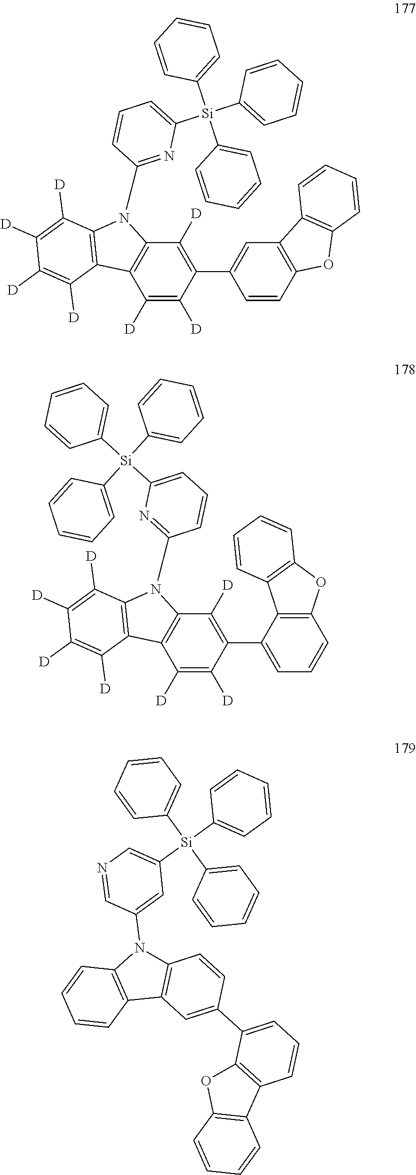 [SMILES: [2H]c1c([2H])c([2H])c2c(c1[2H])c1c([2H])c([2H])c(-c3ccc4oc5ccccc5c4c3)c([2H])c1n2-c1cccc([Si](c2ccccc2)(c2ccccc2)c2ccccc2)n1 ; [2H]c1c([2H])c([2H])c2c(c1[2H])c1c([2H])c([2H])c(-c3cccc4oc5ccccc5c34)c([2H])c1n2-c1cccc([Si](c2ccccc2)(c2ccccc2)c2ccccc2)n1 ; c1ccc([Si](c2ccccc2)(c2ccccc2)c2cncc(-n3c4ccccc4c4cc(-c5cccc6c5oc5ccccc56)ccc43)c2)cc1]

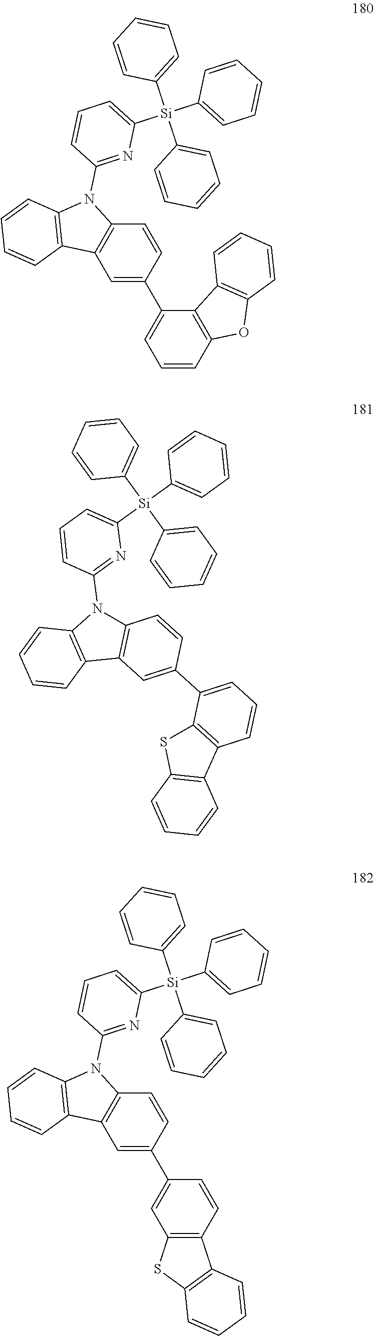 [SMILES: c1ccc([Si](c2ccccc2)(c2ccccc2)c2cccc(-n3c4ccccc4c4cc(-c5cccc6oc7ccccc7c56)ccc43)n2)cc1 ; c1ccc([Si](c2ccccc2)(c2ccccc2)c2cccc(-n3c4ccccc4c4cc(-c5cccc6c5sc5ccccc56)ccc43)n2)cc1 ; c1ccc([Si](c2ccccc2)(c2ccccc2)c2cccc(-n3c4ccccc4c4cc(-c5ccc6c(c5)sc5ccccc56)ccc43)n2)cc1]

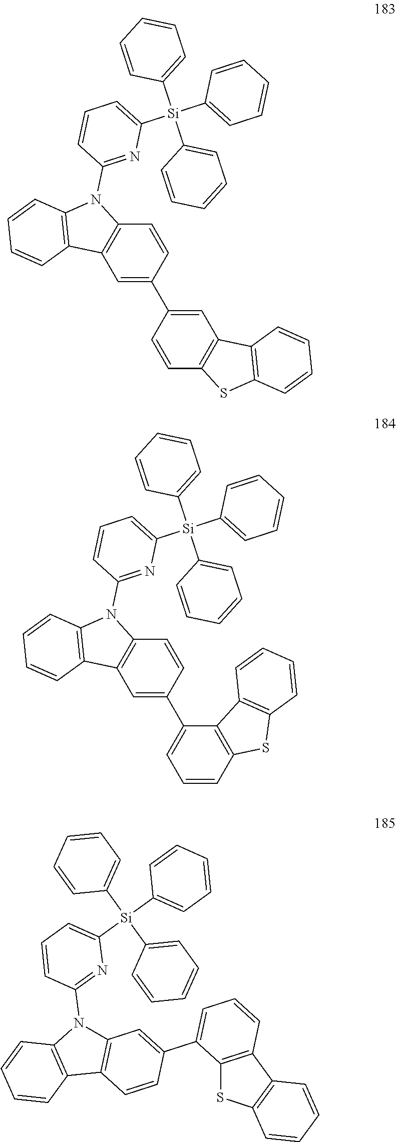 [SMILES: c1ccc([Si](c2ccccc2)(c2ccccc2)c2cccc(-n3c4ccccc4c4cc(-c5ccc6sc7ccccc7c6c5)ccc43)n2)cc1 ; c1ccc([Si](c2ccccc2)(c2ccccc2)c2cccc(-n3c4ccccc4c4cc(-c5cccc6sc7ccccc7c56)ccc43)n2)cc1 ; c1ccc([Si](c2ccccc2)(c2ccccc2)c2cccc(-n3c4ccccc4c4ccc(-c5cccc6c5sc5ccccc56)cc43)n2)cc1]

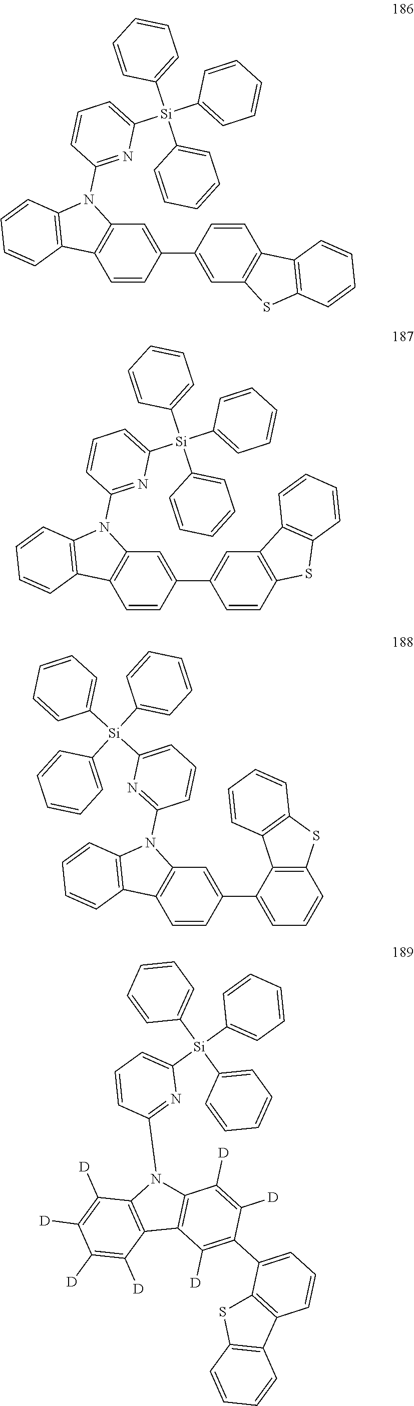

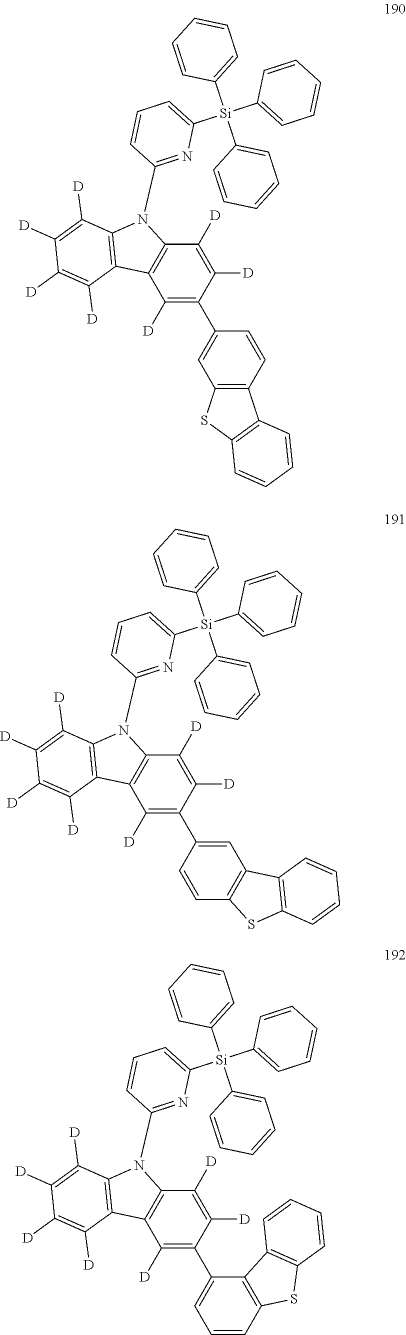 [SMILES: [2H]c1c([2H])c([2H])c2c(c1[2H])c1c([2H])c(-c3ccc4c(c3)sc3ccccc34)c([2H])c([2H])c1n2-c1cccc([Si](c2ccccc2)(c2ccccc2)c2ccccc2)n1 ; [2H]c1c([2H])c([2H])c2c(c1[2H])c1c([2H])c(-c3ccc4sc5ccccc5c4c3)c([2H])c([2H])c1n2-c1cccc([Si](c2ccccc2)(c2ccccc2)c2ccccc2)n1 ; [2H]c1c([2H])c([2H])c2c(c1[2H])c1c([2H])c(-c3cccc4sc5ccccc5c34)c([2H])c([2H])c1n2-c1cccc([Si](c2ccccc2)(c2ccccc2)c2ccccc2)n1]

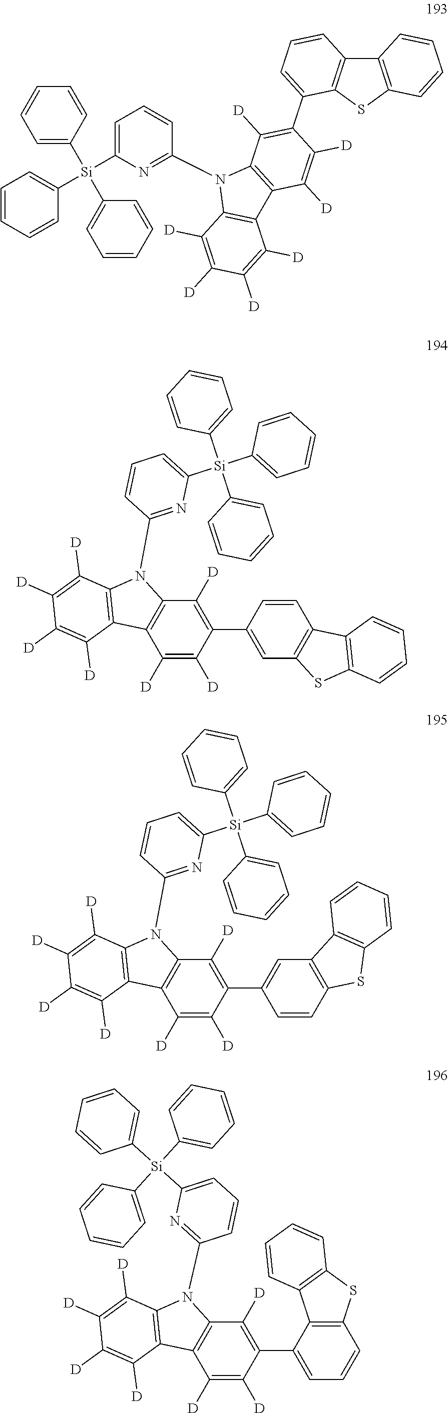

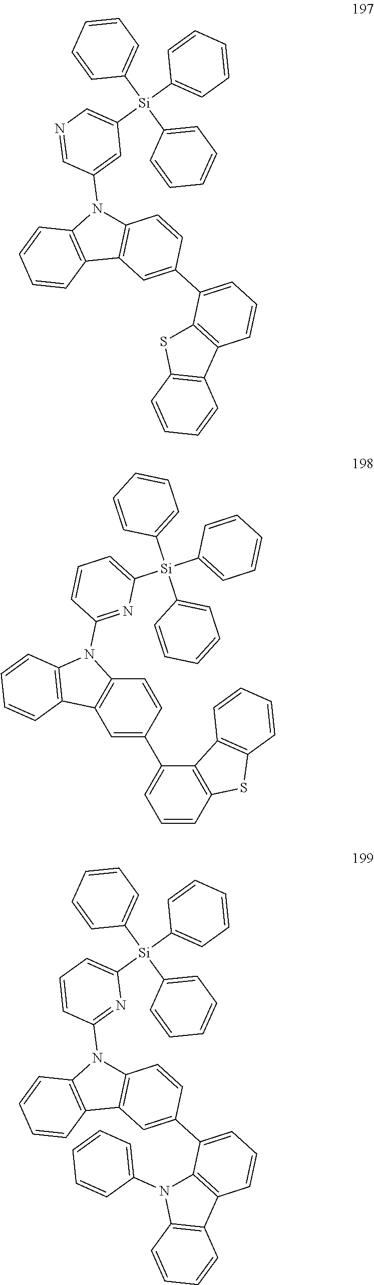 [SMILES: c1ccc([Si](c2ccccc2)(c2ccccc2)c2cncc(-n3c4ccccc4c4cc(-c5cccc6c5sc5ccccc56)ccc43)c2)cc1 ; c1ccc([Si](c2ccccc2)(c2ccccc2)c2cccc(-n3c4ccccc4c4cc(-c5cccc6sc7ccccc7c56)ccc43)n2)cc1 ; c1ccc(-n2c3ccccc3c3cccc(-c4ccc5c(c4)c4ccccc4n5-c4cccc([Si](c5ccccc5)(c5ccccc5)c5ccccc5)n4)c32)cc1]

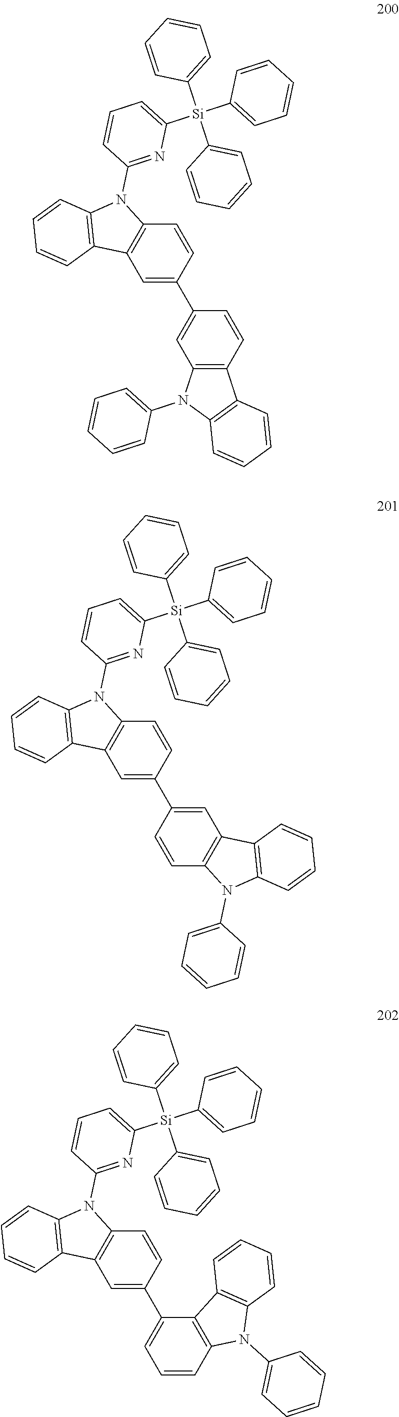 [SMILES: c1ccc(-n2c3ccccc3c3ccc(-c4ccc5c(c4)c4ccccc4n5-c4cccc([Si](c5ccccc5)(c5ccccc5)c5ccccc5)n4)cc32)cc1 ; c1ccc(-n2c3ccccc3c3cc(-c4ccc5c(c4)c4ccccc4n5-c4cccc([Si](c5ccccc5)(c5ccccc5)c5ccccc5)n4)ccc32)cc1 ; c1ccc(-n2c3ccccc3c3c(-c4ccc5c(c4)c4ccccc4n5-c4cccc([Si](c5ccccc5)(c5ccccc5)c5ccccc5)n4)cccc32)cc1]

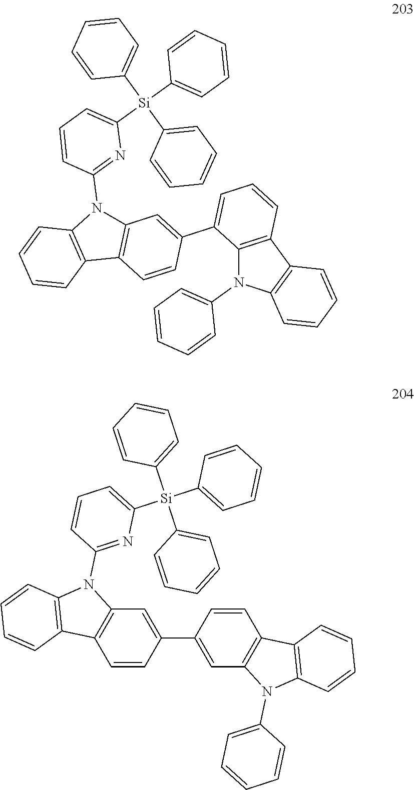 [SMILES: c1ccc(-n2c3ccccc3c3cccc(-c4ccc5c6ccccc6n(-c6cccc([Si](c7ccccc7)(c7ccccc7)c7ccccc7)n6)c5c4)c32)cc1 ; c1ccc(-n2c3ccccc3c3ccc(-c4ccc5c6ccccc6n(-c6cccc([Si](c7ccccc7)(c7ccccc7)c7ccccc7)n6)c5c4)cc32)cc1]

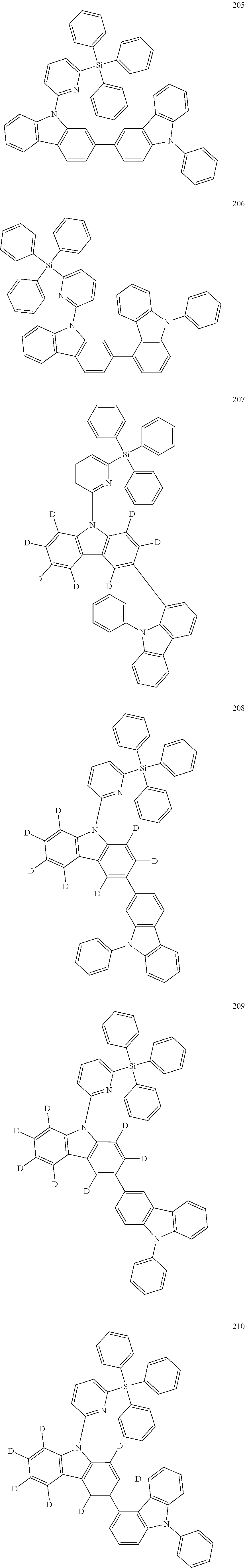

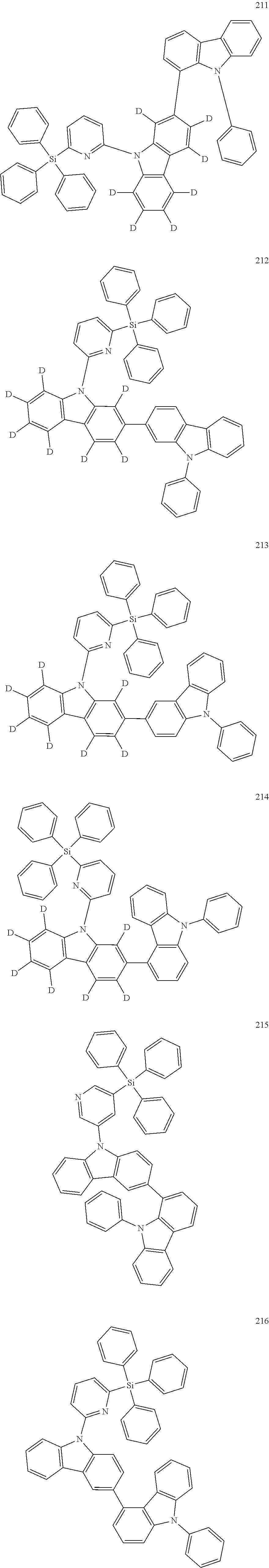

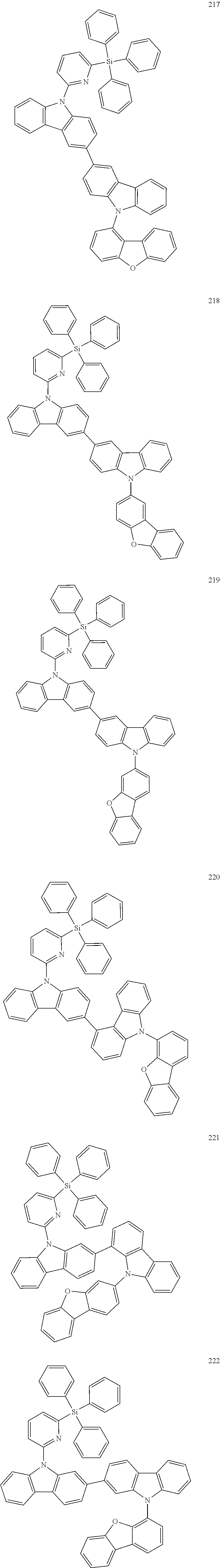

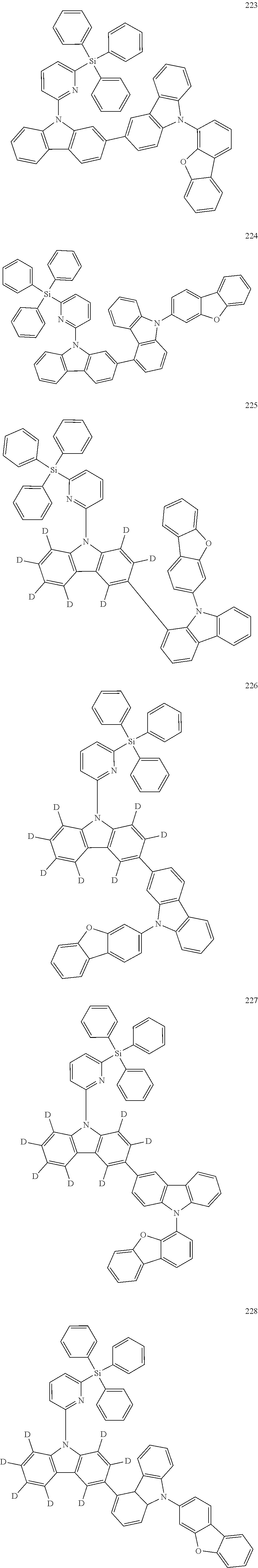

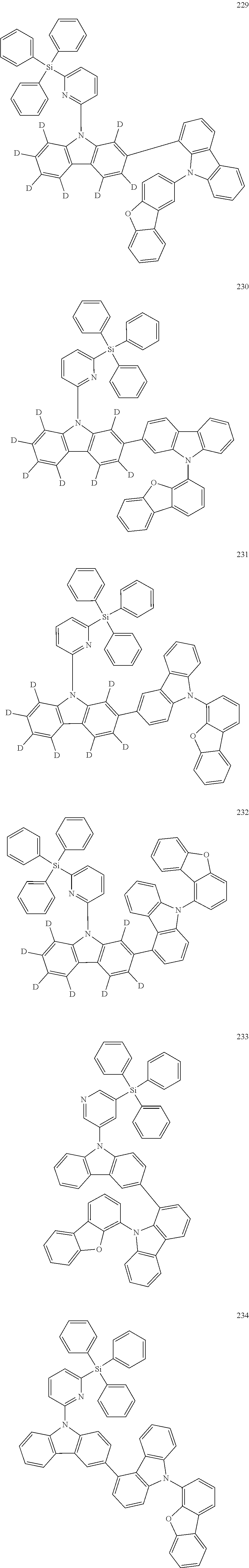

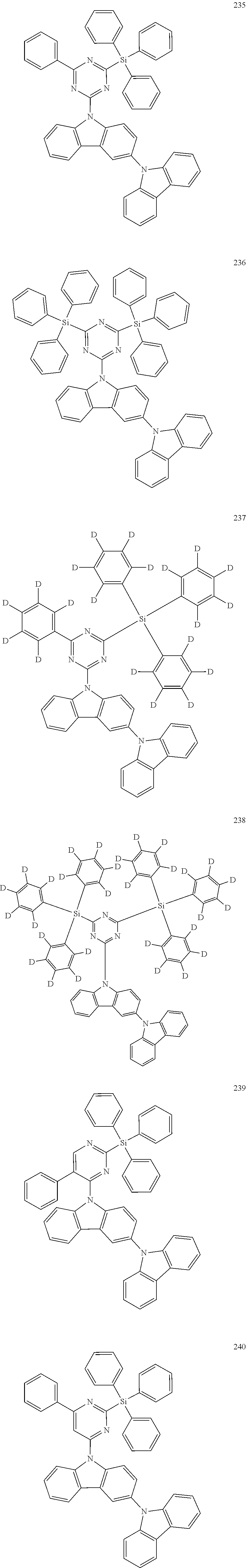

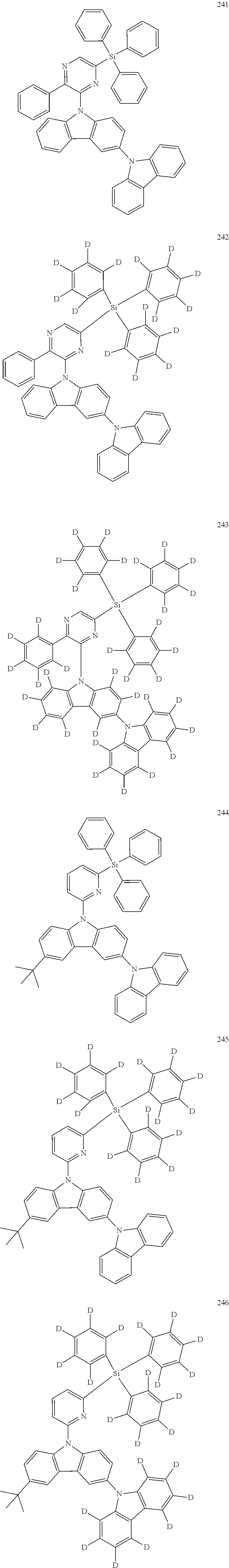

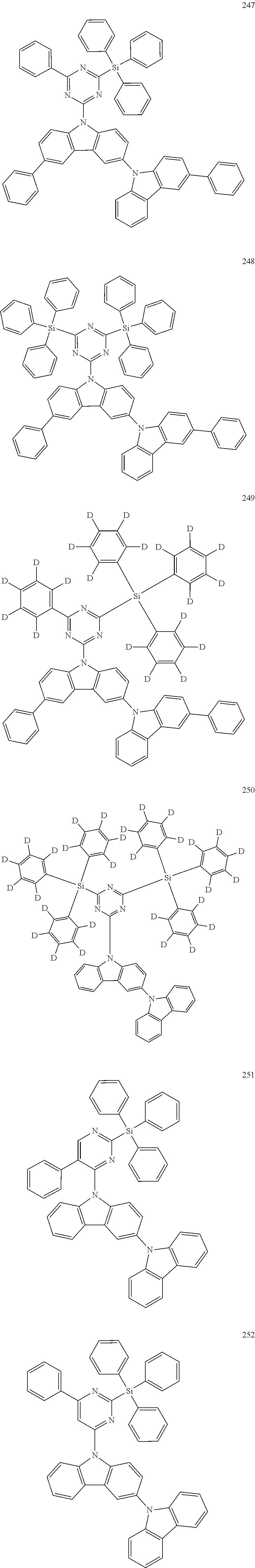

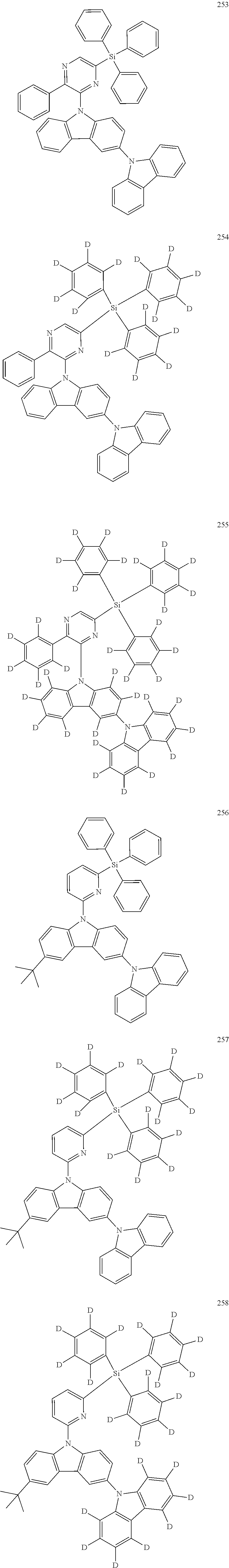

20. An electronic apparatus configured to display an image, the electronic apparatus comprising:
a display device; and
a control part configured to control the display device,
wherein, the display device includes:
a base layer;
a circuit layer disposed on the base layer; and
a display element layer disposed on the circuit layer, the display element layer including a light-emitting element,
wherein the light-emitting element includes a first electrode, and a second electrode facing the first electrode, and at least one functional layer between the first electrode and the second electrode, the at least one functional layer comprising a nitrogen-containing compound represented by any one of Formula 1-1 to Formula 1-4 below: 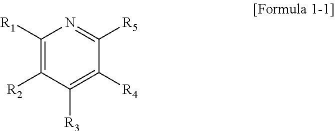
where, in Formula 1-1,
R₁ to R₅ are each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
any one of R₁ to R₅ is a substituent represented by Formula 2, and
at least one of R₁ to R₅ is a substituent represented by Formula 3; 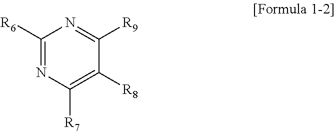
where, in Formula 1-2,
R₆ to R₉ are each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
any one of R₆ to R₉ is a substituent represented by Formula 2, and
at least one of R₆ to R₉ is a substituent represented by Formula 3; 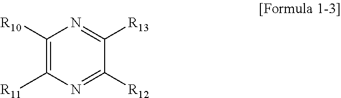
where, in Formula 1-3 above,
R₁₀ to R₁₃ are each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, a substituted or unsubstituted heteroaryl group having 2 to 30 ring-forming carbons, a substituent represented by Formula 2, or a substituent represented by Formula 3,
any one of R₁₀ to R₁₃ is a substituent represented by Formula 2, and
at least one of R₁₀ to R₁₃ is a substituent represented by Formula 3; 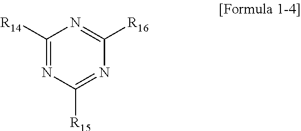
where, in Formula 1-4,
R₁₄ to R₁₆ are each independently a hydrogen atom, a deuterium atom, a halogen atom, a cyano group, a substituted or unsubstituted silyl group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons,
any one of R₁₄ to R₁₆ is a substituent represented by Formula 2, and
at least one of R₁₄ to R₁₆ is a substituent represented by Formula 3; 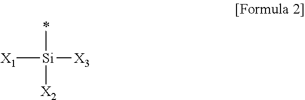
wherein, in Formula 2,
X₁ to X₃ are each independently a hydrogen atom, a deuterium atom, a halogen atom, a cyano group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and
*— is a portion to which any one of Formula 1-1 to Formula 1-4 is connected; 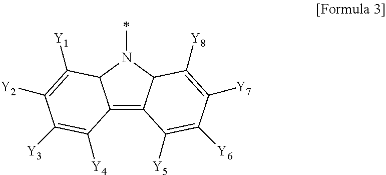
where, in Formula 3,
any one of Y₁ to Y₈ is a substituent represented by Formula 4,
a remainder of Y₁ to Y₈ are each independently a hydrogen atom, a deuterium atom, a halogen atom, a cyano group, a substituted or unsubstituted alkyl group having 1 to 20 carbons, or a substituted or unsubstituted aryl group having 6 to 30 ring-forming carbons, and
*— is a portion to which any one of Formula 1-1 to Formula 1-4 is connected; 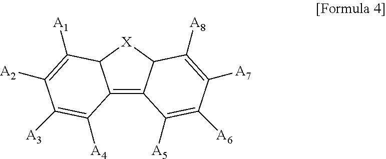
where, in Formula 4,
X is O, S, or NA₉,
any one of A₁ to A₉ is a substituent represented by Formula 3, and
a remainder of A₁ to A₉ are each independently a hydrogen atom, a deuterium atom, a halogen atom, a cyano group, a substituted or unsubstituted alkyl group having 1 to 20 carbons, or a substituted or unsubstituted aryl group having 6 to 30 ring-forming carbons.
